(19) United States
(12) Patent Application Publication
(10) Pub. No.: US 2016/0026083 A1
(43) Pub. Date: Jan. 28, 2016

(54) PATTERN FORMING METHOD AND METHOD FOR MANUFACTURING ELECTRONIC DEVICE

(71) Applicant: FUJIFILM CORPORATION, Tokyo (JP)

(72) Inventors: Naohiro TANGO, Haibara-gun (JP); Yuichiro ENOMOTO, Haibara-gun (JP)

(73) Assignee: FUJIFILM CORPORATION, Tokyo (JP)

(21) Appl. No.: 14/873,700

(22) Filed: Oct. 2, 2015

Related U.S. Application Data
(63) Continuation of application No. PCT/JP2014/058949, filed on Mar. 27, 2014.

(30) Foreign Application Priority Data
Apr. 5, 2013 (JP) 2013-080006

(51) Int. Cl. G03F 7/16; G03F 7/32; G03F 7/20

(52) U.S. Cl. CPC G03F 7/16; G03F 7/2041; G03F 7/322; G03F 7/20; G03F 7/325

(57) ABSTRACT

The present invention has an object to provide a pattern forming method, in which even when a pattern which is fine and has a high aspect ratio is formed, the collapse or peeling of the pattern is inhibited; a method for manufacturing an electronic device, including the pattern forming method; and an electronic device manufactured by the manufacturing method. The pattern forming method of the present invention includes an adhesion aiding layer forming step of forming an adhesion aiding layer containing a polymerizable group and having a light transmittance of 80% or more at a wavelength of 193 nm on a substrate; a resist film forming step of applying a radiation-sensitive resin composition onto the adhesion aiding layer to form a resist film; an exposing step of exposing the resist film; and a developing step of developing the exposed resist film to form a pattern.

### CROSS-REFERENCE TO RELATED APPLICATIONS

This application is a continuation of PCT International Application No. PCT/JP2014/058949 filed on Mar. 27, 2014, which claims priority under 35 U.S.C. §119(a) to Japanese Patent Application No. 2013-080006 filed on Apr. 5, 2013. Each of the above applications is hereby expressly incorporated by reference, in its entirety, into the present application.

### BACKGROUND OF THE INVENTION

The present invention relates to a pattern forming method, which is used for a process for manufacturing a semiconductor such as an IC, for the manufacture of a circuit board for a liquid crystal, a thermal head, or the like, and for a lithography process of photofabrication in addition to these.

After resists for a KrF excimer laser (248 nm) were developed, a pattern forming method using chemical amplification has been used in order to compensate for a decrease in sensitivity due to light absorption.

For example, JP2008-292975A discloses a pattern forming method using a developing liquid containing an organic solvent, and describes that high-precision fine patterns can be stably formed.

### SUMMARY OF THE INVENTION

On the other hand, recently, there has been a demand for the manufacture of a fine wiring in order to improve the performance of electronic equipment, and accordingly, it has also been demanded to form a pattern having a higher aspect ratio.

However, in the case where a pattern is fine and has an aspect ratio, there has been a problem in that the collapse or peeling of the pattern after the development occurs.

The present inventors have carried out pattern formation in accordance with the method described in JP2008-292975A. Thus, they have found that although it was possible to carry out pattern formation at a level which has been required in the prior art, if formation of a pattern which is finer and has a higher aspect than the level which has recently been required is carried out, collapse, peeling, or the like of the pattern occurs.

The present invention has been made in view of the above-described circumstances, and has an object to provide a pattern forming method, in which the collapse or peeling of the pattern is inhibited even when a pattern which is fine and has a high aspect ratio is formed.

In addition, the present invention has other objects to provide a method for manufacturing an electronic device, including the pattern forming method, and an electronic device manufactured by the manufacturing method.

The present inventors have conducted extensive studies on the problems of the prior art, and as a result, they have found that the problems can be solved by interposing an adhesion aiding layer having a predetermined functional group and exhibiting predetermined optical characteristics between a substrate and a pattern.

That is, they have found that the objects can be accomplished by the following configurations.

(1) A pattern forming method including:
an adhesion aiding layer forming step of forming an adhesion aiding layer containing a polymerizable group and having a light transmittance of 80% or more at a wavelength of 193 nm on a substrate;
a resist film forming step of applying a radiation-sensitive resin composition onto the adhesion aiding layer to form a resist film;
an exposing step of exposing the resist film; and
a developing step of developing the exposed resist film to form a pattern.

(2) The pattern forming method as described in (1), further including an antireflection film forming step of forming an antireflection film on the substrate before the adhesion aiding layer forming step, in which
the adhesion aiding layer forming step is a step of forming the adhesion aiding layer on the antireflection film.

(3) The pattern forming method as described in (1) or (2), in which the developing step includes a step of carrying out development using a developing liquid containing an organic solvent.

(4) The pattern forming method as described in (3), in which the developing step further includes a step of carrying out development using an aqueous alkali solution.

(5) The pattern forming method as described in any one of (1) to (4), in which the thickness of the adhesion aiding layer is from 1 nm to 10 nm.

(6) The pattern forming method as described in any one of (1) to (5), in which the exposing step is a step of exposing the resist film through an immersion liquid.

(7) A method for manufacturing an electronic device, including the pattern forming method as described in any one of (1) to (6).

(8) An electronic device manufactured by the method for manufacturing an electronic device as described in (7).

According to the present invention, a pattern forming method, in which even when a pattern which is fine and has a high aspect ratio is formed, the collapse or peeling of the pattern is inhibited can be provided.

Furthermore, according to the present invention, a method for manufacturing an electronic device, including the pattern forming method, and an electronic device manufactured by the manufacturing method can be provided.

### DETAILED DESCRIPTION OF THE INVENTION

Hereinafter, embodiments of the present invention will be described in detail.

In citations for a group (atomic group) in the present specification, when the group is denoted without specifying whether it is substituted or unsubstituted, the group includes both a group having no substituent and a group having a substituent. For example, an “alkyl group” includes not only an alkyl group having no substituent (unsubstituted alkyl group), but also an alkyl group having a substituent (substituted alkyl group).

“Actinic ray(s)” or “radiation” in the present specification means, for example, a bright line spectrum of a mercury lamp or the like, far ultraviolet rays represented by an excimer laser, extreme ultraviolet rays (EUV light), X-rays, electron beams (EB), or the like. In addition, in the present invention, light means actinic rays or radiation.

Furthermore, “exposure” in the present specification includes, unless otherwise specified, not only exposure by a mercury lamp, far ultraviolet rays represented by an excimer laser, extreme ultraviolet rays, X-rays, EUV light, or the like, but also writing by particle rays such as electron beams and ion beams.

Incidentally, in the present specification “˜ to ˜” is used to mean a range including the numeral values represented before and after “˜ to ˜” as a lower limit value and an upper limit value, respectively.

Furthermore, in the present specification, “(meth)acrylate” represents an acrylate or a methacrylate, “(meth)acryl” represents an acryl or a methacryl, and “(meth)acryloyl” represents an acryloyl or a methacryloyl.

In one aspect of the present invention, an adhesion aiding layer may be provided between a substrate and a pattern shape resist film. More specifically, an adhesion aiding layer having a polymerizable group on a substrate and exhibiting predetermined optical characteristics may be provided. By forming a resist film on the adhesion aiding layer, the polymerizable group in the adhesion aiding layer is bonded to the resist film to increase the adhesion therebetween, and as a result, occurrence of the collapse or peeling of the pattern is inhibited. In addition, from the viewpoint that the adhesion aiding layer is excellent in transmittance, the adhesion aiding layer does not cause an adverse effect on an optical image in the film in any case and a good pattern shape or the like is maintained, thereby further improving the adhesion.

In particular, in the case where a resist film is developed by an organic solvent development to form a negative type pattern, since a resist film which is an organic material is generally developed with an organic solvent, the mutual affinity is high, and thus, there is a concern about problems such as pattern collapse. However, according to the present invention, such a concern can be lessened.

In addition, in a so-called double development in which alkali development and organic solvent development are carried out, there is a concern that the alkali development and the organic solvent development have different chemical states and properties on the left and right sides of the line patterns, distortions can occur in the patterns, and therefore, pattern collapse easily occurs. However, in the present invention, even in such a case, the peeling or collapse of the pattern can further be reduced.

### First Embodiment

The pattern forming method of a first embodiment of the present invention includes the following four steps:
(1) an adhesion aiding layer forming step of forming an adhesion aiding layer containing a polymerizable group and having a light transmittance of 80% or more at a wavelength of 193 nm on a substrate;
(2) a resist film forming step of applying a radiation-sensitive resin composition onto the adhesion aiding layer to form a resist film;
(3) an exposing step of exposing the resist film; and
(4) a developing step of developing the exposed resist film to form a pattern.

Hereinafter, the respective steps will be described in detail.

[Step (1): Adhesion Aiding Layer Forming Step]

The step (1) is a step of forming an adhesion aiding layer containing a polymerizable group and having a light transmittance of 80% or more at a wavelength of 193 nm on a substrate. It is considered that the polymerizable group in the adhesion aiding layer formed by the present step forms a chemical or physical bond between the substrate and the resist film, as described above, and as a result, excellent adhesion between the resist film and the substrate is expressed.

The adhesion aiding layer has a light transmittance of 80% or more at a wavelength of 193 nm across the layer, and from the viewpoint of a less adverse effect of the adhesion aiding layer on the optical image in the film, the light transmittance is preferably 90% or more.

However, with respect to a method for measuring the transmittance, for example, the transmittance is measured by applying a composition for forming an adhesion aiding layer as described later onto a transparent substrate prepared for measurement, followed by carrying out a heating treatment to form a film, and irradiating the film with light at a wavelength of 193 nm.

The adhesion aiding layer has a polymerizable group. More specifically, a material (particularly preferably a resin) for forming the adhesion aiding layer has a polymerizable group.

The type of the polymerizable group is not particularly limited, and examples thereof include a (meth)acryloyl group, an epoxy group, an oxetanyl group, a maleimide group, an itaconic ester group, a crotonic ester group, an isocrotonic ester group, a maleic ester group, a styryl group, a vinyl group, an acrylamide group, and a methacrylamide group. Among these, a (meth)acryloyl group, an epoxy group, an oxetanyl group, and a maleimide group are preferred, and a (meth)acryloyl group is more preferred.

The thickness of the adhesion aiding layer is not particularly limited, but in order for a higher-precision fine pattern to be formed, the thickness is preferably from 1 nm to 100 nm, more preferably from 1 nm to 50 nm, still more preferably from 1 nm to 10 nm, and particularly preferably from 1 nm to 5 nm.

A method for forming the adhesion aiding layer is not particularly limited, and examples thereof include a method (application method) in which a composition for forming an adhesion aiding layer is applied onto a substrate, followed by carrying out a curing treatment, if desired, to form the adhesion aiding layer, and a method in which an adhesion aiding layer is formed on a temporary support and the adhesion aiding layer is transferred to a substrate. Among these, the application method is preferred from the viewpoint of excellent productivity.

Hereinafter, an embodiment using the application method will be described in detail.

First, members and materials used in the application method will be described in detail, and subsequently, the order thereof will be described in detail.

(Substrate)

The substrate used in the present invention is not particularly limited, and a substrate generally used in a process for manufacturing an inorganic substrate such as silicon, SiN, and SiO₂, an application-based inorganic substrate such as Spin on Glass (SOG), or a semiconductor such as an IC, or a process for manufacturing a circuit board such as a liquid crystal and a thermal head, and further, a lithography process for photofabrication in addition to these can be used.

Incidentally, in the pattern forming method of the present invention, a stepped substrate can be used as a substrate in fine processing in an ion implantation application or the like. The stepped substrate refers to a substrate on which at least one stepped shape is formed.

(Composition for Forming Adhesion Aiding Layer)

The composition for forming an adhesion aiding layer includes the materials for forming an adhesion aiding layer.

It is preferable that the composition for forming an adhesion aiding layer includes a compound having a polymerizable group (hereinafter appropriately referred to a compound A). The definition of the polymerizable group is as described above.

The number of the polymerizable groups in the compound A is not particularly limited, but from the viewpoint that many polymerizable groups are contained in the adhesion aiding layer, the number is preferably 2 or more, more preferably from 2 to 20, and still more preferably from 2 to 10.

One of suitable embodiments of the compound A is a compound (A-1) represented by (Formula 1), which has a value (Z) of the relationship formula among the number of carbon atoms, the number of oxygen atoms, and the total number of the atoms of 3.8 or more, and a molecular weight of 400 or more.

(Total number of the atoms)/(Number of carbon atoms−Number of oxygen atoms) (Formula 1)

The compound (A-1) has a molecular weight of 400 or more, and may be either a low molecular compound or a polymer, among which the polymer is preferred. The molecular weight is preferably 500 or more, more preferably 1000 or more, and still more preferably 3000 or more. The upper limit of the molecular weight is preferably 200000 or less, more preferably 100000 or less, and still more preferably 50000 or less. By setting the molecular weight to 400 or more, the volatilization of the component can be inhibited.

In the compound (A-1), the value (Z) represented by (Formula 1), of the relationship formula among the number of carbon atoms, the number of oxygen atoms, and the total number of the atoms, is 3.8 or more. The value of (Formula 1) is preferably 4.0 or more, more preferably 4.5 or more, and most preferably 5.0 or more.

The upper limit value is not specifically defined, and but can be set to, for example, 20 or less.

The compound (A-1) is preferably one having a small content of aromatic groups, and in the case of the polymer, the content of the repeating units having an aromatic group is preferably 50% by mole or less, more preferably 30% by mole or less, and still more preferably 10% by mole or less. It is particularly preferable that the compound (A-1) substantially does not have an aromatic group.

Examples of suitable embodiments of the compound (A-1) include polyfunctional (meth)acrylates having a plurality (particularly 2 to 10) of (meth)acryloyl groups.

Examples of the polyfunctional (meth)acrylate include polyethylene glycol di(meth)acrylate, oligoethylene glycol di(meth)acrylate, ethylene glycol di(meth)acrylate, trimethylolpropane tri(meth)acrylate, trimethylolethane tri(meth)acrylate, pentaerythritol tri(meth)acrylate, dipentaerythritol tri(meth)acrylate, pentaerythritol tetra(meth)acrylate, ditrimethylolpropane tetra(meth)acrylate, dipentaerythritol penta(meth)acrylate, and dipentaerythritol hexa(meth)acrylate.

Furthermore, suitable embodiments other than the compound (A-1) include a polymer represented by the following Formula (1).

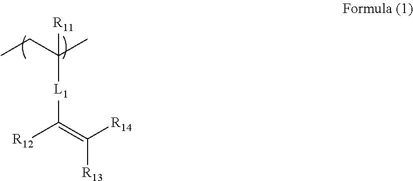

In Formula (1), R₁₁ to R₁₄ each independently represent a hydrogen atom, or a substituted or unsubstituted alkyl group.

In the case where R₁₁ to R₁₄ are a substituted or unsubstituted alkyl group, they are each preferably an alkyl group having 1 to 6 carbon atoms, and more preferably an alkyl group having 1 to 4 carbon atoms. More specifically, examples of the unsubstituted alkyl group include a methyl group, an ethyl group, a propyl group, and a butyl group, and examples of the substituted alkyl group include a methoxy group, a hydroxyl group, a methyl group, an ethyl group, a propyl group, and a butyl group, each substituted with a halogen atom (for example, a chlorine atom, a bromine atom, and a fluorine atom).

R₁₁ is preferably a hydrogen atom or a methyl group.

In Formula (1), L₁ represents a single bond or a divalent linking group. Examples of the divalent linking group include a substituted or unsubstituted divalent aliphatic hydrocarbon group (preferably having 1 to 8 carbon atoms; for example, an alkylene group such as a methylene group, an ethylene group, and a propylene group), a substituted or unsubstituted divalent aromatic hydrocarbon group (preferably having 6 to 12 carbon atoms; for example, a phenylene group), —O—, —CO—, and a group formed by combination of these groups (for example, an alkyleneoxy group, an alkyleneoxycarbonyl group, and an alkylenecarbonyloxy group).

Other suitable embodiments of the compound A include a polymer having a polymerizable group (hereinafter also referred to as a compound (A-2)). The compound (A-2) is preferably a polymer including no cyclic structure in the side chain. When such a polymer is used, the interaction between the adjacent molecules is inhibited and aggregation can be inhibited, as compared with a polymer including a cyclic structure in the side chain, and thus, it has a planar shape at a time of applying it onto the substrate, and the inhibition of pattern defects is more effectively inhibited. Examples of the cyclic structure include a 5- or 6-membered ring, among which the 6-membered ring is preferred. Further, the cyclic structure is preferably a hydrocarbon group, and more preferably an unsaturated hydrocarbon group.

For the compound (A-2), a main chain preferably contains an aromatic ring, the main chain more preferably includes an aromatic ring and an alkylene group, and the main chain more preferably contains a structure in which a benzene ring and a methylene group are alternately bonded to each other.

In addition, the compound (A-2) preferably has a polymerizable group in the side chain, more preferably has a (meth)acryloyl group in the side chain, and still more preferably has an acryloyl group in the side chain.

The molecular weight of the compound (A-2) is preferably 1,000 or more, and more preferably 3,000 or more. The upper limit of the molecular weight is preferably 200,000 or less, more preferably 100,000 or less, still more preferably 50,000 or less, and particularly preferably 10,000 or less. By setting the molecular weight to such a value, the volatilization of the component can be inhibited, and further, the planar shape at a time of applying it onto the substrate can be improved.

Moreover, the compound (A-2) is preferably a polymer having a structural unit represented by the following General Formula (A) as a main component, and more preferably a polymer having a structural unit represented by the following General Formula (A) accounting for 90% by mole or more.

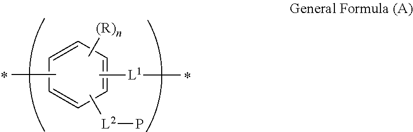

In General Formula (A), R is an alkyl group, L¹ and L² are each a divalent linking group, P is a polymerizable group, and n is an integer of 0 to 3.

R is preferably an alkyl group having 1 to 5 carbon atoms, and more preferably a methyl group.

L¹ is preferably an alkylene group, more preferably an alkylene group having 1 to 3 carbon atoms, and still more preferably —CH₂—.

L² is preferably —CH₂—, —O—, —CHR— (in which R is a substituent), and a divalent linking group formed by combination of two or more thereof, and R is preferably an OH group.

P is preferably a (meth)acryloyl group, and more preferably an acryloyl group.

n is preferably an integer of 0 to 2, and more preferably 0 or 1.

Specific examples of the compound A used in the present invention include epoxy (meth)acrylate polymers, among which a novolac-type epoxy (meth)acrylate polymer is preferred. Examples of the novolac-type epoxy (meth)acrylate include cresol novolac and phenol novolac, both of which are preferred.

The content of the compound (A) in the composition for forming an adhesion aiding layer is not particularly limited, but is preferably 30% by mass or more, more preferably 50% by mass or more, still more preferably 70% by mass or more, and particularly preferably 90% by mass or more, with respect to the total mass (only solid contents) of the composition, from the viewpoints of excellent applicability and handling properties.

The composition for forming an adhesion aiding layer may contain other components other than the compound A, and may contain, for example, a solvent, a crosslinking agent, a surfactant, a light or heat polymerization initiator, or a polymerization inhibitor. The blending amount thereof is preferably 50% by mass or less with respect to all the components excluding the solvent.

The composition for forming an adhesion aiding layer preferably contains a solvent. As the solvent, a solvent having a boiling point at normal pressure of 80° C. to 200° C. is preferred. With respect to the type of the solvent, any solvent capable of dissolving materials for forming an adhesion aiding layer such as the compound A may be used, but solvents having at least any one of an ester structure, a ketone structure, a hydroxyl group, and an ether structure are preferred. Specifically, the solvent is preferably a single or mixed solvent selected from propylene glycol monomethyl ether acetate, cyclohexanone, 2-heptanone, γ-butyrolactone, propylene glycol monomethyl ether, or ethyl lactate, with a solvent containing propylene glycol monomethyl ether acetate being most preferred from the viewpoint of application uniformity.

The content of the solvent in the composition for forming an adhesion aiding layer is optimally adjusted depending on the viscosity of the components excluding the solvent, applicability, and a desired thickness of the film. However, from the viewpoint of improving the applicability, the solvent may be added in the amount of 70% by mass or more, and preferably 90% by mass or more, of the entire composition.

The composition for forming an adhesion aiding layer can be prepared by mixing the respective components as described above. After mixing the respective components as described above, the mixture is preferably filtered through a filter with a pore size of 0.003 μm to 5.0 μm. The filtration may be conducted in a multi-stage manner or may be repeated multiple times. Further, the filtrate may be re-filtered. As a material of the filter used for filtration, any one of a polyethylene resin, a polypropylene resin, a fluorine resin, a nylon resin, and the like may be used without particular limitation.

(Procedure of Application Method)

A method for applying the composition for forming an adhesion aiding layer onto a substrate is not particularly limited, and a known method may be used. However, spin coating is preferably used in a field of the manufacture of semiconductor.

After applying the composition for forming an adhesion aiding layer onto a substrate, a curing treatment may be carried out, if desired. The curing treatment is not particularly limited, but examples thereof include an exposure treatment and a heating treatment.

For the exposure treatment, light irradiation using a UV lamp, visible rays, or the like is used. Examples of the light source include a mercury lamp, a metal halide lamp, a xenon lamp, a chemical lamp, and a carbon arc lamp. Examples of the radiation include electron beams, X-rays, ion beams, and far-infrared rays. Specific embodiments thereof include scanning exposure using infrared laser beams, high-illuminance flash exposure using a xenon discharge lamp or the like, and exposure with an infrared lamp.

The exposure time varies depending on the reactivity of the polymer and the light source, but is usually from 10 seconds to 5 hours. The exposure energy may be from about 10 mJ to 10000 mJ, and preferably in the range of 100 mJ to 8000 mJ.

Furthermore, in the case of using a heating treatment, an air blowing drier, an oven, an infrared drier, a heating drum, or the like can be used.

A combination of the exposure treatment and the heating treatment may also be used.

[Step (2): Resist Film Forming Step]

The step (2) is a step in which a radiation-sensitive resin composition is applied onto the adhesion aiding layer formed in the step (1) to form a resist film.

First, the materials used in the present step will be described in detail, and subsequently, the procedure of the step (2) will be described in detail.

<Radiation-Sensitive Resin Composition>

Hereinbelow, the radiation-sensitive resin composition (hereinafter also referred to as a composition for forming a resist film) used in the present invention will be described. The type of the radiation-sensitive resin composition used in the present invention is not particularly limited, but is preferably one containing at least any one selected from the components shown below.

[1] Resin (A) Capable of Increasing Polarity by Action of Acid to Decrease Solubility for Developing Liquid Containing Organic Solvent

Examples of the resin (A) capable of increasing the polarity by the action of an acid to decrease the solubility for a developing liquid containing an organic solvent, which is contained in the radiation-sensitive resin composition used in the present invention, include a resin (hereinafter also referred to as an “acid-decomposable resin” or a “resin (A)”) having a group capable of decomposing by an action of an acid to generate a polar group (hereinafter also referred to as an “acid-decomposable group”), on either one or both of the main chain and the side chain of the resin.

It is preferable that the acid-decomposable group has a structure with a polar group protected by a group capable of leaving by decomposing by the action of an acid.

The polar group is not particularly limited as long as it is a group sparingly soluble or insoluble in the developing liquid including an organic solvent, and examples thereof include a phenolic hydroxyl group, a carboxyl group, a fluorinated alcohol group (preferably a hexafluoroisopropanol group), an acidic group (a group which dissociates in a 2.38%-by-mass aqueous tetramethylammonium hydroxide solution, which is used as a developing liquid of a resist in the prior art), such as a sulfonic acid group, a sulfonamide group, a sulfonylimide group, an (alkylsulfonyl)(alkylcarbonyl)methylene group, an (alkyl sulfonyl)(alkylcarbonyl)imide group, a bis(alkylcarbonyl)methylene group, bis(alkylcarbonyl)imide group, a bis(alkyl sulfonyl)methylene group, a bis(alkylsulfonyl)imide group, a tris(alkylcarbonyl)methylene group, and a tris(alkylsulfonyl)methylene group, and an alcoholic hydroxyl group.

Further, the alcoholic hydroxyl group refers to a hydroxyl group bonded to a hydrocarbon group, which is other than a hydroxyl group directly bonded on an aromatic ring (a phenolic hydroxyl group), and excludes an aliphatic alcohol (for example, a fluorinated alcohol group (a hexafluoroisopropanol group or the like)), of which the α-position is substituted with an electron-withdrawing group such as a fluorine atom as a hydroxyl group. As the alcoholic hydroxyl group, a hydroxyl group having a pKa ranging from 12 to 20 is preferred.

Preferred examples of the polar group include a carboxyl group, a fluorinated alcohol group (preferably a hexafluoroisopropanol group), and a sulfonic acid group.

As the acid-decomposable group, a group substituted with a group having a hydrogen atom capable of leaving by an acid is preferred.

Examples of the group capable of leaving by an acid include —C(R₃₆)(R₃₇)(R₃₈), —C(R₃₆)(R₃₇)(OR₃₉), and —C(R₀₁)(R₀₂)(OR₃₉).

In the formulae, R₃₆ to R₃₉ each independently represent an alkyl group, a cycloalkyl group, an aryl group, an aralkyl group, or an alkenyl group. R₃₆ and R₃₇ may be bonded to each other to form a ring.

R₀₁ to R₀₂ each independently represent a hydrogen atom, an alkyl group, a cycloalkyl group, an aryl group, an aralkyl group, or an alkenyl group.

The alkyl group of R₃₆ to R₃₉, R₀₁, and R₀₂ is preferably an alkyl group having 1 to 8 carbon atoms, and examples thereof include a methyl group, an ethyl group, a propyl group, an n-butyl group, a sec-butyl group, a hexyl group, and an octyl group.

The cycloalkyl group of R₃₆ to R₃₉, R₀₁, and R₀₂ may be monocyclic or polycyclic. As the monocyclic cycloalkyl group, a cycloalkyl group having 3 to 8 carbon atoms is preferred, and as the polycyclic cycloalkyl group, a cycloalkyl group having 6 to 20 carbon atoms is preferred. Incidentally, at least one of the carbon atoms in the cycloalkyl group may be substituted with a heteroatom such as an oxygen atom.

The aryl group of R₃₆ to R₃₉, R₀₁, and R₀₂ is preferably an aryl group having 6 to 10 carbon atoms, and examples thereof include a phenyl group, a naphthyl group, and an anthryl group.

The aralkyl group of R₃₆ to R₃₉, R₀₁, and R₀₂ is preferably an aralkyl group having 7 to 12 carbon atoms.

The alkenyl group of R₃₆ to R₃₉, R₀₁, and R₀₂ is preferably an alkenyl group having 2 to 8 carbon atoms.

The ring formed by the mutual bonding of R₃₆ and R₃₇ is preferably a cycloalkyl group (monocyclic or polycyclic). The cycloalkyl group is preferably a monocyclic cycloalkyl group such as a cyclopentyl group and a cyclohexyl group, or a polycyclic cycloalkyl group such as a norbornyl group, a tetracyclodecanyl group, a tetracyclododecanyl group, and an adamantyl group, more preferably a monocyclic cycloalkyl group having 5 to 6 carbon atoms, and particularly preferably a monocyclic cycloalkyl group having 5 carbon atoms.

The acid-decomposable group is preferably a cumyl ester group, an enol ester group, an acetal ester group, a tertiary alkyl ester group, or the like, and more preferably a tertiary alkyl ester group.

The resin (A) preferably has a repeating unit having an acid-decomposable group.

Furthermore, the resin (A) preferably has, as the repeating unit having an acid-decomposable group, a repeating unit represented by the following General Formula (AI). The repeating unit represented by General Formula (AI) generates a carboxyl group as a polar group by the action of an acid, and exhibits strong interaction by hydrogen bonding among a plurality of carboxyl groups. Thus, it can further raise the glass transition temperature (Tg) of the resin (A). As a result, even when a film is deposited in the periphery of a resist pattern by a CVD method (in particular, a high-temperature CVD method), high rectangularity in the cross-sectional profile of the resist pattern is less likely to be impaired by heat during film growth, and consequently, the process cost can be further inhibited from being increased.

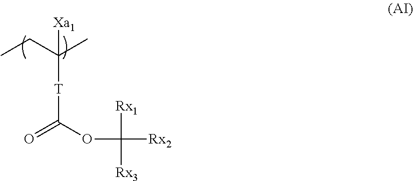

In General Formula (AI),
Xa₁ represents a hydrogen atom, an alkyl group, a cyano group, or a halogen atom;
T represents a single bond or a divalent linking group;
Rx₁ to Rx₃ each independently represent an alkyl group or a cycloalkyl group; and
two members out of Rx₁ to Rx₃ may be bonded to each other to form a ring structure.

Examples of the divalent linking group of T include an alkylene group, a —COO-Rt-group, an —O-Rt-group, and a phenylene group. In the formula, Rt represents an alkylene group or a cycloalkylene group.

T is preferably a single bond or a —COO-Rt-group. Rt is preferably an alkylene group having 1 to 5 carbon atoms, more preferably a —CH₂-group, a —(CH₂)₂-group, or a —(CH₂)₃-group, and still more preferably a single bond.

The alkyl group of Xa₁ may have a substituent, and examples of the substituent include a hydroxyl group and a halogen atom (preferably a fluorine atom).

The alkyl group of Xa₁ is preferably an alkyl group having 1 to 4 carbon atoms, and examples thereof include a methyl group, an ethyl group, a propyl group, a hydroxymethyl group, and a trifluoromethyl group, among which the methyl group is preferred.

Xa₁ is preferably a hydrogen atom or a methyl group.

The alkyl group of Rx₁, Rx₂, and Rx₃ may be linear or branched, and it is preferably an alkyl group having 1 to 4 carbon atoms, such as a methyl group, an ethyl group, an n-propyl group, an isopropyl group, an n-butyl group, an isobutyl group, and a t-butyl group.

The cycloalkyl group of Rx₁, Rx₂, and Rx₃ is preferably a monocyclic cycloalkyl group such as a cyclopentyl group and a cyclohexyl group, or a polycyclic cycloalkyl group such as a norbornyl group, a tetracyclodecanyl group, a tetracyclododecanyl group, and an adamantyl group.

As the ring structure formed by the mutual bonding of two members out of Rx₁, Rx₂, and Rx₃, a monocyclic cycloalkane ring such as a cyclopentyl ring and a cyclohexyl ring, or a polycyclic cycloalkyl ring such as a norbornane ring, a tetracyclodecane ring, a tetracyclododecane ring, and an adamantane ring is preferred, and a monocyclic cycloalkane ring having 5 to 6 carbon atoms is particularly preferred.

Rx₁, Rx₂, and Rx₃ are each independently preferably an alkyl group, and more preferably a linear or branched alkyl group having 1 to 4 carbon atoms.

Each of the above groups may have a substituent, and examples of the substituent include an alkyl group (having 1 to 4 carbon atoms), a cycloalkyl group (having 3 to 8 carbon atoms), a halogen atom, an alkoxy group (having 1 to 4 carbon atoms), a carboxyl group, and an alkoxycarbonyl group (having 2 to 6 carbon atoms), and the number of carbon atoms is preferably 8 or less. Among these, a substituent which does not have a heteroatom such as an oxygen atom, a nitrogen atom, and a sulfur atom is more preferred (still more preferably, for example, a group which is not an alkyl group substituted with a hydroxyl group or the like), from the viewpoint of further improving dissolution contrast for a developing liquid including an organic solvent before and after acid-decomposition, a group formed only from hydrogen atoms and carbon atoms is still more preferred, and a linear or branched alkyl group, or a cycloalkyl group is particularly preferred.

Specific examples of the repeating unit represented by General Formula (AI) are shown below, but the present invention is not limited to these.

In the specific examples, Rx represents a hydrogen atom, CH₃, CF₃, or CH₂OH. Rxa and Rxb each represent an alkyl group having 1 to 4 carbon atoms. Xa₁ represents a hydrogen atom, CH₃, CF₃, or CH₂OH. Z represents a substituent, and in the case of being present in plural numbers, plural numbers of Z's may be the same as or different from each other. p represents 0 or a positive integer. Specific examples and preferred examples of Z are the same as the specific examples and the preferred examples of the substituents that each group such as Rx₁ to Rx₃ may have.

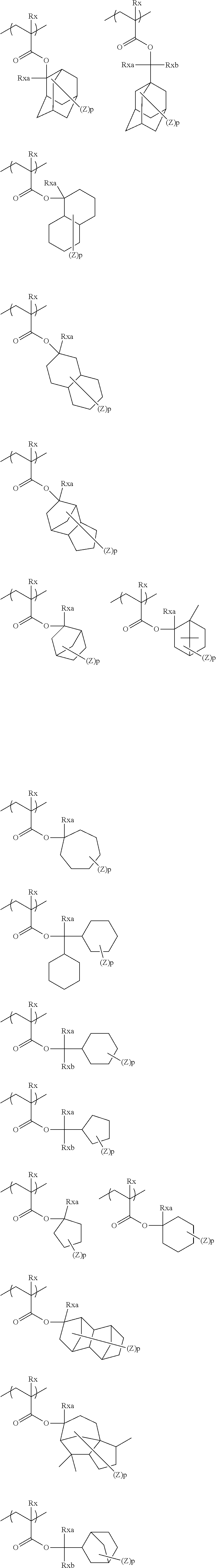

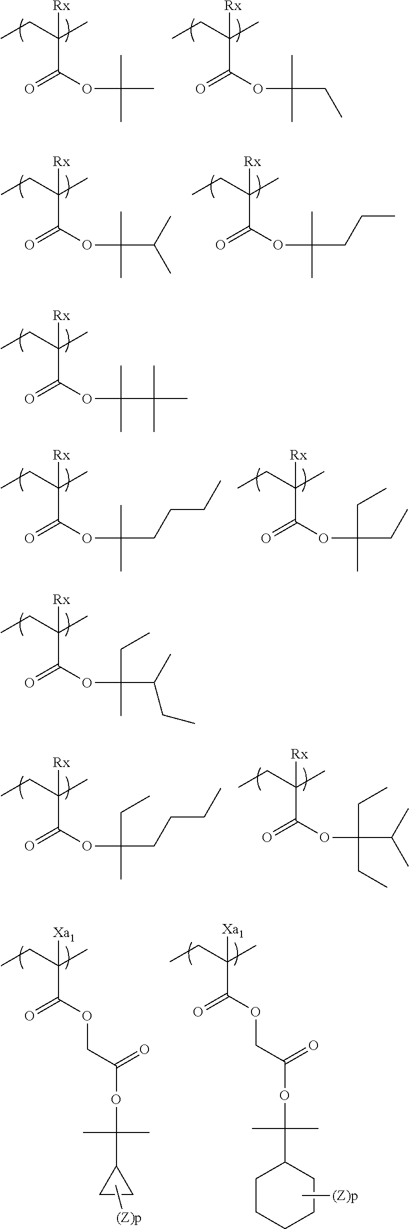

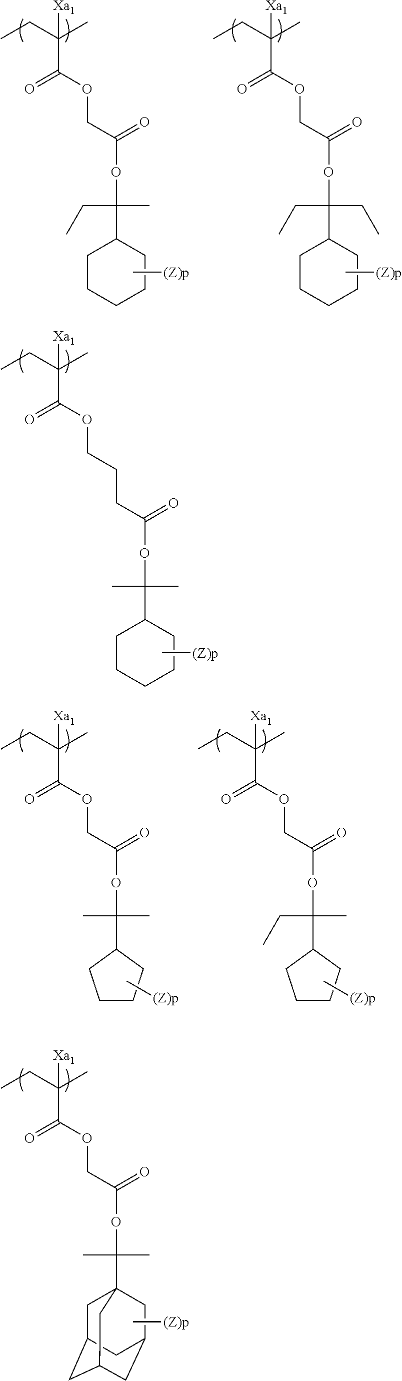

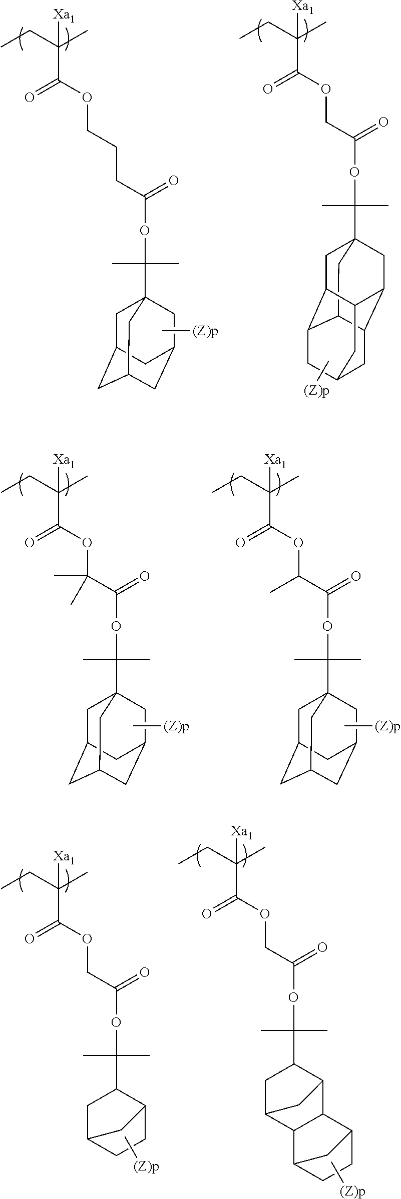

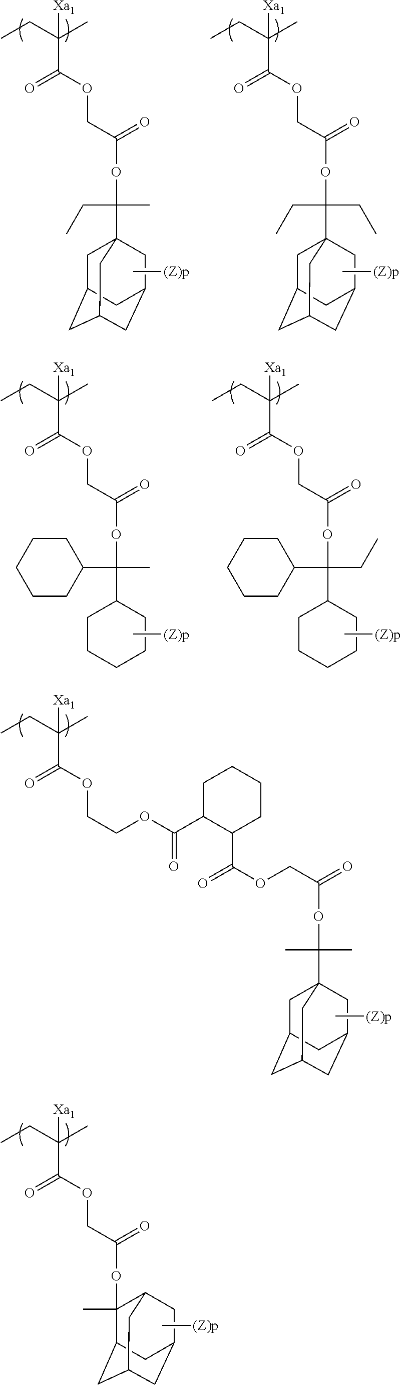

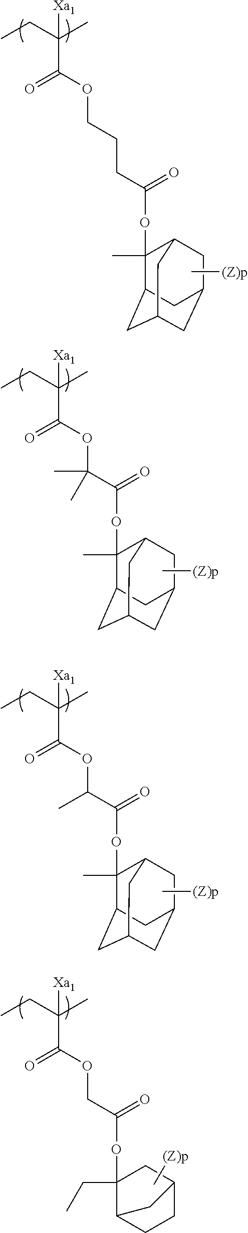

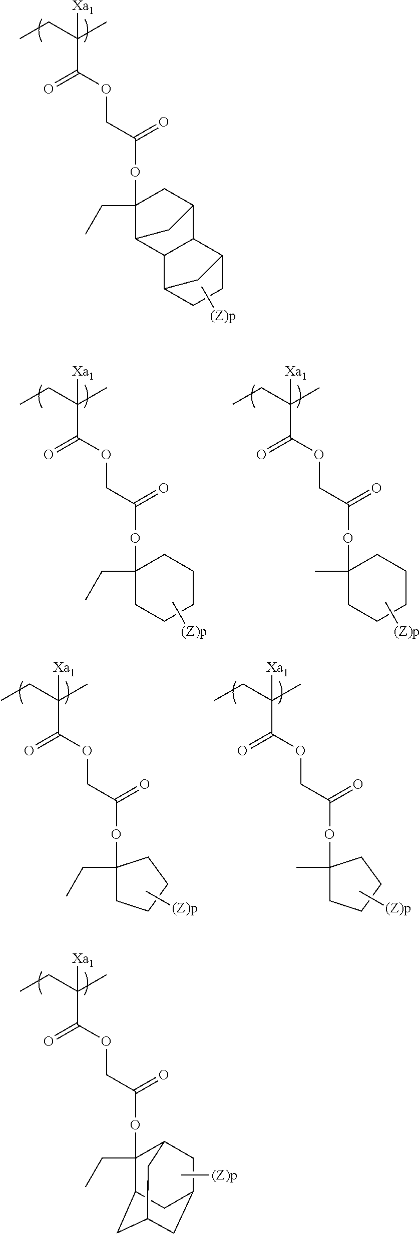

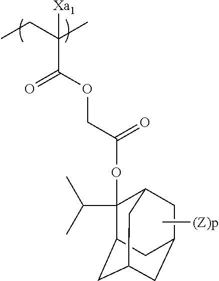

In addition, the resin (A) also preferably has a repeating unit represented by following General Formula (IV) as the repeating unit having an acid-decomposable group.

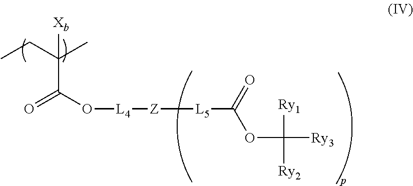

In General Formula (IV), X_{b} represents a hydrogen atom, an alkyl group, a cyano group, or a halogen atom.

Ry₁ to Ry₃ each independently represent an alkyl group or a cycloalkyl group, and two members out of Ry₁ to Ry₃ may be linked to each other to form a ring.

Z represents a (p+1)-valent linking group having a polycyclic hydrocarbon structure, which may have a heteroatom as a ring member thereof. It is preferable that Z contains no ester bond in an atomic group constituting the polycyclic ring (or equivalently, it is preferable that Z contains no lactone ring as a ring constituting the polycyclic ring).

L₄ and L₅ each independently represent a single bond or a divalent linking group.

p represents an integer of 1 to 3.

When p is 2 or 3, a plurality of L₅'s, a plurality of Ry₁'s, a plurality of Ry₂'s, and a plurality of Ry₃'s may be the same as or different from each other.

The alkyl group of X_{b} may have a substituent, and examples of the substituent include a hydroxyl group and a halogen atom (preferably a fluorine atom).

The alkyl group of X_{b} is preferably an alkyl group having 1 to 4 carbon atoms, and examples thereof include a methyl group, an ethyl group, a propyl group, a hydroxymethyl group, and a trifluoromethyl group, among which the methyl group is preferred.

X_{b} is preferably a hydrogen atom or a methyl group.

Specific examples and preferred examples of the alkyl group and the cycloalkyl group of Ry₁ to Ry₃ are the same as the specific examples and the preferred examples of the alkyl group and the cycloalkyl group of Rx₁ to Rx₃ in General Formula (AI).

Specific examples and preferred examples of the ring structure formed by the mutual bonding of two members of Ry₁ to Ry₃ are the same as the specific examples and the preferred examples of the ring structure formed by the mutual bonding of two members of Rx₁ to Rx₃ in General Formula (AI).

Ry₁ to Ry₃ are each independently preferably an alkyl group, and more preferably a chained or branched alkyl group having 1 to 4 carbon atoms. Further, the total number of carbon atoms in the chained or branched alkyl group as Ry₁ to Ry₃ is preferably 5 or less.

Ry₁ to Ry₃ may further have a substituent, and examples of the substituent are the same ones as substituents, which each of Rx₁ to Rx₃ in General Formula (AI) may further have.

Examples of the linking group having a polycyclic hydrocarbon structure of Z include a ring-assembly hydrocarbon ring group and a crosslinked cyclic hydrocarbon ring group, and may further include a group formed by removing (p+1) arbitrary hydrogen atoms from a ring-assembly hydrocarbon ring and a group formed by removing (p+1) arbitrary hydrogen atoms from a crosslinked cyclic hydrocarbon ring.

The linking group having a polycyclic hydrocarbon structure represented by Z may have a substituent. Examples of the substituent that Z may have include a substituent such as an alkyl group, a hydroxyl group, a cyano group, a keto group (an alkylcarbonyl group or the like), an acyloxy group, —COOR, —CON(R)₂, —SO₂R, —SO₃R, and —SO₂N(R)₂. Here, R represents a hydrogen atom, an alkyl group, a cycloalkyl group, or an aryl group.

The alkyl group, the alkylcarbonyl group, the acyloxy group, —COOR, —CON(R)₂, —SO₂R, —SO₃R, and —SO₂N(R)₂ as the substituent that Z may have may further have a substituent. Examples of such a substituent include a halogen atom (preferably a fluorine atom).

In the linking group having a polycyclic hydrocarbon structure represented by Z, carbon constituting the polycyclic ring (carbon contributing to ring formation) may be carbonyl carbon. Further, the polycyclic ring may contain, as mentioned above, a heteroatom such as an oxygen atom and a sulfur atom as a ring member. However, as mentioned above, Z contains no ester bond in an atomic group constituting the polycyclic ring.

Examples of the linking groups represented by L₄ and L₅ include —COO—, —OCO—, —CONH—, —NHCO—, —CO—, —O—, —S—, —SO—, —SO₂—, an alkylene group (preferably having 1 to 6 carbon atoms), a cycloalkylene group (preferably having 3 to 10 carbon atoms), an alkenylene group (preferably having 2 to 6 carbon atoms), and a linking group formed by combination of a plurality of these groups. The linking group having a total number of carbon atoms of 12 or less is preferred.

L₄ is preferably a single bond, an alkylene group, —COO—, —OCO—, —CONH—, —NHCO—, -alkylene group-COO—, -alkylene group-OCO—, -alkylene group-CONH—, -alkylene group-NHCO—, —CO—, —O—, —SO₂—, or -alkylene group-O—, and more preferably a single bond, an alkylene group, -alkylene group-COO— or -alkylene group-O—.

L₅ is preferably a single bond, an alkylene group, —COO—, —OCO—, —CONH—, —NHCO—, —COO-alkylene group-, —OCO-alkylene group-, —CONH-alkylene group-, —NHCO-alkylene group-, —CO—, —O—, —SO₂—, —O-alkylene group-, or —O-cycloalkylene group-, and more preferably a single bond, an alkylene group, —COO-alkylene group-, —O-alkylene group-, or —O-cyclo alkylene group-.

In the method described above, the bonding arm “-” at the left end means to be bonded to an ester bond on the main chain side in L₄ and bonded to Z in L₅, while the bonding arm “-” at the right end means to be bonded to Z in L₄ and bonded to an ester bond connected to a group represented by (Ry₁)(Ry₂)(Ry₃)C— in L₅.

Incidentally, L₄ and L₅ may be bonded to the same atom constituting the polycyclic ring in Z.

p is preferably 1 or 2, and more preferably 1.

Specific examples of the repeating unit represented by General Formula (IV) are shown below, but the present invention is not limited thereto. In specific examples below, Xₐ represents a hydrogen atom, an alkyl group, a cyano group, or a halogen atom.

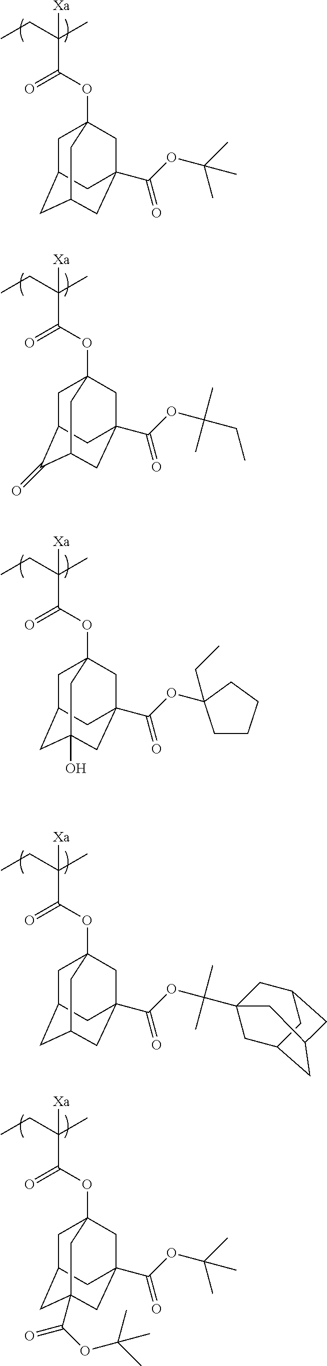

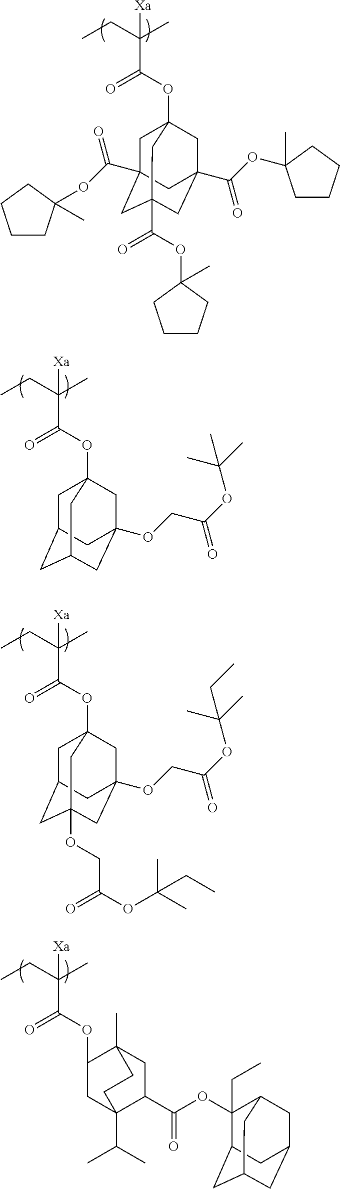

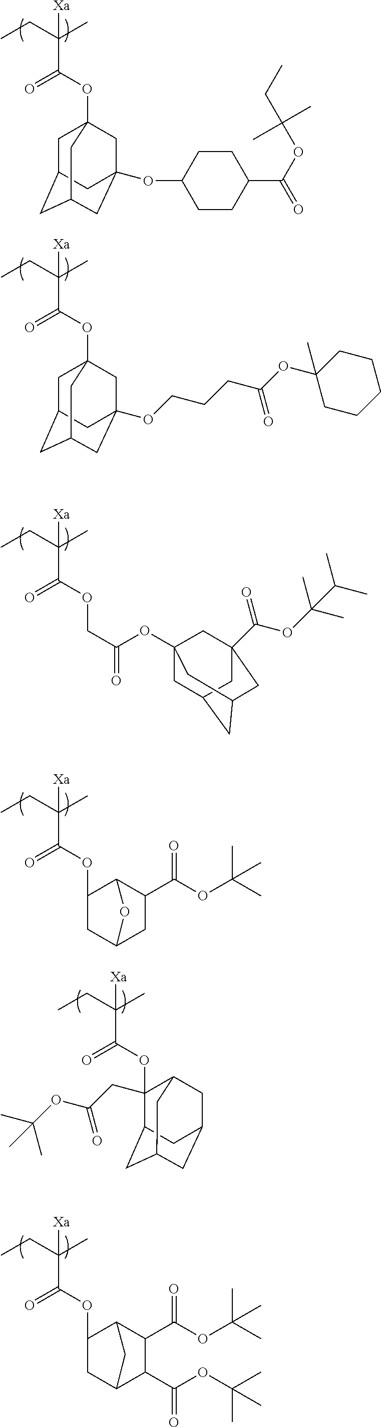

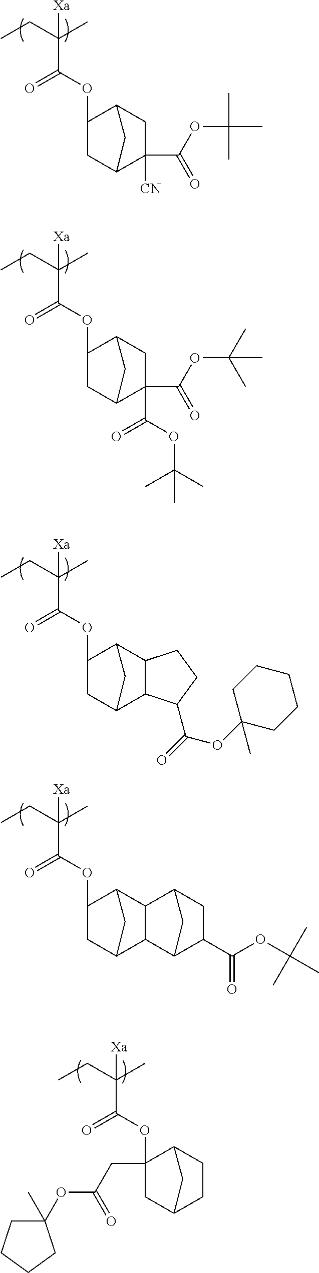

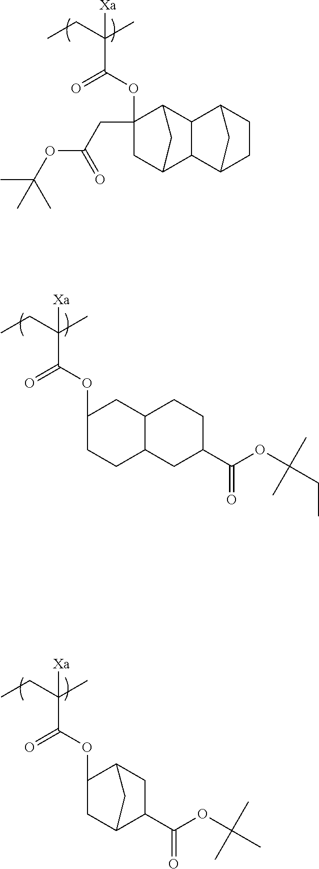

Furthermore, the resin (A) may contain a repeating unit capable of decomposing by the action of an acid to generate an alcoholic hydroxyl group as shown below, as the repeating unit having an acid-decomposable group.

In specific examples below, Xa₁ represents a hydrogen atom, CH₃, CF₃, or CH₂OH.

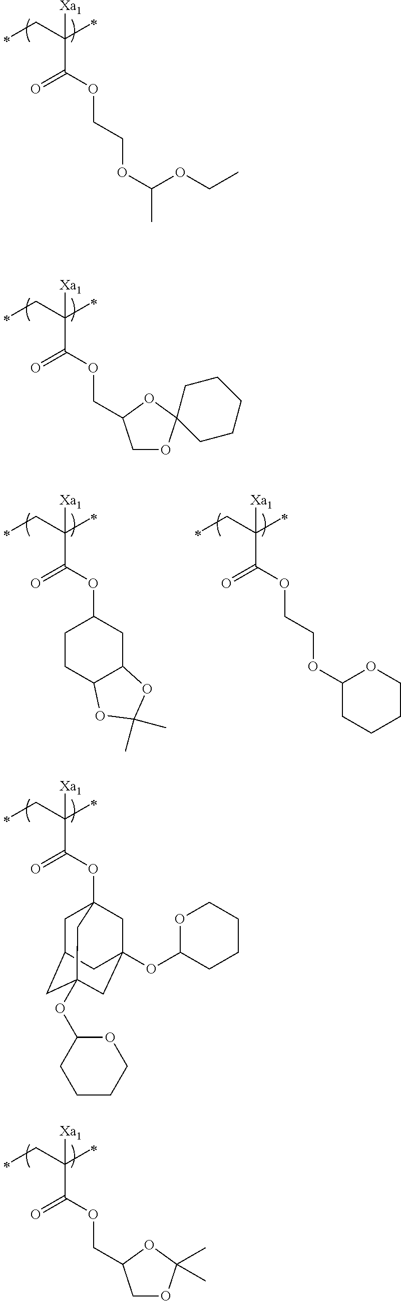

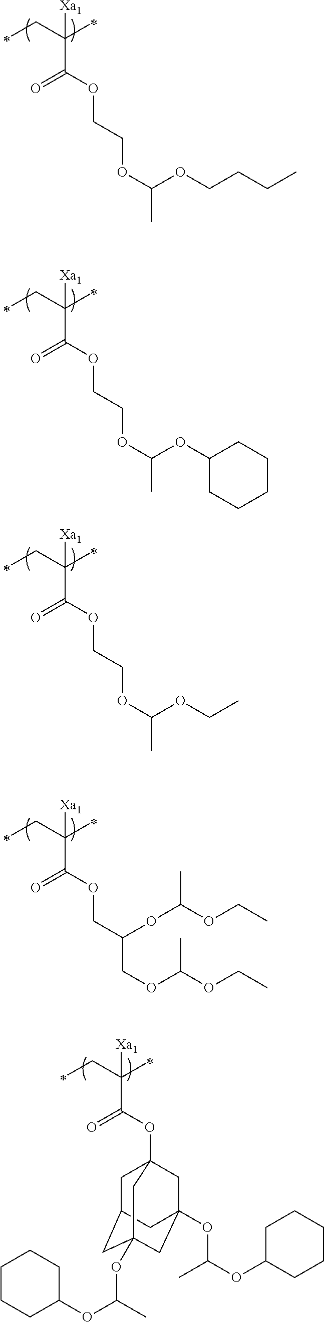

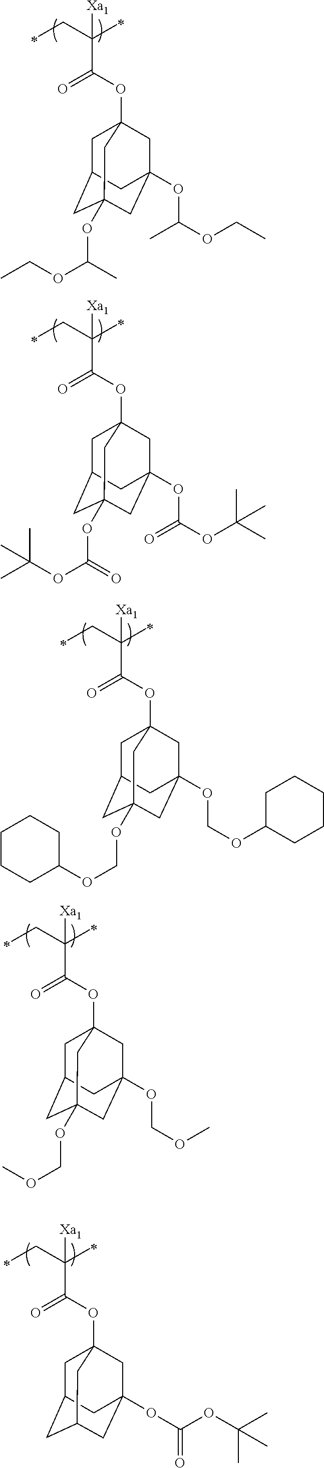

The repeating units having an acid-decomposable group can be used alone or in combination of two or more kinds thereof.

It is considered that examples in which a combination of two or more kinds include a combination as below and a combination of the repeating units represented by General Formula (AI) with the repeating units capable of decomposing by the action of an acid to generate an alcoholic hydroxyl group. In addition, in the following specific examples, R represents a hydrogen atom, an alkyl group (for example, CH₃), CF₃, CH₂OH, a cyano group, or a halogen atom.

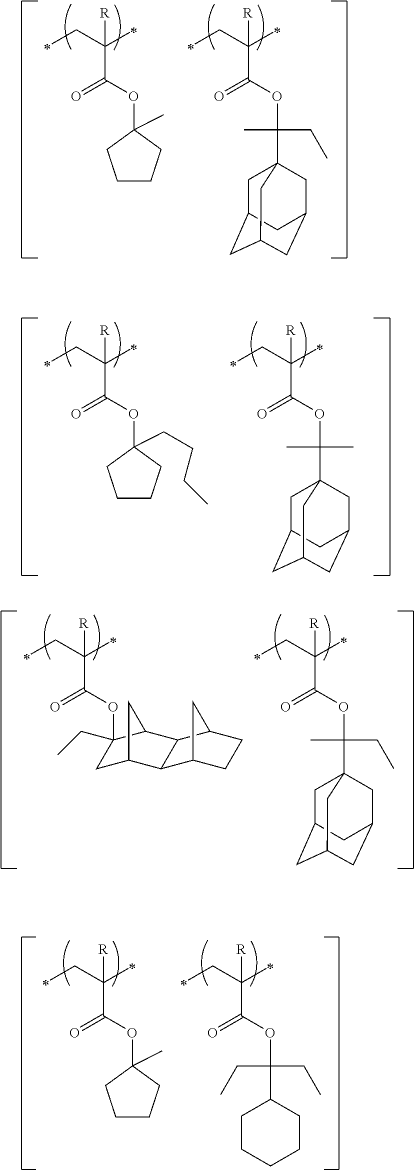

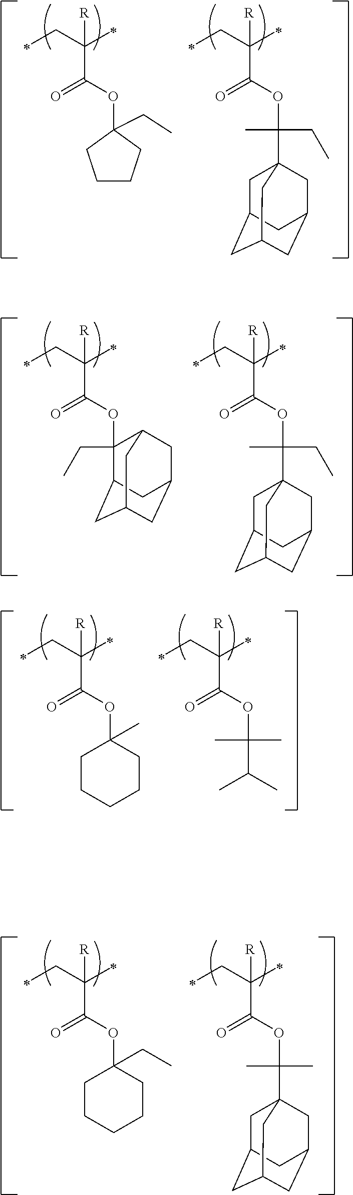

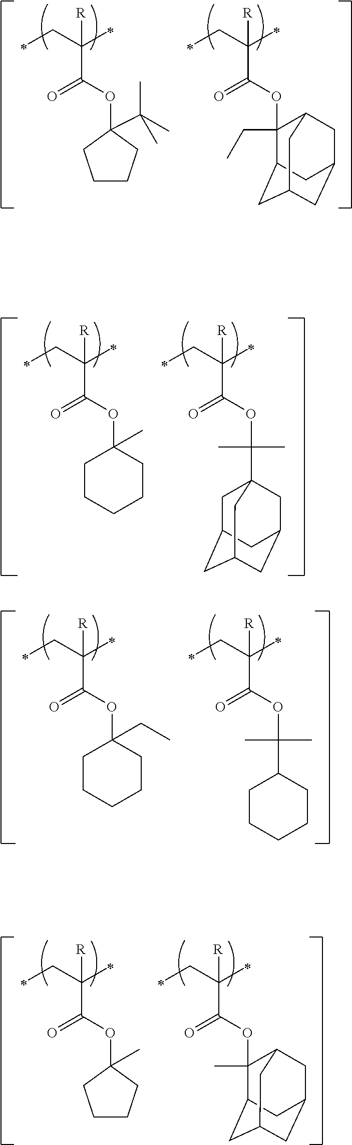

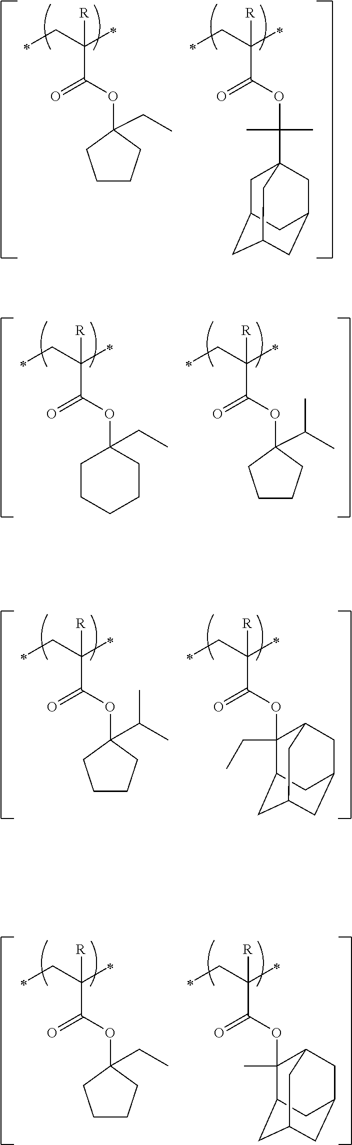

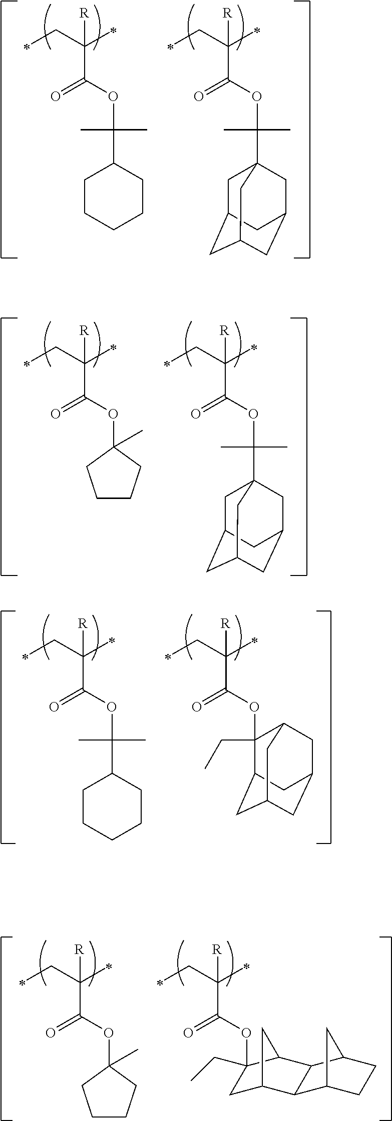

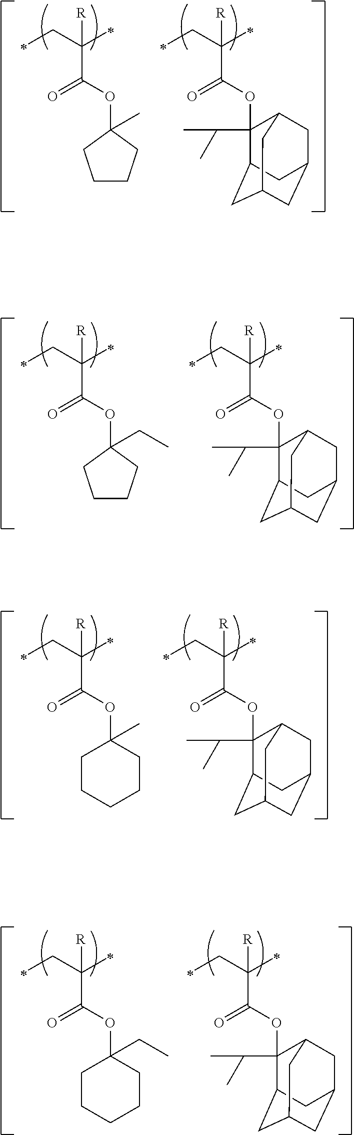

The content of the repeating units having an acid-decomposable group contained in the resin (A) (the total thereof in the case where a plurality of repeating units having acid-decomposable groups are present) is preferably 15% by mole or more, more preferably 20% by mole or more, still more preferably 25% by mole or more, and particularly preferably 40% by mole or more, with respect to all the repeating units in the resin (A). Among these, it is preferable that the resin (A) has the repeating units represented by General Formula (AI) and the content of the repeating units represented by General Formula (AI) is 40% by mole or more with respect to all the repeating units in the resin (A).

When the content of the repeating units having an acid-decomposable group is 40% by mole or more with respect to all the repeating units in the resin (A), the glass transition temperature (Tg) of the resin (A) can be made more reliably, and as a result, an effect capable of inhibiting an increase in the process cost can be obtained more reliably.

In addition, the content of the repeating units having an acid-decomposable group is preferably 80% by mole or less, more preferably 70% by mole or less, and more preferably 65% by mole or less, with respect to all the repeating units in the resin (A).

The resin (A) may contain a repeating unit having a lactone structure or a sultone structure.

As the lactone structure or the sultone structure, any structure may be used as long as it has a lactone structure or a sultone structure, but the structure is preferably a 5- to 7-membered ring lactone structure or a 5- to 7-membered ring sultone structure, and more preferably a 5- to 7-membered ring lactone structure to which another ring structure is fused in the form of forming a bicyclo or spiro structure, or a 5- to 7-membered ring sultone structure to which another ring structure is fused in the form of forming a bicyclo or spiro structure. The resin more preferably has a repeating unit having a lactone structure represented by any one of the following General Formulae (LC1-1) to (LC1-21) or a sultone structure represented by any one of the following General Formulae (SL1-1) to (SL1-3). The lactone structure or sultone structure may be bonded directly to the main chain. Preferred lactone structures are (LC1-1), (LC1-4), (LC1-5), (LC1-6), (LC1-13), (LC1-14), and (LC1-17), among which the lactone structure of (LC1-4) is more preferred. By using such a specific lactone structure, LER and development defects are relieved.

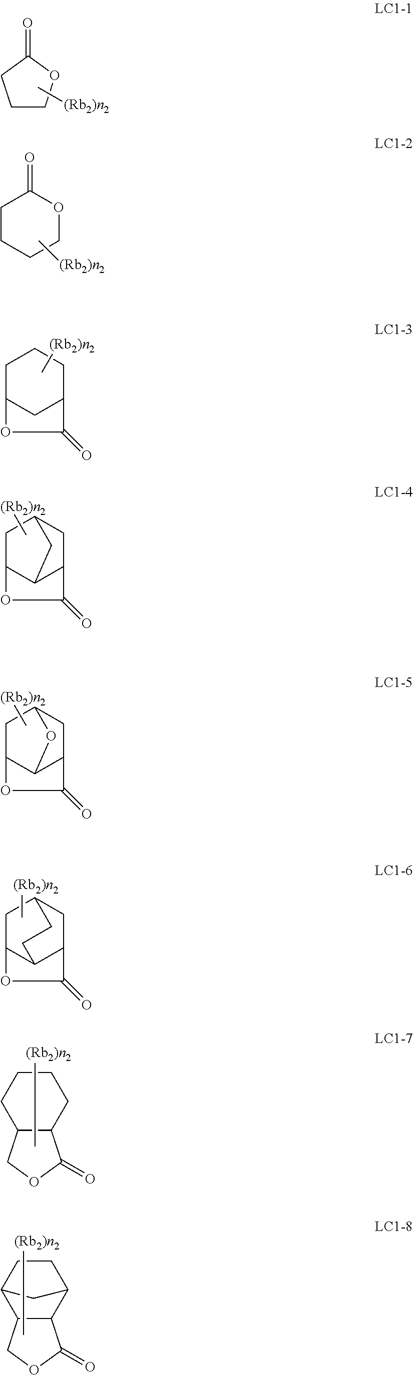

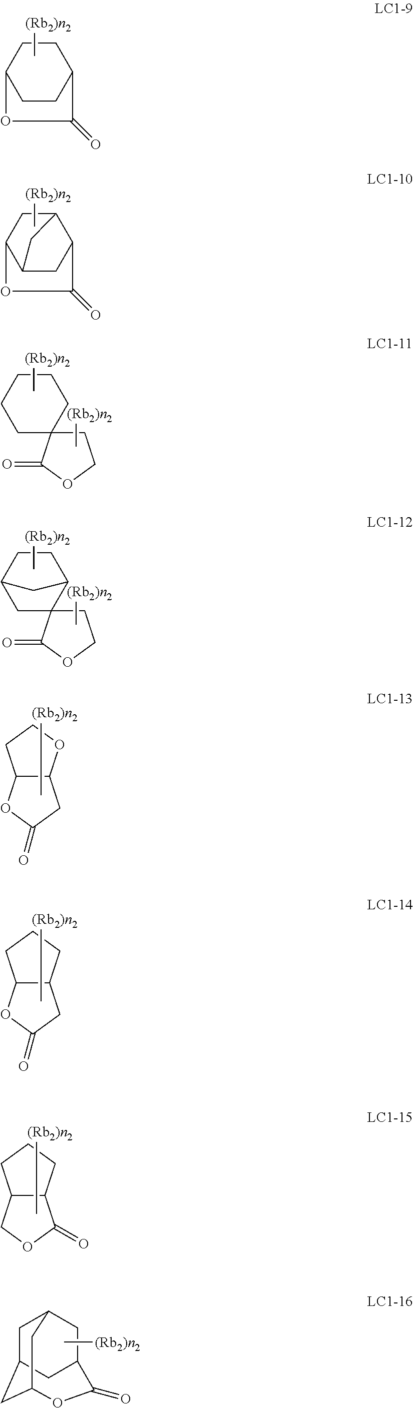

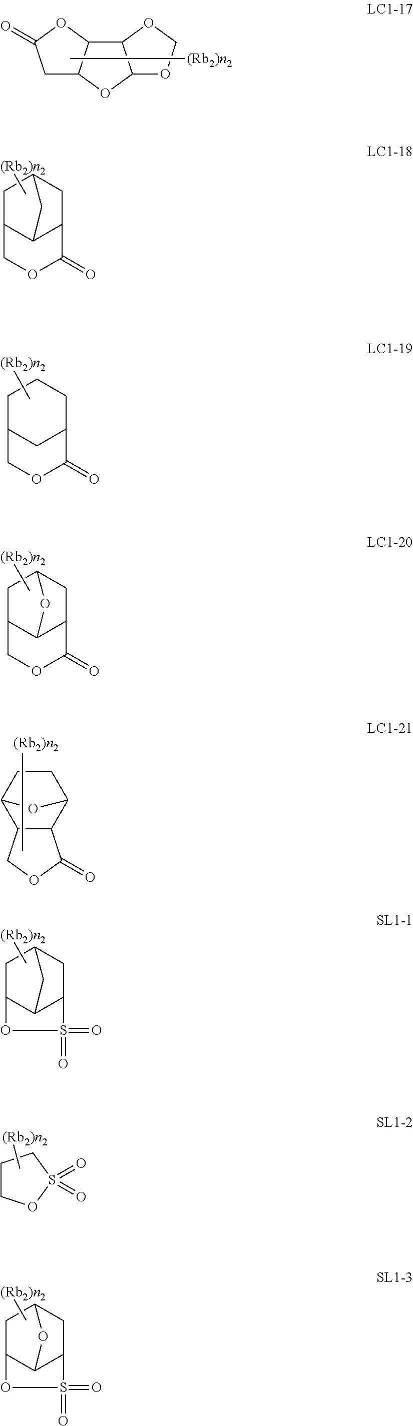

The lactone structure moiety or the sultone structure moiety may or may not have a substituent (Rb₂). Preferred examples of the substituent (Rb₂) include an alkyl group having 1 to 8 carbon atoms, a cycloalkyl group having 4 to 7 carbon atoms, an alkoxy group having 1 to 8 carbon atoms, an alkoxycarbonyl group having 2 to 8 carbon atoms, a carboxyl group, a halogen atom, a hydroxyl group, a cyano group, and an acid-decomposable group. Among these, an alkyl group having 1 to 4 carbon atoms, a cyano group, and an acid-decomposable group are more preferred. n₂ represents an integer of 0 to 4. When n₂ is an integer of 2 or more, a plurality of the substituents (Rb₂) which are present may be the same as or different from each other. Further, a plurality of the substituents (Rb₂) may be bonded to each other to form a ring.

The repeating unit having a lactone structure or a sultone structure usually has an optical isomer, and any optical isomer may be used. Further, one kind of optical isomer may be used alone or a plurality of optical isomers may be mixed and used. In the case of mainly using one kind of optical isomer, the optical purity (ee) thereof is preferably 90% or more, and more preferably 95% or more.

The repeating unit having a lactone structure or a sultone structure is preferably a repeating unit represented by the following General Formula (III).

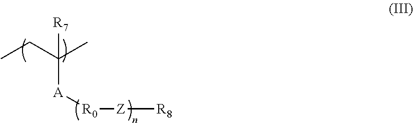

In General Formula (III),
A represents an ester bond (a group represented by —COO—) or an amide bond (a group represented by —CONH—);
in the case where a plurality of R₀'s are present, R₀'s each independently represent an alkylene group, a cycloalkylene group, or a combination thereof; and
in the case where a plurality of Z's are present, Z's each independently represent a single bond, an ether bond, an ester bond, an amide bond, a urethane bond, a group represented by the following General Formula,

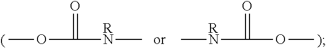

an urea bond, or a group represented by the following General Formula.

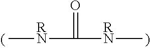

Here, R's each independently represent a hydrogen atom, an alkyl group, a cycloalkyl group, or an aryl group;
R₈ represents a monovalent organic group having a lactone structure or a sultone structure;
n is the repetition number of the structure represented by —R₀—Z—, and represents an integer of 0 to 5, preferably 0 or 1, and more preferably 0, and in the case where n is 0, —R₀—Z— is not present and a single bond is formed; and
R₇ represents a hydrogen atom, a halogen atom, or an alkyl group.

The alkylene group and the cycloalkylene group of R₀ may have a substituent.

Z is preferably an ether bond or an ester bond, and more preferably an ester bond.

The alkyl group of R₇ is preferably an alkyl group having 1 to 4 carbon atoms, more preferably a methyl group or an ethyl group, and particularly preferably a methyl group.

The alkylene group and the cycloalkylene group in R₀, and the alkyl group in R₇ may be each substituted, and examples of the substituent include a halogen atom such as a fluorine atom, a chlorine atom, and a bromine atom, a mercapto group, a hydroxyl group, an alkoxy group, and an acyloxy group.

R₇ is preferably a hydrogen atom, a methyl group, a trifluoromethyl group, or a hydroxymethyl group.

The chained alkylene group in R₀ is preferably a chained alkylene group having 1 to 10 carbon atoms, and more preferably having 1 to 5 carbon atoms, and examples thereof include a methylene group, an ethylene group, and a propylene group. The cycloalkylene group is preferably a cycloalkylene group having 3 to 20 carbon atoms, and examples thereof include a cyclohexylene group, a cyclopentylene group, a norbornylene group, and an adamantylene group. In order to express the effects of the present invention, a chained alkylene group is more preferred, and a methylene group is particularly preferred.

The monovalent organic group having a lactone structure or a sultone structure represented by R₈ is not limited as long as it has a lactone structure or a sultone structure. Specific examples thereof include ones having a lactone structure or a sultone structure represented by any one of General Formulae (LC1-1) to (LC1-21) and (SL1-1) to (SL1-3), among which the structure represented by (LC1-4) is particularly preferred. In (LC1-1) to (LC1-21), n₂ is preferably 2 or less.

Furthermore, R₈ is preferably a monovalent organic group having an unsubstituted lactone structure or sultone structure, or a monovalent organic group having a lactone structure or a sultone structure having a methyl group, a cyano group, or an alkoxycarbonyl group as a substituent, and more preferably a monovalent organic group having a lactone structure having a cyano group as a substituent (cyanolactone).

Specific examples of the repeating unit having a group having a lactone structure or a sultone structure are shown below, but the present invention is not limited thereto.

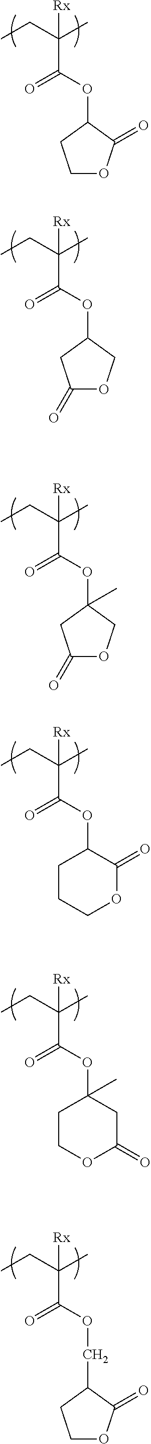

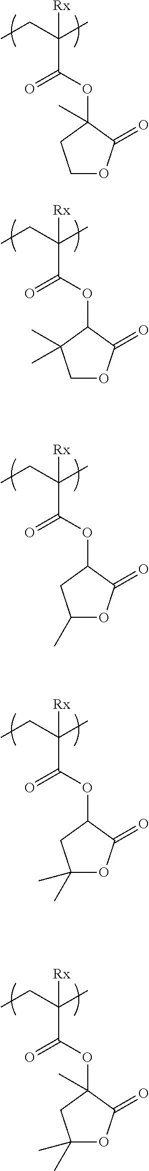

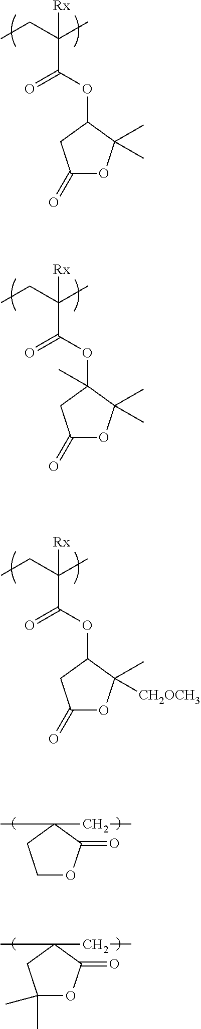

(in the formulae, Rx represents H, CH₃, CH₂OH, or CF₃)

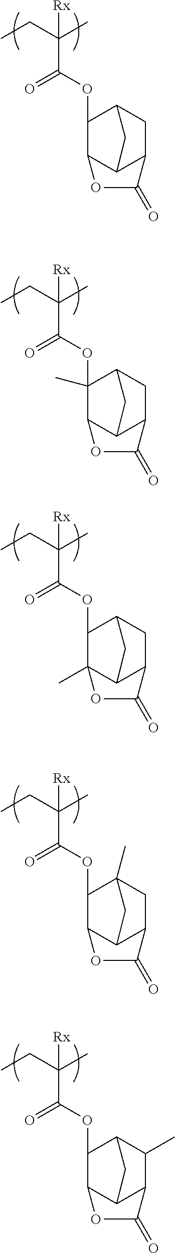

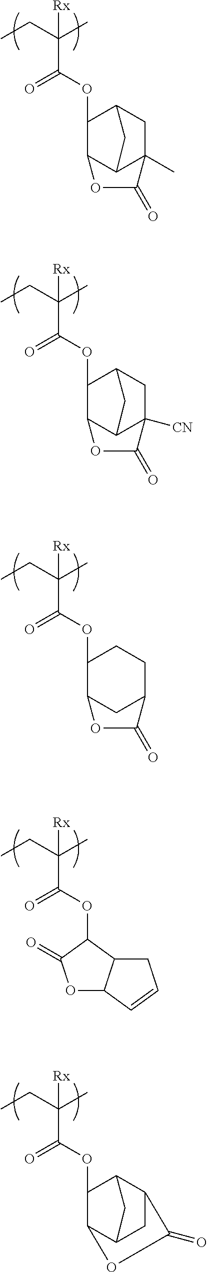

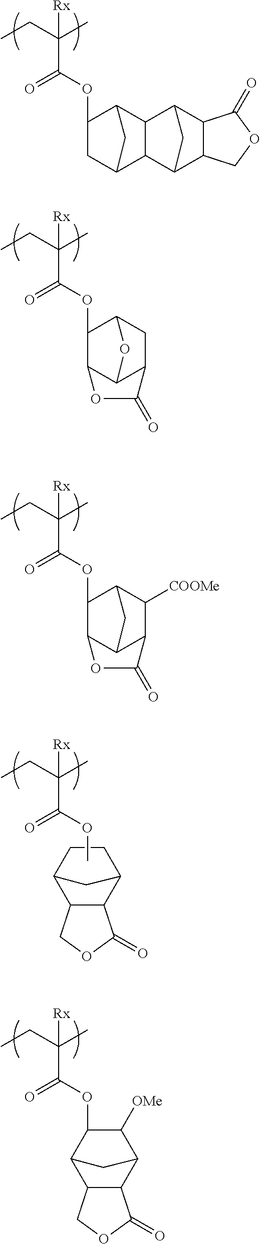

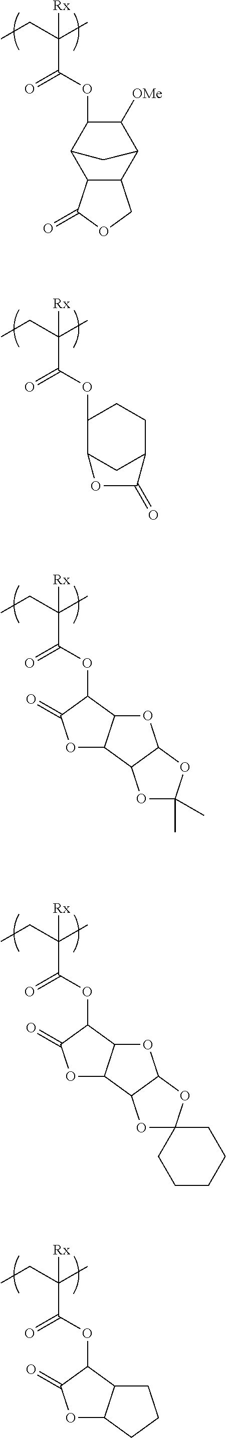

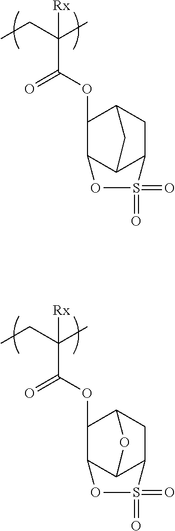

(in the formulae, Rx represents H, CH₃, CH₂OH, or CF₃)

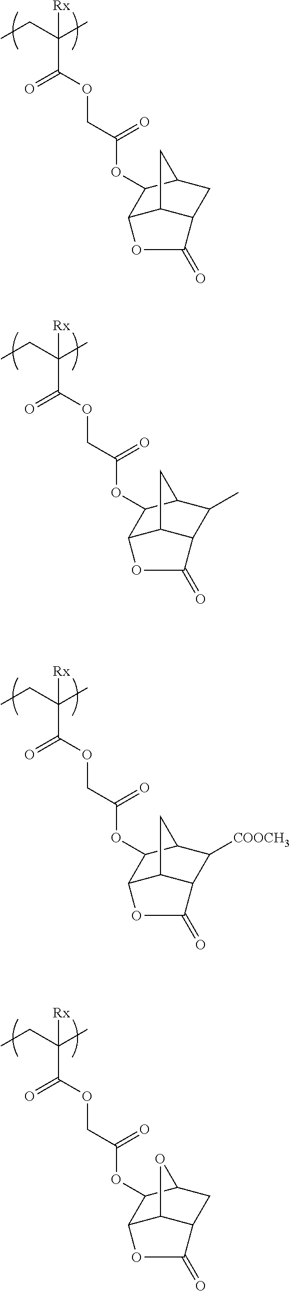

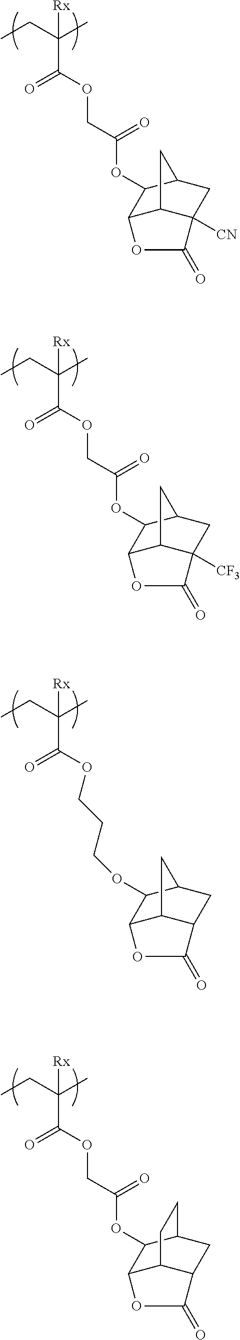

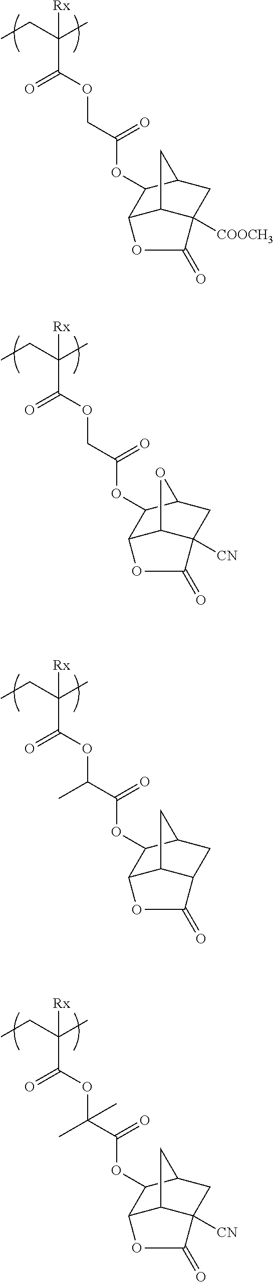

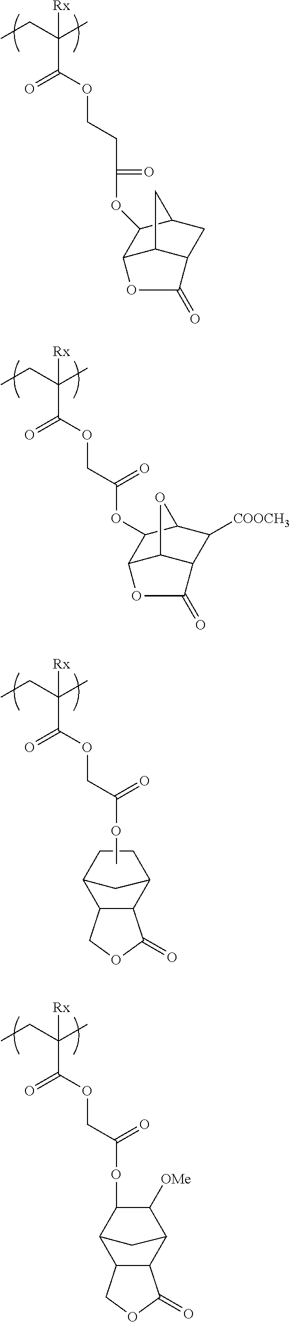

(in the formulae, Rx represents H, CH₃, CH₂OH, or CF₃)

In order to enhance the effects of the present invention, it is also possible to use two or more kinds of repeating units having a lactone structure or a sultone structure in combination.

In the case where the resin (A) contains the repeating units having a lactone structure or a sultone structure, the content of the repeating units having a lactone structure or a sultone structure is preferably from 5% by mole to 60% by mole, more preferably from 5% by mole to 55% by mole, and still more preferably from 10% by mole to 50% by mole, with respect to all the repeating units in the resin (A).

Furthermore, the resin (A) may have a repeating unit having a cyclic carbonic ester structure.

The repeating unit having a cyclic carbonic ester structure is preferably a repeating unit represented by the following General Formula (A-1).

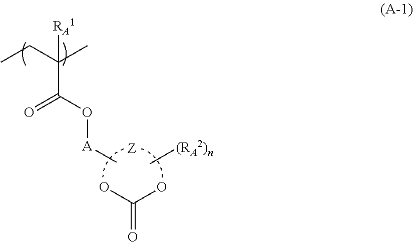

In General Formula (A-1),
R_{A}¹ represents a hydrogen atom or an alkyl group;
in the case where n is 2 or more, R_{A}²'s each independently represent a substituent;
A represents a single bond or a divalent linking group;
Z represents an atomic group which forms a monocyclic or polycyclic structure together with a group represented by —O—C(═O)—O— in the formula; and
n represents an integer of 0 or more.

General Formula (A-1) will be described in detail.

The alkyl group represented by R_{A}¹ may have a substituent such as a fluorine atom. R_{A}¹ preferably represents a hydrogen atom, a methyl group, or a trifluoromethyl group, and more preferably represents a methyl group.

The substituent represented by R_{A}² is, for example, an alkyl group, a cycloalkyl group, a hydroxyl group, an alkoxy group, an amino group, or an alkoxycarbonylamino group, and preferably an alkyl group having 1 to 5 carbon atoms. The alkyl group may have a substituent such as a hydroxyl group.

n represents the number of substituents and is an integer of 0 or more. n is preferably from 0 to 4, and more preferably 0.

Examples of the divalent linking group represented by A include an alkylene group, a cycloalkylene group, an ester bond, an amide bond, an ether bond, a urethane bond, a urea bond, and a combination thereof. The alkylene group is preferably an alkylene group having 1 to 10 carbon atoms, and more preferably an alkylene group having 1 to 5 carbon atoms, and examples thereof include a methylene group, an ethylene group, and a propylene group.

In one embodiment of the present invention, A is preferably a single bond or an alkylene group.

Examples of the monocyclic ring containing —O—C(═O)—O— represented by Z include a 5- to 7-membered ring in which in a cyclic carbonic ester represented by the following General Formula (a), n_{A} is from 2 to 4, and is preferably a 5- or 6-membered ring (n_{A} is 2 or 3), and more preferably a 5-membered ring (n_{A}=2).

Examples of the polycyclic ring containing —O—C(═O)—O— represented by Z include a structure in which a cyclic carbonic ester represented by the following General Formula (a) forms a fused ring together with another ring structure or two or more other ring structures, and a structure in which a Spiro ring is formed. The “other ring structure” capable of forming a fused ring or a spiro ring may be any one of an alicyclic hydrocarbon group, an aromatic hydrocarbon group, and a heterocycle.

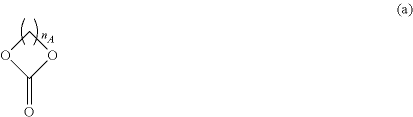

The monomer corresponding to the repeating unit represented by General Formula (A-1) can be synthesized by, for example, methods known in the prior art, described in Tetrahedron Letters, Vol. 27, No. 32, p. 3741 (1986), Organic Letters, Vol. 4, No. 15, p. 2561 (2002), or the like.

The resin (A) may contain one kind of repeating units represented by General Formula (A-1) alone, or two or more kinds thereof.

In the resin (A), the content of the repeating unit having a cyclic carbonic ester structure (preferably the repeating units represented by General Formula (A-1)) is preferably from 3% by mole to 80% by mole, more preferably from 3% by mole to 60% by mole, particularly preferably from 3% by mole to 30% by mole, and most preferably from 10% by mole to 15% by mole, with respect to all the repeating units constituting the resin (A). By setting the content to such a range, the developability, low defect rates, low LWR, low PEB temperature dependency, profiles, and the like for the resist can be improved.

Specific examples (repeating units (A-1a) to (A-1w)) of the repeating unit represented by General Formula (A-1) are shown below, but the present invention is not limited thereto.

Further, in specific examples, R_{A}¹ has the same meaning as R_{A}¹ in General Formula (A-1).

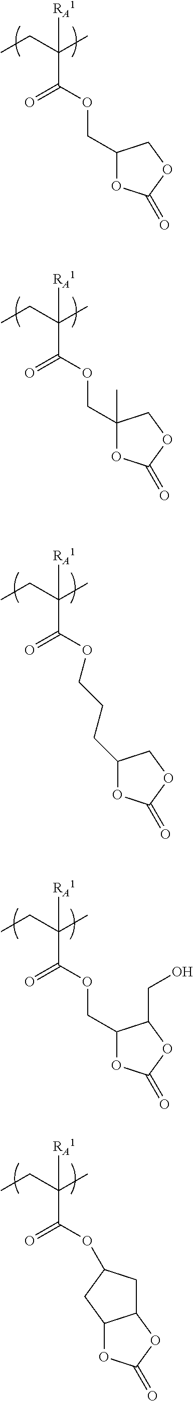

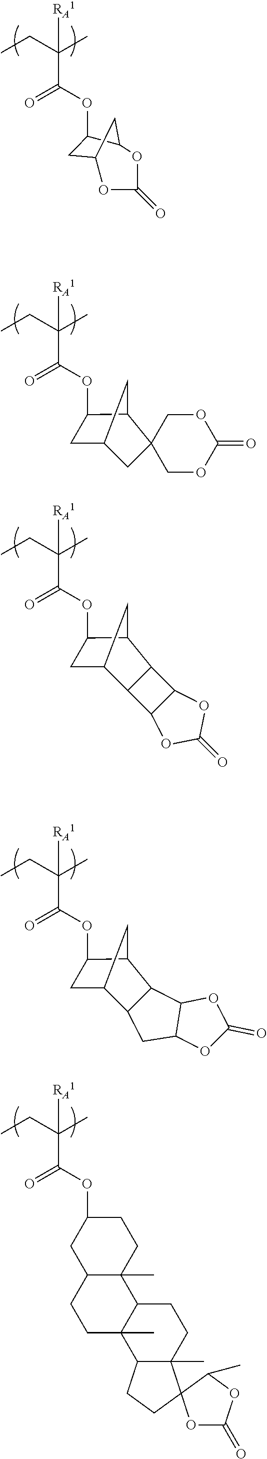

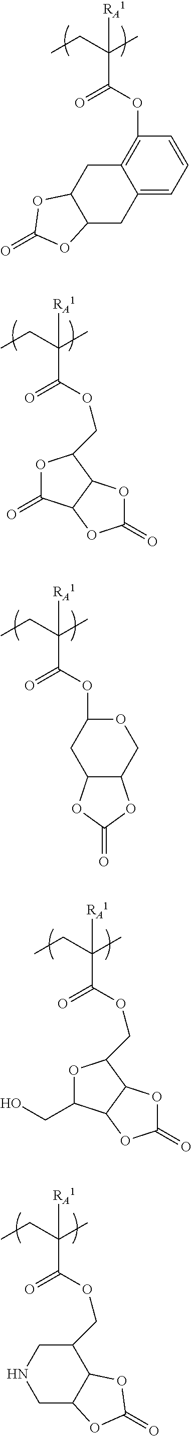

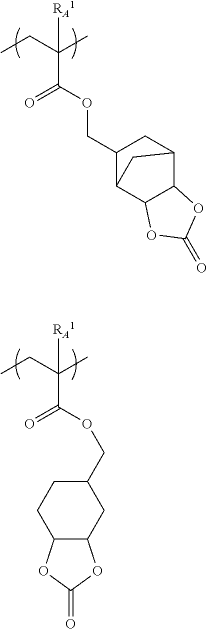

The resin (A) may contain a repeating unit having a hydroxyl group or a cyano group. With the repeating unit, the adhesion to a substrate and the affinity for developing liquid are enhanced. The repeating unit having a hydroxyl group or a cyano group is preferably a repeating unit having an alicyclic hydrocarbon structure substituted with a hydroxyl group or a cyano group, and preferably has no acid-decomposable group.

Incidentally, the repeating unit having an alicyclic hydrocarbon structure substituted with a hydroxyl group or a cyano group is preferably different from the repeating unit having an acid-decomposable group (that is, preferably a repeating unit which is stable against an acid).

The alicyclic hydrocarbon structure in the alicyclic hydrocarbon structure substituted with a hydroxyl group or a cyano group is preferably an adamantyl group, a diamantyl group, or a norbornane group.

More preferred examples of the repeating unit include a repeating unit represented by any one of the following General Formulae (AIIa) to (AIIc).

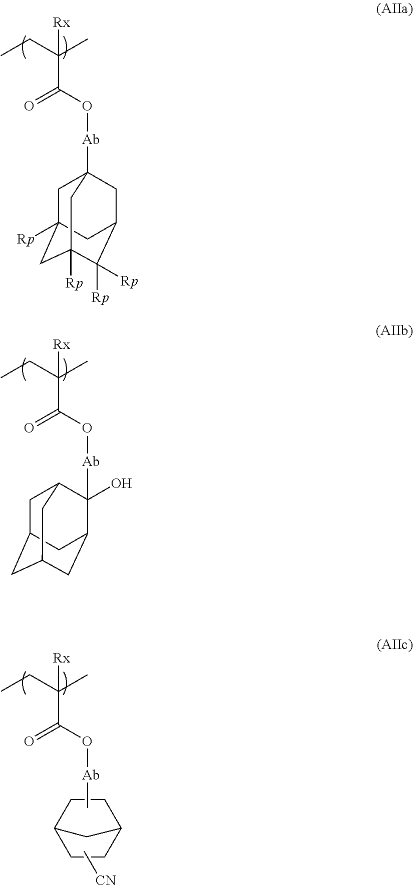

In the formulae, Rx represents a hydrogen atom, a methyl group, a hydroxymethyl group, or a trifluoromethyl group.

Ab represents a single bond or a divalent linking group.

Examples of the divalent linking group represented by Ab include an alkylene group, a cycloalkylene group, an ester bond, an amide bond, an ether bond, a urethane bond, a urea bond, and a combination thereof. The alkylene group is preferably an alkylene group having 1 to 10 carbon atoms, and more preferably an alkylene group having 1 to 5 carbon atoms, and examples thereof include a methylene group, an ethylene group, and a propylene group.

In one embodiment of the present invention, Ab is preferably a single bond or an alkylene group.

Rp represents a hydrogen atom, a hydroxyl group, or a hydroxyalkyl group. A plurality of Rp's may be the same as or different from each other, but at least one of a plurality of Rp's represents a hydroxyl group or a hydroxyalkyl group.

The resin (A) may or may not contain a repeating unit having a hydroxyl group or a cyano group, but in the case where the resin (A) contains a repeating unit having a hydroxyl group or a cyano group, the content of the repeating units having a hydroxyl group or a cyano group is preferably from 1% by mole to 40% by mole, more preferably from 3% by mole to 30% by mole, and still more preferably from 5% by mole to 25% by mole, with respect to all the repeating units in the resin (A).

Specific examples of the repeating unit having a hydroxyl group or a cyano group are shown below, but the present invention is not limited thereto.

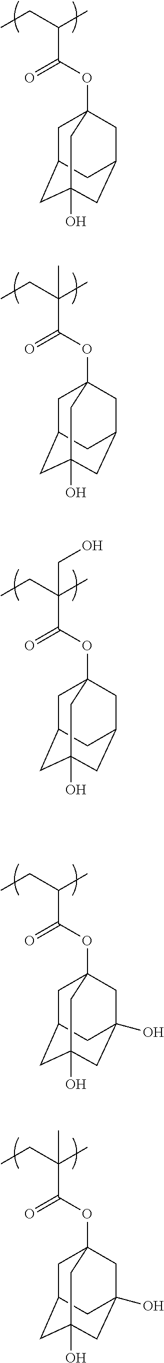

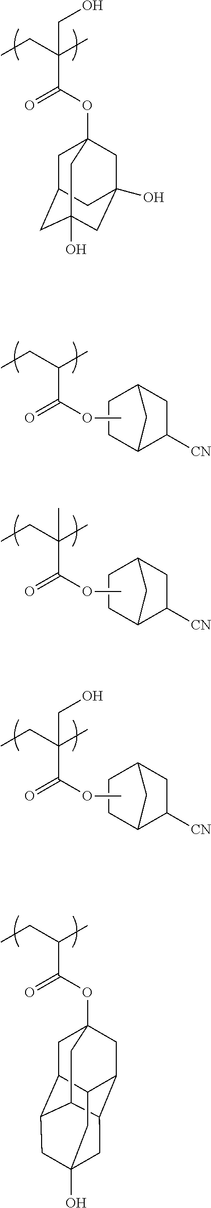

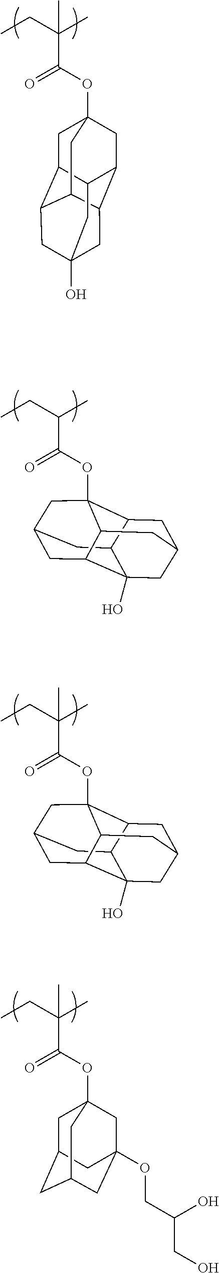

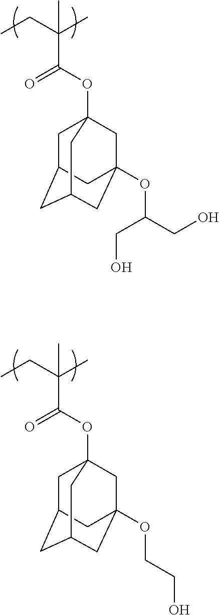

In addition to the above, the monomers described in paragraph [0011] of WO2011/122336A, or the repeating units corresponding thereto can also be suitably used.

The resin (A) may contain a repeating unit having an acid group. The acid group includes a carboxyl group, a sulfonamide group, a sulfonylimide group, a bissulfonylimide group, a naphthol structure, and an aliphatic alcohol group substituted with an electron-withdrawing group on the α-position (for example, a hexafluoroisopropanol group), and it is more preferable that resin (A) contains a repeating unit having a carboxyl group. By incorporating a repeating unit having an acid group thereinto, the resolution in contact holes application increases. With regard to the repeating unit having an acid group, all of a repeating unit in which an acid group is directly bonded to the main chain of the resin, such as repeating unit by an acrylic acid or a methacrylic acid, a repeating unit in which an acid group is bonded to the main chain of the resin through a linking group, and a repeating unit in which an acid group is introduced into the polymer chain terminal by using a polymerization initiator or chain transfer agent having an acid group during the polymerization, are preferred. The linking group may have a monocyclic or polycyclic cyclic hydrocarbon structure. In particular, a repeating unit by an acrylic acid or a methacrylic acid is preferred.

The resin (A) may or may not contain a repeating unit having an acid group, but in the case where the repeating unit having an acid group is contained, the content thereof is preferably 25% by mole or less, and more preferably 20% by mole or less, with respect to all the repeating units in the resin (A). In the case where the resin (A) contains a repeating unit having an acid group, the content of the repeating units having an acid group in the resin (A) is usually 1% by mole or more.

Specific examples of the repeating unit having an acid group are shown below, but the present invention is not limited thereto.

In specific examples, Rx represents H, CH₃, CH₂OH, or CF₃.

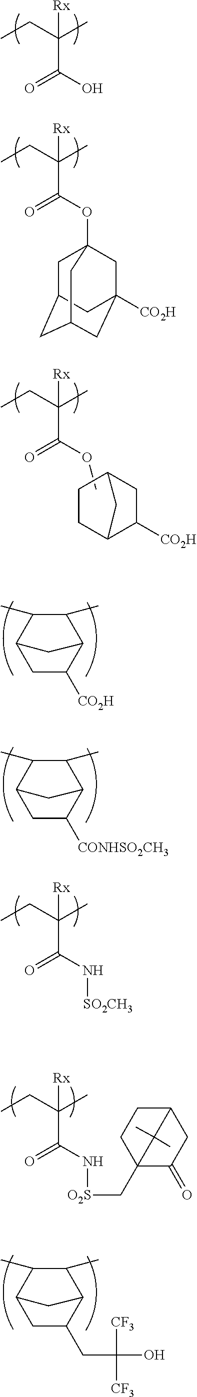

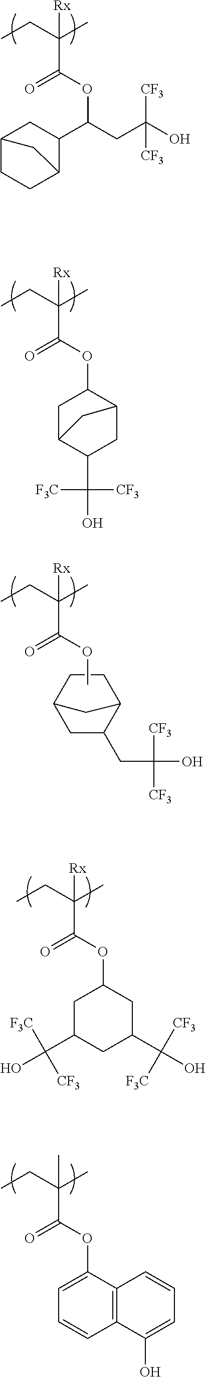

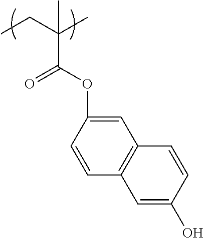

The resin (A) in the present invention may further contain a repeating unit having an alicyclic hydrocarbon structure having no polar group (for example, the acid groups, a hydroxyl group, and a cyano group) and not exhibiting acid-decomposability. With this repeating unit, elution of a low molecular component from the resist film to the immersion liquid can be reduced during the liquid immersion exposure and in addition, the solubility of the resin at the development using a developing liquid including an organic solvent can be appropriately adjusted. Such a repeating unit includes a repeating unit represented by General Formula (IV).

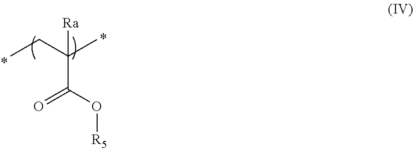

In General Formula (IV), R₅ represents a hydrocarbon group having at least one cyclic structure and having no polar group.

Ra represents a hydrogen atom, an alkyl group, or a —CH₂—O—Ra₂ group. In the formula, Ra₂ represents a hydrogen atom, an alkyl group, or an acyl group. Ra is preferably a hydrogen atom, a methyl group, a hydroxymethyl group, or a trifluoromethyl group, and particularly preferably a hydrogen atom or a methyl group.

The cyclic structure contained in R₅ includes a monocyclic hydrocarbon group and a polycyclic hydrocarbon group. Preferred examples of the monocyclic hydrocarbon group include a cyclopentyl group and a cyclohexyl group.

Examples of the polycyclic hydrocarbon group include a ring-assembly hydrocarbon group and a crosslinked cyclic hydrocarbon group. Examples of the ring-assembly hydrocarbon group include a bicyclohexyl group and a perhydronaphthalenyl group, and examples of the crosslinked cyclic hydrocarbon ring include bicyclic hydrocarbon rings such as a pinane ring, a bornane ring, a norpinane ring, a norbornane ring, and a bicyclooctane ring (a bicyclo[2.2.2]octane ring, a bicyclo[3.2.1]octane ring, or the like); tricyclic hydrocarbon rings such as a homobledane ring, an adamantane ring, a tricyclo[5.2.1.0^{2,6}]decane ring, and a tricyclo[4.3.1.1^{2,5}]undecane ring; and tetracyclic hydrocarbon rings such as a tetracyclo[4.4.0.1^{2,5}.1^{7,10}]dodecane ring and a perhydro-1,4-methano-5,8-methanonaphthalene ring. Other examples of the crosslinked cyclic hydrocarbon ring include fused cyclic hydrocarbon rings, and more specifically, fused rings formed by fusing a plurality of 5- to 8-membered cycloalkane rings, such as a perhydronaphthalene (decalin) ring, a perhydroanthracene ring, a perhydrophenanthrene ring, a perhydroacenaphthene ring, a perhydrofluorene ring, a perhydroindene ring, and a perhydrophenalene ring.

Preferred examples of the crosslinked cyclic hydrocarbon ring include a norbornyl group, an adamantyl group, a bicyclooctanyl group, and a tricyclo[5.2.1.0^{2,6}]decanyl group. More preferred examples of the crosslinked cyclic hydrocarbon rings include a norbornyl group and an adamantyl group.

Such an alicyclic hydrocarbon group may have a substituent. Preferred examples of the substituent include a halogen atom, an alkyl group, a hydroxyl group substituted with a hydrogen atom, and an amino group substituted with a hydrogen atom.

The resin (A) may or may not contain a repeating unit having an alicyclic hydrocarbon structure having no polar group and not exhibiting acid-decomposability, but in the case where such a repeating unit is contained in the resin (A), the content thereof is preferably from 1% by mole to 50% by mole, more preferably from 5% by mole to 50% by mole, and still more preferably from 5% by mole to 30% by mole, with respect to all the repeating units in the resin (A).

Specific examples of the repeating unit having an alicyclic hydrocarbon structure having no polar group and not exhibiting acid-decomposability are shown below, but the present invention is not limited thereto. In the formulae, Ra represents H, CH₃, CH₂OH, or CF₃.

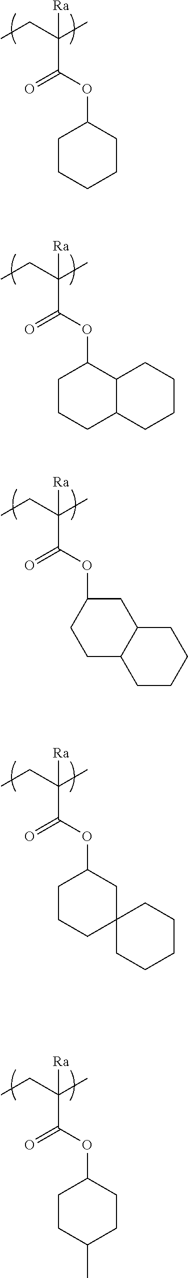

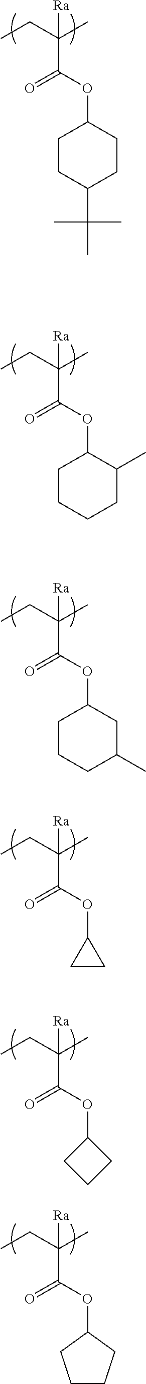

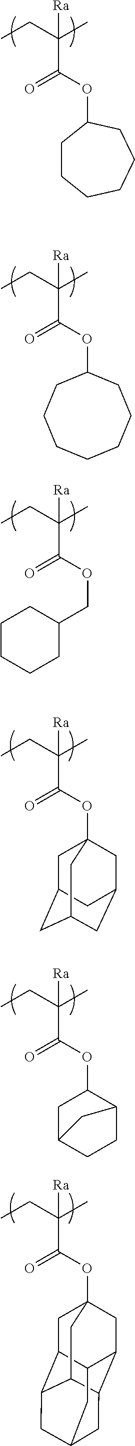

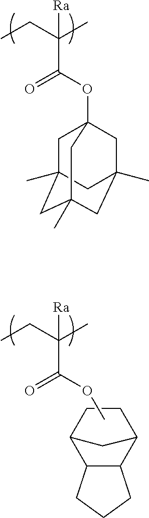

In addition to the repeating structural units as described above, the resin (A) used in the radiation-sensitive resin composition can have a variety of repeating structural units for the purpose of adjusting dry etching resistance, suitability for a standard developing liquid, adhesion to a substrate and a resist profile, and in addition, resolving power, heat resistance, sensitivity, and the like, which are characteristics generally required of the radiation-sensitive resin composition.

Examples of such repeating structural units include, but are not limited to, repeating structural units corresponding to the following monomers.

Thus, it becomes possible to perform fine adjustments to performance required for the resin used in the radiation-sensitive resin composition, in particular:
(1) solubility for a coating solvent,
(2) film-forming properties (glass transition point),
(3) alkali developability,
(4) film reduction (selection of hydrophilic, hydrophobic, or alkali-soluble groups),
(5) adhesion of an unexposed area to a substrate,
(6) dry etching resistance,
and the like.

Examples of such a monomer include a compound having one addition-polymerizable unsaturated bond selected from acrylic esters, methacrylic esters, acrylamides, methacrylamides, allyl compounds, vinyl ethers, and vinyl esters.

In addition to these, an addition-polymerizable unsaturated compound that is copolymerizable with the monomers corresponding to various repeating structural units as described above may be copolymerized.

In the resin (A) used in the radiation-sensitive resin composition, the molar ratio of each repeating structural unit content is appropriately set in order to adjust dry etching resistance, suitability for a standard developing liquid, adhesion to a substrate and a resist profile of the radiation-sensitive resin composition, and in addition, resolving power, heat resistance, sensitivity, and the like, each of which is performance generally required for the radiation-sensitive resin composition.

The form of the resin (A) may be any of random-type, block-type, comb-type, and star-type forms. The resin (A) can be synthesized by, for example, radical, cationic, or anionic polymerization of unsaturated monomers corresponding to respective structures. It is also possible to obtain a desired resin after polymerization using unsaturated monomers corresponding to precursors of respective structures, and then by carrying out a polymer reaction.

When the radiation-sensitive resin composition is for ArF exposure, it is preferable that the resin (A) has substantially no aromatic rings (specifically, the proportion of repeating units having an aromatic group in the resin is preferably 5% by mole or less, more preferably 3% by mole or less, and ideally 0% by mole, that is, the resin does not have an aromatic group) in terms of transparency to ArF light. It is preferable that the resin (A) has a monocyclic or polycyclic alicyclic hydrocarbon structure.

In the case where the radiation-sensitive resin composition contains a resin (D) as described later, it is preferable that the resin (A) contains neither a fluorine atom nor a silicon atom (specifically, the proportion of repeating units having fluorine atom or silicon atom in the resin is preferably 5% by mole or less, more preferably 3% by mole or less, and ideally 0% by mole) from the viewpoint of compatibility with the resin (D).

The resin (A) used in the radiation-sensitive resin composition is preferably a resin in which all the repeating units are composed of (meth)acrylate-based repeating units. In this case, all the repeating units may be methacrylate-based repeating units, all the repeating units may be acrylate-based repeating units, or all the repeating units may be composed of methacrylate-based repeating units and acrylate-based repeating units, but the acrylate-based repeating units preferably accounts for 50% by mole or less with respect to all the repeating units.

Specific examples of the resin (A) include ones mentioned in Examples as described later, but resins other than those as below can also be applied as appropriate.

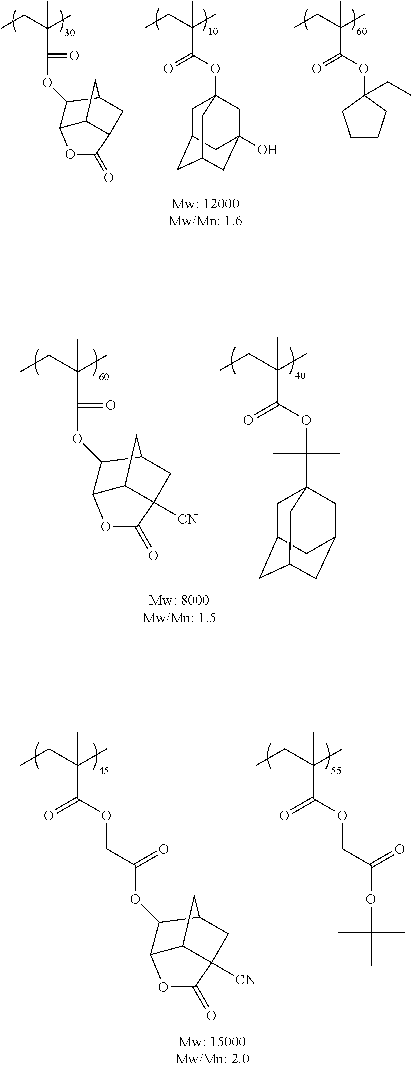

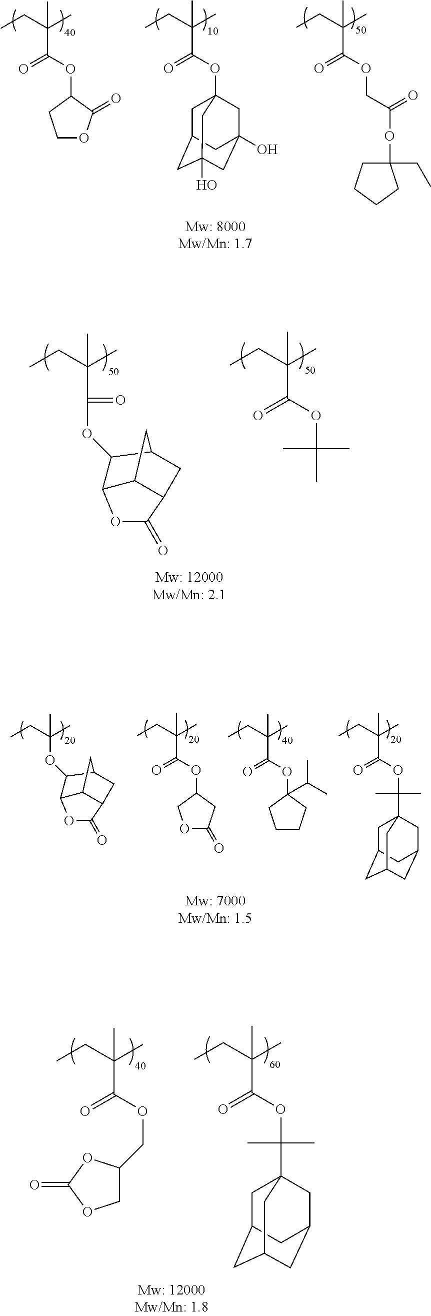

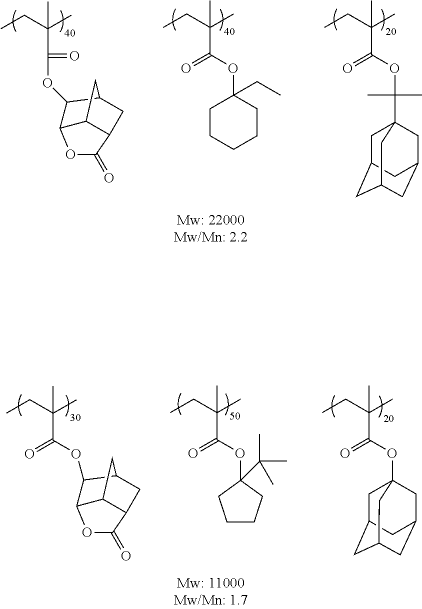

In the case of irradiating the radiation-sensitive resin composition with KrF excimer laser light, electron beams, X-rays, or high-energy beams at a wavelength of 50 nm or less (EUV or the like), the resin (A) preferably further contains a repeating unit having an aromatic ring structure such as a hydroxystyrene-based repeating unit. It is more preferable to contain a hydroxystyrene-based repeating unit, a hydroxystyrene-based repeating unit protected by an acid-decomposable group, and an acid-decomposable repeating unit such as tertiary alkyl ester (meth)acrylate.

Preferred examples of the hydroxystyrene-based repeating unit having an acid-decomposable group include repeating units composed of t-butoxycarbonyloxystyrene, 1-alkoxyethoxystyrene, and tertiary alkyl ester (meth)acrylate. Repeating units composed of 2-alkyl-2-adamantyl (meth)acrylate and dialkyl(1-adamantyl)methyl (meth)acrylate are more preferred.

Specific examples of the resin (P1) having a repeating unit containing an aromatic ring structure are shown below, but the present invention is not limited thereto.

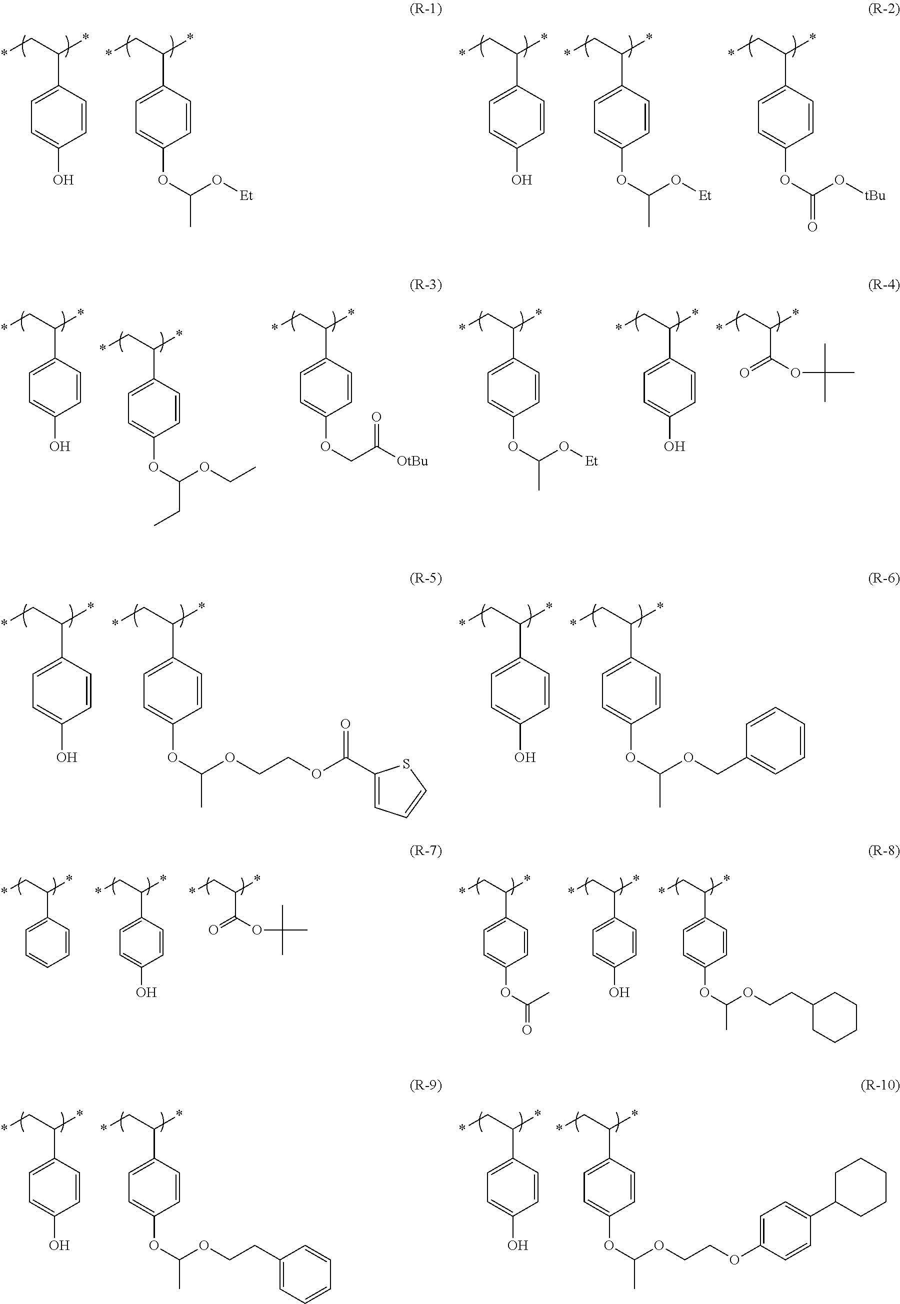

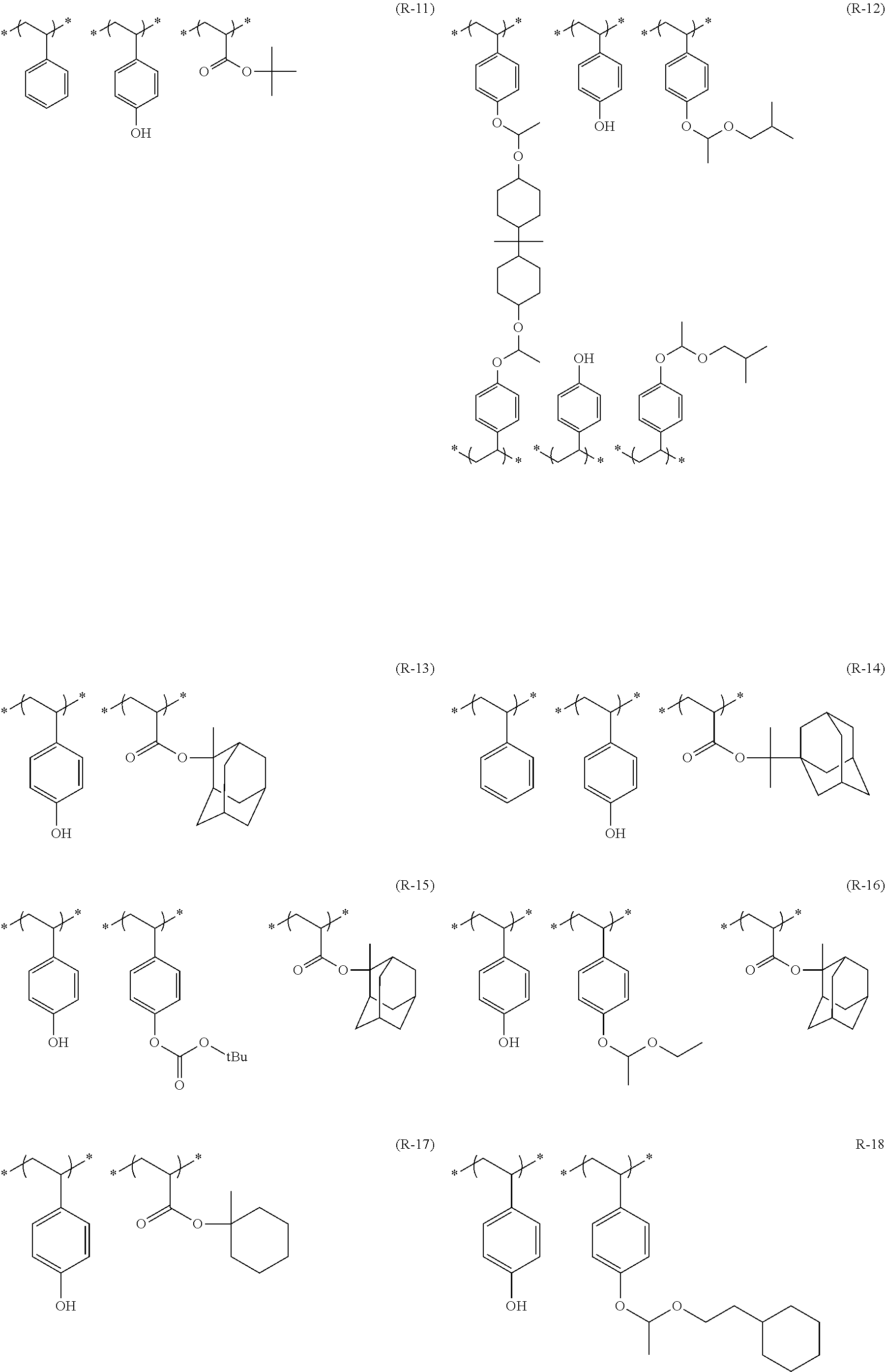

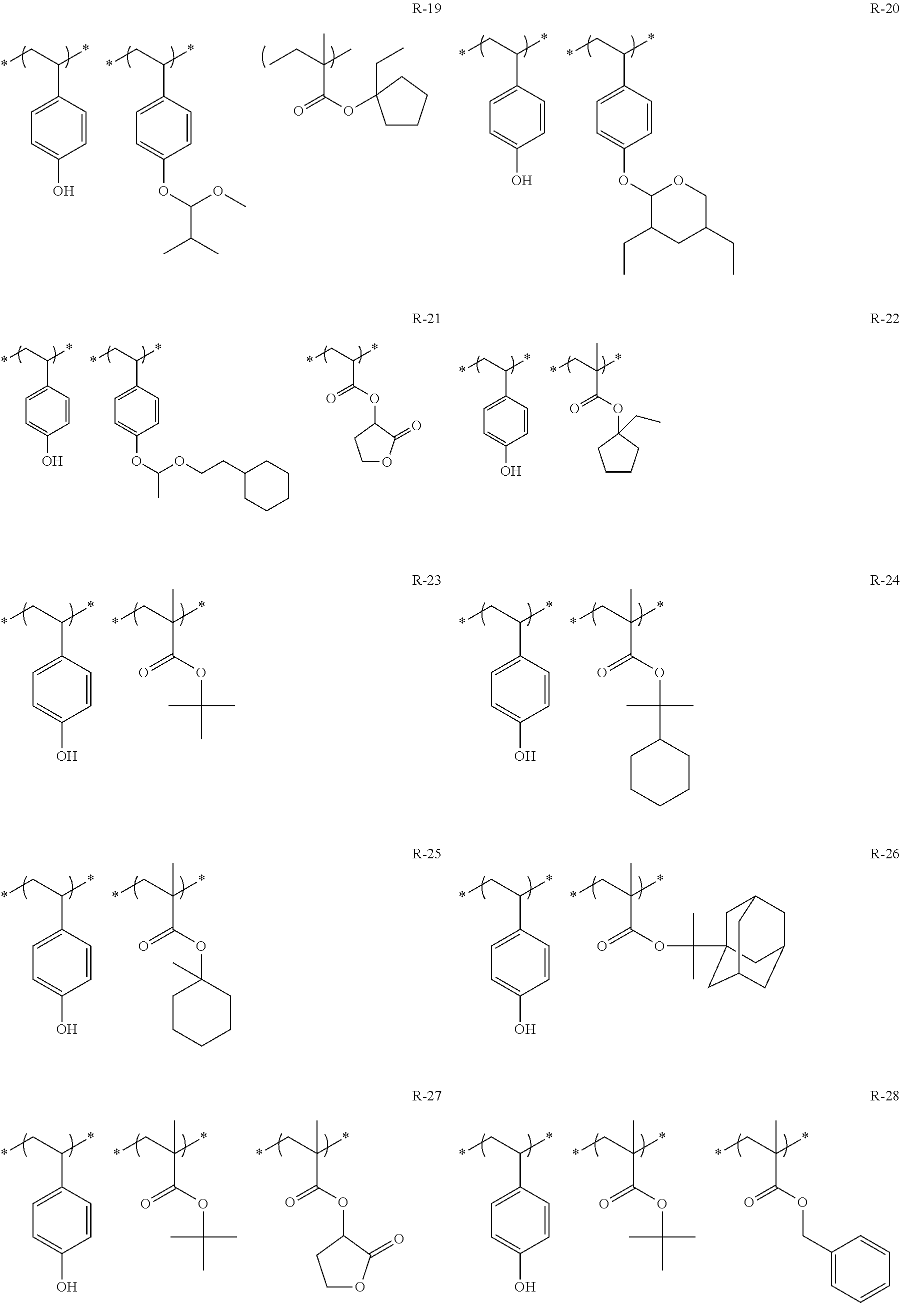

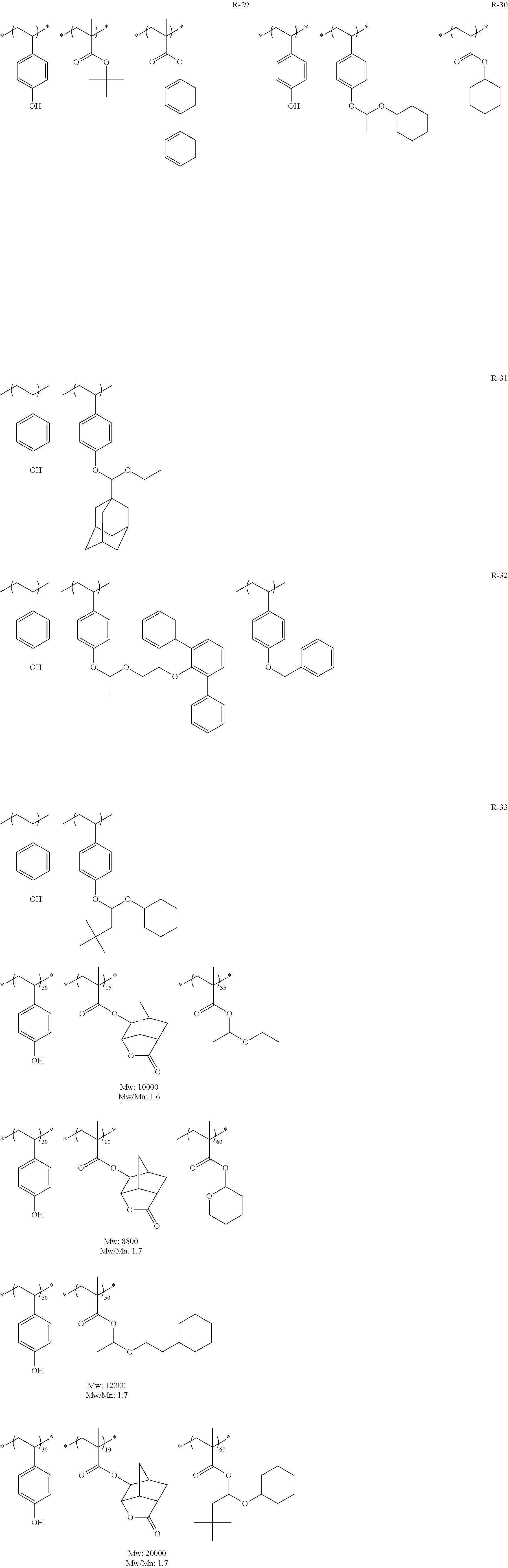

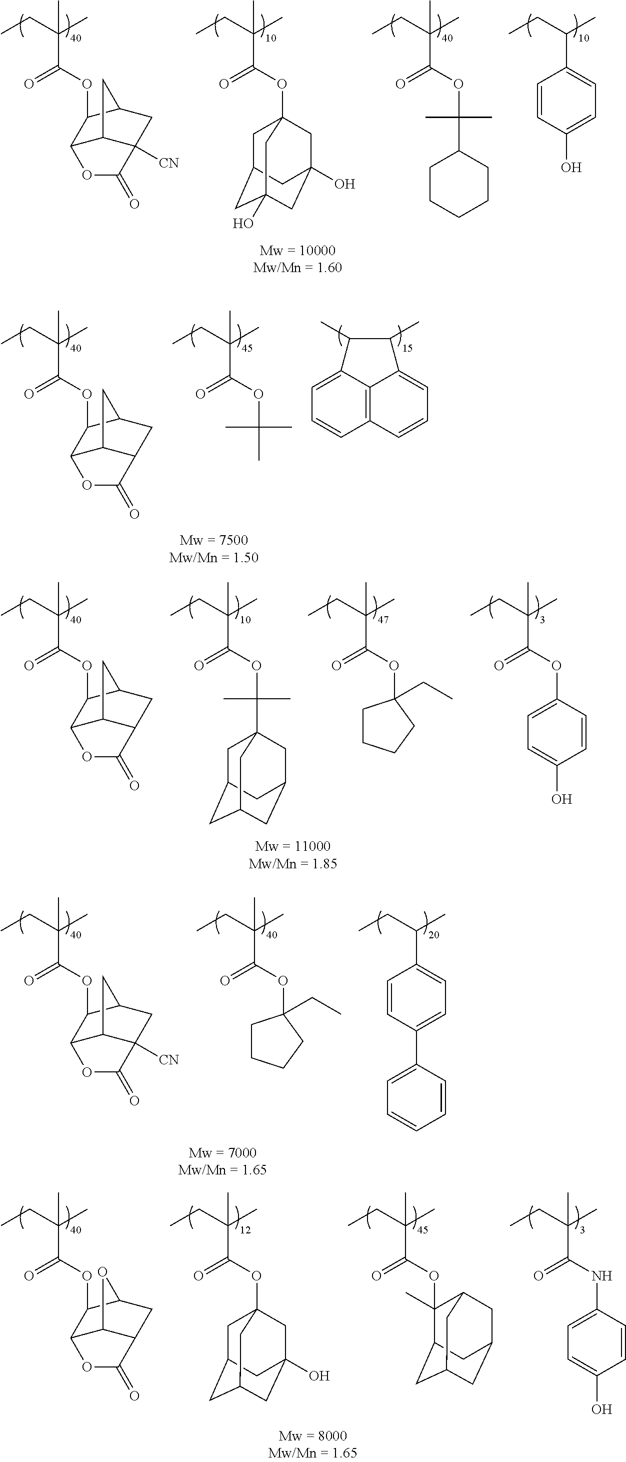

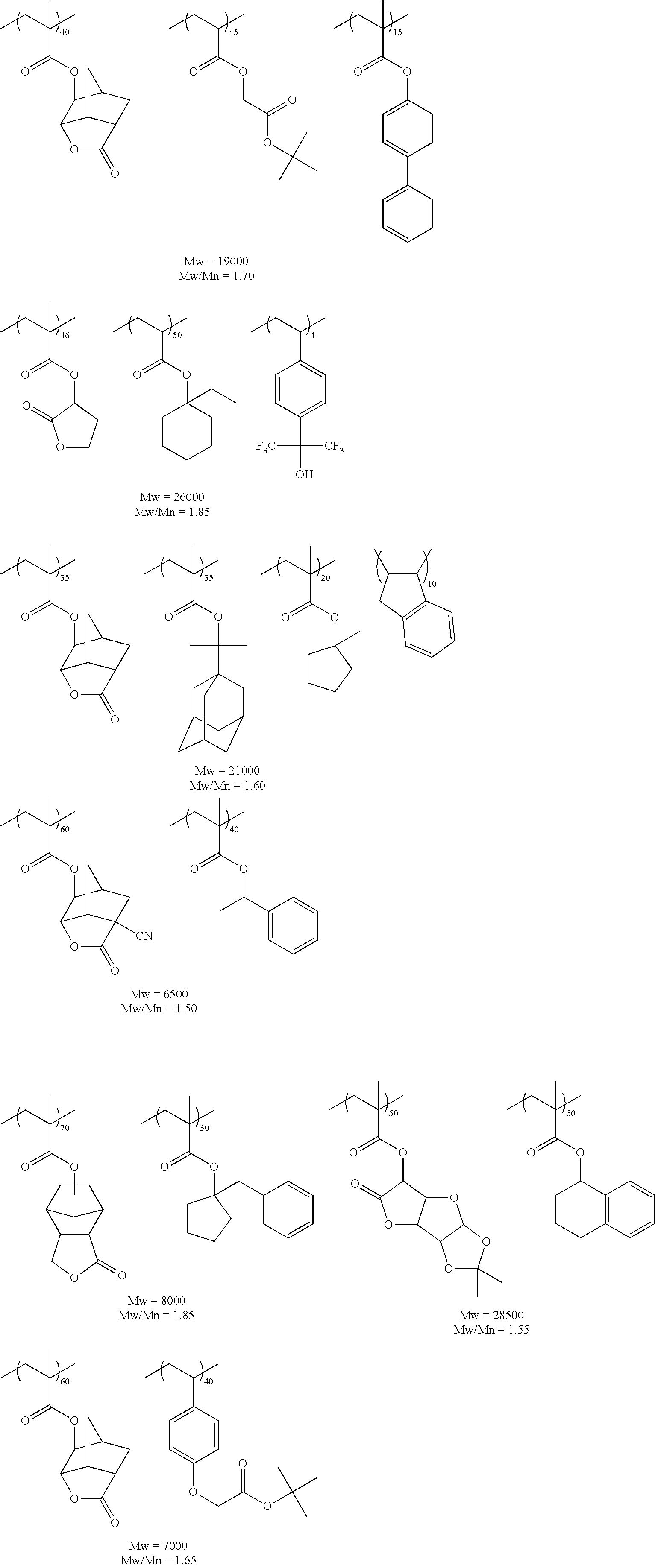

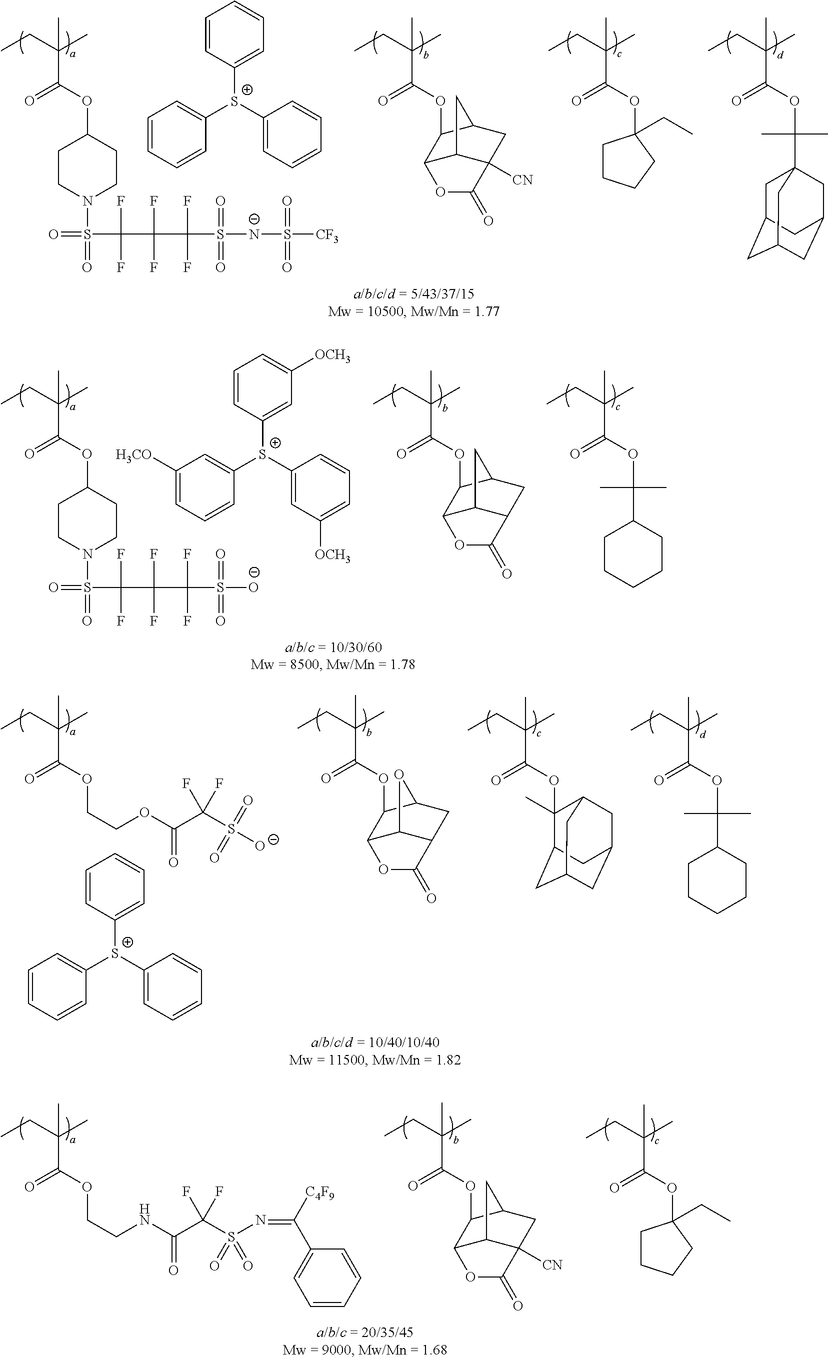

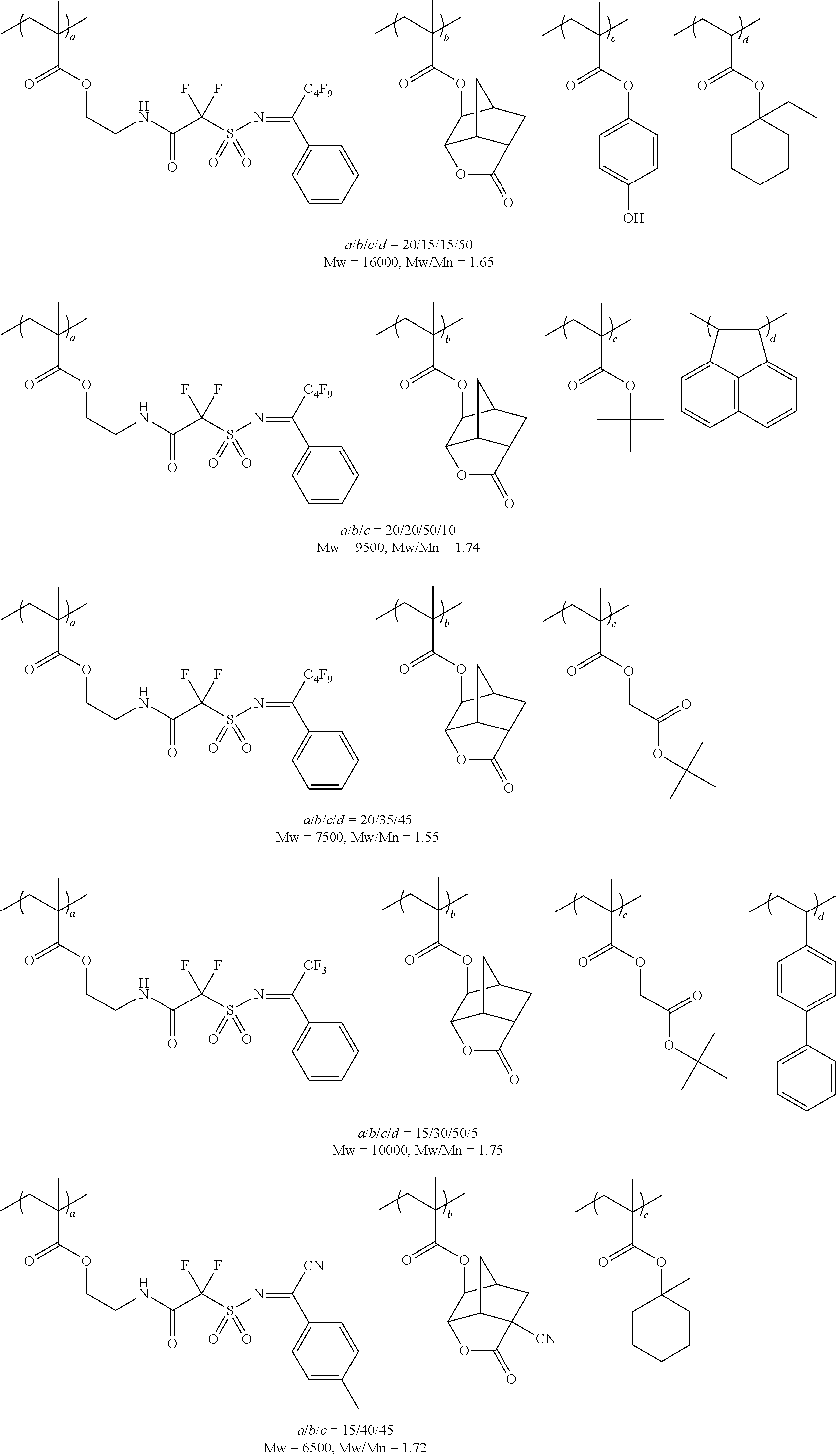

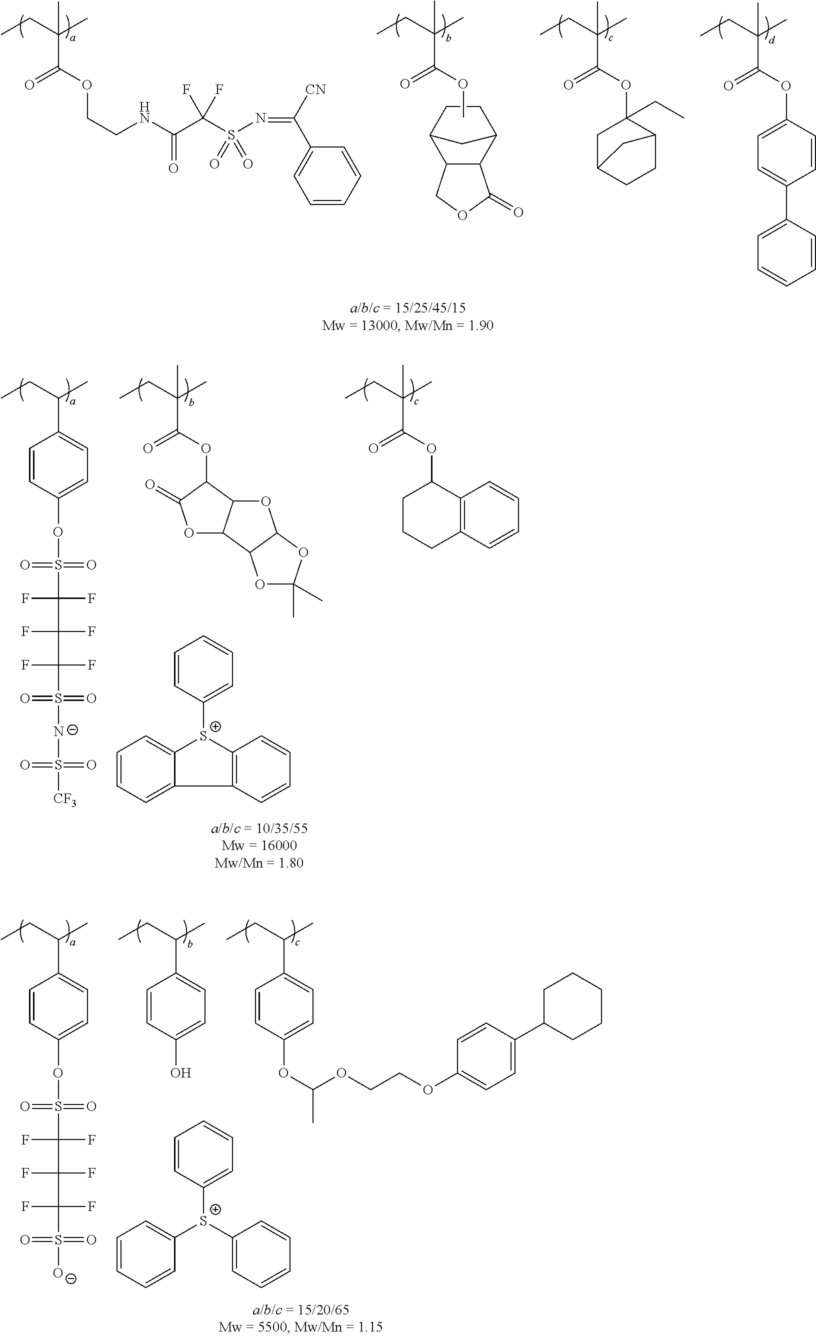

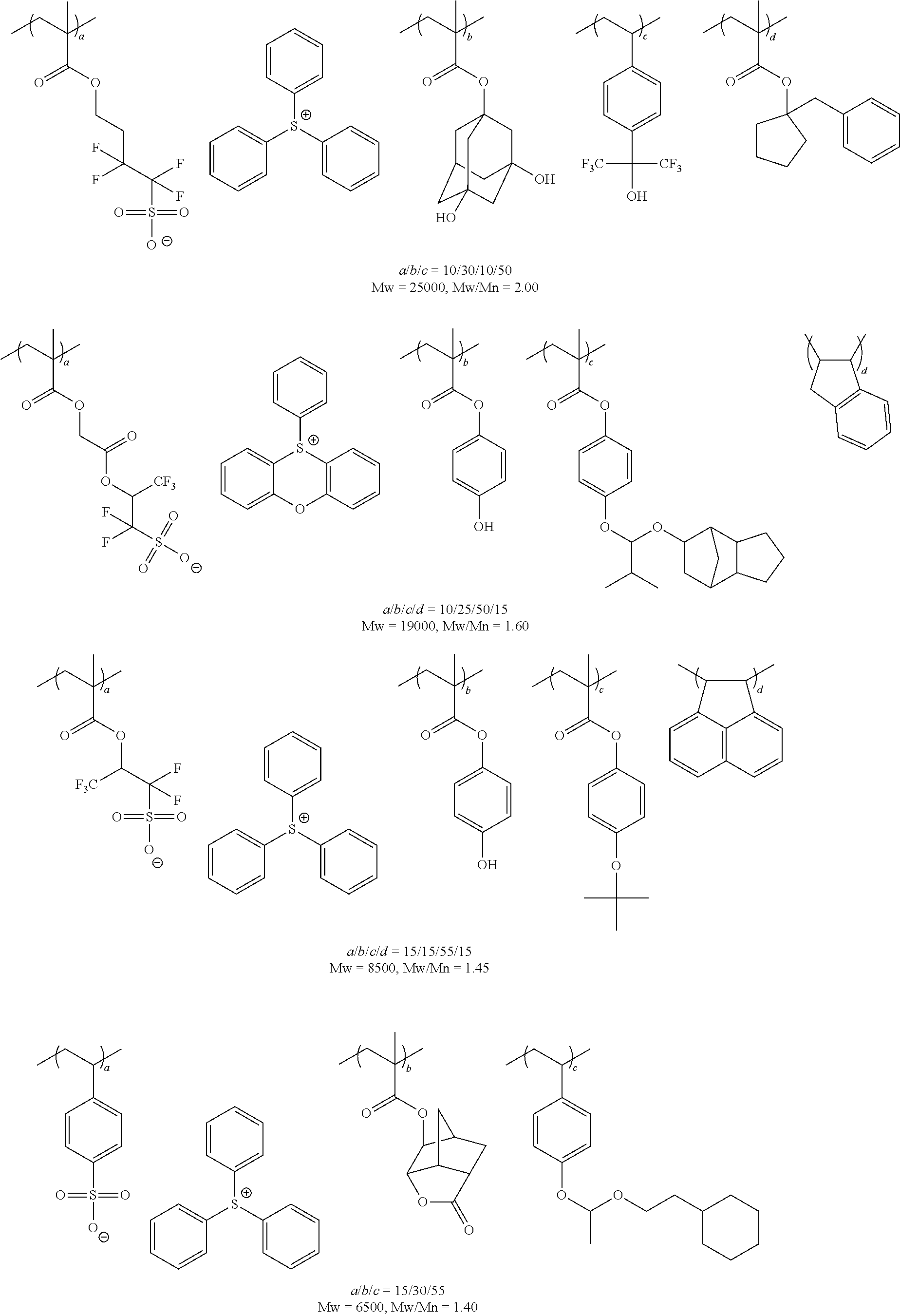

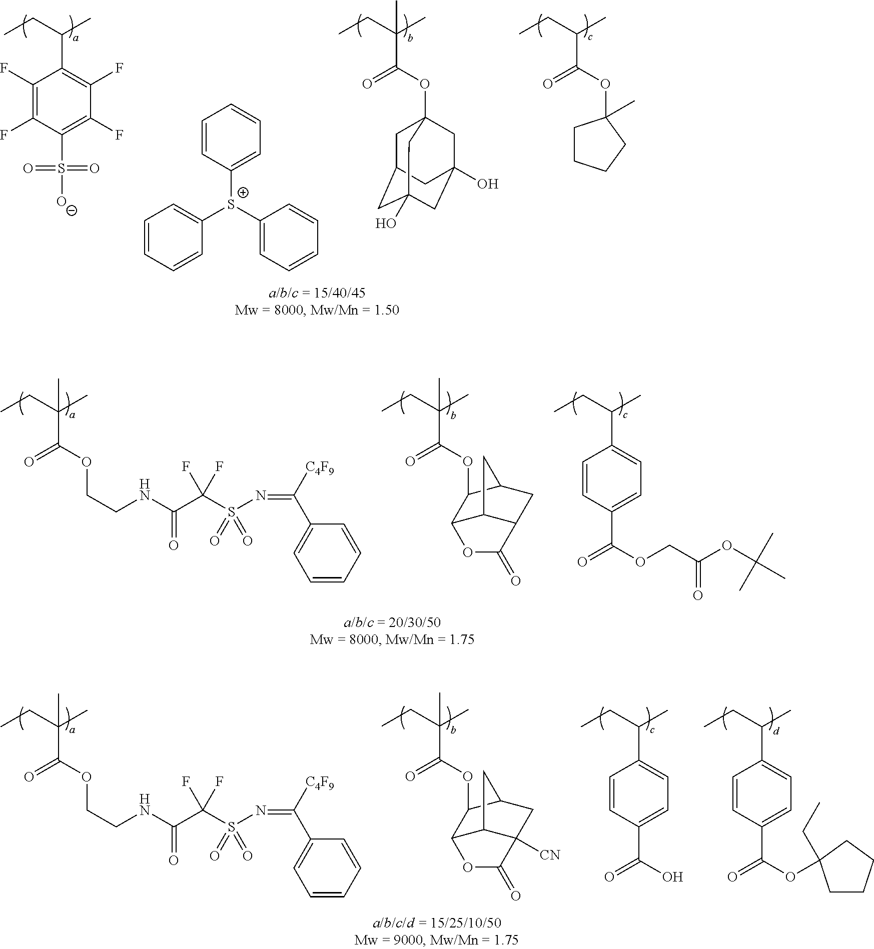

In these specific examples, tBu represents a t-butyl group.

The resin (A) in the present invention can be synthesized in accordance with an ordinary method (for example, radical polymerization, living radical polymerization, and anionic polymerization). For example, reference can be made to the descriptions of paragraphs 0121 to 0128 of JP2012-073402A (paragraphs 0203 to 0211 of the corresponding US2012/077122A), the contents of which are incorporated in the specification of the present application.

The weight-average molecular weight of the resin (A) in the present invention is preferably 7,000 or more as mentioned above, preferably from 7,000 to 200,000, more preferably from 7,000 to 50,000, still more preferably from 7,000 to 40,000 and particularly preferably from 7,000 to 30,000, as measured by a GPC method, and calculated in terms of polystyrene. When the weight-average molecular weight is lower than 7,000, the solubility in an organic developing liquid becomes too high, and as a result, there is a concern that it may fail to form precise patterns.

The dispersity (molecular-weight distribution) of the resin used is generally from 1.0 to 3.0, preferably from 1.0 to 2.6, more preferably from 1.0 to 2.0, and particularly preferably from 1.4 to 2.0. The narrower the molecular-weight distribution of the resin, the more excellent resolution and resist profile are achieved, and in addition, the smoother side wall of a resist pattern and the more excellent roughness are obtained.

In the radiation-sensitive resin composition, the blending ratio of the resin (A) in the entire composition is preferably from 30% by mass to 99% by mass, and more preferably 60% by mass to 95% by mass, with respect to the total solid content.

In addition, in the present invention, the resins (A) may be used alone or in combination of a plurality thereof.

[2] Compound (B) Capable of Generating Acid by Irradiation with Actinic Rays or Radiation

The radiation-sensitive resin composition used in the present invention typically further contains a compound (B) capable of generating an acid by irradiation with actinic rays or radiation (hereinafter also referred to as an “acid generator”). The compound (B) capable of generating an acid by irradiation with actinic rays or radiation is preferably a compound capable of generating an organic acid by irradiation with actinic rays or radiation.

The compound (B) capable of generating an acid by irradiation with actinic rays or radiation may be either a form of a low molecular compound or a form introduced into a part of a polymer. Further, a combination of the form of a low molecular compound and the form introduced into a part of a polymer may also be used.

In the case where the compound (B) capable of generating an acid by irradiation with actinic rays or radiation is the form of a low molecular compound, the molecular weight is preferably 3,000 or less, more preferably 2,000 or less, and still more preferably 1,000 or less.

In the case where the compound (B) capable of generating an acid by irradiation with actinic rays or radiation is in the form introduced into a part of a polymer, it may be introduced into a part of the acid-decomposable resin as described above or into a resin other than the acid-decomposable resin.

In the present invention, the compound (B) capable of generating an acid by irradiation with actinic rays or radiation is preferably in the form of a low molecular compound.

The acid generator which can be used may be appropriately selected from a photoinitiator for cationic photopolymerization, a photoinitiator for radical photopolymerization, a photodecoloring agent for dyes, a photodiscoloring agent, a known compound capable of generating an acid by irradiation with actinic rays or radiation, which is used for a microresist or the like, and a mixture thereof.

Examples thereof include a diazonium salt, a phosphonium salt, a sulfonium salt, an iodonium salt, imidesulfonate, oxime sulfonate, diazodisulfone, disulfone, and o-nitrobenzyl sulfonate.

Preferred examples of the compounds among the acid generators include compounds represented by the following General Formulae (ZI), (ZII), and (ZIII).

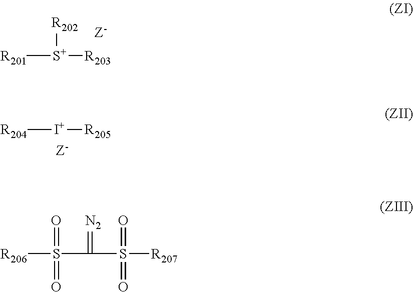

In General Formula (ZI),
R₂₀₁, R₂₀₂, and R₂₀₃ each independently represent an organic group;
the number of carbon atoms of the organic group as R₂₀₁, R₂₀₂, and R₂₀₃ is generally from 1 to 30, and preferably from 1 to 20;
two members out of R₂₀₁ to R₂₀₃ may be bonded to each other to form a ring structure, and the ring may contain an oxygen atom, a sulfur atom, an ester bond, an amide bond, or a carbonyl group, and examples of the group formed by the mutual bonding of two members out of R₂₀₁ to R₂₀₃ include an alkylene group (for example, a butylene group and a pentylene group); and
Z⁻ represents a non-nucleophilic anion.

Examples of the non-nucleophilic anion as Z⁻ include a sulfonic acid anion, a carboxylic acid anion, a sulfonylimide anion, a bis(alkylsulfonyl)imide anion, and a tris(alkylsulfonyl)methyl anion.

The non-nucleophilic anion is an anion having an extremely low ability of causing a nucleophilic reaction and this anion can suppress the decomposition with aging due to an intramolecular nucleophilic reaction. With this anion, the stability with aging of the radiation-sensitive resin composition is improved.

Examples of the sulfonic acid anion include an aliphatic sulfonic acid anion, an aromatic sulfonic acid anion, and a camphorsulfonic acid anion.

Examples of the carboxylic acid anion include an aliphatic carboxylic acid anion, an aromatic carboxylic acid anion, and an aralkylcarboxylic acid anion.

The aliphatic moiety in the aliphatic sulfonic acid anion and aliphatic carboxylic acid anion may be an alkyl group, or a cycloalkyl group but is preferably an alkyl group having 1 to 30 carbon atoms or a cycloalkyl group having 3 to 30 carbon atoms, and examples thereof include a methyl group, an ethyl group, a propyl group, an isopropyl group, an n-butyl group, an isobutyl group, a sec-butyl group, a pentyl group, a neopentyl group, a hexyl group, a heptyl group, an octyl group, a nonyl group, a decyl group, an undecyl group, a dodecyl group, a tridecyl group, a tetradecyl group, a pentadecyl group, a hexadecyl group, a heptadecyl group, an octadecyl group, a nonadecyl group, an eicosyl group, a cyclopropyl group, a cyclopentyl group, a cyclohexyl group, an adamantyl group, a norbornyl group, and a bornyl group.

Preferred examples of the aromatic group in the aromatic sulfonic acid anion and aromatic carboxylic acid anion include an aryl group having 6 to 14 carbon atoms, for example, a phenyl group, a tolyl group, and a naphthyl group.

The alkyl group, the cycloalkyl group, and the aryl group in the aliphatic sulfonic acid anion and the aromatic sulfonic acid anion may have a substituent. Examples of the substituent on the alkyl group, the cycloalkyl group, and the aryl group in the aliphatic sulfonic acid anion and the aromatic sulfonic acid anion include a nitro group, a halogen atom (a fluorine atom, a chlorine atom, a bromine atom, or an iodine atom), a carboxyl group, a hydroxyl group, an amino group, a cyano group, an alkoxy group (preferably having 1 to 15 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), an alkoxycarbonyloxy group (preferably having 2 to 7 carbon atoms), an alkylthio group (preferably having 1 to 15 carbon atoms), an alkylsulfonyl group (preferably having 1 to 15 carbon atoms), an alkyliminosulfonyl group (preferably having 1 to 15 carbon atoms), an aryloxysulfonyl group (preferably having 6 to 20 carbon atoms), an alkylaryloxysulfonyl group (preferably having 7 to 20 carbon atoms), a cycloalkylaryloxysulfonyl group (preferably having 10 to 20 carbon atoms), an alkyloxyalkyloxy group (preferably having 5 to 20 carbon atoms), and a cycloalkylalkyloxyalkyloxy group (preferably having 8 to 20 carbon atoms). The aryl group and the ring structure contained in each group may further have, as the substituent, an alkyl group (preferably having 1 to 15 carbon atoms) or a cycloalkyl group (preferably having 3 to 15 carbon atoms).

Preferred examples of the aralkyl group in the aralkylcarboxylic acid anion include an aralkyl group having 7 to 12 carbon atoms, for example, a benzyl group, a phenethyl group, a naphthylmethyl group, a naphthylethyl group, and a naphthylbutyl group.

The alkyl group, the cycloalkyl group, the aryl group, and the aralkyl group in the aliphatic carboxylic acid anion, the aromatic carboxylic acid anion, and the aralkylcarboxylic acid anion may have a substituent. Examples of the substituent include a halogen atom, an alkyl group, a cycloalkyl group, an alkoxy group, and an alkylthio group, which are the same as those in the aromatic sulfonic acid anion.

Examples of the sulfonylimide anion include a saccharin anion.

Preferred examples of the alkyl group in the bis(alkylsulfonyl)imide anion and the tris(alkylsulfonyl)methide anion include an alkyl group having 1 to 5 carbon atoms, and examples thereof include a methyl group, an ethyl group, a propyl group, an isopropyl group, an n-butyl group, an isobutyl group, a sec-butyl group, a pentyl group, and a neopentyl group.

Two alkyl groups in the bis(alkylsulfonyl)imide anion may be linked to each other to constitute an alkylene group (preferably having 2 to 4 carbon atoms) and to form a ring together with an imide group and two sulfonyl groups. Examples of the substituent which such an alkyl group and an alkylene group formed by the mutual linking of the two alkyl groups in the bis(alkylsulfonyl)imide anion may have include a halogen atom, a halogen atom-substituted alkyl group, an alkoxy group, an alkylthio group, an alkyloxysulfonyl group, an aryloxysulfonyl group, and a cycloalkylaryloxysulfonyl group, among which the fluorine atom-substituted alkyl group is preferred.

Other examples of the non-nucleophilic anion include fluorinated phosphorus (for example, PF₆⁻), fluorinated boron (for example, BF₄⁻), and fluorinated antimony (for example, SbF₆⁻).

The non-nucleophilic anion of Z⁻ is preferably an aliphatic sulfonic acid anion substituted with a fluorine atom at least at the α-position of sulfonic acid, an aromatic sulfonic acid anion substituted with a fluorine atom or a group having a fluorine atom, a bis(alkylsulfonyl)imide anion in which the alkyl group is substituted with a fluorine atom, or a tris(alkylsulfonyl)methide anion in which the alkyl group is substituted with a fluorine atom. The non-nucleophilic anion is more preferably a perfluoroaliphatic sulfonic acid anion having 4 to 8 carbon atoms or a benzenesulfonic acid anion having a fluorine atom, still more preferably a nonafluorobutanesulfonic acid anion, a perfluorooctanesulfonic acid anion, a pentafluorobenzenesulfonic acid anion, or a 3,5-bis(trifluoromethyl)benzenesulfonic acid anion.

The acid generator is preferably a compound capable of generating an acid represented by the following General Formula (V) or (VI) by irradiation with actinic rays or radiation. The compound capable of generating an acid represented by the following General Formula (V) or (VI) has a cyclic organic group, so that the resolution and the roughness performance can be more improved.

The non-nucleophilic anion can be an anion capable of generating an organic acid represented by the following General Formula (V) or (VI).

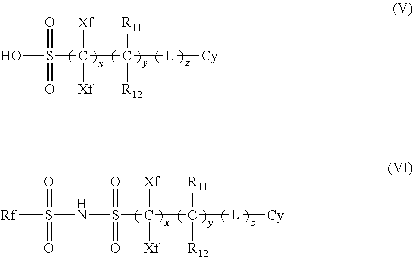

In General Formulae,
Xf's each independently represent a fluorine atom or an alkyl group substituted with at least one fluorine atom;
R₁₁ and R₁₂ each independently represent a hydrogen atom, a fluorine atom, or an alkyl group;
L's each independently represent a divalent linking group;
Cy represents a cyclic organic group;
Rf represents a group containing a fluorine atom;
x represents an integer of 1 to 20;
y represents an integer of 0 to 10; and
z represents an integer of 0 to 10.

Xf represents a fluorine atom or an alkyl group substituted with at least one fluorine atom. The number of carbon atoms of the alkyl group is preferably from 1 to 10, and more preferably from 1 to 4. Further, the alkyl group substituted with at least one fluorine atom is preferably a perfluoroalkyl group.

Xf is preferably a fluorine atom or a perfluoroalkyl group having 1 to 4 carbon atoms. Xf is more preferably a fluorine atom or CF₃, and it is still more preferable that both Xf's are fluorine atoms.

R₁₁ and R₁₂ each independently represent a hydrogen atom, a fluorine atom, or an alkyl group. The alkyl group may have a substituent (preferably a fluorine atom), and is preferably an alkyl group having 1 to 4 carbon atoms, and more preferably a perfluoroalkyl group having 1 to 4 carbon atoms. The alkyl group having the substituent of R₁₁ and R₁₂ is preferably CF₃.

L represents a divalent linking group. Examples of the divalent linking group include —COO—, —OCO—, —CONH—, —NHCO—, —CO—, —O—, —S—, —SO—, —SO₂—, an alkylene group (preferably having 1 to 6 carbon atoms), a cycloalkylene group (preferably having 3 to 10 carbon atoms), an alkenylene group (preferably having 2 to 6 carbon atoms), and a divalent linking group formed by combination of a plurality of these members. Among these, —COO—, —OCO—, —CONH—, —NHCO—, —CO—, —O—, —SO₂—, —COO-alkylene group-, —OCO-alkylene group-, —CONH-alkylene group-, or —NHCO-alkylene group- is preferred, and —COO—, —OCO—, —CONH—, —SO₂—, —COO-alkylene group-, or —OCO-alkylene group- is more preferred.

Cy represents a cyclic organic group. Examples of the cyclic organic group include an alicyclic group, an aryl group, and a heterocyclic group.

The alicyclic group may be monocyclic or polycyclic. Examples of the monocyclic alicyclic group include a monocyclic cycloalkyl group such as a cyclopentyl group, a cyclohexyl group, and a cyclooctyl group. As the polycyclic alicyclic group, an alicyclic group having a bulky structure with 7 or more carbon atoms, such as a norbornyl group, tricyclodecanyl group, a tetracyclodecanyl group, a tetracyclododecanyl group, and an adamantyl group, is preferred from the viewpoints of inhibiting in-film diffusion in a post-exposure bake (PEB) step and improving the Mask Error Enhancement Factor (MEEF).

The aryl group may be monocyclic or polycyclic. Examples of the aryl group include a phenyl group, a naphthyl group, a phenanthryl group, and an anthryl group. Among these, a naphthyl group having a relatively low light absorbance at 193 nm is preferred.

The heterocyclic group may be monocyclic or polycyclic, but with a polycyclic heterocyclic group, the diffusion of an acid can be more inhibited. Further, the heterocyclic group may have aromaticity or may not have aromaticity. Examples of the heterocycle having aromaticity include a furan ring, a thiophene ring, a benzofuran ring, a benzothiophene ring, a dibenzofuran ring, a dibenzothiophene ring, and a pyridine ring. Examples of the heterocycle not having aromaticity include a tetrahydropyran ring, a lactone ring or sultone ring, and a decahydroisoquinoline ring. The heterocycle in the heterocyclic group is particularly preferably a furan ring, a thiophene ring, a pyridine ring, or a decahydroisoquinoline ring. Examples of the lactone ring or sultone ring include lactone structures or sultones exemplified in the resin (A) as mentioned above.

The cyclic organic group as described above may have a substituent, and examples of the substituent include an alkyl group (may be linear or branched, preferably having 1 to 12 carbon atoms), a cycloalkyl group (may be monocyclic, polycyclic or spirocyclic, preferably having 3 to 20 carbon atoms), an aryl group (preferably having 6 to 14 carbon atoms), a hydroxyl group, an alkoxy group, an ester group, an amido group, a urethane group, a ureido group, a thioether group, a sulfonamide group, and a sulfonic ester group. Incidentally, the carbon constituting the cyclic organic group (the carbon contributing to ring formation) may be carbonyl carbon.

x is preferably from 1 to 8, more preferably from 1 to 4, and particularly preferably 1. y is preferably from 0 to 4, and more preferably 0. z is preferably from 0 to 8, and more preferably from 0 to 4.

Examples of the group containing a fluorine atom, represented by Rf, include an alkyl group having at least one fluorine atom, a cycloalkyl group having at least one fluorine atom, and an aryl group having at least one fluorine atom.

The alkyl group, cycloalkyl group, and aryl group may be substituted with a fluorine atom or may be substituted with another substituent containing a fluorine atom. In the case where Rf is a cycloalkyl group having at least one fluorine atom or an aryl group having at least one fluorine atom, examples of other such substituents containing a fluorine atom include an alkyl group substituted with at least one fluorine atom.

Furthermore, the alkyl group, cycloalkyl group, and aryl group may be further substituted with a fluorine atom-free substituent. Examples of this substituent include ones not containing a fluorine atom out of ones described above for Cy.

Examples of the alkyl group having at least one fluorine atom, represented by Rf, are the same as ones described above as the alkyl group substituted with at least one fluorine atom represented by Xf. Examples of the cycloalkyl group having at least one fluorine atom, represented by Rf, include a perfluorocyclopentyl group and a perfluorocyclohexyl group. Examples of the aryl group having at least one fluorine atom represented by Rf include a perfluorophenyl group.

Moreover, it is also preferable that the non-nucleophilic anion is an anion represented by any of the following General Formulae (B-1) to (B-3).

First, an anion represented by the following General Formula (B-1) will be described.

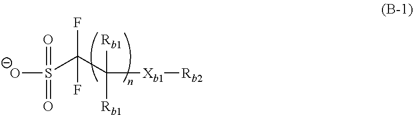

In General Formula (B-1),
R_{b1}'s each independently represent a hydrogen atom, a fluorine atom, or a trifluoromethyl group (CF₃);
n represents an integer of 1 to 4;
n is preferably an integer of 1 to 3, and more preferably 1 or 2;
X_{b1} represents a single bond, an ether bond, an ester bond (—OCO— or —COO—), or a sulfonic ester bond (—OSO₂— or —SO₃—);
X_{b1} is preferably an ester bond (—OCO— or —COO—) or a sulfonic acid ester bond (—OSO₂— or —SO₃—); and
R_{b2} represents a substituent having 6 or more carbon atoms.

The substituent having 6 or more carbon atoms with regard to R_{b2} is preferably a bulky group, and examples thereof include an alkyl group, an alicyclic group, an aryl group, and a heterocyclic group each having 6 or more carbon atoms.

As for R_{b2}, the alkyl group having 6 or more carbon atoms may be linear or branched, and a linear or branched alkyl group having 6 to 20 carbon atoms is preferred. Examples thereof include a linear or branched hexyl group, a linear or branched heptyl group, and a linear or branched octyl group. From the viewpoint of bulkiness, the branched alkyl group is preferred.

The alicyclic group having 6 or more carbon atoms for R_{b2} may be monocyclic or polycyclic. Examples of the monocyclic aliphatic group include a monocyclic cycloalkyl group such as a cyclohexyl group and a cyclooctyl group. Examples of the polycyclic alicyclic group include polycyclic cycloalkyl groups such as a norbornyl group, a tricyclodecanyl group, a tetracyclodecanyl group, a tetracyclododecanyl group, and an adamantyl group. Among these, alicyclic groups having a bulky structure with 7 or more carbon atoms, such as a norbornyl group, a tricyclodecanyl group, a tetracyclodecanyl group, a tetracyclododecanyl group, and an adamantyl group, are preferred from the viewpoints of inhibiting in-film diffusion in a post-exposure bake (PEB) step and improving the Mask Error Enhancement Factor (MEEF).

The aryl group having 6 or more carbon atoms for R_{b2} may be monocyclic or polycyclic. Examples of the aryl group include a phenyl group, a naphthyl group, a phenanthryl group and an anthryl group. Among these, a naphthyl group having a relatively low light absorbance at 193 nm is preferred.

The heterocyclic group having 6 or more carbon atoms for R_{b2} may be monocyclic or polycyclic, but with a polycyclic heterocyclic group, the diffusion of an acid can be more inhibited. Further, the heterocyclic group may have aromaticity or may not have aromaticity. Examples of the heterocycle having aromaticity include a benzofuran ring, a benzothiophene ring, a dibenzofuran ring, and a dibenzothiophene ring. Examples of the heterocycle not having aromaticity include a tetrahydropyran ring, a lactone ring, and a decahydroisoquinoline ring. The heterocycle in the heterocyclic group is particularly preferably a benzofuran ring or a decahydroisoquinoline ring. Examples of the lactone ring include the lactone structures exemplified in the resin (A) as mentioned above.

The substituent having 6 or more carbon atoms for R_{b2} may further have a substituent. Examples of the further substituent include an alkyl group (which may be either linear or branched and preferably has 1 to 12 carbon atoms), a cycloalkyl group (which may be monocyclic, polycyclic, or spirocyclic, and preferably has 3 to 20 carbon atoms), an aryl group (which preferably has 6 to 14 carbon atoms), a hydroxyl group, an alkoxy group, an ester group, an amido group, a urethane group, a ureido group, a thioether group, a sulfonamide group, and a sulfonic ester group. Incidentally, the carbon atom constituting the alicyclic group, the aryl group, or the heterocyclic group as described above (the carbon contributing to ring formation) may be carbonyl carbon.

Examples of the anion represented by General Formula (B-1) are shown below, but the present invention is not limited thereto.

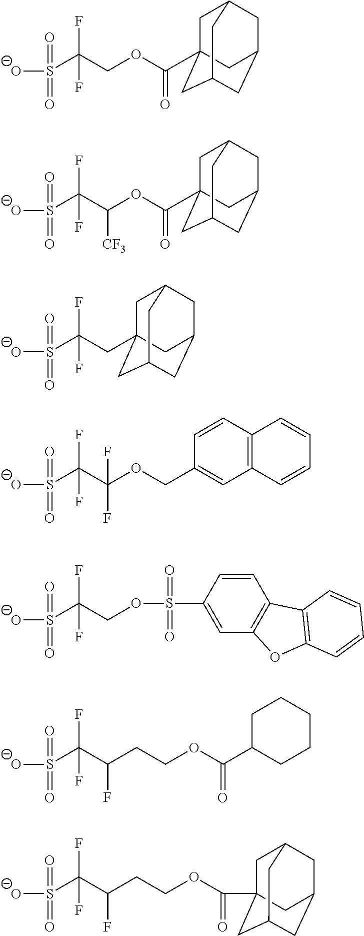

Next, an anion represented by the following General Formula (B-2) will be described.

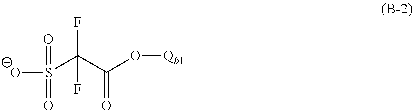

In General Formula (B-2),
Q_{b1} represents a group having a lactone structure, a group having a sultone structure, or a group having a cyclic carbonate structure.

Examples of the lactone structure or the sultone structure for Q_{b1} include the same lactone structures and the sultone structures as in the repeating units having lactone structures and the sultone structures as described earlier in the section of the resin (A). Specific examples thereof include the lactone structures represented by any of General Formulae (LC1-1) to (LC1-17) or the sultone structures represented by any of General Formulae (SL1-1) to (SL1-3).

The lactone structure or sultone structure as mentioned above may be in a state of binding directly to the oxygen atom in the ester group in General Formula (B-2) or the lactone structure or sultone structure as mentioned above may be in a state of binding to the oxygen atom in the ester group through an alkylene group (for example, a methylene group and an ethylene group). In this case, a group having the lactone structure or sultone structure can be referred to as an alkyl group having the lactone structure or sultone structure as a substituent.

The cyclic carbonate structure for Q_{b1} is preferably a 5- to 7-membered cyclic carbonate structure, and examples thereof include 1,3-dioxolane-2-one and 1,3-dioxane-2-one.

The cyclic carbonate structure may be in a state of binding directly to the oxygen atom in the ester group in General Formula (B-2) or the cyclic carbonate structure may be in a state of binding to the oxygen atom in the ester group through an alkylene group (for example, a methylene group and an ethylene group). In this case, the group having the cyclic carbonate structure can be referred to as an alkyl group having the cyclic carbonate structure as a substituent.

Examples of the anion represented by General Formula (B-2) are shown below, but the present invention is not limited thereto.

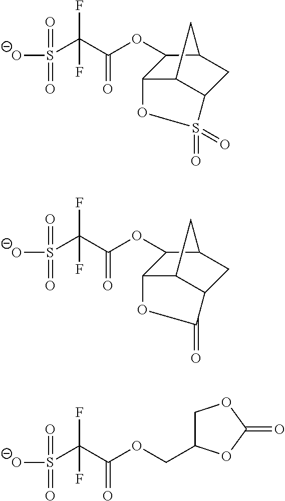

Next, the anion represented by the following General Formula (B-3) will be described.

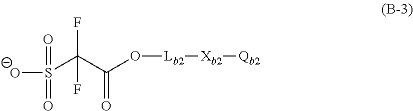

In General Formula (B-3),
L_{b2} represents an alkylene group having 1 to 6 carbon atoms, and examples thereof include a methylene group, an ethylene group, a propylene group, or a butylene group, preferably an alkylene group having 1 to 4 carbon atoms;
X_{b2} represents an ether bond or an ester bond (—OCO— or —COO—); and
Q_{b2} represents an alicyclic group, or a group containing an aromatic ring.

The alicyclic group with regard to Q_{b2} may be monocyclic or polycyclic. Examples of the monocyclic alicyclic group include monocyclic cycloalkyl groups such as a cyclopentyl group, a cyclohexyl group, and a cyclooctyl group. As the polycyclic alicyclic group, an alicyclic group having a bulky structure having 7 or more carbon atoms, such as a norbornyl group, a tricyclodecanyl group, a tetracyclodecanyl group, a tetracyclododecanyl group, and an adamantyl group, is preferred.

The aromatic ring in the group containing an aromatic ring for Q_{b2} is preferably an aromatic ring having 6 to 20 carbon atoms, and examples thereof include a benzene ring, a naphthalene ring, a phenanthrene ring, and an anthracene ring, among which the benzene ring and the naphthalene ring are preferred. The aromatic ring may be substituted with at least one fluorine atom, and examples of the aromatic ring which is substituted with at least one fluorine atom include a perfluorophenyl group.

The aromatic ring may be in a state of binding directly to X_{b2}, or the aromatic ring may be in a state of binding to X_{b2} through an alkylene group (for example, a methylene group and an ethylene group). In this case, the group containing the aromatic ring can be referred to as an alkyl group having the aromatic ring as a substituent.

Specific examples of the anion structure represented by General Formula (B-3) are shown below, but the present invention is not limited thereto.

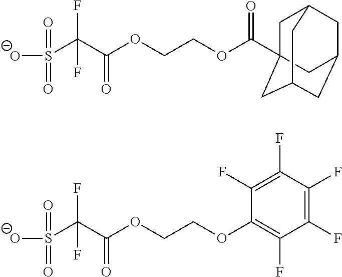

Examples of the organic group represented by R₂₀₁, R₂₀₂, and R₂₀₃ include corresponding groups in the compounds (ZI-1), (ZI-2), (ZI-3), and (ZI-4) as described later.

Incidentally, the compound may be a compound having a plurality of structures represented by General Formula (ZI). For example, the compound may be a compound having a structure in which at least one of R₂₀₁ to R₂₀₃ in a compound represented by General Formula (ZI) is bonded to at least one of R₂₀₁ to R₂₀₃ in another compound represented by General Formula (ZI) through a single bond or a linking group.

More preferred examples of the components (ZI) include the compounds (ZI-1), (ZI-2), (ZI-3), and (ZI-4) as described below.

The compound (ZI-1) is an arylsulfonium compound in which at least one of R₂₀₁ to R₂₀₃ in General Formula (ZI) is an aryl group, that is, a compound having an arylsulfonium as the cation.

In the arylsulfonium compound, all of R₂₀₁ to R₂₀₃ may be an aryl group, or a part of R₂₀₁ to R₂₀₃ may be an aryl group, with the remainder being an alkyl group or a cycloalkyl group.

Examples of the arylsulfonium compound include a triarylsulfonium compound, a diarylalkylsulfonium compound, an aryldialkylsulfonium compound, a diarylcycloalkylsulfonium compound, and an aryldicycloalkylsulfonium compound.

The aryl group in the arylsulfonium compound is preferably a phenyl group or a naphthyl group, and more preferably a phenyl group. The aryl group may be an aryl group having a heterocyclic structure containing an oxygen atom, a nitrogen atom, a sulfur atom, or the like. Examples of the heterocyclic structure include a pyrrole residue, a furan residue, a thiophene residue, an indole residue, a benzofuran residue, and a benzothiophene residue. In the case where the arylsulfonium compound has two or more aryl groups, these two or more aryl groups may be the same as or different from each other.

The alkyl group or cycloalkyl group which is contained, if desired, in the arylsulfonium compound is preferably a linear or branched alkyl group having 1 to 15 carbon atoms or a cycloalkyl group having 3 to 15 carbon atoms, and examples thereof include a methyl group, an ethyl group, a propyl group, an n-butyl group, a sec-butyl group, a t-butyl group, a cyclopropyl group, a cyclobutyl group, and a cyclohexyl group.

The aryl group, the alkyl group, and the cycloalkyl group of R₂₀₁ to R₂₀₃ may have, as the substituent, an alkyl group (for example, having 1 to 15 carbon atoms), a cycloalkyl group (for example, having 3 to 15 carbon atoms), an aryl group (for example, having 6 to 14 carbon atoms), an alkoxy group (for example, having 1 to 15 carbon atoms), a halogen atom, a hydroxyl group, or a phenylthio group. The substituent is preferably a linear or branched alkyl group having 1 to 12 carbon atoms, a cycloalkyl group having 3 to 12 carbon atoms, or a linear, branched, or cyclic alkoxy group having 1 to 12 carbon atoms, more preferably an alkyl group having 1 to 4 carbon atoms, or an alkoxy group having 1 to 4 carbon atoms. The substituent may be substituted with any one of three members R₂₀₁ to R₂₀₃ or may be substituted with all of these three members. In the case where R₂₀₁ to R₂₀₃ are each an aryl group, the substituent is preferably substituted on the p-position of the aryl group.

Next, the compound (ZI-2) will be described.

The compound (ZI-2) is a compound in which R₂₀₁ to R₂₀₃ in Formula (ZI) each independently represent an organic group having no aromatic ring. The aromatic ring as used herein encompasses an aromatic ring containing a heteroatom.

The organic group having no aromatic ring as R₂₀₁ to R₂₀₃ has generally 1 to 30 carbon atoms, and preferably 1 to 20 carbon atoms.

R₂₀₁ to R₂₀₃ are each independently preferably an alkyl group, a cycloalkyl group, an allyl group, or a vinyl group, more preferably a linear or branched 2-oxoalkyl group, a 2-oxocycloalkyl group, or an alkoxycarbonylmethyl group, and particularly preferably a linear or branched 2-oxoalkyl group.

Preferred examples of the alkyl group and the cycloalkyl group of R₂₀₁ to R₂₀₃ include a linear or branched alkyl group having 1 to 10 carbon atoms (for example, a methyl group, an ethyl group, a propyl group, a butyl group, and a pentyl group), and a cycloalkyl group having 3 to 10 carbon atoms (for example, a cyclopentyl group, a cyclohexyl group, and a norbornyl group). More preferred examples of the alkyl group include a 2-oxoalkyl group and an alkoxycarbonylmethyl group. Still more preferred examples of the cycloalkyl group include a 2-oxocycloalkyl group.

The 2-oxoalkyl group may be linear or branched, and preferred examples thereof include a group having >C═O at the 2-position of the alkyl group.

Preferred examples of the 2-oxocycloalkyl group include a group having >C═O at the 2-position of the cycloalkyl group.

Preferred examples of the alkoxy group that may be mentioned as the alkoxycarbonylmethyl group include an alkoxy group having 1 to 5 carbon atoms (for example, a methoxy group, an ethoxy group, a propoxy group, a butoxy group, and a pentoxy group).

R₂₀₁ to R₂₀₃ may be further substituted with a halogen atom, an alkoxy group (for example, having 1 to 5 carbon atoms), a hydroxyl group, a cyano group, and a nitro group.

Next, the compound (ZI-3) will be described.

The compound (ZI-3) is a compound represented by the following General Formula (ZI-3), which has a phenacylsulfonium salt structure.

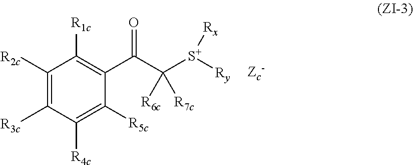

In General Formula (ZI-3),
R_{1c} to R_{5c} each independently represent a hydrogen atom, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group, or an arylthio group;
R_{6c} and R_{7c} each independently represent a hydrogen atom, an alkyl group, a cycloalkyl group, a halogen atom, a cyano group, or an aryl group; and
Rₓ and R_{y} each independently represent an alkyl group, a cycloalkyl group, a 2-oxoalkyl group, a 2-oxocycloalkyl group, an alkoxycarbonylalkyl group, an allyl group, or a vinyl group.

Any two or more members out of R_{1c} to R_{5c}, R_{5c} and R_{6c}, R_{6c} and R_{7c}, R_{5c} and Rₓ, or Rₓ and R_{y} may be bonded to each other to form a ring structure. This ring structure may contain an oxygen atom, a sulfur atom, a ketone group, an ester bond, or an amide bond.

Examples of the ring structure include an aromatic or non-aromatic hydrocarbon ring, an aromatic or non-aromatic heterocycle, and a polycyclic fused ring formed by combination of two or more members out of these rings. Examples of the ring structure include 3- to 10-membered rings, among which 4- to 8-membered rings are preferred, and 5- or 6-membered rings are more preferred.

Examples of the group formed by combination of any two or more members out of R_{1c} to R_{5c}, a pair of R_{6c} and R_{7c}, or a pair of Rₓ and R_{y} include a butylene group, and a pentylene group.

The group formed by combination of a pair of R_{5c} and R_{6c}, or a pair of R_{5c} and Rₓ is preferably a single bond or an alkylene group, and examples of the alkylene group include a methylene group and an ethylene group.

Zc⁻ represents a non-nucleophilic anion, and examples thereof include the same ones as the non-nucleophilic anions of in General Formula (ZI).

The alkyl group as R_{1c} to R_{7c} may be linear or branched and examples thereof include an alkyl group having 1 to 20 carbon atoms, and preferably a linear or branched alkyl group having 1 to 12 carbon atoms (for example, a methyl group, an ethyl group, a linear or branched propyl group, a linear or branched butyl group, and a linear or branched pentyl group). Examples of the cycloalkyl group include a cycloalkyl group having 3 to 10 carbon atoms (for example, a cyclopentyl group and a cyclohexyl group).

The aryl group as R_{1c} to R_{5c} is preferably an aryl group having 5 to 15 carbon atoms, and examples thereof include a phenyl group and a naphthyl group.

The alkoxy group as R_{1c} to R_{5c} may be linear, branched, or cyclic, and examples thereof include an alkoxy group having 1 to 10 carbon atoms, and preferably a linear or branched alkoxy group having 1 to 5 carbon atoms (for example, a methoxy group, an ethoxy group, a linear or branched propoxy group, a linear or branched butoxy group, and a linear or branched pentoxy group), and a cyclic alkoxy group having 3 to 10 carbon atoms (for example, a cyclopentyloxy group and a cyclohexyloxy group).

Specific examples of the alkoxy group in the alkoxycarbonyl group as R_{1c} to R_{5c} are the same as the specific examples of the alkoxy group as R_{1c} to R_{5c} above.

Specific examples of the alkyl group in the alkylcarbonyloxy group and the alkylthio group as R_{1c} to R_{5c} are the same as the specific examples of the alkyl group as R_{1c} to R_{5c} above.

Specific examples of the cycloalkyl group in the cycloalkylcarbonyloxy group as R_{1c} to R_{5c} are the same as the specific examples of the cycloalkyl group as R_{1c} to R_{5c} above.

Specific examples of the aryl group in the aryloxy group and the arylthio group as R_{1c} to R_{5c} are the same as the specific examples of the aryl group as R_{1c} to R_{5c} above.

It is preferable that any one of R_{1c} to R_{5c} is a linear or branched alkyl group, a cycloalkyl group, or a linear, branched, or cyclic alkoxy group, and it is more preferable that the sum of number of carbon atoms of R_{1c} to R_{5c} is from 2 to 15. With this, the solvent solubility is more enhanced, and generation of particles during storage can be inhibited.

Preferred examples of the ring structure which may be formed by the mutual bonding of any two or more members of R_{1c} to R_{5c} include 5- or 6-membered rings, and particularly preferred examples thereof include 6-membered rings (for example, a phenyl ring).

Examples of the ring structure which may be formed by the mutual bonding of R_{5c} and R_{6c} include a 4-membered or higher-membered ring (particularly preferably a 5- or 6-membered ring) formed together with the carbonyl carbon atom and the carbon atom in General Formula (ZI-3) by the mutual bonding of R_{5c} and R_{6c} to constitute a single bond or an alkylene group (a methylene group, an ethylene group, and the like).

The aryl group as R_{6c} and R_{7c} preferably has 5 to 15 carbon atoms, and examples thereof include a phenyl group and a naphthyl group.

As an embodiment of R_{6c} and R_{7c}, a case where both are each an alkyl group is preferred, and in particular, a case where R_{6c} and R_{7c} are each a linear or branched alkyl group having 1 to 4 carbon atoms is more preferred, and a case where both are a methyl group is particularly preferred.

In the case where R_{6c} and R_{7c} are bonded to each other to form a ring, the group formed by the mutual bonding of R_{6c} and R_{7c} is preferably an alkylene group having 2 to 10 carbon atoms, and examples thereof include an ethylene group, a propylene group, a butylene group, a pentylene group, and a hexylene group. Further, the ring formed by the mutual bonding of R_{6c} and R_{7c} may contain a heteroatom such as an oxygen atom in the ring.

Examples of the alkyl group and the cycloalkyl group as Rₓ and R_{y} include the same ones as the alkyl groups and the cycloalkyl groups with respect to R_{1c} to R_{7c}.

Examples of the 2-oxoalkyl group and the 2-oxocycloalkyl group as Rₓ and R_{y} include a group having >C═O at the 2-position of the alkyl group and the cycloalkyl group as R_{1c} to R_{7c}.

Examples of the alkoxy group in the alkoxycarbonylalkyl group as Rₓ and R_{y} include the same ones as the alkoxy groups with respect to R_{1c} to R_{5c}. Examples of the alkyl group include an alkyl group having 1 to 12 carbon atoms, and preferably a linear alkyl group having 1 to 5 carbon atoms (for example, a methyl group and an ethyl group).

The allyl group as Rₓ and R_{y} is not particularly limited but is preferably an unsubstituted allyl group or an allyl group substituted with a monocyclic or polycyclic cycloalkyl group (preferably a cycloalkyl group having 3 to 10 carbon atoms).

The vinyl group as Rₓ and R_{y} is not particularly limited, but is preferably an unsubstituted vinyl group or a vinyl group substituted with a monocyclic or polycyclic cycloalkyl group (preferably a cycloalkyl group having 3 to 10 carbon atoms).

Examples of the ring structure which may be formed by the mutual bonding of R_{5c} and Rₓ include a 5-membered or higher-membered ring (preferably a 5-membered ring) formed by the mutual bonding of R_{5c} and Rₓ to constitute a single bond or an alkylene group (for example, a methylene group and an ethylene group) together with the sulfur atom and carbonyl carbon atom in General Formula (ZI-3).

Examples of the ring structure which may be formed by the mutual bonding of Rₓ and R_{y} include a 5- or 6-membered ring, and preferably a 5-membered ring (that is, a tetrahydrothiophene ring) formed by the mutual bonding of divalent Rₓ and R_{y} (for example, a methylene group, an ethylene group, and a propylene group) together with the sulfur atom in General Formula (ZI-3).

Rₓ and R_{y} are preferably an alkyl or cycloalkyl group having 4 or more carbon atoms, more preferably 6 or more carbon atoms, and still more preferably an alkyl or cycloalkyl group having 8 or more carbon atoms.

R_{1c} to R_{7c}, and Rₓ, and R_{y} may further have a substituent, and examples of such a substituent include a halogen atom (for example, a fluorine atom), a hydroxyl group, a carboxyl group, a cyano group, a nitro group, an alkyl group, a cycloalkyl group, an aryl group, an alkoxy group, an aryloxy group, an acyl group, an arylcarbonyl group, an alkoxyalkyl group, an aryloxyalkyl group, an alkoxycarbonyl group, an aryloxycarbonyl group, an alkoxycarbonyloxy group, and an aryloxycarbonyloxy group.

In General Formula (ZI-3), it is more preferable that R_{1c}, R_{2c}, R_{4c}, and R_{5c} each independently represent a hydrogen atom, and R_{3c} represents a group except for a hydrogen atom, that is, represents an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group, or an arylthio group.

Examples of the cation in the compound represented by General Formula (ZI-2) or (ZI-3) in the present invention include the specific examples as follows.

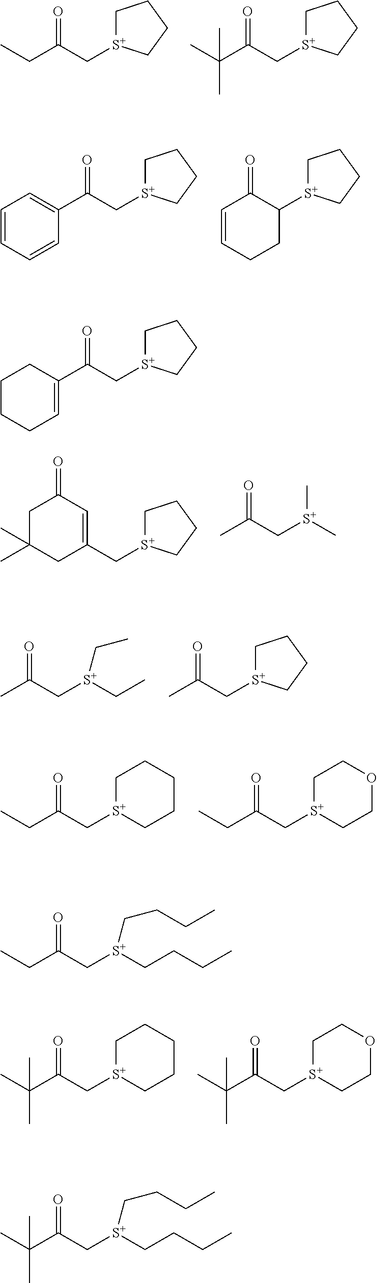

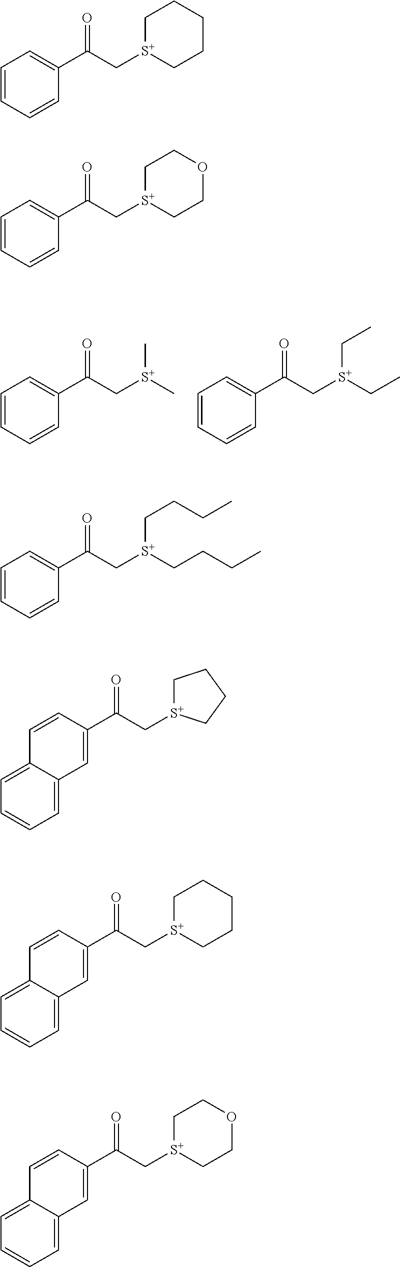

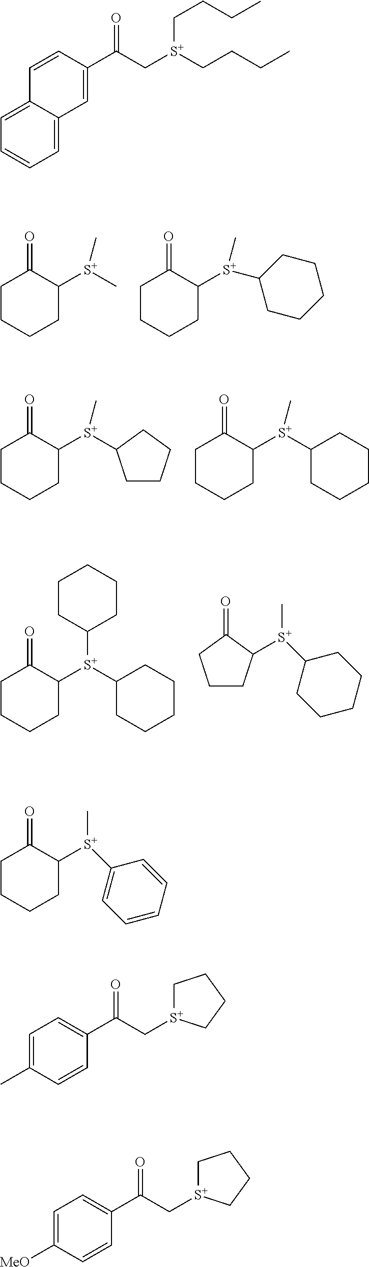

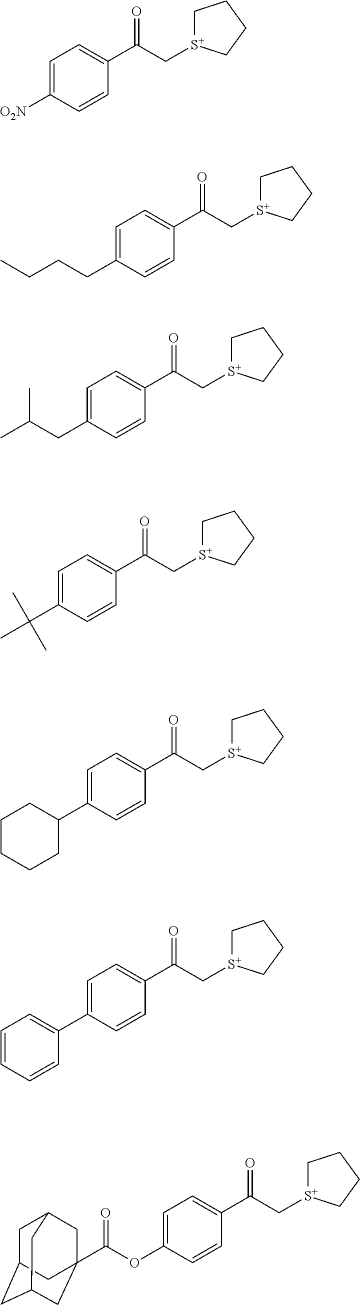

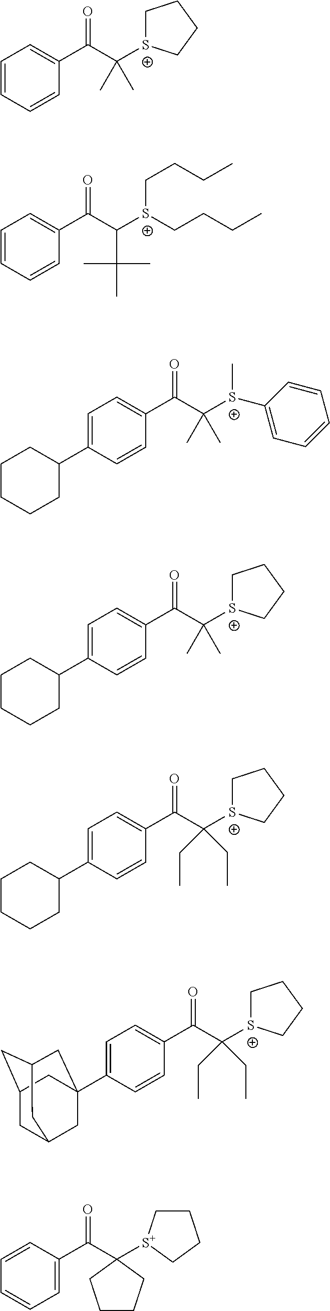

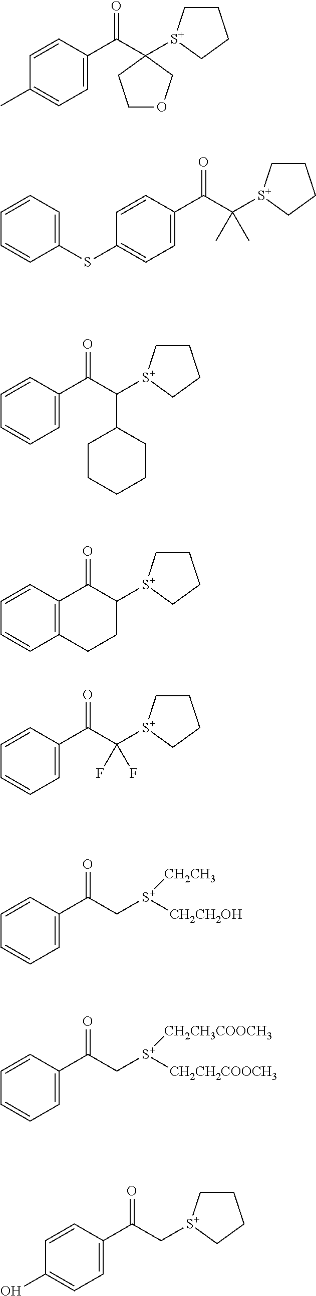

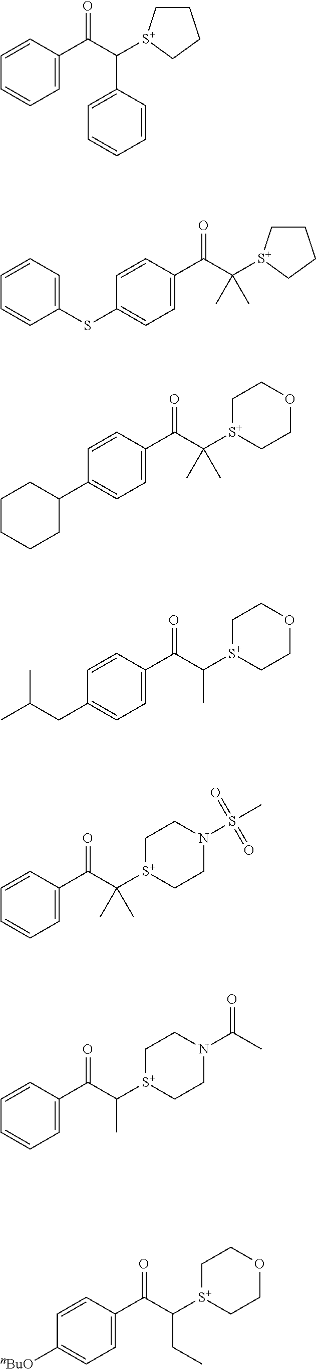

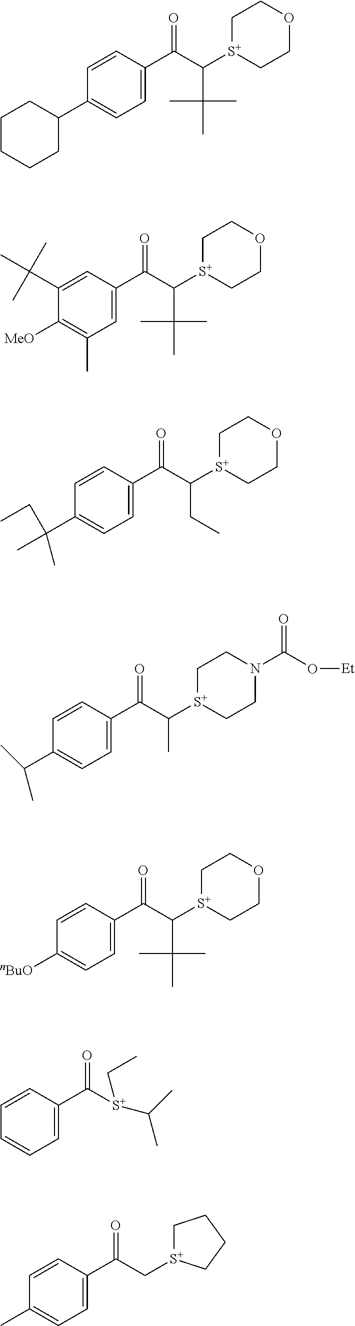

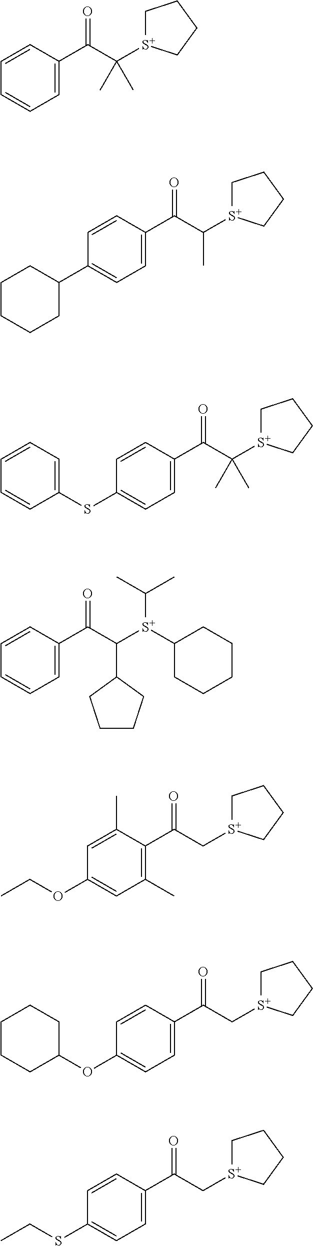

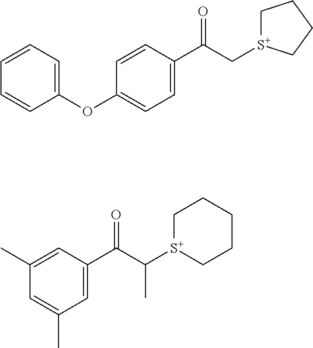

Next, the compound (ZI-4) will be described.

The compound (ZI-4) is represented by the following General Formula (ZI-4).

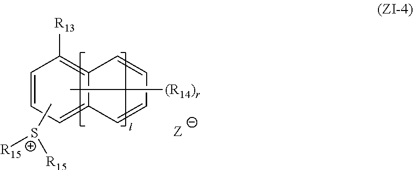

In General Formula (ZI-4),
R₁₃ represents a hydrogen atom, a fluorine atom, a hydroxyl group, an alkyl group, a cycloalkyl group, an alkoxy group, an alkoxycarbonyl group, or a group having a cycloalkyl group, and these groups may have a substituent;
in the case where a plurality of R¹⁴'s are present, R₁₄'s each independently represent a hydroxyl group, an alkyl group, a cycloalkyl group, an alkoxy group, an alkoxycarbonyl group, an alkylcarbonyl group, an alkylsulfonyl group, a cycloalkylsulfonyl group, or a group having a cycloalkyl group, and these groups may have a substituent;
R₁₅'s each independently represent an alkyl group, a cycloalkyl group, or a naphthyl group, two R₁₅'s may be bonded to each other to form a ring, and these groups may have a substituent;
1 represents an integer of 0 to 2;
r represents an integer of 0 to 8; and
Z⁻ represents a non-nucleophilic anion, and examples thereof include the same ones as the non-nucleophilic anions of Z⁻ in General Formula (ZI).

In General Formula (ZI-4), the alkyl group of R₁₃, R₁₄, and R₁₅ is preferably a linear or branched alkyl group having 1 to 10 carbon atoms, and preferred examples thereof include a methyl group, an ethyl group, an n-butyl group, and a t-butyl group.

Examples of the cycloalkyl group of R₁₃, R₁₄, and R₁₅ include a monocyclic or polycyclic cycloalkyl group (preferably a cycloalkyl group having 3 to 20 carbon atoms), among which cyclopropyl, cyclopentyl, cyclohexyl, cycloheptyl, and cyclooctyl are particularly preferred.

The alkoxy group of R₁₃ and R₁₄ is preferably a linear or branched alkoxy group having 1 to 10 carbon atoms, and preferred examples thereof include a methoxy group, an ethoxy group, an n-propoxy group, and an n-butoxy group.

The alkoxycarbonyl group of R₁₃ and R₁₄ is preferably a linear or branched alkoxycarbonyl group having 2 to 11 carbon atoms, and preferred examples thereof include a methoxycarbonyl group, ethoxycarbonyl group, and an n-butoxycarbonyl group.

Examples of the group having a cycloalkyl group of R₁₃ and R₁₄ include a monocyclic or polycyclic cycloalkyl group (preferably a cycloalkyl group having 3 to 20 carbon atoms), and examples thereof include a monocyclic or polycyclic cycloalkyloxy group and an alkoxy group having a monocyclic or polycyclic cycloalkyl group. These groups may further have a substituent.

The monocyclic or polycyclic cycloalkyloxy group of R₁₃ and R₁₄ preferably has a total number of carbon atoms of 7 or more, and more preferably has a total number of carbon atoms of 7 to 15, and it is preferably a monocyclic cycloalkyl group. The monocyclic cycloalkyloxy group having a total number of carbon atoms of 7 or more refers to a monocyclic cycloalkyloxy group in which a cycloalkyloxy group such as a cyclopropyloxy group, a cyclobutyloxy group, a cyclopentyloxy group, a cyclohexyloxy group, a cycloheptyloxy group, a cyclooctyloxy group, and a cyclododecanyloxy group arbitrarily has a substituent such as an alkyl group, a hydroxyl group, a halogen atom (for example, fluorine, chlorine, bromine, and iodine), a nitro group, a cyano group, an amido group, a sulfonamide group, an alkoxy group, an alkoxycarbonyl group, an acyl group, an acyloxy group such as an acetoxy group and a butyryloxy group, and a carboxy group, and in which the total number of carbon atoms inclusive of the number of carbon atoms of an arbitrary substituent on the cycloalkyl group is 7 or more.

Further, examples of the polycyclic cycloalkyloxy group having a total number of carbon atoms of 7 or more include a norbornyloxy group, a tricyclodecanyloxy group, a tetracyclodecanyloxy group, and an adamantyloxy group.

The alkoxy group having a monocyclic or polycyclic cycloalkyl group of R₁₃ and R₁₄ has a total number of carbon atoms of preferably 7 or more, and more preferably a total number of carbon atoms of 7 to 15, and is preferably an alkoxy group having a monocyclic cycloalkyl group. The alkoxy group having a total number of carbon atoms of 7 or more and having a monocyclic cycloalkyl group refers to an alkoxy group in which the above-described monocyclic cycloalkyl group which may have a substituent is substituted on an alkoxy group such as methoxy, ethoxy, propoxy, butoxy, pentyloxy, hexyloxy, heptoxy, octyloxy, dodecyloxy, 2-ethylhexyloxy, isopropoxy, sec-butoxy, t-butoxy, and iso-amyloxy, in which the total number of carbon atoms inclusive of the number of carbon atoms of the substituent is 7 or more. Examples thereof include a cyclohexylmethoxy group, a cyclopentylethoxy group, and a cyclohexylethoxy group, among which a cyclohexylmethoxy group is preferred.

Examples of the alkoxy group having a total number of carbon atoms of 7 or more and having a polycyclic cycloalkyl group include a norbornylmethoxy group, a norbornylethoxy group, a tricyclodecanylmethoxy group, a tricyclodecanylethoxy group, a tetracyclodecanylmethoxy group, a tetracyclodecanylethoxy group, an adamantylmethoxy group, and an adamantylmethoxy group, among which the norbornylmethoxy group and the norbornylethoxy group are preferred.

Examples of the alkyl group in the alkylcarbonyl group of R₁₄ include the same specific examples as the alkyl group of R₁₃ to R₁₅ as described above.

The alkylsulfonyl group and the cycloalkylsulfonyl group of R₁₄ are each a linear, branched, or cyclic, preferably having 1 to 10 carbon atoms, and preferred examples thereof include a methanesulfonyl group, an ethanesulfonyl group, an n-propanesulfonyl group, an n-butanesulfonyl group, a cyclopentanesulfonyl group, and a cyclohexanesulfonyl group.

Examples of the substituent which may be substituted on each of the groups above include a halogen atom (for example, a fluorine atom), a hydroxyl group, a carboxyl group, a cyano group, a nitro group, an alkoxy group, an alkoxyalkyl group, an alkoxycarbonyl group, and an alkoxycarbonyloxy group.

The ring structure which may be formed by the mutual bonding of two R₁₅'s includes a 5- or 6-membered ring, preferably a 5-membered ring (that is, a tetrahydrothiophene ring), formed by two R₁₅'s together with the sulfur atom in General Formula (ZI-4) and may be fused with an aryl group or a cycloalkyl group. The divalent R₁₅ may have a substituent, and examples of the substituent include a hydroxyl group, a carboxyl group, a cyano group, a nitro group, an alkyl group, a cycloalkyl group, an alkoxy group, an alkoxyalkyl group, an alkoxycarbonyl group, and an alkoxycarbonyloxy group. With regard to the substituent on the ring structure, a plurality of substituents may be present, and they may be bonded to each other to form a ring (an aromatic or non-aromatic hydrocarbon ring, an aromatic or non-aromatic heterocycle, or a polycyclic fused ring formed by combination of two or more of these rings).

In General Formula (ZI-4), R₁₅ is preferably, for example, a methyl group, an ethyl group, a naphthyl group, or a divalent group capable of forming a tetrahydrothiophene ring structure together with the sulfur atom when two R₁₅'s are bonded to each other.

The substituent which R₁₃ and R₁₄ may have is preferably a hydroxyl group, an alkoxy group, an alkoxycarbonyl group, or a halogen atom (in particular, a fluorine atom).

1 is preferably 0 or 1, and more preferably 1.

r is preferably from 0 to 2.

Examples of the cation in the compound represented by General Formula (ZI-4) in the present invention include the following specific examples.

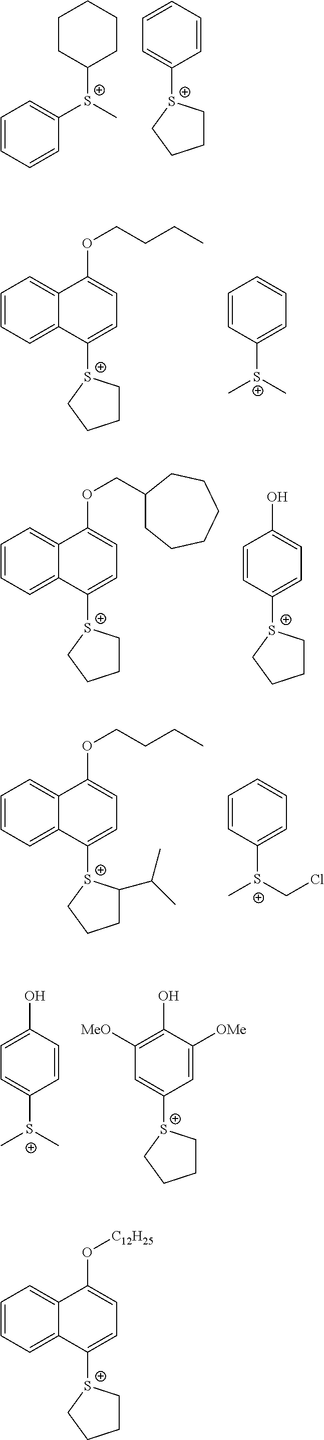

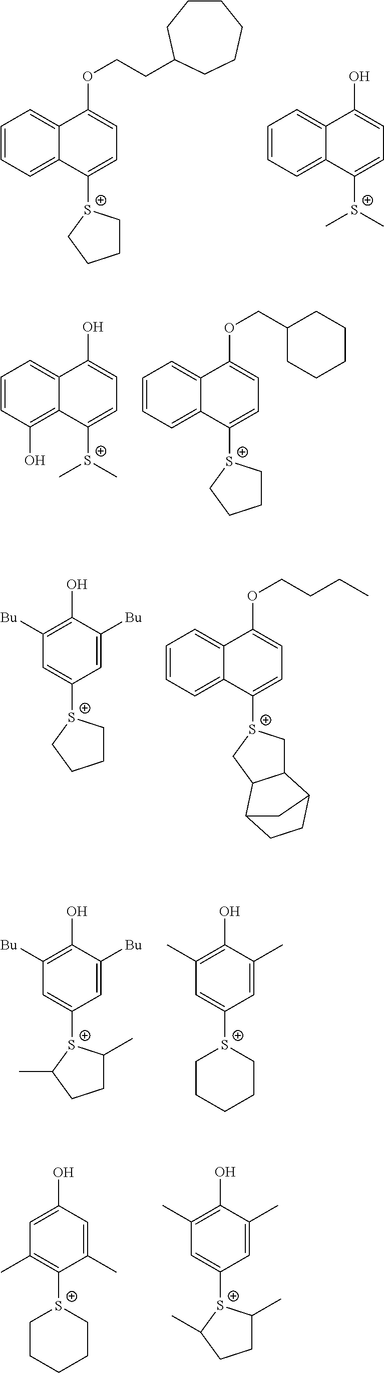

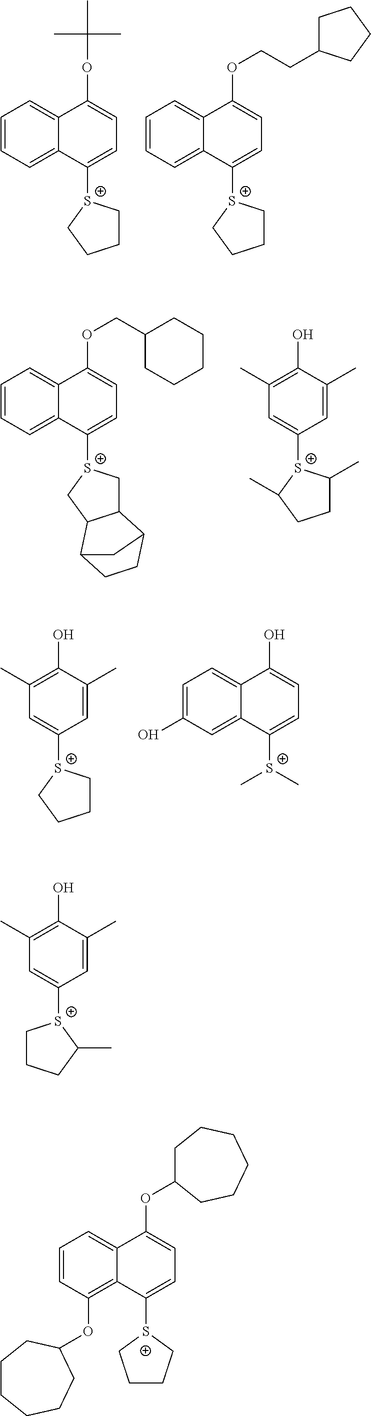

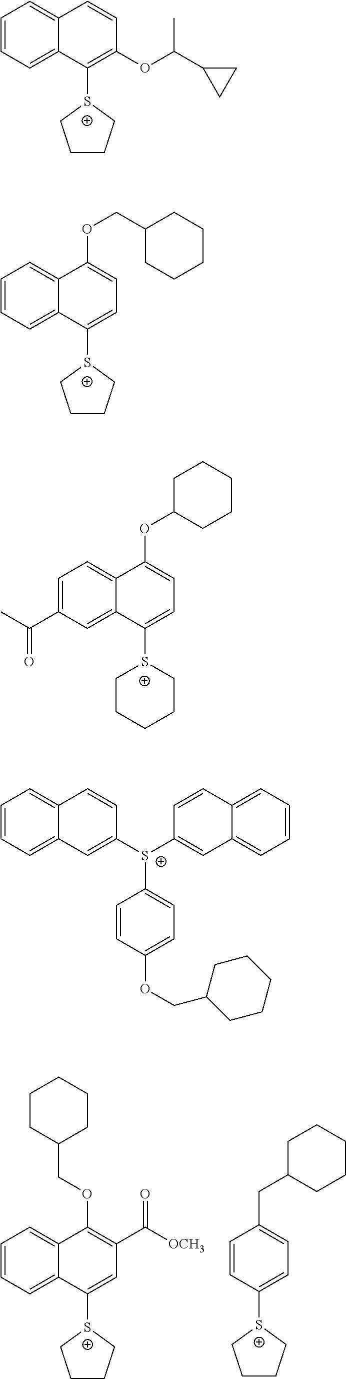

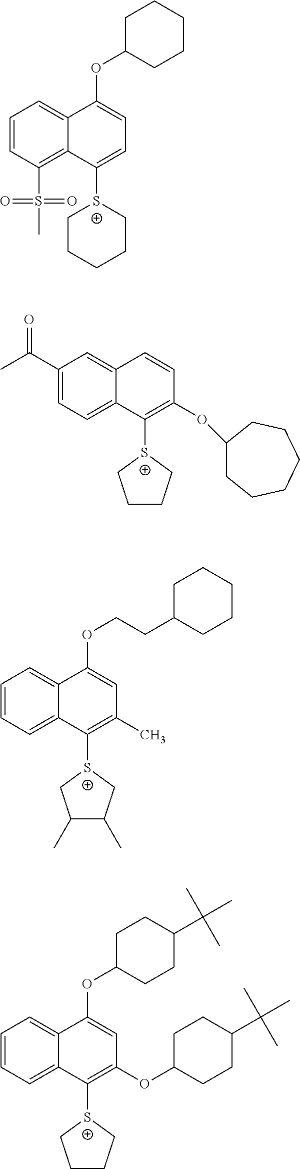

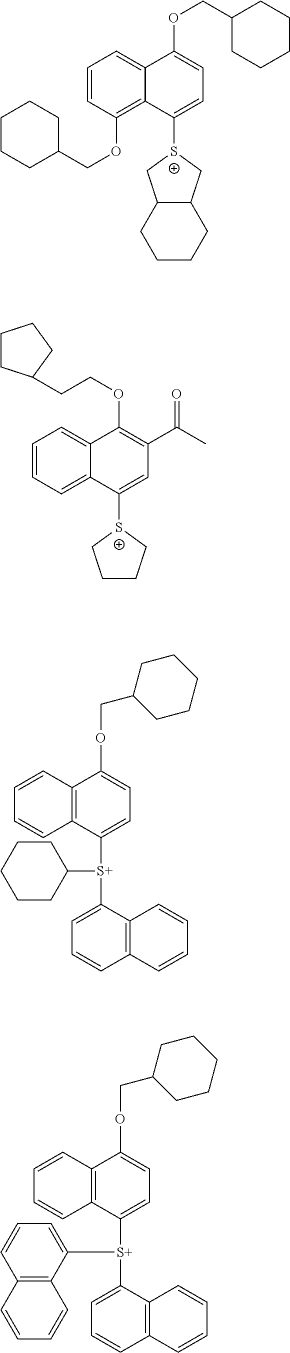

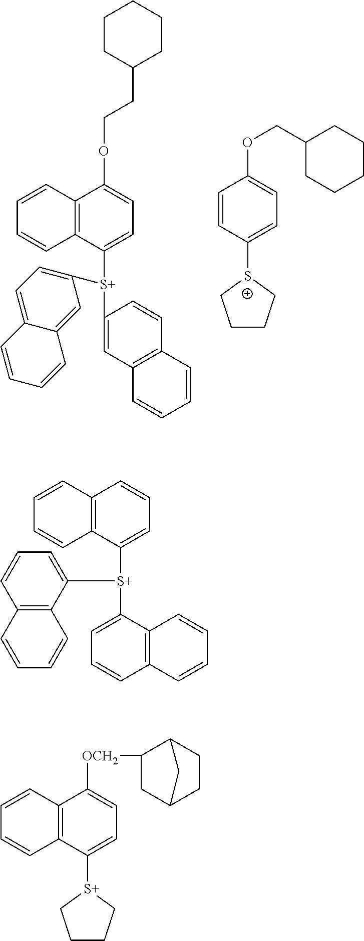

Next, General Formulae (ZII) and (ZIII) will be described.

In General Formulae (ZII) and (ZIII),
R₂₀₄ to R₂₀₇ independently represent an aryl group, an alkyl group, or a cycloalkyl group.

The aryl group of R₂₀₄ to R₂₀₇ is preferably a phenyl group or a naphthyl group, and more preferably a phenyl group. The aryl group of R₂₀₄ to R₂₀₇ may be an aryl group having a heterocyclic structure containing an oxygen atom, a nitrogen atom, a sulfur atom, or the like. Examples of the framework of the aryl group having a heterocyclic structure include pyrrole, furan, thiophene, indole, benzofuran, and benzothiophene.

The alkyl group and the cycloalkyl group with respect to R₂₀₄ to R₂₀₇ are preferably a linear or branched alkyl group having 1 to 10 carbon atoms (for example, a methyl group, an ethyl group, a propyl group, a butyl group, and a pentyl group) and a cycloalkyl group having 3 to 10 carbon atoms (for example, a cyclopentyl group, a cyclohexyl group, and a norbornyl group).

The aryl group, the alkyl group, and the cycloalkyl group of R₂₀₄ to R₂₀₇ may have a substituent, and examples of the substituent which the aryl group, an alkyl group and cycloalkyl group of R₂₀₄ to R₂₀₇ may have include an alkyl group (for example, having 1 to 15 carbon atoms), a cycloalkyl group (for example, having 3 to 15 carbon atoms), an aryl group (for example, having 6 to 15 carbon atoms), an alkoxy group (for example, having 1 to 15 carbon atoms), a halogen atom, a hydroxyl group, and a phenylthio group.

Z⁻ represents a non-nucleophilic anion, and examples thereof include the same ones as the non-nucleophilic anions of Z⁻ in General Formula (ZI).

Other examples of the acid generator include compounds represented by the following General Formulae (ZIV), (ZV), and (ZVI).

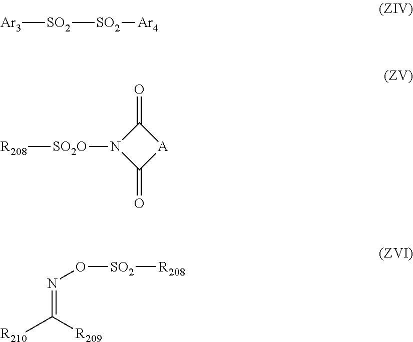

In General Formulae (ZIV) to (ZVI),
Ar₃ and Ar₄ each independently represent an aryl group, and R₂₀₈, R₂₀₉, and R₂₁₀ each independently represent an alkyl group, a cycloalkyl group, or an aryl group; and
A represents an alkylene group, an alkenylene group, or an arylene group.

Specific examples of the aryl group of Ar₃, Ar₄, R₂₀₈, R₂₀₉, and R₂₁₀ include the same ones as the specific examples of the aryl group of R₂₀₁, R₂₀₂, and R₂₀₃ in General Formula (ZI-1).

Specific examples of the alkyl group and the cycloalkyl group of R₂₀₈, R₂₀₉, and R₂₁₀ include the same ones as the specific examples of the alkyl group and the cycloalkyl group of R₂₀₁, R₂₀₂, and R₂₀₃ in General Formula (ZI-2).

Examples of the alkylene group of A include an alkylene group having 1 to 12 carbon atoms (for example, a methylene group, an ethylene group, a propylene group, an isopropylene group, a butylene group, and an isobutylene group); examples of the alkenylene group of A include an alkenylene group having 2 to 12 carbon atoms (for example, an ethenylene group, a propenylene group, and a butenylene group); and examples of the arylene group of A include an arylene group having 6 to 10 carbon atoms (for example, a phenylene group, a tolylene group, and a naphthylene group).

Among the acid generators, the compounds represented by General Formulae (ZI) to (ZIII) are more preferred.

Furthermore, the acid generator is preferably a compound capable of generating an acid having one sulfonic acid group, or imide group, more preferably a compound capable of generating a monovalent perfluoroalkanesulfonic acid, a compound capable of generating an aromatic sulfonic acid substituted with a monovalent fluorine atom or a group containing a fluorine atom, or a compound capable of generating an imide acid substituted with a monovalent fluorine atom or a group containing a fluorine atom, and still more preferably a sulfonium salt of a fluoro-substituted alkanesulfonic acid, a fluorine-substituted benzenesulfonic acid, a fluorine-substituted imide acid, or a fluorine-substituted methide acid. The acid generator which can be used is particularly preferably a compound capable of generating a fluoro-substituted alkanesulfonic acid, a fluoro-substituted benzenesulfonic acid, or a fluoro-substituted imide acid, in which pKa of the acid generated is −1 or less, thereby enhancing the sensitivity.

Among the acid generators, particularly preferred examples are shown below.

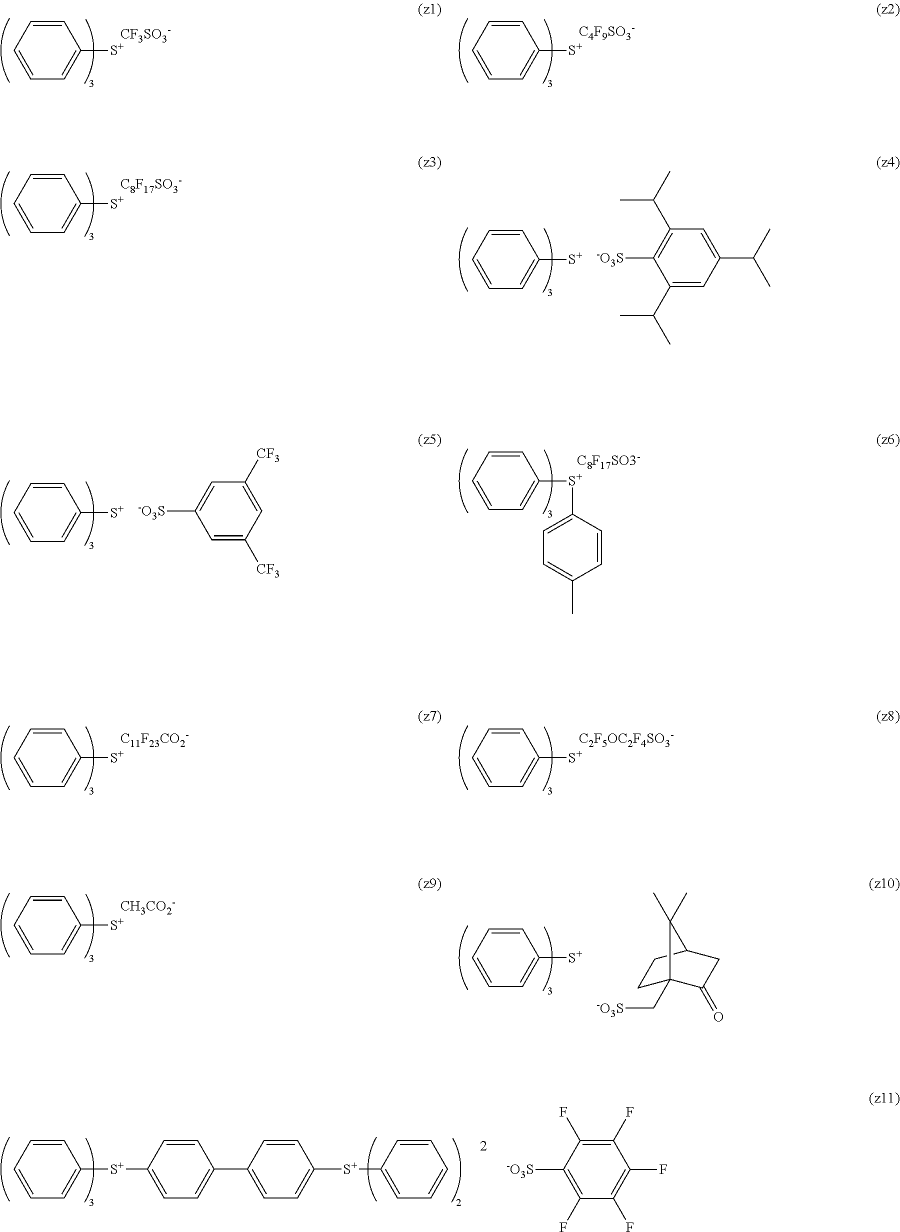

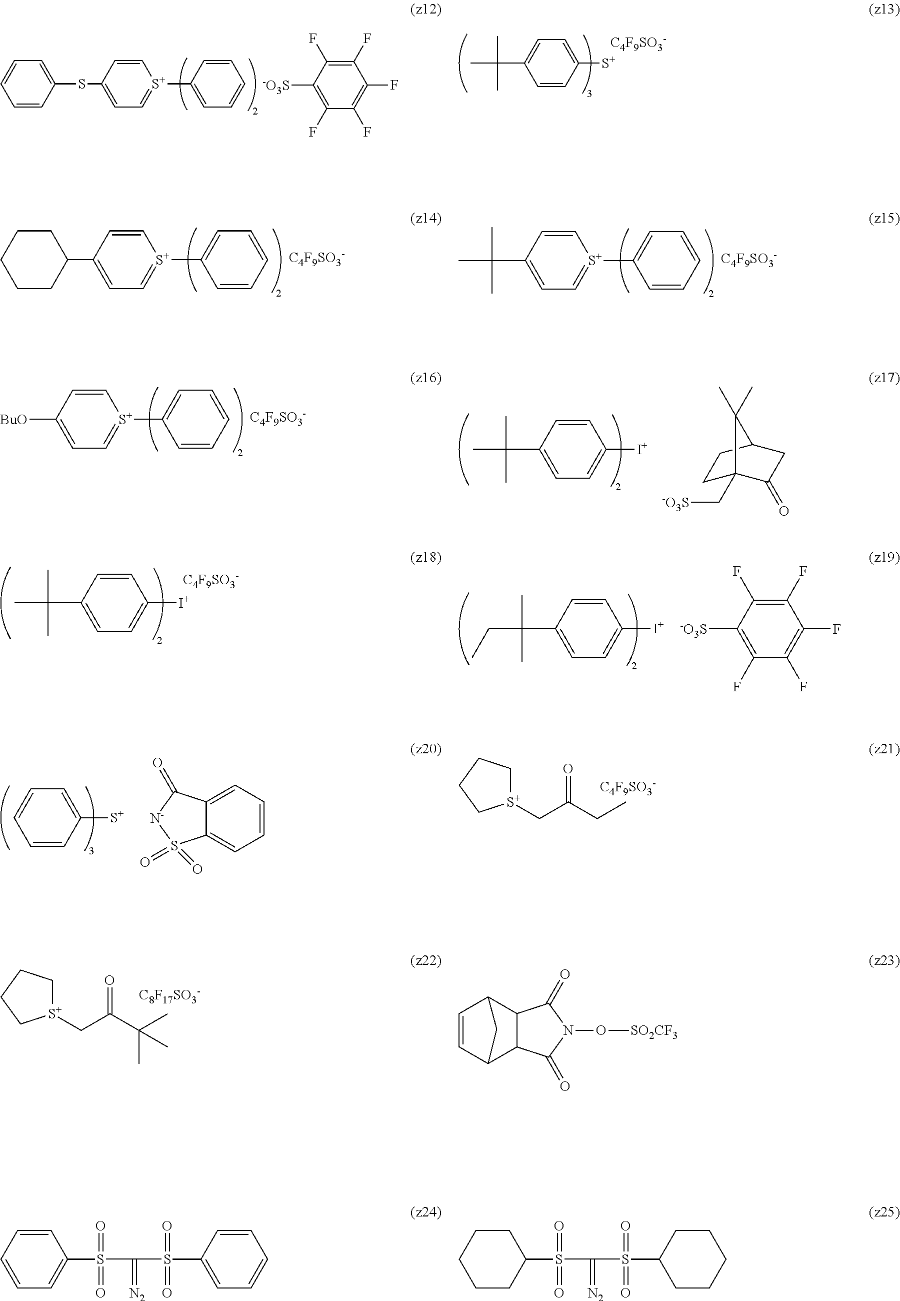

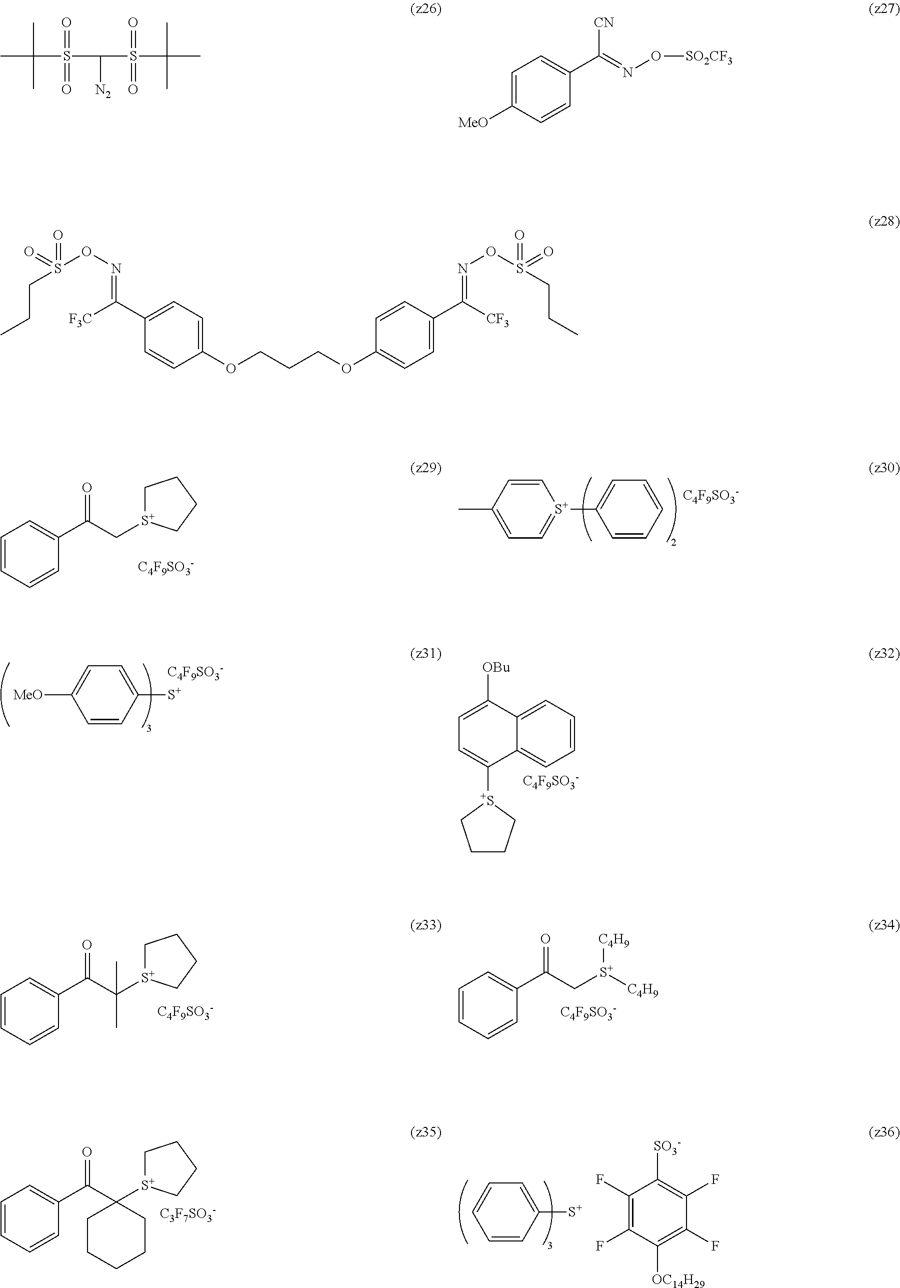

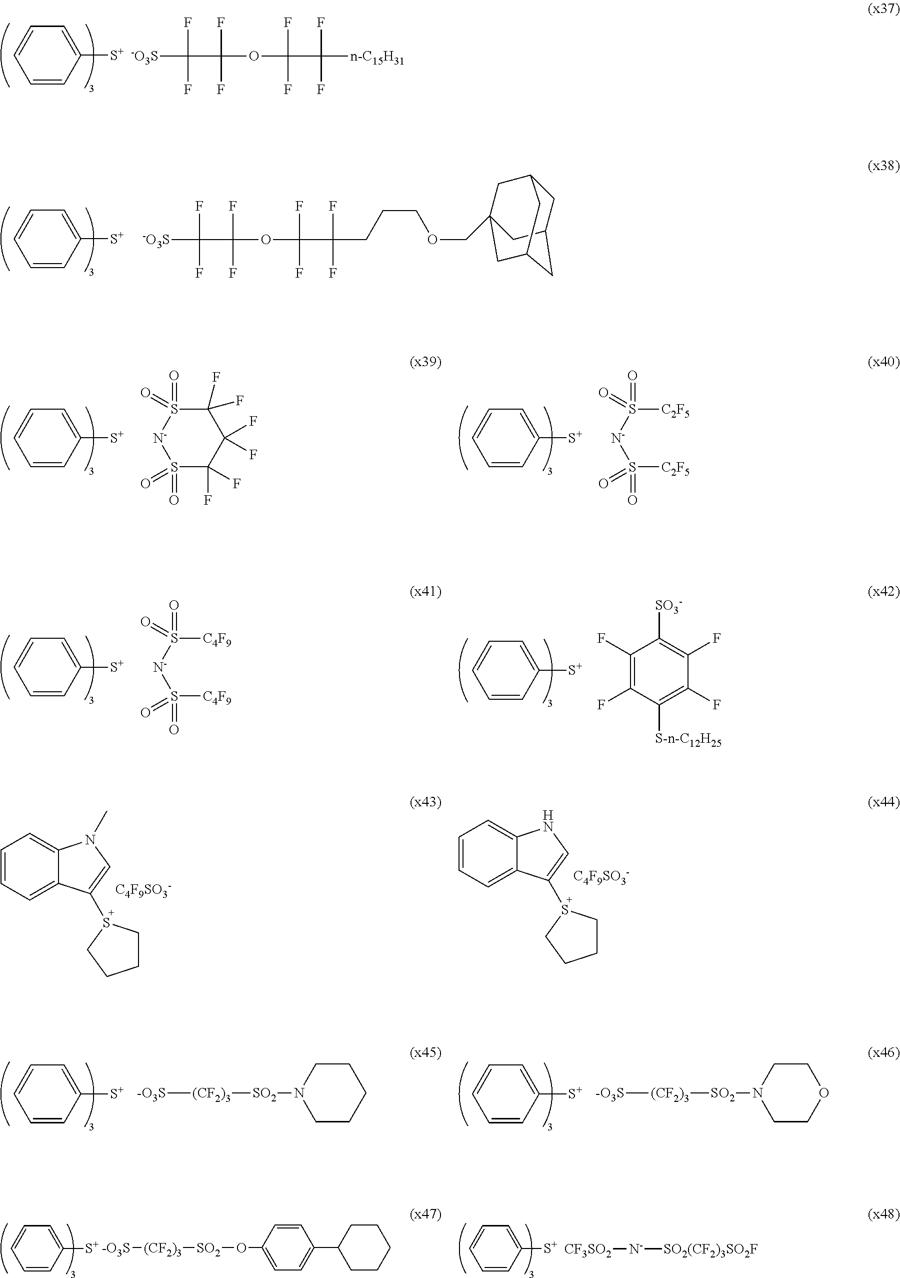

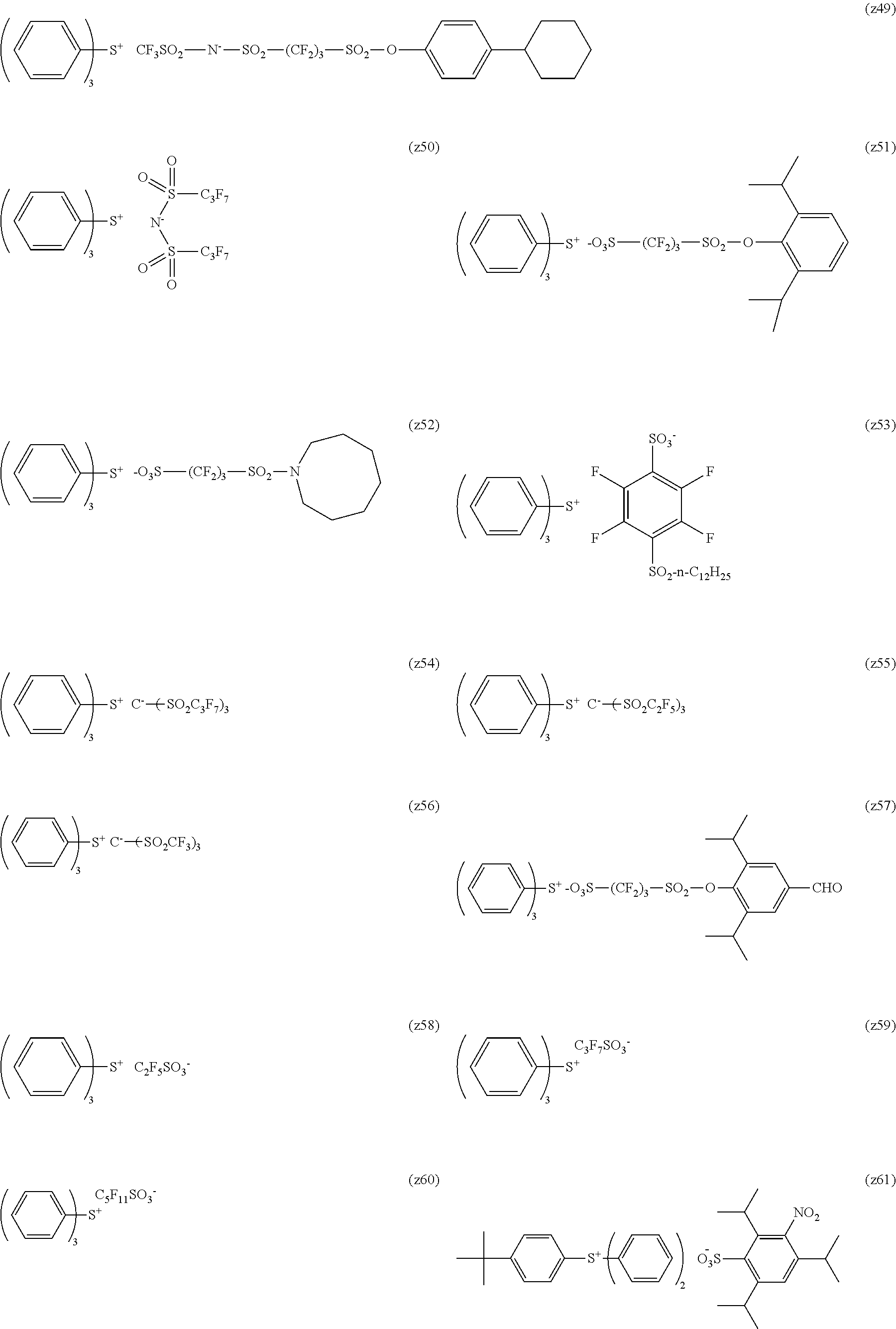

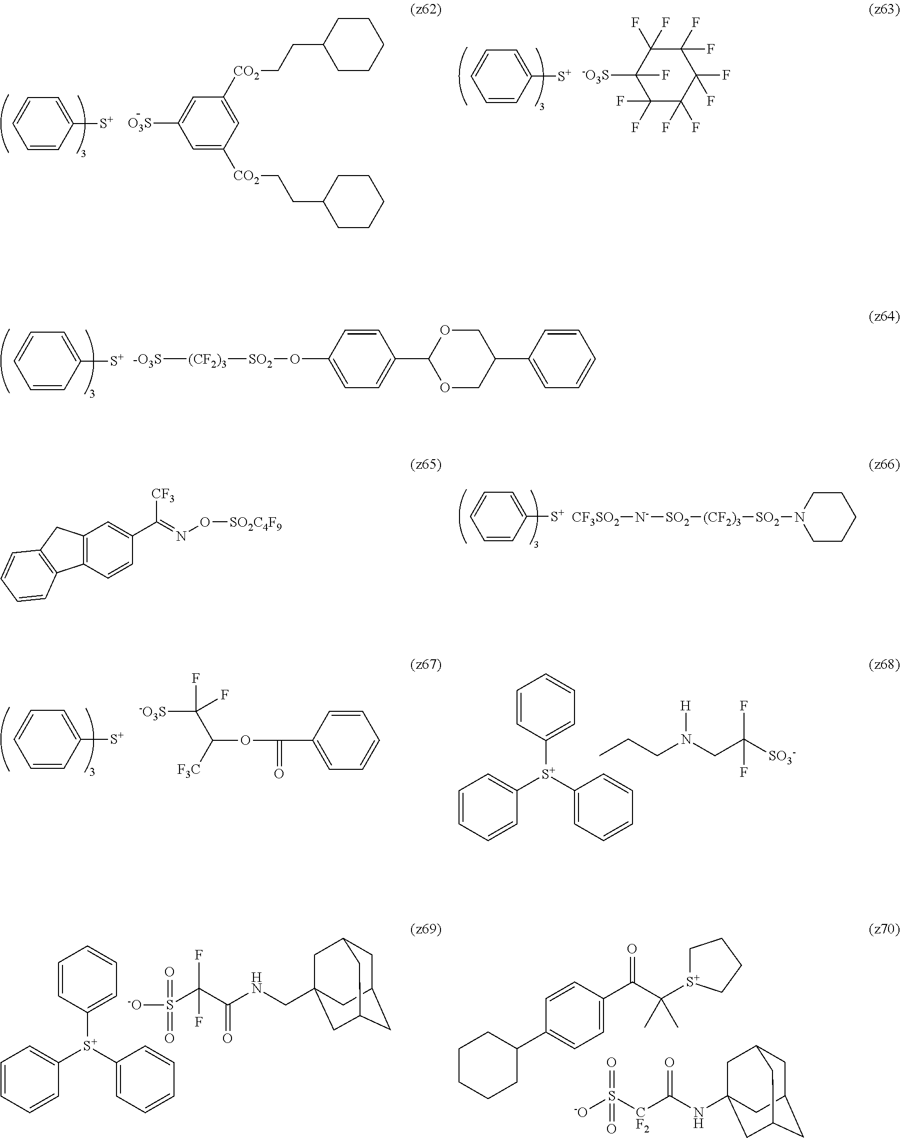

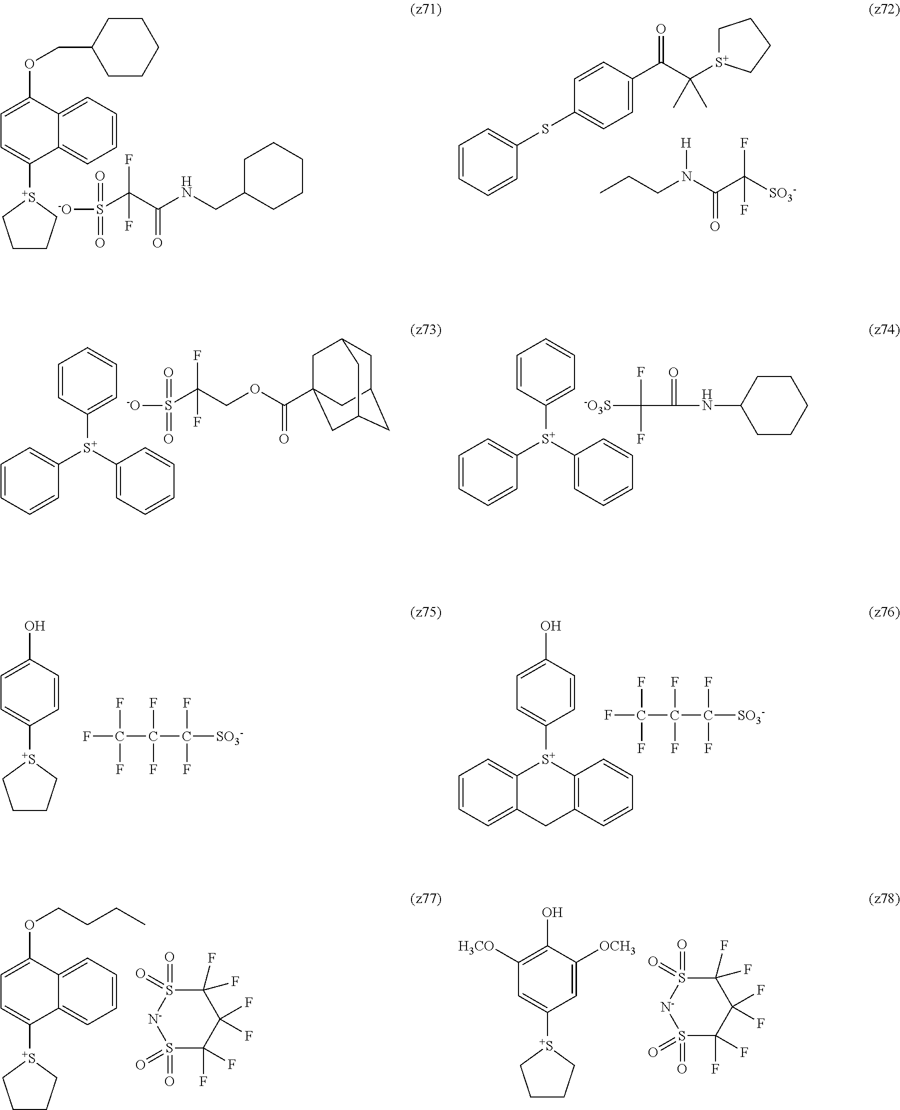

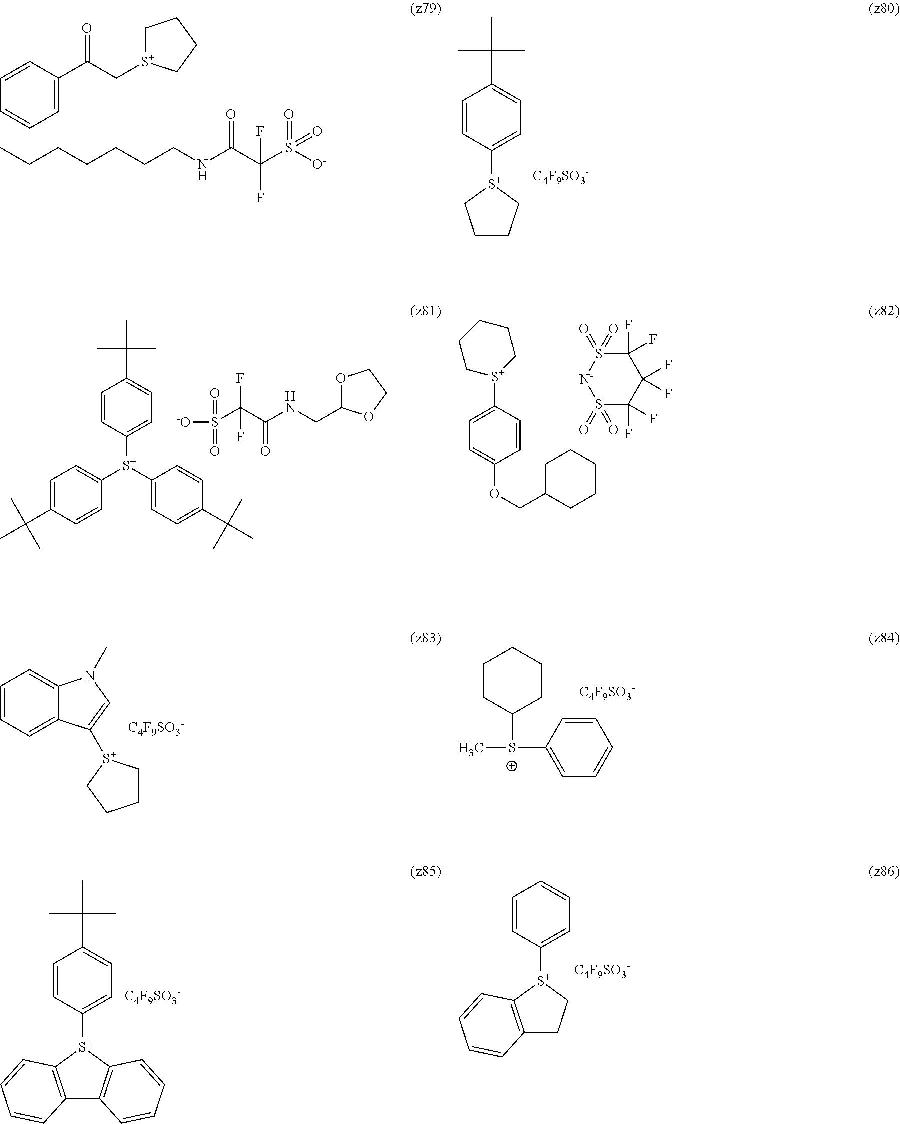

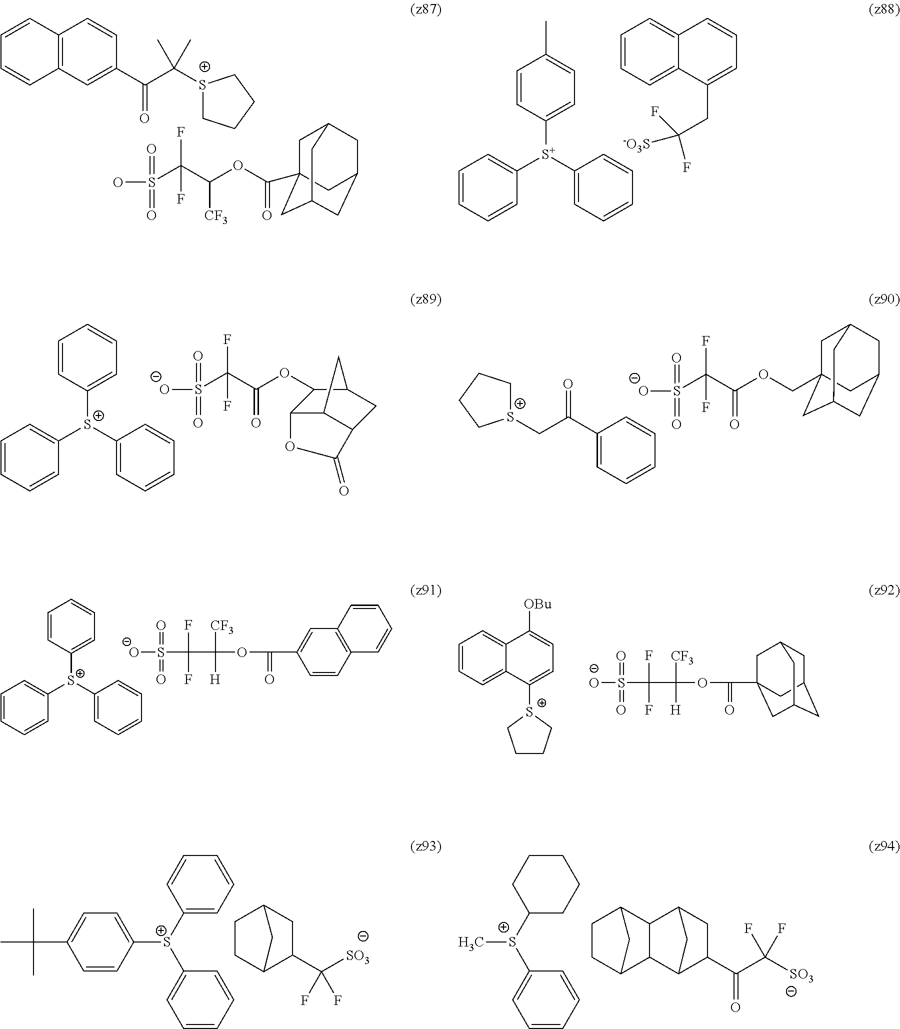

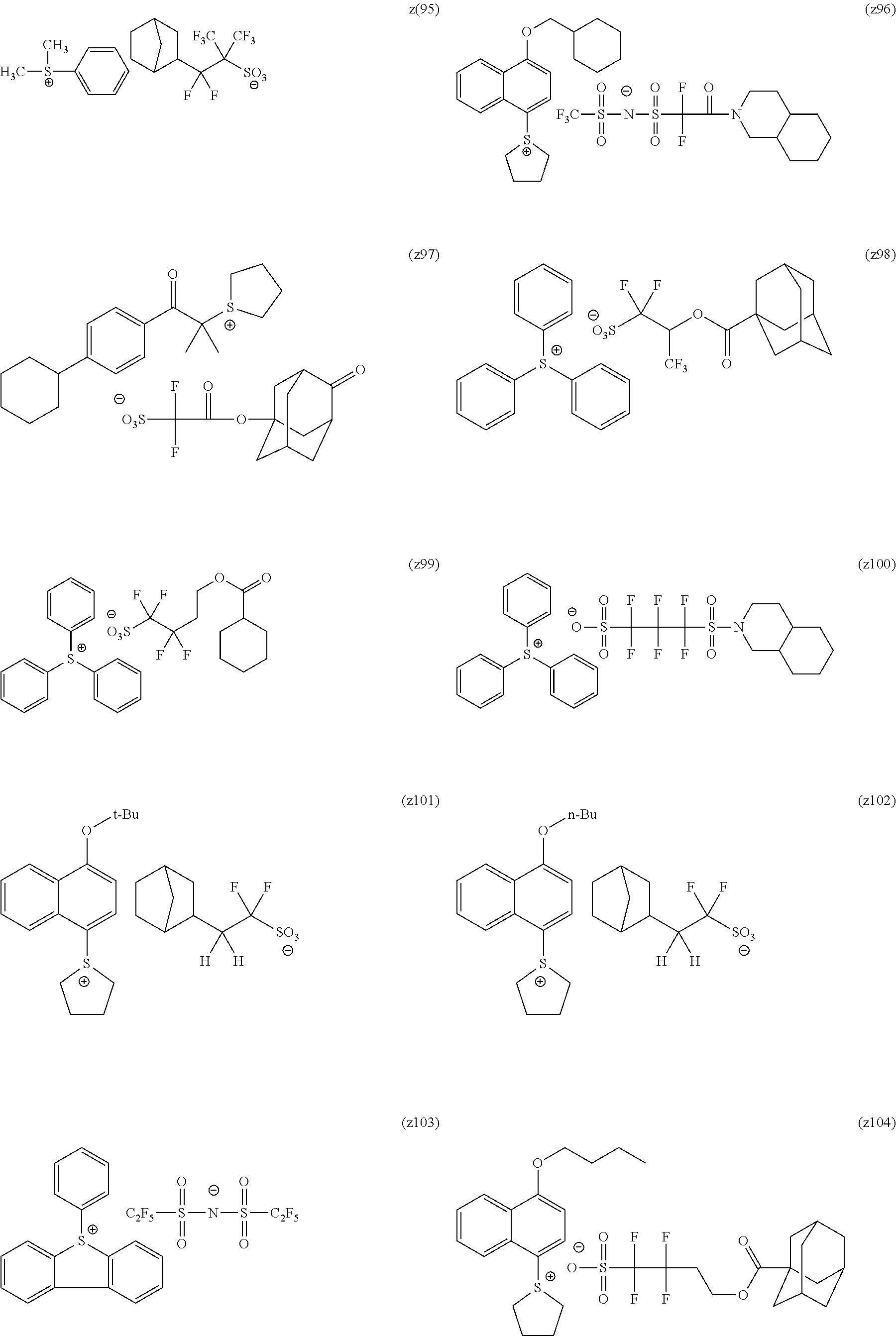

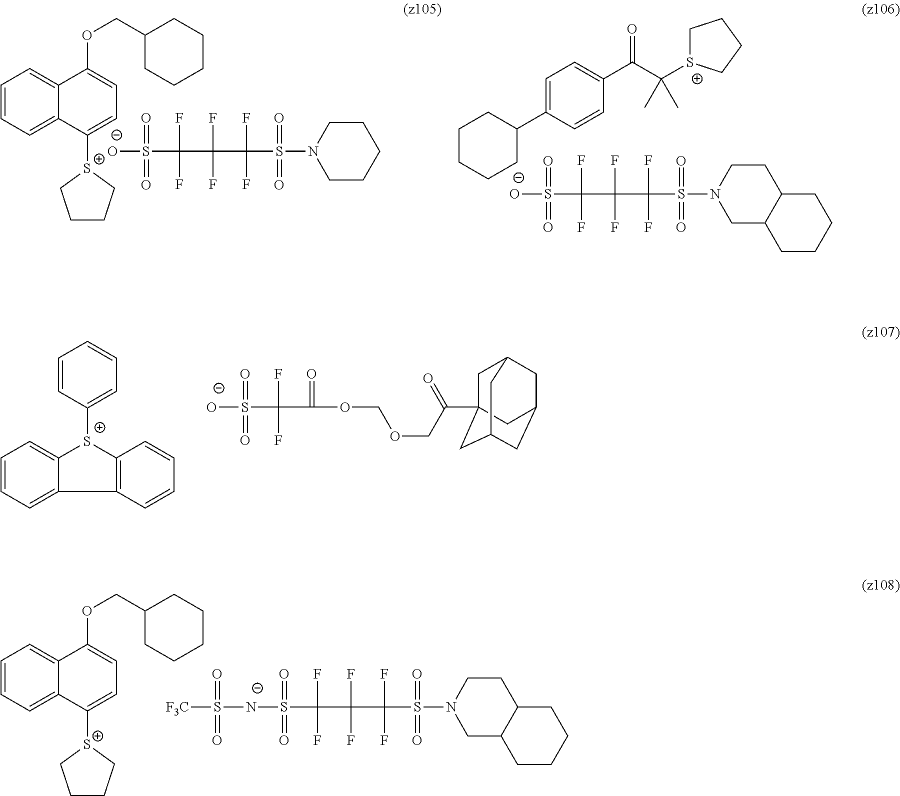

Furthermore, particularly preferred examples of ones having an anion represented by any one of General Formulae (B-1) to (B-3) among the compounds (B) are shown below, but the present invention is not limited thereto.

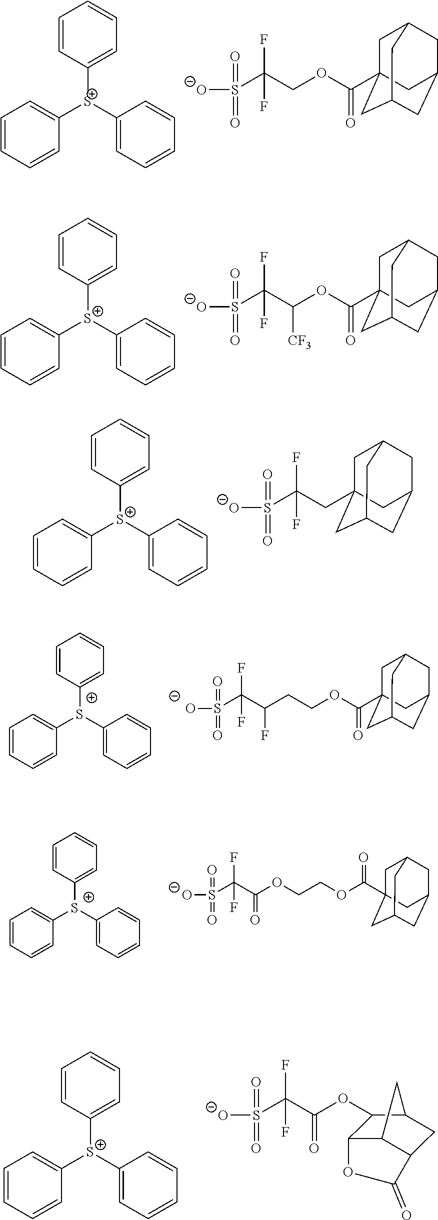

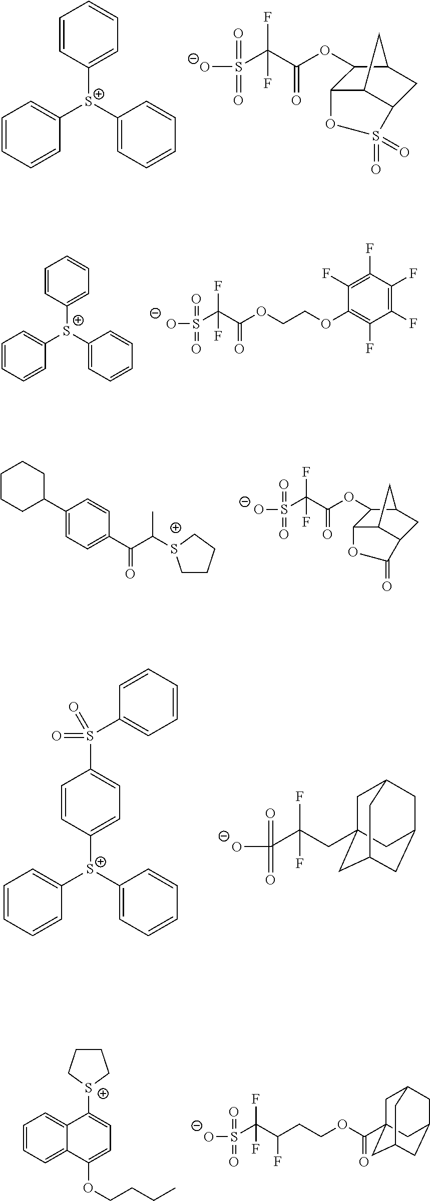

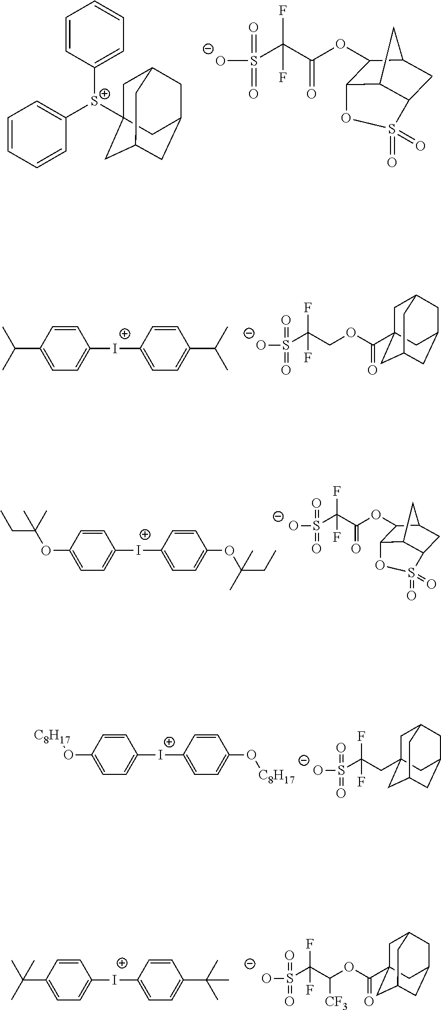

The acid generators can be synthesized by a known method, and can be synthesized in accordance with the methods described in, for example, JP2007-161707A, [0200] to [0210] of JP2010-100595A, [0051] to [0058] of WO2011/093280A, [0382] to [0385] of WO2008/153110A, JP2007-161707A, and the like.

The acid generators can be used alone or in combination of two or more kinds thereof.

The content of the compound capable of generating an acid by irradiation with actinic rays or radiation (exclusive of the case where the compound is represented by General Formula (ZI-3) or (ZI-4)) in the composition is preferably from 0.1% by mass to 30% by mass, more preferably from 0.5% by mass to 25% by mass, still more preferably from 3% by mass to 20% by mass, and particularly preferably from 3% by mass to 15% by mass, with respect to the total solid content of the radiation-sensitive resin composition.

In addition, in the case where the acid generator is represented by General Formula (ZI-3) or (ZI-4), the content thereof is preferably from 5% by mass to 35% by mass, more preferably from 6% by mass to 30% by mass, and particularly preferably from 6% by mass to 25% by mass, with respect to the total solid content of the composition.

[3] Solvent (C)

The radiation-sensitive resin composition used in the present invention contains a solvent (C).

Examples of the solvent (C) that can be used in the preparation of the radiation-sensitive resin composition include organic solvents such as alkylene glycol monoalkyl ether carboxylate, alkylene glycol monoalkyl ether, alkyl lactate ester, alkyl alkoxypropionate, cyclic lactone (preferably having 4 to 10 carbon atoms), a monoketone compound (preferably having 4 to 10 carbon atoms) which may have a ring, alkylene carbonate, alkyl alkoxyacetate, and alkyl pyruvate.

Specific examples of these solvents include ones described in, for example, [0441] to

of US2008/0187860A.

In the present invention, a mixed solvent may be used as the solvent (C).

The solvent is preferably, for example, alkylene glycol monoalkyl ether or alkyl lactate, and more preferably a mixed solvent of two or more kinds of solvents selected from propylene glycol monomethyl ether (PGME, alternative name: 1-methoxy-2-propanol), ethyl lactate, alkylene glycol monoalkyl ether acetate, alkyl alkoxy propionate, a monoketone compound which may contain a ring, cyclic lactone, and alkyl acetate. Among these, a mixed solvent of propylene glycol monomethyl ether acetate (PGMEA, alternative name: 1-methoxy-2-acetoxypropane) (hereinafter referred to a solvent A) with one kind or two or more kinds of solvents (hereinafter referred to a solvent B) selected from propylene glycol monomethyl ether, ethyl ethoxypropionate, 2-heptanone, γ-butyrolactone, cyclohexanone, and butyl acetate is preferred.

The mixing ratio (solvent A/solvent B) (mass ratio) of the mixed solvent is from 1/99 to 99/1, preferably from 10/90 to 90/10, and more preferably from 20/80 to 60/40.

The solvent (C) preferably contains propylene glycol monomethyl ether acetate, and is preferably a solvent composed of propylene glycol monomethyl ether acetate alone or a mixed solvent of two or more kinds of solvents including propylene glycol monomethyl ether acetate.

[4] Hydrophobic Resin (D)

The radiation-sensitive resin composition used in the present invention may contain a hydrophobic resin (hereinafter also referred to as a “hydrophobic resin (D)” or simply a “resin (D)”), particularly when the composition is applied to liquid immersion exposure. Further, it is preferable that the hydrophobic resin (D) is different from the resin (A).

With this, the hydrophobic resin (D) is unevenly distributed to the film surface layer, and in the case where the liquid immersion medium is water, the static/dynamic contact angle of the resist film surface with respect to water is improved, which can enhance the immersion liquid tracking properties.

It is preferable that the hydrophobic resin (D) is designed to be unevenly distributed to the interface as mentioned above, but in contrast to a surfactant, the resin (D) is not necessarily required to have a hydrophilic group in the molecule, and may not contribute to uniform mixing of polar/nonpolar materials.

From the viewpoint of uneven distribution to the film surface layer, it is preferable that the hydrophobic resin (D) contains any of at least one kind of a “fluorine atom”, a “silicon atom”, and a “CH₃ partial structure contained in the side chain portion of the resin”, and it is more preferable that the resin (D) contains two or more kinds thereof.

In the case where the hydrophobic resin (D) contains a fluorine atom and/or a silicon atom, the fluorine atom and/or the silicon atom in the hydrophobic resin (D) may be contained in the main chain of the resin or may be contained in the side chain.

In the case where the hydrophobic resin (D) contains a fluorine atom, the resin is preferably a resin which contains an alkyl group having a fluorine atom, a cycloalkyl group having a fluorine atom, or an aryl group having a fluorine atom, as a partial structure having a fluorine atom.

The alkyl group having a fluorine atom (preferably having 1 to 10 carbon atoms, and more preferably having 1 to 4 carbon atoms) is a linear or branched alkyl group in which at least one hydrogen atom is substituted with a fluorine atom, and may further have a substituent other than a fluorine atom.

The cycloalkyl group having a fluorine atom is a monocyclic or polycyclic cycloalkyl group in which at least one hydrogen atom is substituted with a fluorine atom, and may further have a substituent other than a fluorine atom.

The aryl group having a fluorine atom is an aryl group such as a phenyl group and a naphthyl group, in which at least one hydrogen atom is substituted with a fluorine atom, and may further have a substituent other than a fluorine atom.

Preferred examples of the alkyl group having a fluorine atom, the cycloalkyl group having a fluorine atom, and the aryl group having a fluorine atom include groups represented by the following General Formulae (F2) to (F4), but the present invention is not limited thereto.

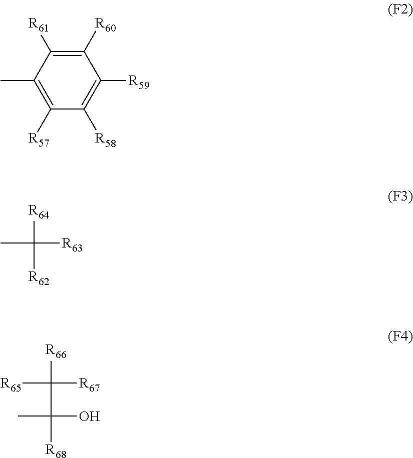

In General Formulae (F2) to (F4),

R₅₇ to R₆₈ each independently represent a hydrogen atom, a fluorine atom, or an (linear or branched) alkyl group, provided that at least one of R₅₇ to R₆₁, at least one of R₆₂ to R₆₄, and at least one of R₆₅ to R₆₈ each independently represents a fluorine atom or an alkyl group (preferably having 1 to 4 carbon atoms) in which at least one hydrogen atom is substituted with a fluorine atom.

It is preferable that R₅₇ to R₆₁, and R₆₅ to R₆₇ are all fluorine atoms. R₆₂, R₆₃, and R₆₈ are each preferably an alkyl group (preferably having 1 to 4 carbon atoms) in which at least one hydrogen atom is substituted with a fluorine atom, and more preferably a perfluoroalkyl group having 1 to 4 carbon atoms. R₆₂ and R₆₃ may be linked to each other to form a ring.

Specific examples of the group represented by General Formula (F2) include a p-fluorophenyl group, a pentafluorophenyl group, and a 3,5-di(trifluoromethyl)phenyl group.

Specific examples of the group represented by General Formula (F3) include a trifluoromethyl group, a pentafluoropropyl group, a pentafluoroethyl group, a heptafluorobutyl group, a hexafluoroisopropyl group, a heptafluoroisopropyl group, a hexafluoro(2-methyl)isopropyl group, a nonafluorobutyl group, an octafluoroisobutyl group, a nonafluorohexyl group, a nonafluoro-t-butyl group, a perfluoroisopentyl group, a perfluorooctyl group, a perfluoro(trimethyl)hexyl group, a 2,2,3,3-tetrafluorocyclobutyl group, and a perfluorocyclohexyl group, among which a hexafluoroisopropyl group, a heptafluoroisopropyl group, a hexafluoro(2-methyl)isopropyl group, an octafluoroisobutyl group, a nonafluoro-t-butyl group, and a perfluoroisopentyl group are preferred, and a hexafluoroisopropyl group and a heptafluoroisopropyl group are more preferred.

Specific examples of the group represented by General Formula (F4) include —C(CF₃)₂OH, —C(C₂F₅)₂OH, —C(CF₃)(CH₃)OH, and —CH(CF₃)OH, among which —C(CF₃)₂OH is preferred.

The partial structure having a fluorine atom may be bonded directly to the main chain or may be bonded to the main chain through a group selected from the group consisting of an alkylene group, a phenylene group, an ether bond, a thioether bond, a carbonyl group, an ester bond, an amide bond, a urethane bond, and a ureylene bond, or a group formed by combination of two or more thereof.

Hereinafter, with regard to the specific examples of the repeating unit having a fluorine atom, reference can be made to the repeating units described in paragraphs 0274 to 0276 of JP2012-073402A (paragraphs 0398 to 0399 of the corresponding US2012/077122A), the contents of which are incorporated in the specification of the present application.

The hydrophobic resin (D) may contain a silicon atom. With regard to the partial structure having a silicon atom, reference can be made to the partial structures described in paragraphs 0277 to 0281 of JP2012-073402A (paragraphs 0400 to 0405 of the corresponding US2012/077122A), the contents of which are incorporated in the specification of the present application.

Moreover, it is also preferable that the hydrophobic resin (D) contains a CH₃ partial structure in the side chain portion thereof as described above.

Here, the CH₃ partial structure contained in the side chain portion in the resin (D) (hereinafter also referred to as a “side chain CH₃ partial structure”) are intended to include CH₃ partial structures contained in an ethyl group, a propyl group, and the like.

On the other hand, a methyl group bonded directly to the main chain of the resin (D) (for example, an α-methyl group in the repeating unit having a methacrylic acid structure) makes only a small contribution of uneven distribution to the surface of the resin (D) due to the effect of the main chain, and it is therefore not included in the CH₃ partial structure in the present invention.

More specifically, in the case where the resin (D) contains a repeating unit derived from a monomer having a polymerizable moiety with a carbon-carbon double bond, such as a repeating unit represented by the following General Formula (M), and in addition, R₁₁ to R₁₄ are CH₃ “themselves”, such CH₃ is not included in the CH₃ partial structure contained in the side chain portion in the present invention.

On the other hand, a CH₃ partial structure which is present through some atom(s) from the C—C main chain is intended to correspond to the CH₃ partial structure in the present invention. For example, in the case where R₁₁ is an ethyl group (CH₂CH₃), it is intended that the repeating unit has “one” CH₃ partial structure in the present invention.

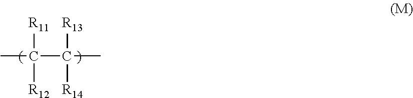

In General Formula (M),

R₁₁ to R₁₄ each independently represent a side chain portion.

Examples of R₁₁ to R₁₄ at the side chain portion include a hydrogen atom and a monovalent organic group.

Examples of the monovalent organic group for R₁₁ to R₁₄ include an alkyl group, a cycloalkyl group, an aryl group, an alkyloxycarbonyl group, a cycloalkyloxycarbonyl group, an aryloxycarbonyl group, an alkylaminocarbonyl group, a cycloalkylaminocarbonyl group, and an arylaminocarbonyl group, each of which may further have a substituent.

It is preferable that the hydrophobic resin (D) is a resin containing a repeating unit having the CH₃ partial structure in the side chain portion thereof. Further, it is more preferable that such a repeating unit has at least one repeating unit (x) selected from a repeating unit represented by the following General Formula (II) and a repeating unit represented by the following General Formula (III).

Hereinafter, the repeating unit represented by General Formula (II) will be described in detail.

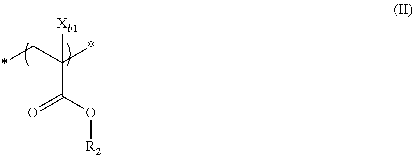

In General Formula (II), X_{b1} represents a hydrogen atom, an alkyl group, a cyano group, or a halogen atom, and R₂ represents an organic group which has one or more CH₃ partial structures and is stable against an acid. Here, more specifically, the organic group which is stable against an acid is preferably an organic group which does not have “the group capable of decomposing by the action of an acid to generate a polar group” as mentioned with respect to the resin (A).

The alkyl group of X_{b1} is preferably an alkyl group having 1 to 4 carbon atoms, and examples include a methyl group, an ethyl group, a propyl group, a hydroxymethyl group, and a trifluoromethyl group, among which a methyl group is preferred.

X_{b1} is preferably a hydrogen atom or a methyl group.

Examples of R₂ include an alkyl group, a cycloalkyl group, an alkenyl group, a cycloalkenyl group, an aryl group, and an aralkyl group, each of which has one or more CH₃ partial structures. Each of the cycloalkyl group, the alkenyl group, the cycloalkenyl group, the aryl group and the aralkyl group may further have an alkyl group as a substituent.

R₂ is preferably an alkyl group or an alkyl-substituted cycloalkyl group, each of which has one or more CH₃ partial structures.

The number of the CH₃ partial structures contained in the organic group which has one or more CH₃ partial structures and is stable against an acid as R₂ is preferably from 2 to 10, and more preferably from 2 to 8.

The alkyl group having one or more CH₃ partial structures in R₂ is preferably a branched alkyl group having 3 to 20 carbon atoms.

The cycloalkyl group having one or more CH₃ partial structures in R₂ may be monocyclic or polycyclic. Specific examples thereof include a group having 5 or more carbon atoms, which has a monocyclic, bicyclic, tricyclic, or tetracyclic structure. The number of carbon atoms thereof is preferably from 6 to 30, and more preferably from 7 to 25.

The alkenyl group having one or more CH₃ partial structures in R₂ is preferably a linear or branched alkenyl group having 1 to 20 carbon atoms, and more preferably a branched alkenyl group.

The aryl group having one or more CH₃ partial structures in R₂ is preferably an aryl group having 6 to 20 carbon atoms, such as a phenyl group and a naphthyl group, and more preferably a phenyl group.

The aralkyl group having one or more CH₃ partial structures in R₂ is preferably an aralkyl group having 7 to 12 carbon atoms, such as a benzyl group, a phenethyl group, and a naphthylmethyl group.

Specific preferred examples of the repeating unit represented by General Formula (II) are shown below, but the present invention is not limited thereto.

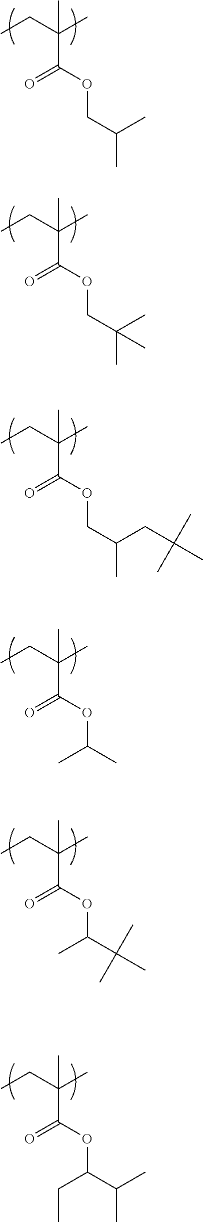

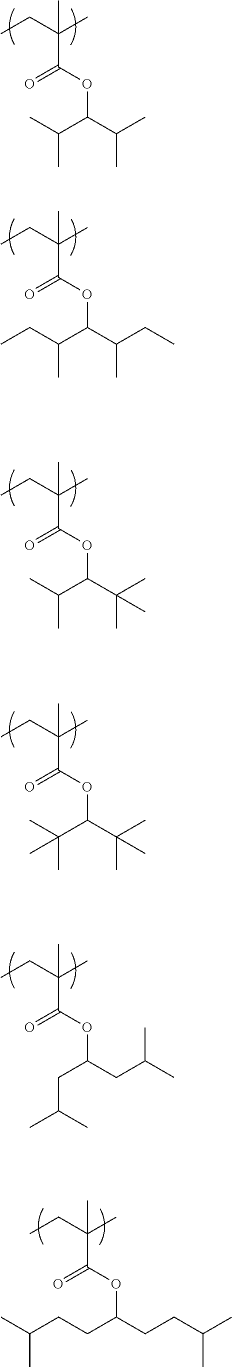

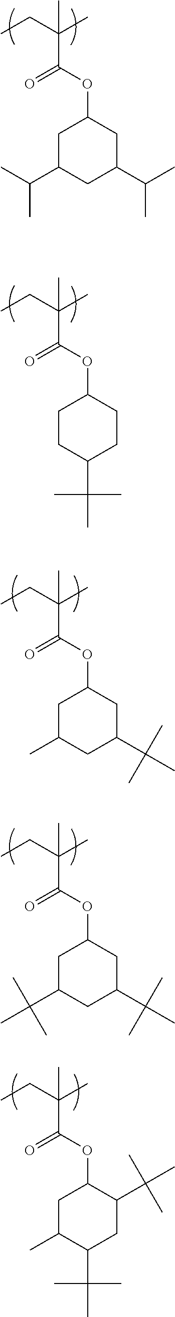

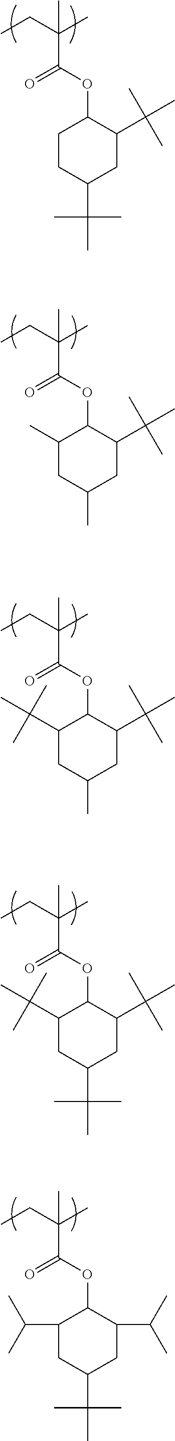

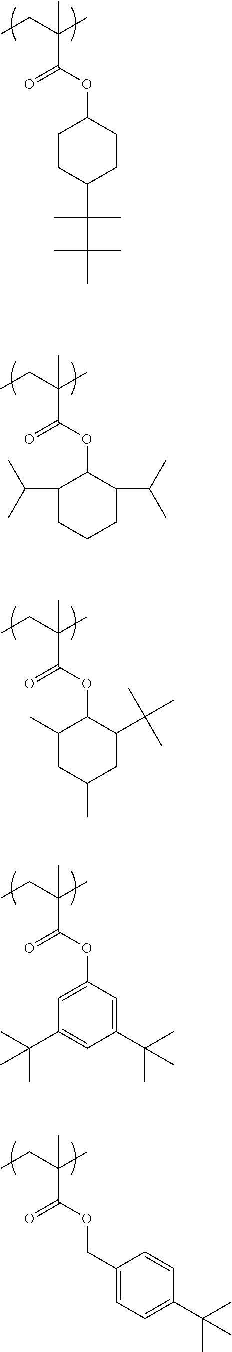

The repeating unit represented by General Formula (II) is preferably a repeating unit which is stable against an acid (acid-indecomposable), and specifically, it is preferably a repeating unit having no group capable of decomposing by the action of an acid to generate a polar group.

The repeating unit represented by the following General Formula (III) will be described in detail.

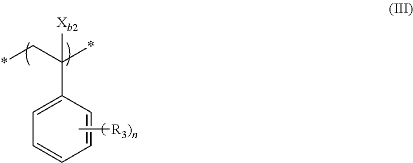

In General Formula (III), X_{b2} represents a hydrogen atom, an alkyl group, a cyano group, or a halogen atom, R₃ represents an organic group which has one or more CH₃ partial structures and is stable against an acid, and n represents an integer of 1 to 5.

The alkyl group of X_{b2} is preferably an alkyl group having 1 to 4 carbon atoms, and examples thereof include a methyl group, an ethyl group, a propyl group, a hydroxymethyl group, and a trifluoromethyl group, but a hydrogen atom is preferred.

X_{b2} is preferably a hydrogen atom.

R₃ is an organic group which is stable against an acid. Therefore, to be more specific, R₃ is preferably an organic group which does not have “the group capable of decomposing by the action of an acid to generate a polar group” as mentioned in the resin (A).

Examples of R₃ include an alkyl group having one or more CH₃ partial structures.

The number of the CH₃ partial structures contained in the organic group which has one or more CH₃ partial structures and is stable against an acid as R₃ is preferably from 1 to 10, more preferably from 1 to 8, and still more preferably from 1 to 4.

The alkyl group having one or more CH₃ partial structures in R₃ is preferably a branched alkyl group having 3 to 20 carbon atoms.

n represents an integer of 1 to 5, preferably 1 to 3, and more preferably 1 or 2.

Specific preferred examples of the repeating unit represented by General Formula (III) are shown below, but the present invention is not limited thereto.

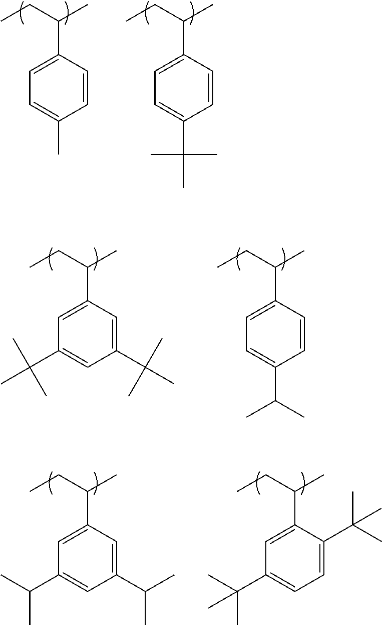

The repeating unit represented by General Formula (III) is preferably a repeating unit which is stable against an acid (acid-indecomposable), and specifically, it is a repeating unit which has no group capable of decomposing by the action of an acid to generate a polar group.

In the case where the resin (D) contains a CH₃ partial structure in the side chain portion thereof, and in particular, it has neither a fluorine atom nor a silicon atom, the content of at least one repeating unit (x) of the repeating unit represented by General Formula (II) and the repeating unit represented by General Formula (III) is preferably 90% by mole or more, and more preferably 95% by mole or more, with respect to all the repeating units of the resin (C). Further, the content is usually 100% by mole or less with respect to all the repeating units of the resin (C).

By incorporating at least one repeating unit (x) of the repeating unit represented by General Formula (II) and the repeating unit represented by General Formula (III) in a proportion of 90% by mole or more with respect to all the repeating units of the resin (D) into the resin (D), the surface free energy of the resin (C) is increased. As a result, it is difficult for the resin (D) to be unevenly distributed on the surface of the resist film and the static/dynamic contact angle of the resist film with respect to water can be securely increased, thereby enhancing the immersion liquid tracking properties.

In addition, the hydrophobic resin (D) may have at least one group selected from the following groups (x) to (z) in the case (i) of containing a fluorine atom and/or a silicon atom as well as in the case (ii) of containing a CH₃ partial structure in the side chain portion:
(x) an acid group,
(y) a group having a lactone structure, an acid anhydride group, or an acid imide group, and
(z) a group capable of decomposing by the action of an acid.

Examples of the acid group (x) include a phenolic hydroxyl group, a carboxylic acid group, a fluorinated alcohol group, a sulfonic acid group, a sulfonamide group, a sulfonylimide group, an (alkylsulfonyl)(alkylcarbonyl)methylene group, an (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group, and a tris(alkylsulfonyl)methylene group.

Preferred examples of the acid group include a fluorinated alcohol group (preferably hexafluoroisopropanol), a sulfonimide group, and a bis(alkylcarbonyl)methylene group.

Examples of the repeating unit having an acid group (x) include a repeating unit in which the acid group is directly bonded to the main chain of the resin, such as a repeating unit by an acrylic acid or a methacrylic acid, and a repeating unit in which the acid group is bonded to the main chain of the resin through a linking group, and the acid group may also be introduced into the polymer chain terminal by using a polymerization initiator or chain transfer agent having an acid group during the polymerization. All of these cases are preferred. The repeating unit having an acid group (x) may have at least one of a fluorine atom and a silicon atom.

The content of the repeating units having an acid group (x) is preferably from 1% by mole to 50% by mole, more preferably from 3% by mole to 35% by mole, and still more preferably from 5% by mole to 20% by mole, with respect to all the repeating units in the hydrophobic resin (D).

With regard to specific examples of the repeating unit having an acid group (x), reference can be made to the repeating units described in paragraphs 0285 to 0287 of JP2012-073402A (paragraph 0414 of the corresponding US2012/077122A), the contents of which are incorporated in the specification of the present application.

As the group having a lactone structure, the acid anhydride group, or the acid imide group (y), the group having a lactone structure is particularly preferred.

The repeating unit containing such a group is, for example, a repeating unit in which the group is directly bonded to the main chain of the resin, such as a repeating unit by an acrylic ester or a methacrylic ester. This repeating unit may be a repeating unit in which the group is bonded to the main chain of the resin through a linking group. Alternatively, this repeating unit may be introduced into the terminal of the resin by using a polymerization initiator or chain transfer agent containing the group during the polymerization.

Examples of the repeating unit containing a group having a lactone structure include the same ones as those of the repeating unit having a lactone structure as described earlier in the section of the acid-decomposable resin (A).

The content of the repeating units having a group having a lactone structure, an acid anhydride group, or an acid imide group is preferably from 1% by mole to 100% by mole, more preferably from 3% by mole to 98% by mole, and still more preferably from 5% by mole to 95% by mole, with respect to all the repeating units in the hydrophobic resin (D).

With respect to the hydrophobic resin (D), examples of the repeating unit having a group (z) capable of decomposing by the action of an acid include the same ones as the repeating units having an acid-decomposable group, as mentioned with respect to the resin (A). The repeating unit having a group (z) capable of decomposing by the action of an acid may contain at least one of a fluorine atom and a silicon atom. In the hydrophobic resin (D), the content of the repeating units having a group (z) capable of decomposing by the action of an acid is preferably from 1% by mole to 80% by mole, more preferably from 10% by mole to 80% by mole, and still more preferably from 20% by mole to 60% by mole, with respect to all the repeating units in the resin (D).

The hydrophobic resin (D) may also contain a repeating unit represented by the following General Formula (III).

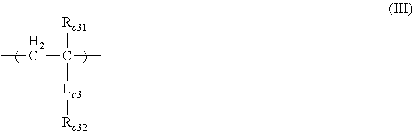

In General Formula (III),
R_{c31} represents a hydrogen atom, an alkyl group (which may be substituted with a fluorine atom or the like), a cyano group, or a —CH₂—O-Rac₂ group, in which Rac₂ represents a hydrogen atom, an alkyl group, or an acyl group, and R_{c31} is preferably a hydrogen atom, a methyl group, a hydroxymethyl group, or a trifluoromethyl group, and more preferably a hydrogen atom or a methyl group;
R_{c32} represents a group having an alkyl group, a cycloalkyl group, an alkenyl group, a cycloalkenyl group, or an aryl group, each of which may be substituted with a group containing a fluorine atom or a silicon atom; and
L_{c3} represents a single bond or a divalent linking group.

In General Formula (III), the alkyl group of R_{c32} is preferably a linear or branched alkyl group having 3 to 20 carbon atoms.

The cycloalkyl group is preferably a cycloalkyl group having 3 to 20 carbon atoms.

The alkenyl group is preferably an alkenyl group having 3 to 20 carbon atoms.

The cycloalkenyl group is preferably a cycloalkenyl group having 3 to 20 carbon atoms.

The aryl group is preferably an aryl group having 6 to 20 carbon atoms, and more preferably a phenyl group or a naphthyl group, and these groups may have a substituent.

R_{c32} is preferably an unsubstituted alkyl group or an alkyl group substituted with a fluorine atom.

The divalent linking group of L_{c3} is preferably an alkylene group (preferably having 1 to 5 carbon atoms), an ether bond, a phenylene group, or an ester bond (a group represented by —COO—).

The content of the repeating units represented by formula (III) is preferably from 1% by mole to 100% by mole, more preferably from 10% by mole to 90% by mole, and still more preferably from 30% by mole to 70% by mole, with respect to all the repeating units in the hydrophobic resin.

It is also preferable that the hydrophobic resin (D) further contains a repeating unit represented by the following General Formula (CII-AB).

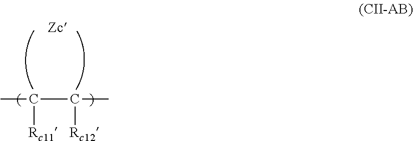

In Formula (CII-AB),
R_{c11}′ and R_{c12}′ each independently represent a hydrogen atom, a cyano group, a halogen atom, or an alkyl group; and
Zc′ represents an atomic group for forming an alicyclic structure containing two carbon atoms (C—C) to which Zc′ is bonded.

The content of the repeating units represented by General Formula (CII-AB) is preferably from 1% by mole to 100% by mole, more preferably from 10% by mole to 90% by mole, and still more preferably from 30% by mole to 70% by mole, with respect to all the repeating units in the hydrophobic resin.

Specific examples of the repeating units represented by General Formulae (III) and (CII-AB) are shown below, but the present invention is not limited thereto. In the formulae, Ra represents H, CH₃, CH₂OH, CF₃, or CN.

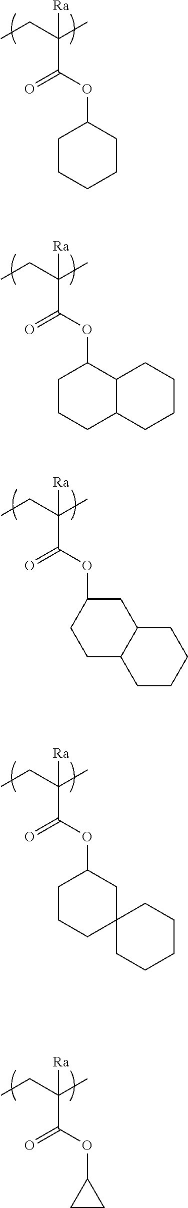

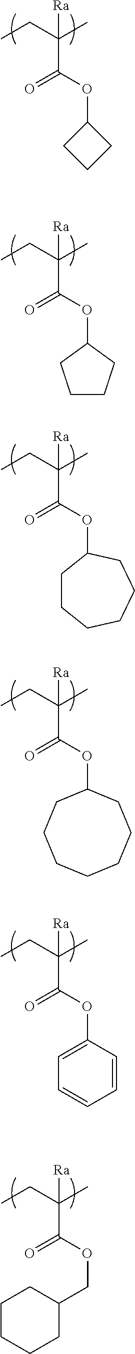

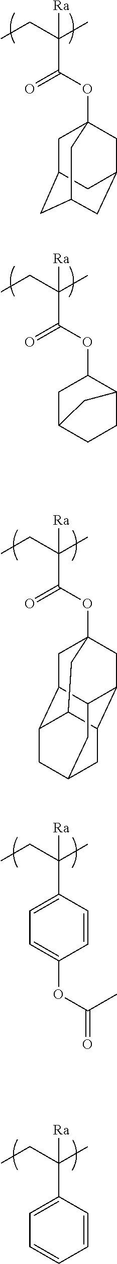

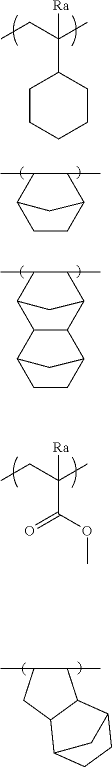

In the case where the hydrophobic resin (D) has a fluorine atom, the content of the fluorine atom is preferably from 5% by mass to 80% by mass, and more preferably from 10% by mass to 80% by mass, with respect to the weight-average molecular weight of the hydrophobic resin (D). Further, the proportion of the repeating units containing a fluorine atom is preferably from 10% by mole to 100% by mole, and more preferably from 30% by mole to 100% by mole, with respect to all the repeating units contained in the hydrophobic resin (D).

In the case where the hydrophobic resin (D) contains a silicon atom, the content of the silicon atom is preferably from 2% by mass to 50% by mass, and more preferably from 2% by mass to 30% by mass, with respect to the weight-average molecular weight of the hydrophobic resin (D). Further, the proportion of the repeating unit containing a silicon atom is preferably 10% by mole to 100% by mole, and more preferably from 20% by mole to 100% by mole, with respect to all the repeating units contained in the hydrophobic resin (D).

On the other hand, in particular, in the case where the resin (D) contains a CH₃ partial structure in the side chain portion thereof, it is also preferable that the resin (D) has a form having substantially neither a fluorine atom nor a silicon atom. In this case, specifically, the content of the repeating units containing a fluorine atom or a silicon atom is preferably 5% by mole or less, more preferably 3% by mole or less, still more preferably 1% by mole or less, and ideally 0% by mole, that is, containing neither a fluorine atom nor a silicon atom, with respect to all the repeating units in the resin (D). In addition, it is preferable that the resin (D) is composed substantially of a repeating unit constituted with only an atom selected from the group consisting of a carbon atom, an oxygen atom, a hydrogen atom, a nitrogen atom, and a sulfur atom. More specifically, the proportion of the repeating unit constituted with only an atom selected from the group consisting of a carbon atom, an oxygen atom, a hydrogen atom, a nitrogen atom, and a sulfur atom is preferably 95% by mole or more, more preferably 97% by mole or more, still more preferably 99% by mole or more, and ideally 100% by mole, of all the repeating units in the resin (D).

The weight-average molecular weight of the hydrophobic resin (D) in terms of standard polystyrene is preferably from 1,000 to 100,000, more preferably from 1,000 to 50,000, and still more preferably from 2,000 to 15,000.

Furthermore, the hydrophobic resins (D) may be used alone or in combination of two or more kinds thereof.

The content of the hydrophobic resins (D) in the composition is preferably from 0.01% by mass to 10% by mass, more preferably from 0.05% by mass to 8% by mass, and still more preferably from 0.1% by mass to 7% by mass, with respect to the total solid content of the radiation-sensitive resin composition.

In the hydrophobic resin (D), similarly to the resin (A), it is certain that the content of impurities such as metal is small, but the content of residual monomers or oligomer components is also preferably from 0.01% by mass to 5% by mass, more preferably from 0.01% by mass to 3% by mass, and still more preferably from 0.05% by mass to 1% by mass. Within these ranges, a radiation-sensitive resin composition free from in-liquid extraneous materials and a change in sensitivity or the like with aging can be obtained. Further, from the viewpoints of a resolution, a resist profile, the side wall of a resist pattern, a roughness, and the like, the molecular weight distribution (Mw/Mn, also referred to as a dispersity) is preferably in the range of 1 to 5, more preferably 1 to 3, and still more preferably 1 to 2.

As the hydrophobic resin (D), various commercial products may be used, or the resin may be synthesized by an ordinary method (for example, radical polymerization). Examples of the general synthesis method include a batch polymerization method of dissolving monomer species and an initiator in a solvent and heating the solution, thereby carrying out the polymerization, and a dropping polymerization method of adding dropwise a solution containing monomer species and an initiator to a heated solvent for 1 hour to 10 hours, among which the dropping polymerization method is preferred.

The reaction solvent, the polymerization initiator, the reaction conditions (a temperature, a concentration, and the like) and the method for purification after reaction are the same as ones described for the resin (A), but in the synthesis of the hydrophobic resin (D), the concentration at the reaction is preferably from 30% by mass to 50% by mass.

Specific examples of the hydrophobic resin (D) are shown below. Further, the molar ratio of the repeating units (corresponding to the respective repeating units in order from the left side), the weight-average molecular weight, and the dispersity with respect to the respective resins are shown in the following Table.

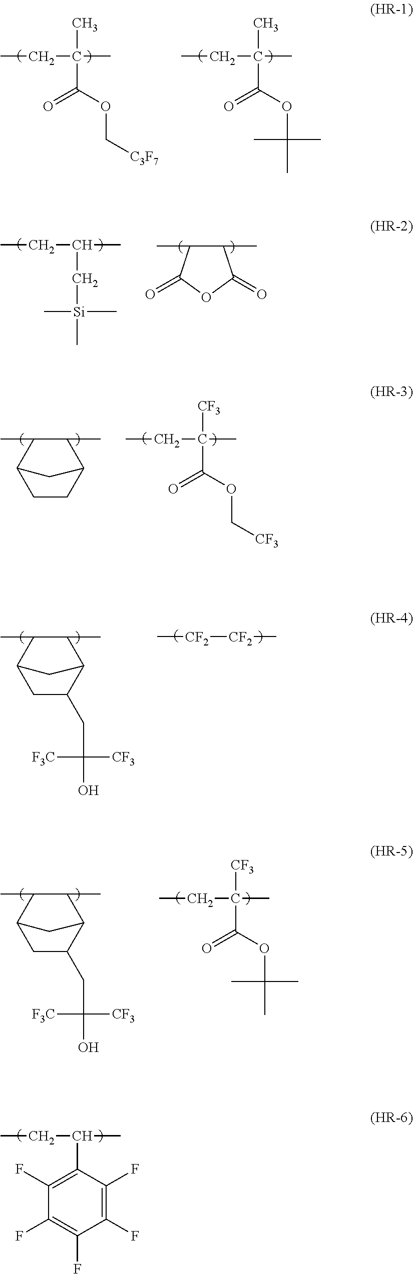

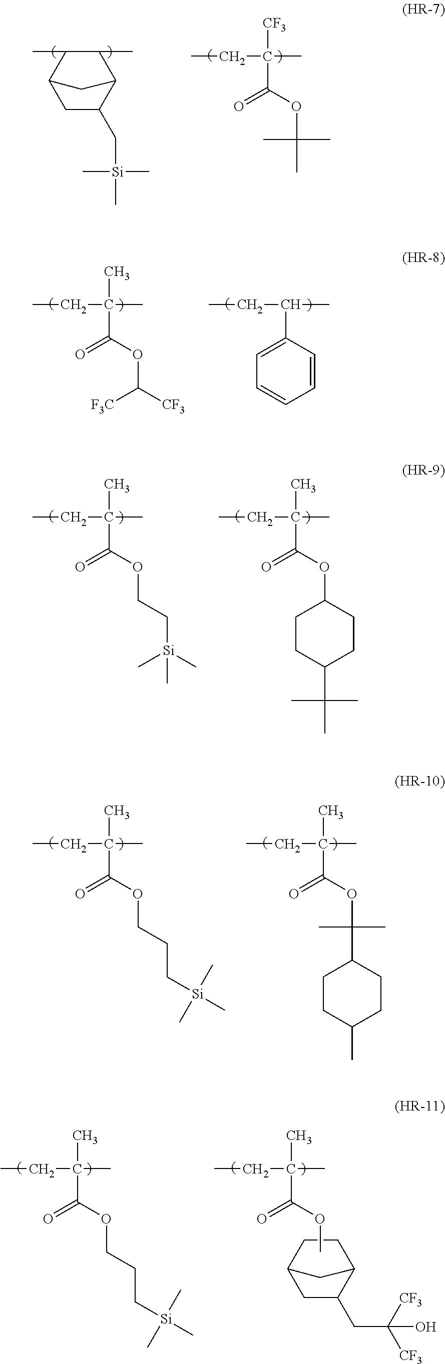

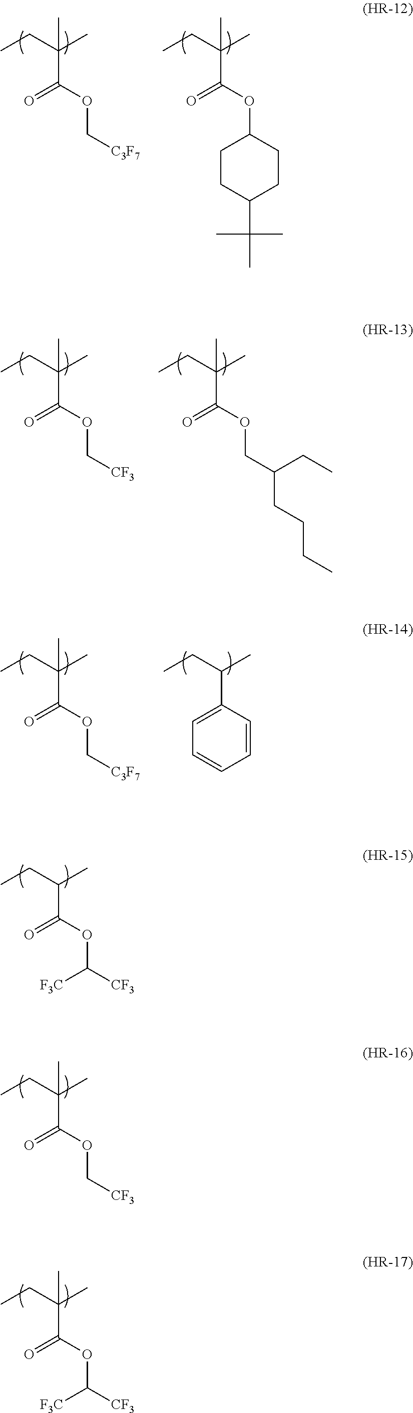

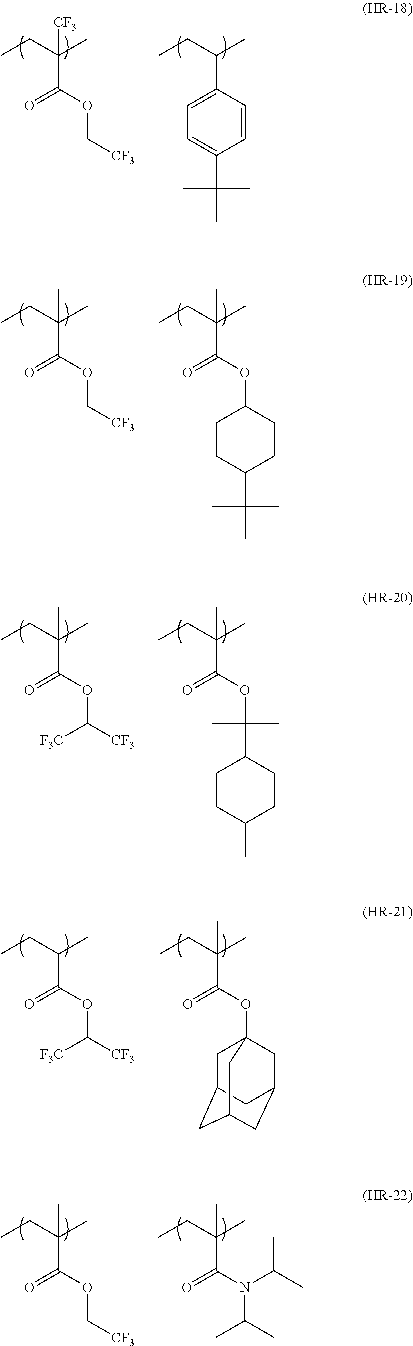

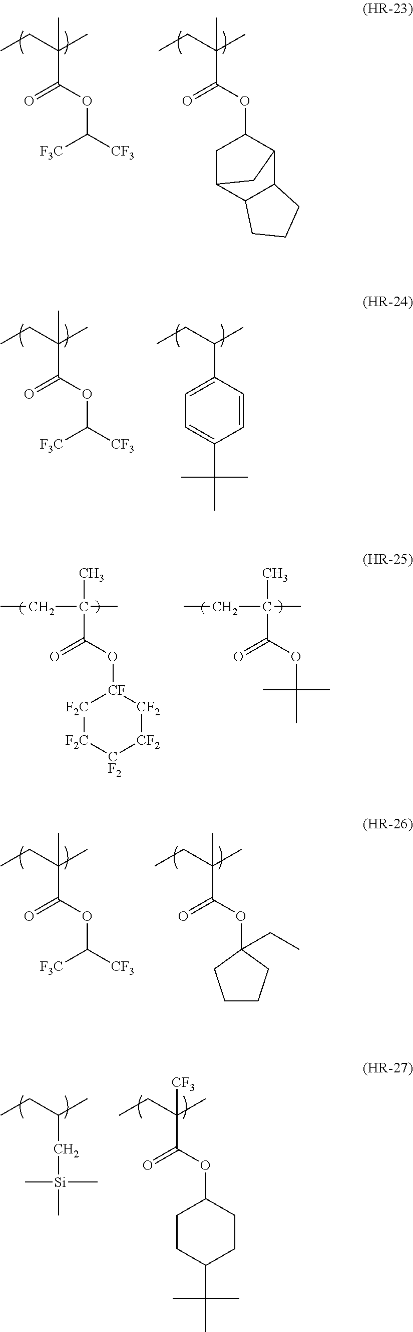

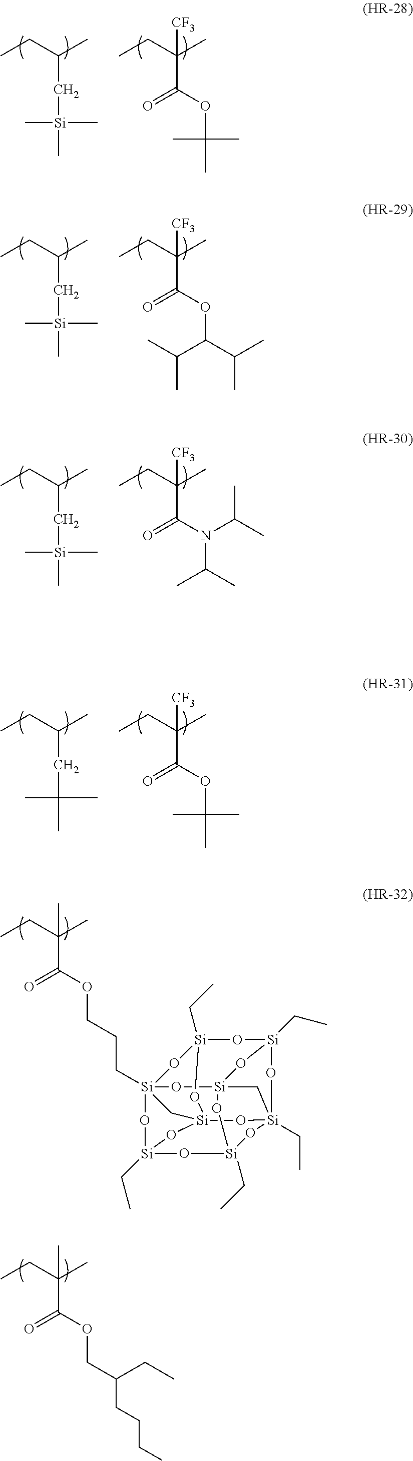

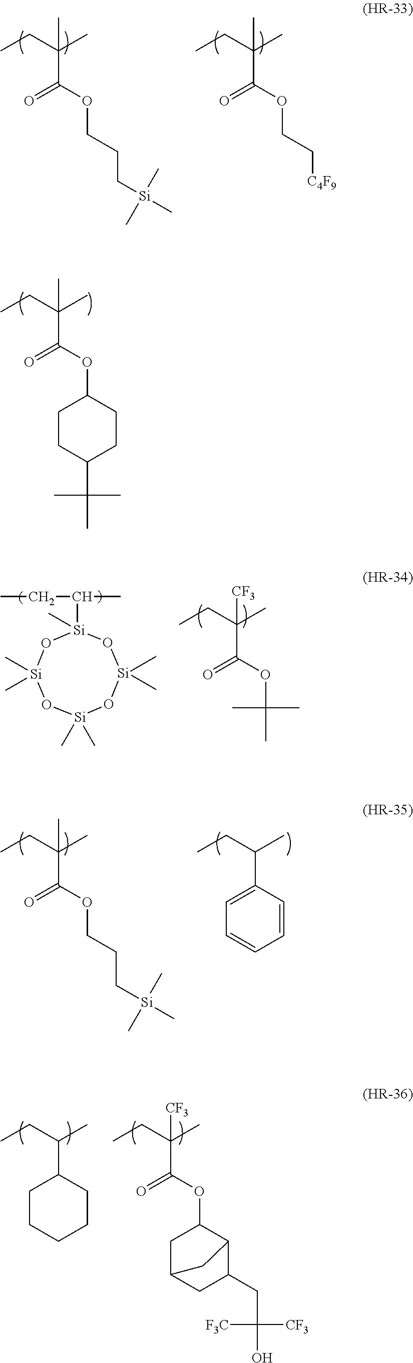

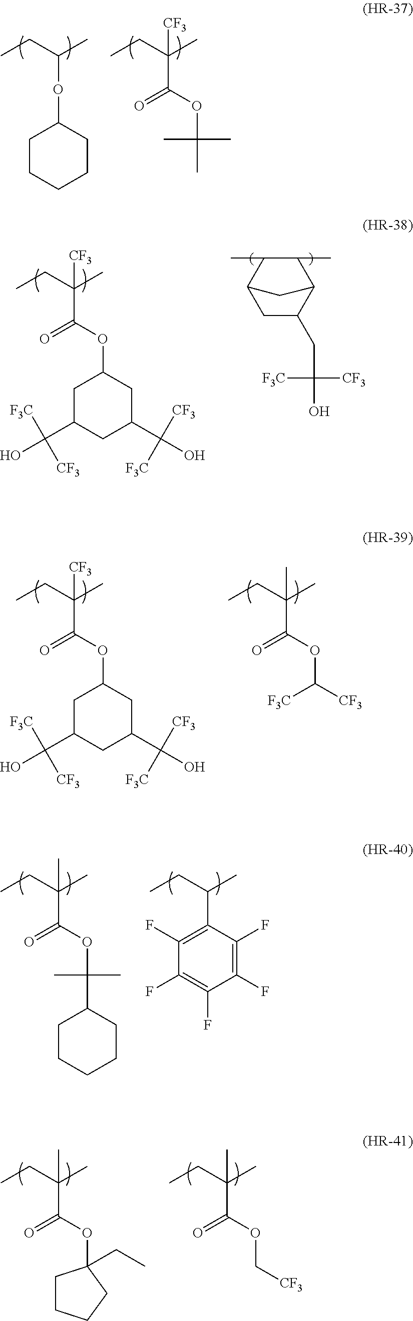

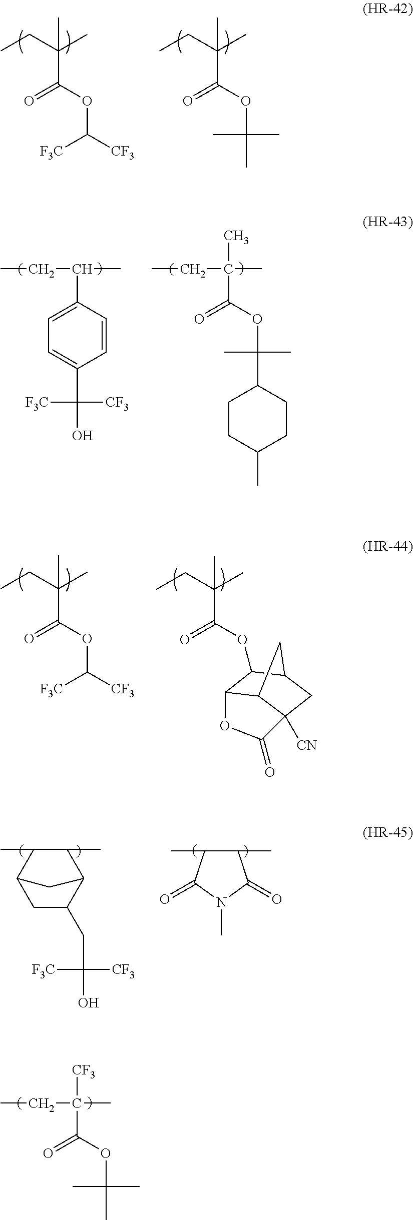

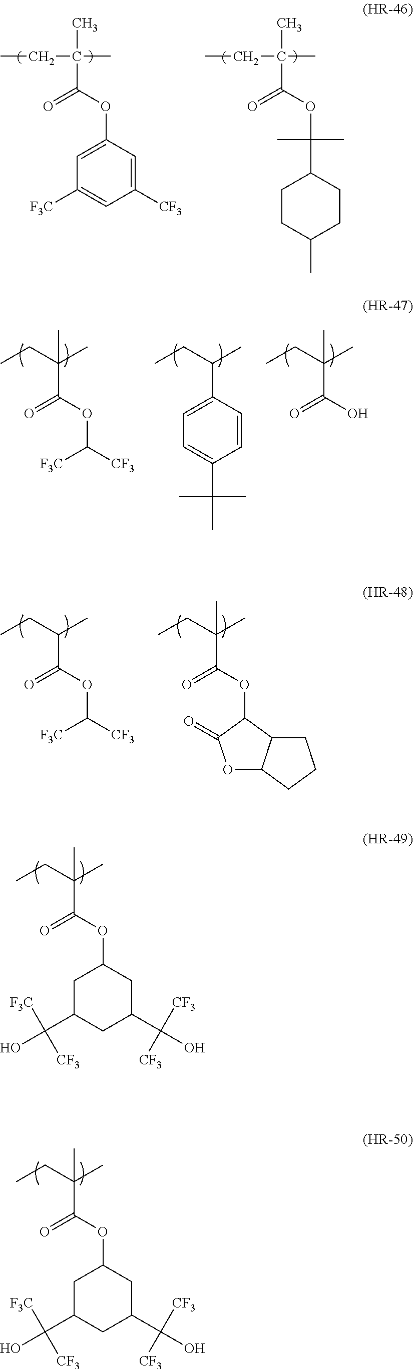

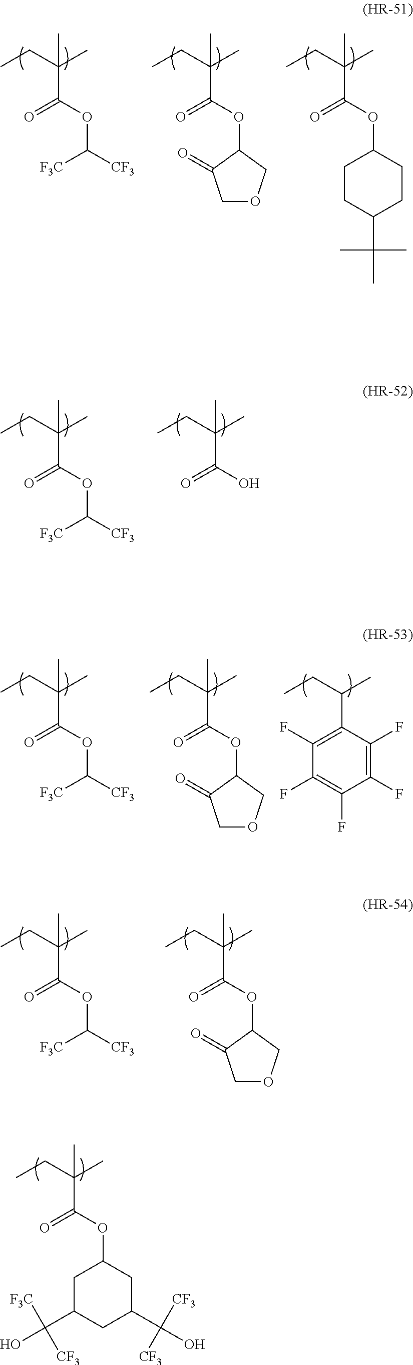

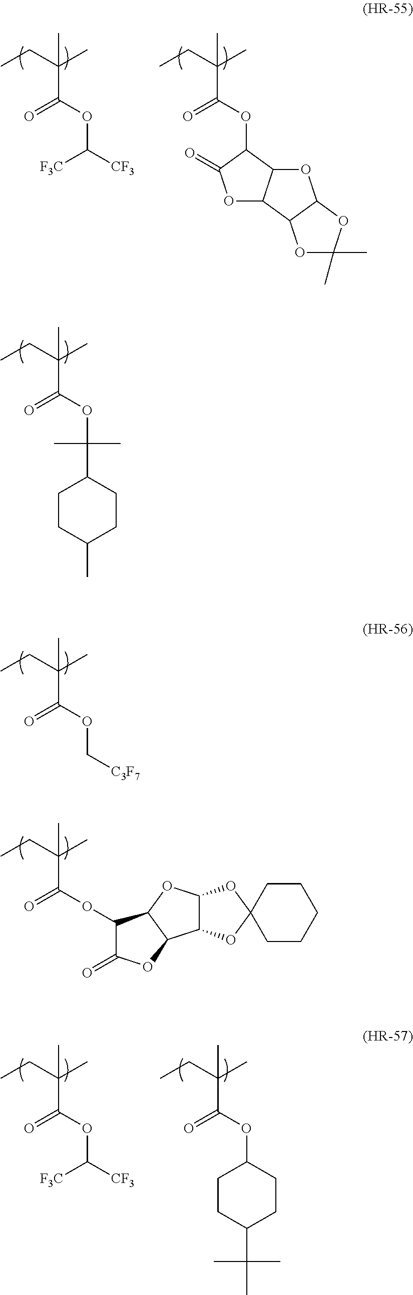

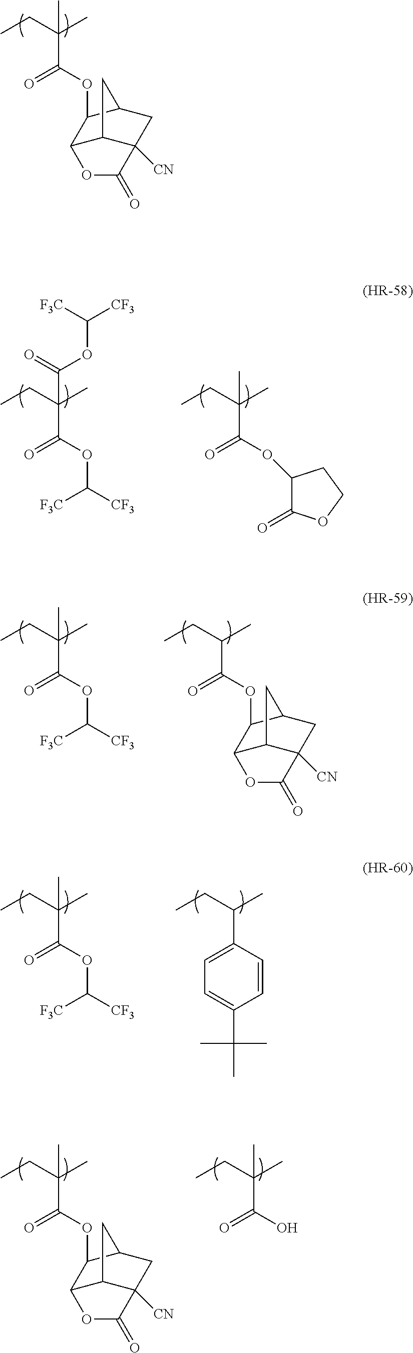

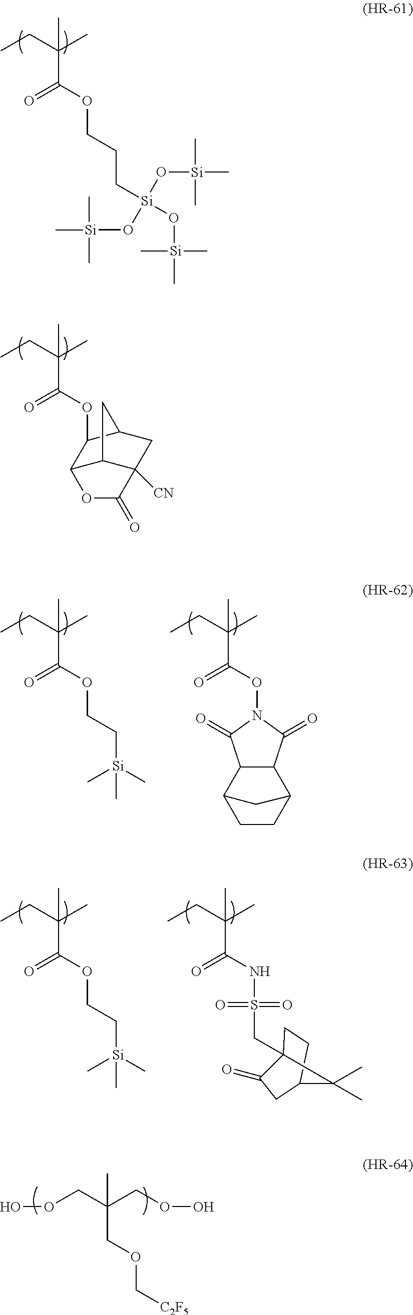

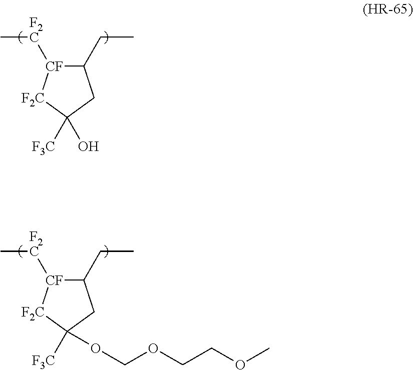

| Resin | Composition | Mw | Mw/Mn |
|---|---|---|---|
| HR-1 | 50/50 | 4900 | 1.4 |
| HR-2 | 50/50 | 5100 | 1.6 |
| HR-3 | 50/50 | 4800 | 1.5 |
| HR-4 | 50/50 | 5300 | 1.6 |
| HR-5 | 50/50 | 4500 | 1.4 |
| HR-6 | 100 | 5500 | 1.6 |
| HR-7 | 50/50 | 5800 | 1.9 |
| HR-8 | 50/50 | 4200 | 1.3 |
| HR-9 | 50/50 | 5500 | 1.8 |
| HR-10 | 40/60 | 7500 | 1.6 |
| HR-11 | 70/30 | 6600 | 1.8 |
| HR-12 | 40/60 | 3900 | 1.3 |
| HR-13 | 50/50 | 9500 | 1.8 |
| HR-14 | 50/50 | 5300 | 1.6 |
| HR-15 | 100 | 6200 | 1.2 |
| HR-16 | 100 | 5600 | 1.6 |
| HR-17 | 100 | 4400 | 1.3 |
| HR-18 | 50/50 | 4300 | 1.3 |
| HR-19 | 50/50 | 6500 | 1.6 |
| HR-20 | 30/70 | 6500 | 1.5 |
| HR-21 | 50/50 | 6000 | 1.6 |
| HR-22 | 50/50 | 3000 | 1.2 |
| HR-23 | 50/50 | 5000 | 1.5 |
| HR-24 | 50/50 | 4500 | 1.4 |
| HR-25 | 30/70 | 5000 | 1.4 |
| HR-26 | 50/50 | 5500 | 1.6 |
| HR-27 | 50/50 | 3500 | 1.3 |
| HR-28 | 50/50 | 6200 | 1.4 |
| HR-29 | 50/50 | 6500 | 1.6 |
| HR-30 | 50/50 | 6500 | 1.6 |
| HR-31 | 50/50 | 4500 | 1.4 |
| HR-32 | 30/70 | 5000 | 1.6 |
| HR-33 | 30/30/40 | 6500 | 1.8 |
| HR-34 | 50/50 | 4000 | 1.3 |
| HR-35 | 50/50 | 6500 | 1.7 |
| HR-36 | 50/50 | 6000 | 1.5 |
| HR-37 | 50/50 | 5000 | 1.6 |
| HR-38 | 50/50 | 4000 | 1.4 |
| HR-39 | 20/80 | 6000 | 1.4 |
| HR-40 | 50/50 | 7000 | 1.4 |
| HR-41 | 50/50 | 6500 | 1.6 |
| HR-42 | 50/50 | 5200 | 1.6 |
| HR-43 | 50/50 | 6000 | 1.4 |
| HR-44 | 70/30 | 5500 | 1.6 |
| HR-45 | 50/20/30 | 4200 | 1.4 |
| HR-46 | 30/70 | 7500 | 1.6 |
| HR-47 | 40/58/2 | 4300 | 1.4 |
| HR-48 | 50/50 | 6800 | 1.6 |
| HR-49 | 100 | 6500 | 1.5 |
| HR-50 | 50/50 | 6600 | 1.6 |
| HR-51 | 30/20/50 | 6800 | 1.7 |
| HR-52 | 95/5 | 5900 | 1.6 |
| HR-53 | 40/30/30 | 4500 | 1.3 |
| HR-54 | 50/30/20 | 6500 | 1.8 |
| HR-55 | 30/40/30 | 7000 | 1.5 |
| HR-56 | 60/40 | 5500 | 1.7 |
| HR-57 | 40/40/20 | 4000 | 1.3 |
| HR-58 | 60/40 | 3800 | 1.4 |
| HR-59 | 80/20 | 7400 | 1.6 |
| HR-60 | 40/40/15/5 | 4800 | 1.5 |
| HR-61 | 60/40 | 5600 | 1.5 |
| HR-62 | 50/50 | 5900 | 2.1 |
| HR-63 | 80/20 | 7000 | 1.7 |
| HR-64 | 100 | 5500 | 1.8 |
| HR-65 | 50/50 | 9500 | 1.9 |

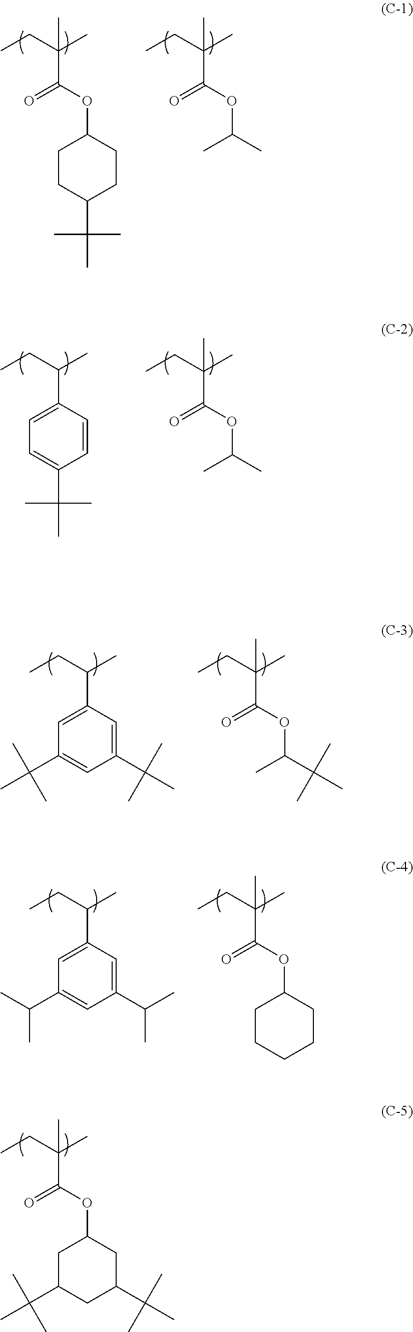

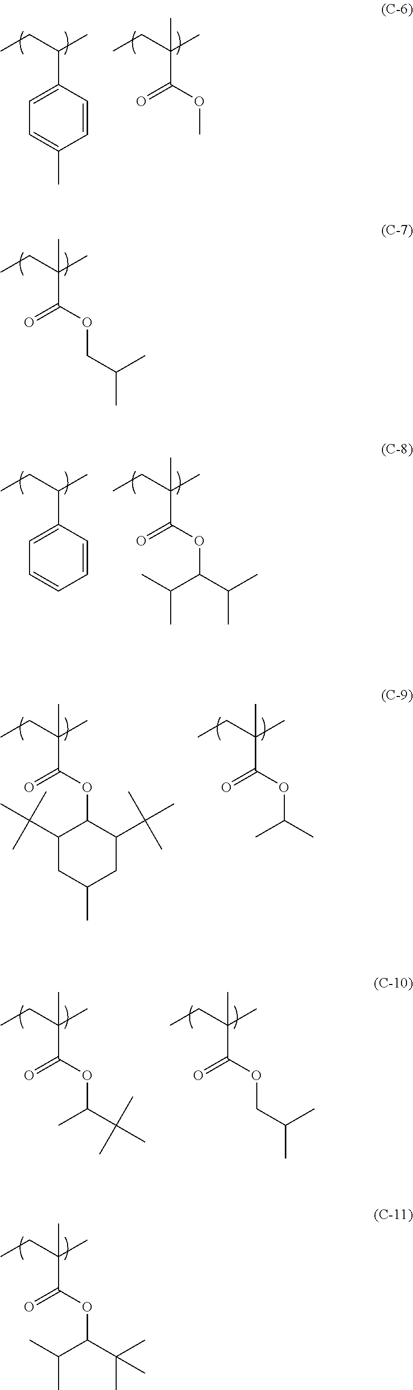

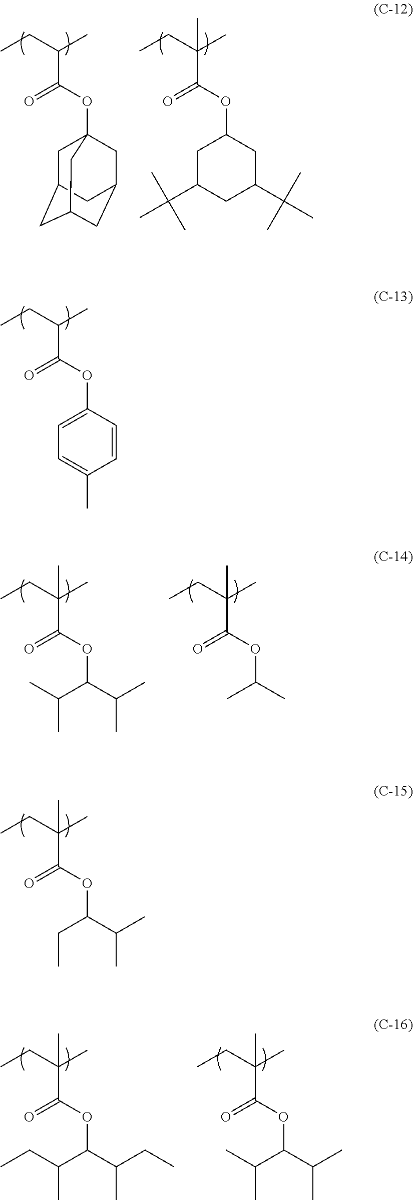

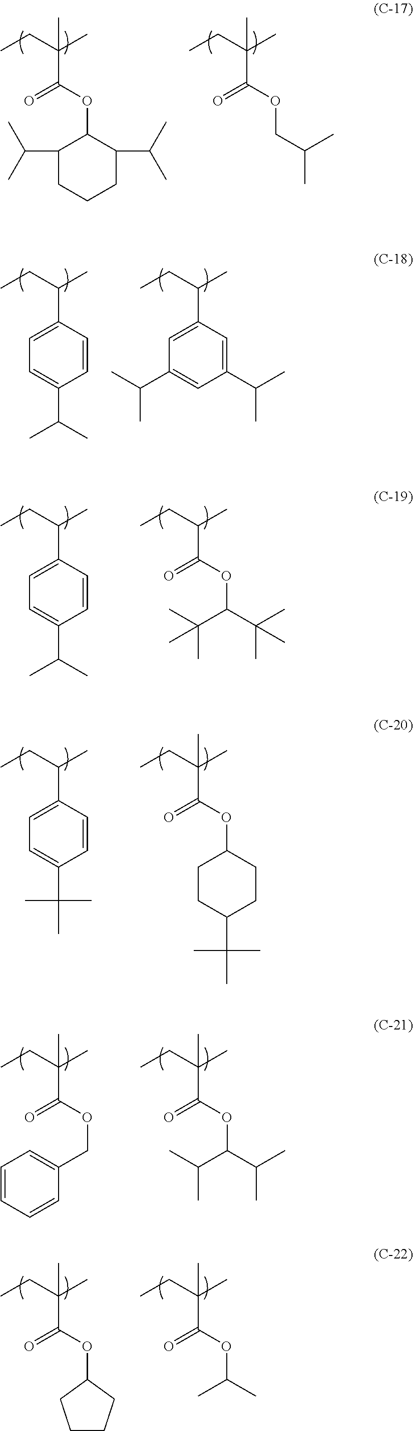

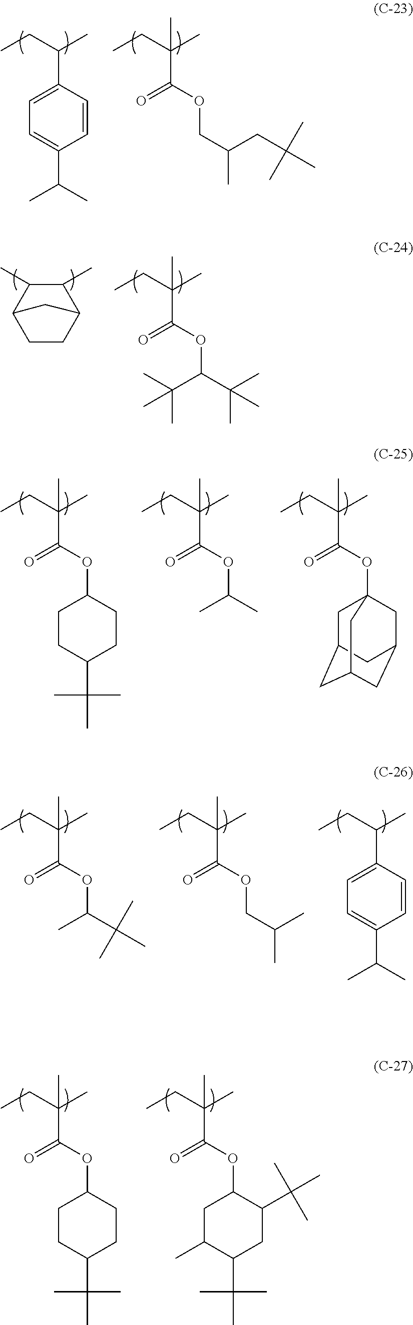

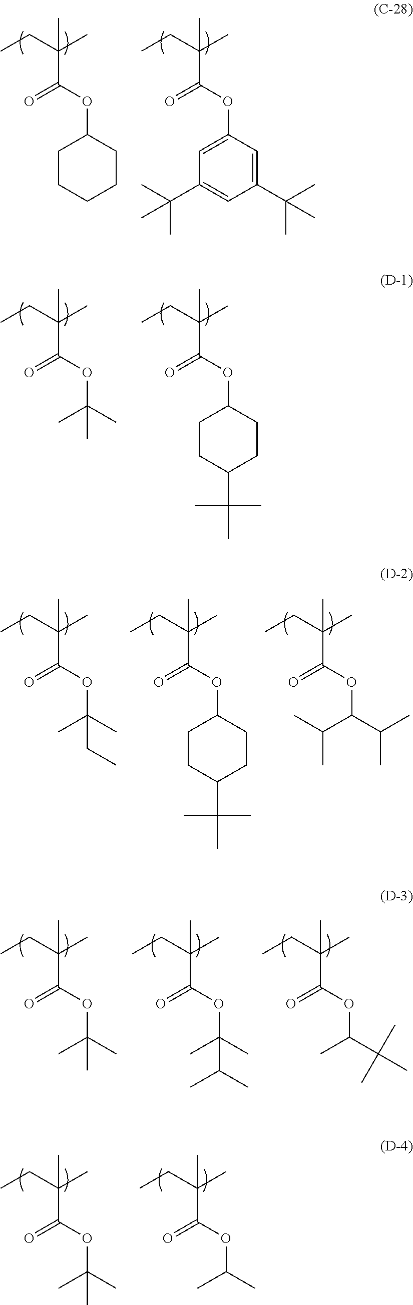

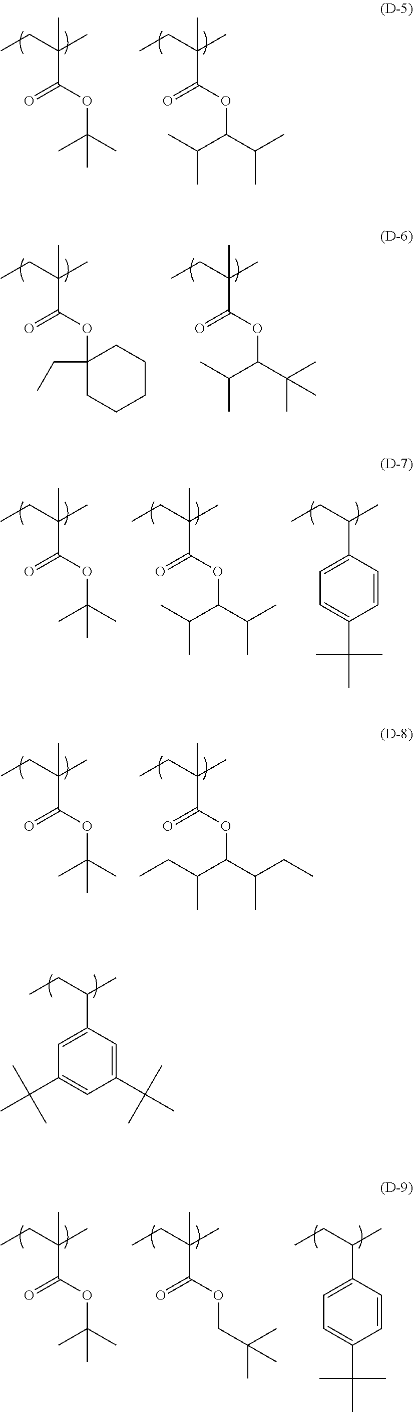

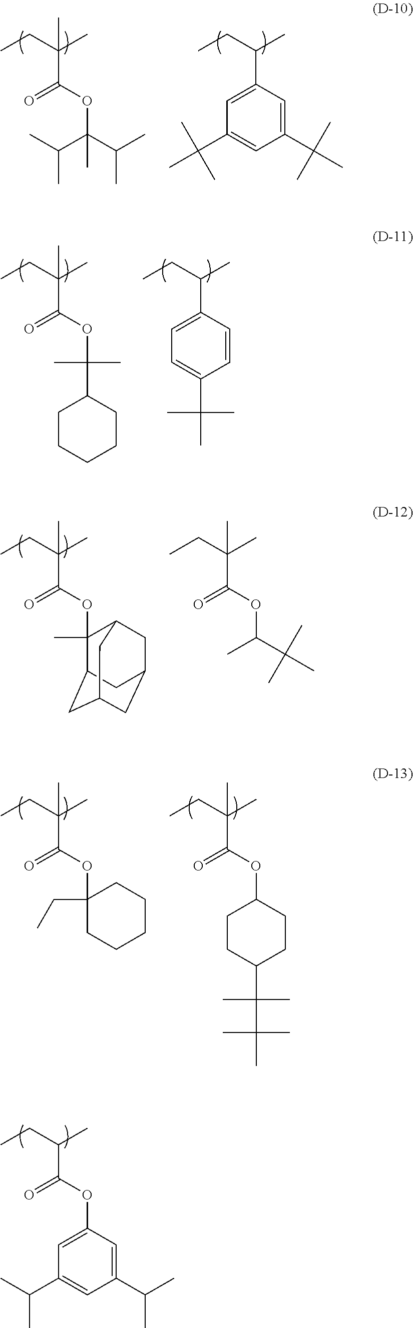

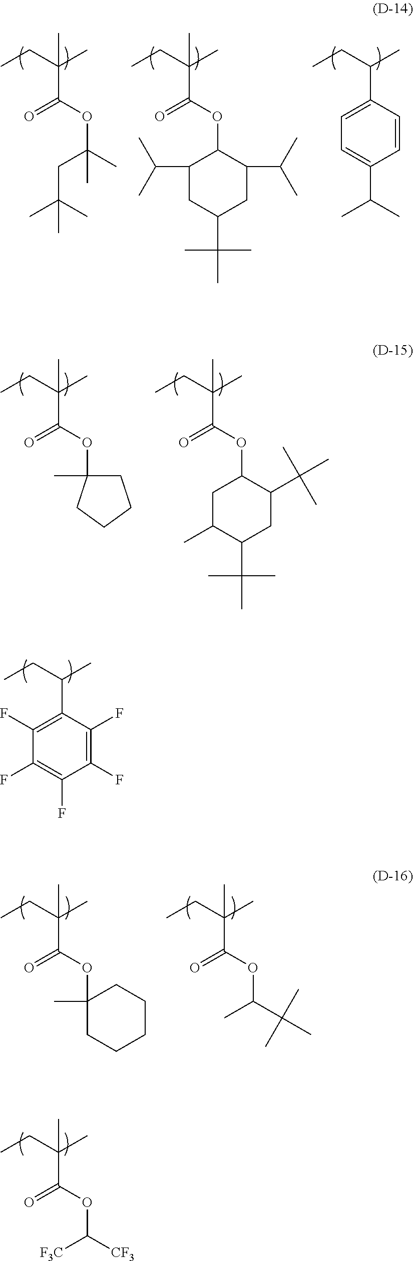

| Resin | Composition | Mw | Mw/Mn |
|---|---|---|---|
| C-1 | 50/50 | 9600 | 1.74 |
| C-2 | 60/40 | 34500 | 1.43 |
| C-3 | 30/70 | 19300 | 1.69 |
| C-4 | 90/10 | 26400 | 1.41 |
| C-5 | 100 | 27600 | 1.87 |
| C-6 | 80/20 | 4400 | 1.96 |
| C-7 | 100 | 16300 | 1.83 |
| C-8 | 5/95 | 24500 | 1.79 |
| C-9 | 20/80 | 15400 | 1.68 |
| C-10 | 50/50 | 23800 | 1.46 |
| C-11 | 100 | 22400 | 1.57 |
| C-12 | 10/90 | 21600 | 1.52 |
| C-13 | 100 | 28400 | 1.58 |
| C-14 | 50/50 | 16700 | 1.82 |
| C-15 | 100 | 23400 | 1.73 |
| C-16 | 60/40 | 18600 | 1.44 |
| C-17 | 80/20 | 12300 | 1.78 |
| C-18 | 40/60 | 18400 | 1.58 |
| C-19 | 70/30 | 12400 | 1.49 |
| C-20 | 50/50 | 23500 | 1.94 |
| C-21 | 10/90 | 7600 | 1.75 |
| C-22 | 5/95 | 14100 | 1.39 |
| C-23 | 50/50 | 17900 | 1.61 |
| C-24 | 10/90 | 24600 | 1.72 |
| C-25 | 50/40/10 | 23500 | 1.65 |
| C-26 | 60/30/10 | 13100 | 1.51 |
| C-27 | 50/50 | 21200 | 1.84 |
| C-28 | 10/90 | 19500 | 1.66 |
| D-1 | 50/50 | 16500 | 1.72 |
| D-2 | 10/50/40 | 18000 | 1.77 |
| D-3 | 5/50/45 | 27100 | 1.69 |
| D-4 | 20/80 | 26500 | 1.79 |
| D-5 | 10/90 | 24700 | 1.83 |
| D-6 | 10/90 | 15700 | 1.99 |
| D-7 | 5/90/5 | 21500 | 1.92 |
| D-8 | 5/60/35 | 17700 | 2.10 |
| D-9 | 35/35/30 | 25100 | 2.02 |
| D-10 | 70/30 | 19700 | 1.85 |
| D-11 | 75/25 | 23700 | 1.80 |
| D-12 | 10/90 | 20100 | 2.02 |
| D-13 | 5/35/60 | 30100 | 2.17 |
| D-14 | 5/45/50 | 22900 | 2.02 |
| D-15 | 15/75/10 | 28600 | 1.81 |
| D-16 | 25/55/20 | 27400 | 1.87 |

[5] Basic Compound

It is preferable that the radiation-sensitive resin composition used in the present invention contains a basic compound in order to reduce the change in performance with aging from exposure to heating. The basic compound that can be used is not particularly limited, and for example, compounds classified into (1) to (5) below can be used.

(1) Basic Compound (N)

Preferred examples of the basic compound include compounds (N) having structures represented by the following Formulae (A) to (E).

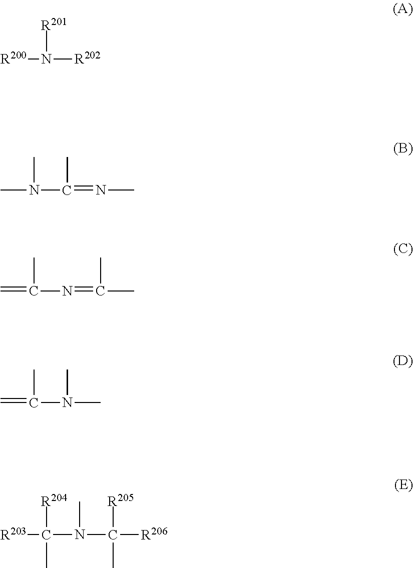

In General Formulae (A) and (E),
R²⁰⁰, R²⁰¹, and R²⁰², which may be the same as or different from each other, and each represent a hydrogen atom, an alkyl group (preferably having 1 to 20 carbon atoms), a cycloalkyl group (preferably having 3 to 20 carbon atoms), or an aryl group (having 6 to 20 carbon atoms), and R²⁰¹ and R²⁰² may be bonded to each other to form a ring; and
R²⁰³, R²⁰⁴, R²⁰⁵, and R²⁰⁶, which may be the same as or different from each other, each represent an alkyl group having 1 to 20 carbon atoms.

With regard to the alkyl group, the alkyl group having a substituent is preferably an aminoalkyl group having 1 to 20 carbon atoms, a hydroxyalkyl group having 1 to 20 carbon atoms, or a cyanoalkyl group having 1 to 20 carbon atoms.

It is more preferable for the alkyl groups in General Formulae (A) and (E) to be unsubstituted.

Preferred examples of the compound (N) include guanidine, aminopyrrolidine, pyrazole, pyrazoline, piperazine, aminomorpholine, aminoalkylmorpholine, and piperidine. More preferred examples of the compound (N) include compounds (N) having an imidazole structure, a diazabicyclo structure, an onium hydroxide structure, an onium carboxylate structure, a trialkylamine structure, an aniline structure, or a pyridine structure; alkylamine derivatives having a hydroxyl group and/or an ether bond; and aniline derivatives having a hydroxyl group and/or an ether bond.

Examples of the compound (N) having an imidazole structure include imidazole, 2,4,5-triphenylimidazole, benzimidazole, and 2-phenylbenzimidazole. Examples of the compound (N) having a diazabicyclo structure include 1,4-diazabicyclo[2,2,2]octane, 1,5-diazabicyclo[4,3,0]nona-5-ene, and 1,8-diazabicyclo[5,4,0]undeca-7-ene. Examples of the compound (N) having an onium hydroxide structure include tetrabutyl ammonium hydroxide, triarylsulfonium hydroxide, phenacylsulfonium hydroxide, sulfonium hydroxide having 2-oxoalkyl group, specifically triphenylsulfonium hydroxide, tris(t-butyl phenyl)sulfonium hydroxide, bis(t-butyl phenyl)iodonium hydroxide, phenacylthiophenium hydroxide, and 2-oxopropylthiophenium hydroxide. The compound (N) having an onium carboxylate structure is a compound in which the anion moiety of the compound (N) having an onium hydroxide structure becomes a carboxylate, and examples thereof include acetate, adamantane-1-carboxylate, and perfluoroalkyl carboxylate. Examples of the compound (N) having a trialkylamine structure include tri(n-butyl)amine and tri(n-octyl)amine. Examples of the compound (N) having an aniline structure include 2,6-diisopropylaniline, N,N-dimethylaniline, N,N-dibutylaniline, and N,N-dihexylaniline. Examples of the alkylamine derivative having a hydroxyl group and/or an ether bond include ethanolamine, diethanolamine, triethanolamine, N-phenyldiethanolamine, and tris(methoxyethoxyethyl)amine. Examples of the aniline derivative having a hydroxyl group and/or an ether bond include N,N-bis(hydroxyethyl)aniline.

Preferred examples of the basic compound (N) include an amine compound having a phenoxy group, an ammonium salt compound having a phenoxy group, an amine compound containing a sulfonic ester group, and an ammonium salt compound having a sulfonic ester group. Examples of these compounds include the compounds (C1-1) to (C3-3) exemplified in paragraph [0066] of US2007/0224539A.

Furthermore, the following compounds are also preferred as the basic compounds (N).

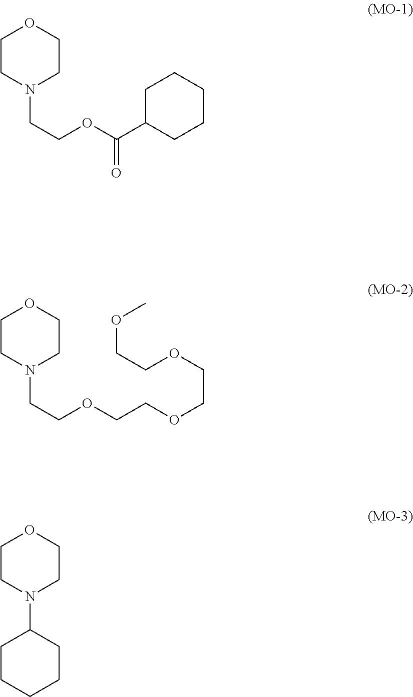 [SMILES: O=C(OCCN1CCOCC1)C1CCCCC1 ; COCCOCCOCCOCCN1CCOCC1 ; C1CCC(N2CCOCC2)CC1]

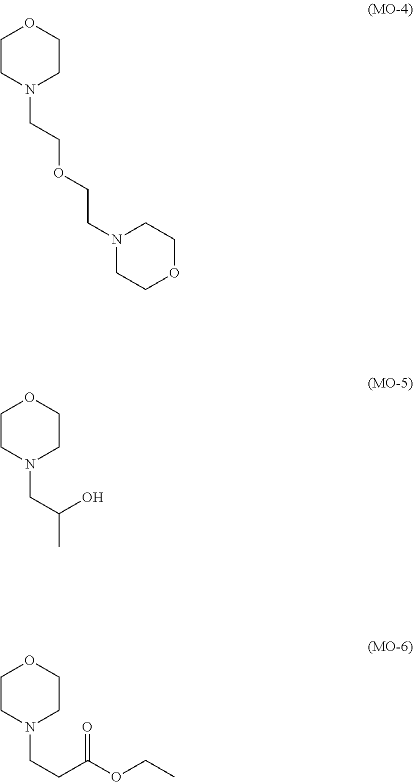

In addition to the compounds as described above, as the basic compound (N), the compounds described in [0180] to [0225] of JP2011-22560A, [0218] to [0219] of JP2012-137735A, and [0416] to [0438] of WO2011/158687A, and the like can also be used. The basic compound (N) may be a basic compound or an ammonium salt compound, whose basicity is decreased by irradiation with actinic rays or radiation. The basic compounds (N) may be used alone or in combination of two or more kinds thereof.

The radiation-sensitive resin composition may or may not contain the basic compound (N), but in the case where the basic compound (N) is contained, the content of the basic compound (N) is usually from 0.001% by mass to 10% by mass, and preferably from 0.01% by mass to 5% by mass, with respect to the solid content of the radiation-sensitive resin composition.

The ratio between the acid generator and the basic compound (N) used in the composition is preferably acid generator/basic compound (molar ratio)=2.5 to 300. That is, the molar ratio is preferably 2.5 or more in view of sensitivity and resolution, and is preferably 300 or less in view of suppressing the reduction in resolution due to thickening of the resist pattern with aging after exposure until the heat treatment. The acid generator/basic compound (N) (molar ratio) is more preferably from 5.0 to 200, and still more preferably from 7.0 to 150.

(2) Basic Compound or Ammonium Salt Compound (E), Whose Basicity is Decreased by Irradiation with Actinic Rays or Radiation

The radiation-sensitive resin composition preferably contains a basic compound or an ammonium salt compound (hereinafter, also referred to as a “compound (E)”), whose basicity is decreased by irradiation with actinic rays or radiation.

The compound (E) is preferably a compound (E-1) having a basic functional group or an ammonium group, and a group capable of generating an acidic functional group by irradiation with actinic rays or radiation. That is, the compound (E) is preferably a basic compound having a basic functional group and a group capable of generating an acidic functional group by irradiation with actinic rays or radiation, or an ammonium salt compound having an ammonium group and a group capable of generating an acidic functional group by irradiation with actinic rays or radiation.

Examples of the compounds whose basicity is decreased, and generated by the decomposition of the compound (E) or (E-1) by irradiation with actinic rays or radiation, include compounds represented by the following General Formulae (PA-I), (PA-II), and (PA-III). The compounds of General Formulae (PA-II) and (PA-III) are particularly preferred from the viewpoints of the higher-order simultaneous attainment of excellent effects with respect to LWR, uniformity in local pattern dimensions, and DOF.

First, the compound represented by General Formula (PA-I) will be described.

Q-A₁-(X)ₙ—B—R (PA-I)

In General Formula (PA-I),
A₁ represents a single bond or a bivalent linking group;
Q represents —SO₃H, or —CO₂H, and corresponds to the acidic functional group generated by irradiation with actinic rays or radiation;
X represents —SO₂— or —CO—;
n represents 0 or 1;
B represents a single bond, an oxygen atom, or —N(Rx)—;
Rx represents a hydrogen atom or a monovalent organic group; and
R represents a monovalent organic group containing a basic functional group, or a monovalent organic group containing an ammonium group.

Next, the compound represented by General Formula (PA-II) will be described.

Q₁-X₁—NH—X₂-Q₂ (PA-II)

In General Formula (PA-II),
Q₁ and Q₂ each independently represent a monovalent organic group, provided that any one of Q₁ and Q₂ has a basic functional group, and Q₁ and Q₂ may be bonded to each other to form a ring and the ring formed may have a basic functional group; and
X₁ and X₂ each independently represent —CO— or —SO₂—.

Incidentally, —NH— corresponds to an acidic functional group which is generated by irradiation with actinic rays or radiation.

Next, the compound represented by formula (PA-III) will be described.

Q₁-X₁—NH—X₂-A₂-(X₃)ₘ—B-Q₃ (PA-III)

In General Formula (PA-III),
Q₁ and Q₃ each independently represent a monovalent organic group, provided that either one of Q₁ and Q₃ has a basic functional group, or Q₁ and Q₃ may be bonded to each other to form a ring, and the ring formed may have a basic functional group;
X₁, X₂ and X₃ each independently represent —CO— or —SO₂—;
A₂ represents a divalent linking group;
B represents a single bond, an oxygen atom, or —N(Qₓ)-;
Qₓ represents a hydrogen atom or a monovalent organic group;
when B is —N(Qₓ)-, Q₃ and Qₓ may be bonded to each other to form a ring; and m represents 0 or 1.

Incidentally, —NH— corresponds to an acidic functional group that is generated by irradiation with actinic rays or radiation.

Specific examples of the compound (E) include, but are not limited to, the following compounds. Further, in addition to the exemplified compounds, specific preferred examples of the compound (E) include the compounds (A-1) to (A-44) of US2010/0233629A and the compounds (A-1) to (A-23) of US2012/0156617A.

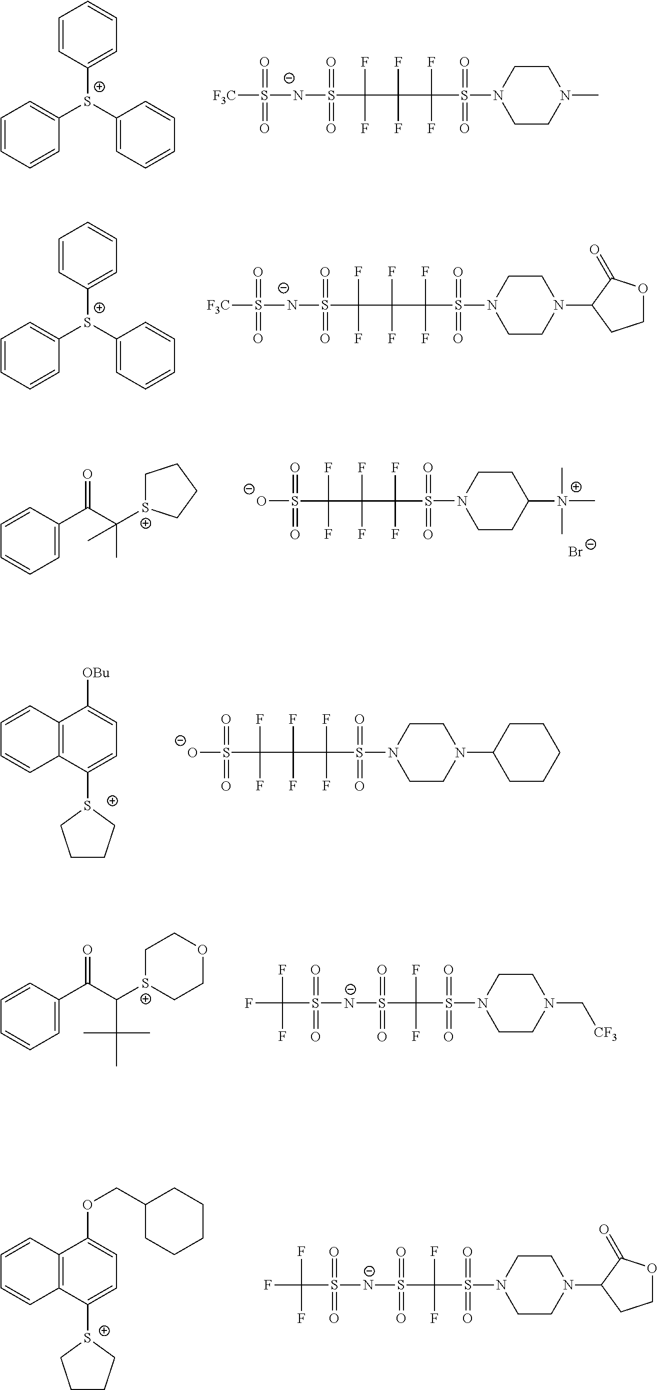

The molecular weight of the compound (E) is preferably from 500 to 1000.

The radiation-sensitive resin composition may or may not contain the compound (E), but in the case where the compound (E) is contained, the content of the compound (E) is preferably from 0.1% by mass to 20% by mass, and more preferably from 0.1% by mass to 10% by mass, with respect to the solid content of the radiation-sensitive resin composition.

Furthermore, in one embodiment of the compound (E), the compound (E) also includes a compound (E-2) that is decomposed by irradiation with actinic rays or radiation to generate an acid (weak acid) with a strength of a degree at which the acid-decomposition of the acid-decomposable group of the resin (A) is not realized.

Examples of this compound include an onium salt (preferably a sulfonium salt) of a carboxylic acid containing no fluorine atom, and an onium salt (preferably a sulfonium salt) of a sulfonic acid containing no fluorine atom. More specific examples thereof include onium salts represented by General Formula (6A) as described later, in which a carboxylic acid anion has no fluorine atom, and onium salts represented by General Formula (6B) as described later, in which a sulfonic acid anion has no fluorine atom. Preferred examples of the cation structure of the sulfonium salt include sulfonium cation structures mentioned for the acid generator (B).

More specific examples of the compound (E-2) include the compounds mentioned in

of WO2012/053527A, and compounds of [0268] to [0269] of JP2012-173419A.

(3) Low Molecular Compound (F) Having Nitrogen Atom and Group Capable of Leaving by Action of Acid

The radiation-sensitive resin composition may contain a compound having a nitrogen atom and a group capable of leaving by the action of an acid (hereinafter also referred to as a “compound (F)”).

The group capable of leaving by the action of an acid is not particularly limited, but is preferably an acetal group, a carbonate group, a carbamate group, a tertiary ester group, a tertiary hydroxyl group, and a hemiaminal ether group, and particularly preferably a carbamate group and a hemiaminal ether group.

The molecular weight of the compound (N″) having a group capable of leaving by the action of an acid is preferably from 100 to 1000, more preferably from 100 to 700, and particularly preferably from 100 to 500.

The compound (F) is preferably an amine derivative having a group capable of leaving by the action of an acid on a nitrogen atom.

The compound (F) may contain a carbamate group having a protecting group on a nitrogen atom. The protecting group constituting the carbamate group can be represented by the following General Formula (d-1).

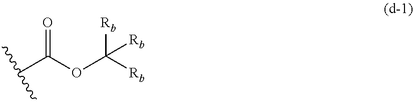

In General Formula (d-1),
R_{b}'s each independently represent a hydrogen atom, an alkyl group (preferably having 1 to 10 carbon atoms), a cycloalkyl group (preferably having 3 to 30 carbon atoms), an aryl group (preferably having 3 to 30 carbon atoms), an aralkyl group (preferably having 1 to 10 carbon atoms), or an alkoxyalkyl group (preferably having 1 to 10 carbon atoms). R_{b}'s may be bonded to each other to form a ring.

The alkyl group, the cycloalkyl group, the aryl group, or the aralkyl group represented by Rₐ may be substituted with a functional group such as a hydroxyl group, a cyano group, an amino group, a pyrrolidino group, a piperidino group, a morpholino group, and an oxo group, an alkoxy group, or a halogen atom. This applies to the alkoxyalkyl group represented by R_{b}.

R_{b} is preferably a linear or branched alkyl group, a cycloalkyl group, or an aryl group, and more preferably a linear or branched alkyl group, or a cycloalkyl group.

Examples of the ring formed by the mutual linking of two R_{b}'s include an alicyclic hydrocarbon group, an aromatic hydrocarbon group, a heterocyclic hydrocarbon group, and derivatives thereof.

Examples of the specific structure of the group represented by General Formula (d-1) include, but are not limited to, structures disclosed in paragraph [0466] of US2012/0135348A.

It is particularly preferable that the compound (F) has a structure of the following General Formula (6).

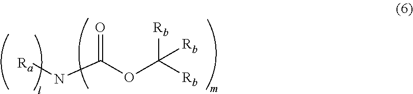

In General Formula (6),
Rₐ represents a hydrogen atom, an alkyl group, a cycloalkyl group, an aryl group, or an aralkyl group. When 1 is 2, two Rₐ's may be the same as or different from each other. Two Rₐ's may be linked to each other to form a heterocycle together with the nitrogen atom in the formula. The heterocycle may contain a heteroatom other than the nitrogen atom in the formula.

R_{b} has the same meaning as R_{b} in General Formula (d-1), and preferred examples are also the same.

1 represents an integer of 0 to 2, and m represents an integer of 1 to 3, satisfying 1+m=3.

In General Formula (6), the alkyl group, the cycloalkyl group, the aryl group, and the aralkyl group as Rₐ may be substituted with the same groups as the group mentioned above as a group which may be substituted in the alkyl group, the cycloalkyl group, the aryl group, and the aralkyl group as R_{b}.

Preferred examples of the alkyl group, the cycloalkyl group, the aryl group, and the aralkyl group as Rₐ (the alkyl group, cycloalkyl group, aryl group, and aralkyl group may be substituted with the group as mentioned above) include the same groups as the preferred examples mentioned above with respect to R_{b}.

In addition, the heterocycle formed by the mutual linking of Rₐ's is preferably, for example, a group preferably having 1 to 20 carbon atoms, which is derived from a heterocyclic compound such as pyrrolidine, piperidine, morpholine, 1,4,5,6-tetrahydropyrimidine, 1,2,3,4-tetrahydroquinoline, 1,2,3,6-tetrahydropyridine, homopiperazine, 4-azabenzimidazole, benzotriazole, 5-azabenzotriazole, 1H-1,2,3-triazole, 1,4,7-triazacyclononane, tetrazole, 7-azaindole, indazole, benzimidazole, imidazo[1,2-a]pyridine, (1S,4S)-(+)-2,5-diazabicyclo[2.2.1]heptane, 1,5,7-triazabicyclo[4.4.0]dec-5-ene, indole, indoline, 1,2,3,4-tetrahydroquinoxaline, perhydroquinoline, and 1,5,9-triazacyclododecane, or a group in which the group derived from a heterocyclic compound is substituted with one or more kinds, or one or more groups such as a group derived from a linear or branched alkane, a group derived from a cycloalkane, a group derived from an aromatic compound, a group derived from a heterocyclic compound, and a functional group such as a hydroxyl group, a cyano group, an amino group, a pyrrolidino group, a piperidino group, a morpholino group, and an oxo group.

Specific preferred examples of, the compounds (F) include, but are not limited to, the compounds disclosed in paragraph [0475] of US2012/0135348A.

The compounds represented by General Formula (6) can be synthesized in accordance with JP2007-298569A, JP2009-199021A, and the like.

In the present invention, the low molecular compounds (F) may be used alone or in combination of two or more kinds thereof.

The content of the compound (F) in the radiation-sensitive resin composition is preferably from 0.001% by mass to 20% by mass, more preferably from 0.001% by mass to 10% by mass, and still more preferably from 0.01% by mass to 5% by mass, with respect to the total solid content of the composition.

(4) Onium Salt

Furthermore, the composition may include an onium salt represented by the following General Formula (6A) or (6B) as the basic compound. It is expected that this onium salt regulates the diffusion of generated acids in a resist system in relation to the acid strength of photoacid generators usually used in resist compositions.

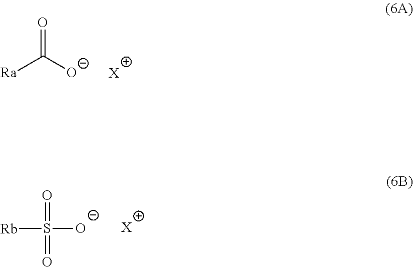

In General Formula (6A), Ra represents an organic group, provided that any one in which the carbon atom directly bonded to the carboxyl group in the formula is substituted with a fluorine atom is excluded, and X⁺ represents an onium cation.

In General Formula (6B), Rb represents an organic group, provided that any one in which the carbon atom directly bonded to the sulfonic acid group in the formula is substituted with a fluorine atom is excluded, and X⁺ represents an onium cation.

For organic groups represented by Ra and Rb, the atom directly bonded to the carboxylic acid group, or sulfonic acid group in the formula is preferably a carbon atom. However, in this case, for the realization of a relatively weak acid as compared to the acids generated from the above photoacid generators, the carbon atom directly bonded to the sulfonic acid group or carboxylic acid group is not substituted with a fluorine atom in any case.

Examples of the organic groups represented by Ra and Rb include an alkyl group having 1 to 20 carbon atoms, a cycloalkyl group having 3 to 20 carbon atoms, an aryl group having 6 to 30 carbon atoms, an aralkyl group having 7 to 30 carbon atoms, and a heterocyclic group having 3 to 30 carbon atoms. In these groups, the hydrogen atoms may be partially or entirely replaced.

Examples of the substituents which the alkyl group, the cycloalkyl group, the aryl group, the aralkyl group, and the heterocyclic group can have include a hydroxyl group, a halogen atom, an alkoxy group, a lactone group, and an alkylcarbonyl group.

Examples of the onium cations represented by X⁺ in General Formulae (6A) and (6B) include a sulfonium cation, an ammonium cation, an iodonium cation, a phosphonium cation, and a diazonium cation, among which the sulfonium cation is more preferred.

As the sulfonium cation, for example, an arylsulfonium cation containing at least one aryl group is preferred, and a triarylsulfonium cation is more preferred. The aryl group may have a substituent, and as the aryl group, a phenyl group is preferred.

Preferred examples of the sulfonium cations and iodonium cations include the sulfonium cation structures in General Formula (ZI) and the iodonium structures in General Formula (ZII) with respect to the compound (B) as mentioned above.

Specific structures of the onium salt represented by General Formula (6A) or (6B) are shown below.

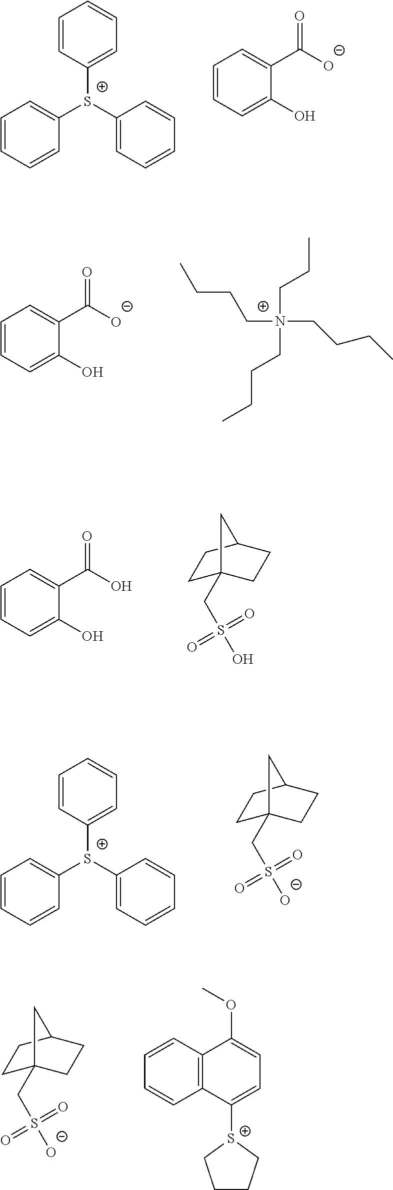

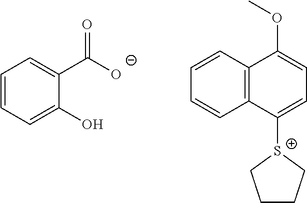

(5) Betaine Compound

Furthermore, for the composition, a compound (hereinafter also referred to as a “betaine compound”) containing both an onium salt structure and an acid anion structure in one molecule, such as a compound represented by Formula (I) in JP2012-189977A, a compound represented by Formula (I) in JP2013-6827A, a compound represented by Formula (I) in JP2013-8020A, and a compound represented by Formula (I) in JP2012-252124A can also be preferably used. Examples of the onium salt structure include sulfonium, iodonium, and ammonium structures, among which the sulfonium or iodonium salt structure is preferred. Further, the acid anion structure is preferably a sulfonic acid anion or a carboxylic acid anion. Examples of these compounds include the following examples.

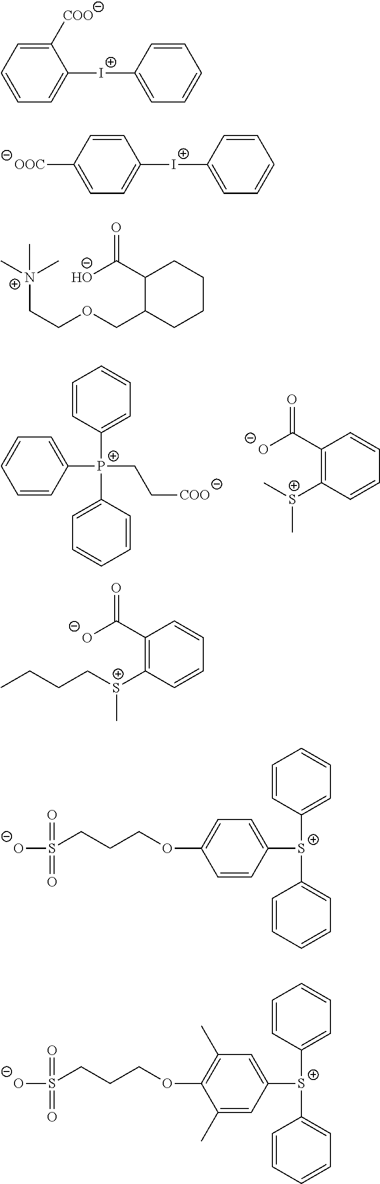

[6] Surfactant (F)

The radiation-sensitive resin composition may or may not further contain a surfactant, but in the case where a surfactant is contained, it is preferable to contain any one of fluorine- and/or silicon-based surfactants (a fluorine-based surfactant, a silicon-based surfactant, and a surfactant having both a fluorine atom and a silicon atom), or two or more kinds thereof.

By incorporating the surfactant into the radiation-sensitive resin composition, it becomes possible to provide a resist pattern which is improved in adhesion and decreased in development defects with good sensitivity and resolution when an exposure light source of 250 nm or less, and particularly 220 nm or less, is used.

Examples of the fluorine- and/or silicon-based surfactants include the surfactants described in [0276] of US2008/0248425A, and examples thereof include EFtop EF301 and EF303 (manufactured by Shin-Akita Kasei K.K.); Florad FC430, 431, and 4430 (manufactured by Sumitomo 3M Inc.); Megaface F171, F173, F176, F189, F113, F110, F177, F120, and R08 (manufactured by DIC Corp.); Surflon S-382, SC101, 102, 103, 104, 105, and 106, and KH-20 (manufactured by Asahi Glass Co., Ltd.); Troysol S-366 (manufactured by Troy Chemical Corp.); GF-300 and GF-150 (manufactured by Toagosei Chemical Industry Co., Ltd.); Surflon S-393 (manufactured by Seimi Chemical Co., Ltd.); EFtop EF121, EF122A, EF122B, RF122C, EF125M, EF135M, EF351, EF352, EF801, EF802, and EF601 (manufactured by JEMCO Inc.); PF636, PF656, PF6320, and PF6520 (manufactured by OMNOVA); and FTX-204G, 208G, 218G, 230G, 204D, 208D, 212D, 218D, and 222D (manufactured by NEOS Co., Ltd.). In addition, Polysiloxane Polymer KP-341 (manufactured by Shin-Etsu Chemical Co., Ltd.) can also be used as the silicon-based surfactant.

In addition to those known surfactants as described above, a surfactant using a polymer having a fluoro-aliphatic group derived from a fluoro-aliphatic compound which is produced by a telomerization method (also referred to as a telomer method) or an oligomerization method (also referred to as an oligomer method), can be used. The fluoro-aliphatic compound can be synthesized in accordance with the method described in JP2002-90991A.

Examples of the surfactant corresponding to the above include Megaface F178, F-470, F-473, F-475, F-476, and F-472 (manufactured by DIC Corp.); a copolymer of an acrylate (or methacrylate) having a C₆F₁₃ group with a (poly(oxyalkylene)) acrylate (or methacrylate); and a copolymer of an acrylate (or methacrylate) having a C₃F₇ group with a (poly(oxyethylene)) acrylate (or methacrylate) and a (poly(oxypropylene)) acrylate (or methacrylate).

In addition, in the present invention, a surfactant other than the fluorine- and/or silicon-based surfactants described in [0280] of US2008/0248425A can also be used.

These surfactants may be used alone or in combination of some kinds thereof.

In the case where the radiation-sensitive resin composition contains the surfactant, the amount of the surfactant used is preferably from 0.0001% by mass to 2% by mass, and more preferably from 0.0005% by mass to 1% by mass, with respect to the total amount (excluding the solvent) of the radiation-sensitive resin composition.

On the other hand, by setting the amount of the surfactant added to 10 ppm or less with respect to the total amount (excluding the solvent) of the radiation-sensitive resin composition, the hydrophobic resin is more unevenly distributed to the surface, so that the resist film surface can be made more hydrophobic, which can enhance the water tracking properties during the liquid immersion exposure.

[7] Other Additives (G)

The radiation-sensitive resin composition can contain, for example, an acid-increasing agent, a dye, a plasticizer, a photosensitizer, a light absorber, an alkali-soluble resin, a dissolution inhibitor, and a compound for accelerating dissolution in a developing liquid (for example, a phenol compound having a molecular weight of 1000 or less, and a carboxyl group-containing alicyclic or aliphatic compound).

The phenol compound having a molecular weight of 1000 or less can be easily synthesized by a person skilled in the art by referring to the method described, for example, in JP1992-122938A (JP-H04-122938A), JP1990-28531A (JP-H02-28531A), U.S. Pat. No. 4,916,210A, EP219294A, and the like.

Specific examples of the carboxyl group-containing alicyclic or aliphatic compound include, but are not limited to, a carboxylic acid derivative having a steroid structure, such as cholic acid, deoxycholic acid and lithocholic acid, an adamantanecarboxylic acid derivative, an adamantanedicarboxylic acid, a cyclohexanecarboxylic acid, and a cyclohexanedicarboxylic acid.

From the viewpoint of enhancing the resolving power, the radiation-sensitive resin composition is preferably used in a film thickness of 30 nm to 250 nm, and more preferably from 30 nm to 200 nm. Such a film thickness can be achieved by setting the solid content concentration in the composition to an appropriate range, thereby imparting an appropriate viscosity and enhancing the applicability and the film-forming properties.

The solid content concentration of the radiation-sensitive resin composition is usually from 1.0% by mass to 10% by mass, preferably from 2.0% by mass to 5.7% by mass, and more preferably from 2.0% by mass to 5.3% by mass. By setting the solid content concentration to the range above, the resist solution can be uniformly coated on a substrate and furthermore, a resist pattern improved in the line width roughness can be formed. The reason therefor is not clearly known, but it is considered that by virtue of setting the solid content concentration to be 10% by mass or less, and preferably 5.7% by mass or less, the materials, particularly the photoacid generator, in the resist solution can be prevented from aggregation, and as a result, a uniform resist film can be formed.

The solid content concentration is a weight percentage of the weight of resist components excluding the solvent, with respect to the total weight of the radiation-sensitive resin composition.

The radiation-sensitive resin composition is prepared by dissolving the components above in a predetermined organic solvent, and preferably in the mixed solvent.

Here, a step of reducing metal impurities in the composition to a ppb level by means of an ion exchange membrane, a step of filtering impurities such as various particles by means of an appropriate filter, a step of deaeration, and the like may be carried out at the time of preparation. The particulars of these steps are described in JP2012-88574A, JP2010-189563A, JP2001-12529A, JP2001-350266A, JP2002-99076A, JP1993-307263A (JP-H05-307263A), JP2010-164980A, WO2006/121162A, JP2010-243866A, JP2010-020297A, and the like.

Particularly, a suitable filter used in the filtering step is preferably a polytetrafluoroethylene-, polyethylene-, or nylon-made filter having a pore size of 0.1 μm or less, more preferably 0.05 μm or less, and still more preferably 0.03 μm or less.

In addition, the radiation-sensitive resin composition preferably has a low moisture content. Specifically, the moisture content is preferably 2.5% by mass or less, more preferably 1.0% by mass or less, and still more preferably 0.3% by mass or less, with respect to the total weight of the composition.

(Procedure of Step (2))

A method for applying the radiation-sensitive resin composition onto an adhesion aiding layer is not particularly limited, and examples thereof include the application method mentioned in the step (1) as described above.

Furthermore, a drying treatment for removing the solvent may be carried out, if desired, after applying the radiation-sensitive resin composition. A method for carrying out the drying treatment is not particularly limited, but examples thereof include a heating treatment and an air drying treatment.

<Resist Film>

The receding contact angle of the resist film formed using the radiation-sensitive resin composition in the present invention is 70° or more at 23±3° C. at a humidity of 45±5%, which is appropriate in the case of the exposure through a liquid immersion medium. The receding contact angle is more preferably 75° or more, and still more preferably from 75° to 85°.

When the receding contact angle is extremely small, the resist film cannot be appropriately used in the case of the exposure through a liquid immersion medium, and the effect of suppressing any residual water (watermark) defect cannot be satisfactorily exerted. For the realization of a desirable receding contact angle, it is preferable to incorporate the hydrophobic resin (HR) in the actinic ray-sensitive or radiation-sensitive resin composition. Alternatively, the receding contact angle may be increased by forming a coating layer (known as a “top coat”) of the hydrophobic resin composition on the resist film.

The thickness of the resist film is not particularly limited, but in order for a higher-precision fine pattern to be formed, the thickness is preferably from 1 nm to 500 nm, and more preferably from 1 nm to 100 nm.

[Step (3): Exposure Step]

The step (3) is a step of exposing the resist film formed in the step (2). More specifically, it is a step of selectively exposing the resist film to provide a desired pattern. With this step, the resist film is patternwise exposed, and only in the exposed area, the solubility of the resist film changes.

The light used in the exposure is not particularly limited, and examples thereof include infrared rays, visible light, ultraviolet rays, far ultraviolet rays, extreme ultraviolet rays, X-rays, and electron beams, in particular, far ultraviolet rays at a wavelength of preferably 250 nm or less, more preferably 220 nm or less, and still more preferably 1 nm to 200 nm.

More specific examples of the light include a KrF excimer laser (248 nm), an ArF excimer laser (193 nm), and an F2 excimer laser (157 nm), X-rays, EUV (13 nm), and electron beams, among which the KrF excimer laser, the ArF excimer laser, the EUV, and the electron beams are preferred, and the ArF excimer laser is more preferred.

A method for selectively exposing the resist film is not particularly limited, and known methods can be used. For example, a Binary-Mask having a transmittance of a light shielding portion of 0%, or a half-tone type phase shift mask (HT-Mask) having a transmittance of a light shielding portion of 6% can be employed.

As the Binary-Mask, those in which a chromium film, a chromium oxide film, or the like is formed as the light shielding portion on a quartz glass substrate are generally used.

As the half-tone type phase shift mask, those in which a MoSi (molybdenum silicide) film, a chromium film, a chromium oxide film, a silicon oxynitride film, or the like is formed as the light shielding portion on a quartz glass substrate are generally used.

In addition, the present invention is not limited to exposure which is carried out through a photomask, and exposure which is not carried out through a photomask, for example, selective exposure (pattern exposure) by means of writing using electron beams or the like may also be carried out.

The present step may include exposure to be carried out multiple times.

(Heating Treatment)

The resist film may be subjected to a heating treatment (PB: Prebake) prior to the present step. The heating treatment (PB) may also be carried out multiple times.

In addition, the resist film after the present step may be subjected to a heating treatment (PEB: Post Exposure Bake). The heating treatment (PEB) may also be carried out multiple times.

By the heating treatment, the reaction in the exposed area is promoted, and thus, the sensitivity or the pattern profile is further improved.

For both PB and PEB, the temperature for the heating treatment is preferably from 70° C. to 130° C., and more preferably from 80° C. to 120° C.

For both PB and PEB, the time for the heating treatment is preferably from 30 seconds to 300 seconds, more preferably from 30 seconds to 180 seconds, and still more preferably from 30 seconds to 90 seconds.

For both PB and PEB, the heating treatment can be carried out using a device installed in an ordinary exposure-and-development machine, or may also be carried out using a hot plate or the like.

(Suitable Embodiments: Liquid Immersion Exposure)

Examples of suitable embodiments of the exposure include liquid immersion exposure. By using the liquid immersion exposure, a fine pattern can be formed. Incidentally, it is possible to combine the liquid immersion exposure with super-resolution technology such as a phase shift method and a modified illumination method.

The immersion liquid used for liquid immersion exposure is preferably a liquid which is transparent to exposure wavelength and has a minimum temperature coefficient of refractive index so as to minimize the distortion of an optical image projected on the resist film. In particular, in the case where the exposure light source is an ArF excimer laser (wavelength: 193 nm), water is preferably used in terms of easy availability and easiness of handling, in addition to the above-described viewpoints.

In the case of using water as the immersion liquid, an additive (liquid) that decreases the surface tension of water while increasing the interfacial activity may be added at a slight proportion. It is preferable that this additive does not dissolve the resist film, and gives a negligible effect on the optical coat at the undersurface of a lens element.

Such an additive is preferably, for example, an aliphatic alcohol having a refractive index substantially equal to that of water, and specific examples thereof include methyl alcohol, ethyl alcohol, and isopropyl alcohol. By adding an alcohol having a refractive index substantially equal to that of water, even when the alcohol component in water is evaporated and its content concentration is changed, an advantage in that the change in the refractive index of the liquid as a whole can be advantageously made very small is obtained.

On the other hand, if materials opaque to light at 193 nm or impurities having a great difference in the refractive index from water are incorporated, the distortion of the optical image projected on the resist is caused. Therefore, the water to be used is preferably distilled water. Further, pure water after filtration through an ion exchange filter or the like may also be used.

The electrical resistance of water used as the immersion liquid is preferably 18.3 MQcm or more, and Total Organic Carbon (TOC) is preferably 20 ppb or less. The water is preferably subjected to a deaeration treatment.

In addition, the lithography performance can be enhanced by increasing the refractive index of the immersion liquid. From such a viewpoint, an additive for increasing the refractive index, for example, may be added to water, or heavy water (D₂O) may be used in place of water.

In the liquid immersion exposure, the surface of the resist film may be washed with an aqueous chemical liquid before the exposure and/or after the exposure (before the heating treatment).

Here, in the present application, an ordinary exposure (exposure not using an immersion liquid) other than liquid immersion exposure is also referred to as dry exposure.

[Step (4): Development Step]

The step (4) is a step of developing the resist film exposed in the step (3). With this step, a desired pattern is formed.

The present step may be (i) a step of carrying out development using a developing liquid containing an organic solvent (organic developing liquid) (organic solvent development), (ii) a step of carrying out development using an alkali developing liquid (alkali development), or (iii) a step including both the (i) organic solvent development and the (ii) alkali development. Here, in the case of (iii), the sequence of (i) and (ii) is not critical.

In the present invention, generally, in the case of carrying out development using an organic developing liquid (i), a negative type pattern is formed; and in the case of carrying out development using an alkali developing liquid (ii), a positive type pattern is formed. In the case of carrying out both (i) and (ii), it is possible to obtain a pattern of a resolution corresponding to twice the frequency of an optical aerial image, as described in FIGS. 1 to 11 in U.S. Pat. No. 8,227,183A.

Hereinafter, the organic solvent development and the alkali development will be described in detail.

<Organic Solvent Development>

As described above, the organic solvent development is a development using an organic developing liquid.

(Organic Developing Liquid)

The organic solvent contained in the organic developing liquid is not particularly limited, and examples thereof include polar solvents such as a ketone-based solvent, an ester-based solvent, an alcohol-based solvent, an amide-based solvent, and an ether-based solvent, and hydrocarbon-based solvents.

Examples of the ketone-based solvent include 1-octanone, 2-octanone, 1-nonanone, 2-nonanone, acetone, 2-heptanone (methyl amyl ketone), 4-heptanone, 1-hexanone, 2-hexanone, diisobutyl ketone, cyclohexanone, methylcyclohexanone, phenyl acetone, methyl ethyl ketone, methyl isobutyl ketone, acetyl acetone, acetonyl acetone, ionone, diacetonyl alcohol, acetyl carbinol, acetophenone, methylnaphthyl ketone, isophorone, and propylene carbonate.

Examples of the ester-based solvent include methyl acetate, butyl acetate, ethyl acetate, isopropyl acetate, pentyl acetate, isopentyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, methyl formate, ethyl formate, butyl formate, propyl formate, ethyl lactate, butyl lactate, and propyl lactate.

Examples of the alcohol-based solvent include an alcohol such as methyl alcohol, ethyl alcohol, n-propyl alcohol, isopropyl alcohol, n-butyl alcohol, sec-butyl alcohol, tert-butyl alcohol, isobutyl alcohol, n-hexyl alcohol, n-heptyl alcohol, n-octyl alcohol, and n-decanol; a glycol-based solvent such as ethylene glycol, diethylene glycol, and triethylene glycol; and a glycol ether-based solvent such as ethylene glycol monomethyl ether, propylene glycol monomethyl ether, ethylene glycol monoethyl ether, propylene glycol monoethyl ether, diethylene glycol monomethyl ether, triethylene glycol monoethyl ether, and methoxymethyl butanol.

Examples of the ether-based solvent include, in addition to the glycol ether-based solvents, dioxane and tetrahydrofuran.

Examples of the amide-based solvent include N-methyl-2-pyrrolidone, N,N-dimethylacetamide, N,N-dimethylformamide, hexamethylphosphoric triamide and 1,3-dimethyl-2-imidazolidinone.

Examples of the hydrocarbon-based solvent include aromatic hydrocarbon-based solvents such as toluene and xylene, and aliphatic hydrocarbon-based solvents such as pentane, hexane, octane, and decane.

In particular, the organic developing liquid is preferably a developing liquid containing at least one organic solvent selected from the group consisting of a ketone-based solvent and an ester-based solvent, and particularly preferably a developing liquid containing butyl acetate as the ester-based solvent and methyl amyl ketone (2-heptanone) as the ketone-based solvent.

A plurality of these solvents may be mixed, or the solvent may be used by mixing it with a solvent other than ones described above or with water. However, in order to exhibit the effects of the present invention sufficiently, the moisture content ratio of the entire developing liquid is preferably less than 10% by mass, and it is more preferable to contain substantially no moisture content.

That is, the amount of the organic solvent used with respect to the organic developing liquid is preferably from 90% by mass to 100% by mass, and more preferably from 95% by mass to 100% by mass, with respect to the entire amount of the developing liquid.

The vapor pressure at 20° C. of the organic developing liquid is preferably 5 kPa or less, more preferably 3 kPa or less, and particularly preferably 2 kPa or less. By setting the vapor pressure of the organic developing liquid to 5 kPa or less, the evaporation of the developing liquid on a substrate or in a development cup is inhibited, and the temperature uniformity within a wafer plane is improved, whereby the dimensional uniformity within a wafer plane is enhanced.

An appropriate amount of a surfactant may be added to the organic developing liquid, if desired.

The surfactant is not particularly limited, and for example, an ionic or nonionic fluorine- and/or silicon-based surfactant can be used. Examples of such a fluorine- and/or silicon-based surfactant include surfactants described in JP1987-36663A (JP-S62-36663A), JP1986-226746A (JP-S61-226746A), JP1986-226745A (JP-S61-226745A), JP1987-170950A (JP-S62-170950A), JP1988-34540A (JP-S63-34540), JP1995-230165A (JP-H07-230165A), JP1996-62834A (JP-H08-62834A), JP1997-54432A (JP-H09-54432A), JP1997-5988A (JP-H09-5988A), and U.S. Pat. No. 5,405,720A, U.S. Pat. No. 5,360,692A, U.S. Pat. No. 5,529,881A, U.S. Pat. No. 5,296,330A, U.S. Pat. No. 5,436,098A, U.S. Pat. No. 5,576,143A, U.S. Pat. No. 5,294,511A, and U.S. Pat. No. 5,824,451A, among which the nonionic surfactant is preferred. The nonionic surfactant is not particularly limited, but a fluorine-based surfactant or a silicon-based surfactant is more preferably used.

The amount of the surfactant used is usually from 0.001% by mass to 5% by mass, preferably from 0.005% by mass to 2% by mass, and more preferably from 0.01% by mass to 0.5% by mass, with respect to the entire amount of the developing liquid.

In addition, the organic developing liquid may contain a nitrogen-containing compound as described in JP2013-11833A. By such an embodiment, improvement in the contrast during the development, inhibition of a reduction in films, and the like can be expected.

(Developing Method)

As the developing method, for example, a method in which a substrate is immersed in a tank filled with a developing liquid for a certain period of time (a dip method), a method in which a developing liquid is heaped up to the surface of a substrate by surface tension and developed by resting for a certain period of time (a paddle method), a method in which a developing liquid is sprayed on the surface of a substrate (a spray method), a method in which a developing liquid is continuously discharged on a substrate rotated at a constant rate while scanning a developing liquid discharging nozzle at a constant rate (a dynamic dispense method), or the like, can be applied.

If a variety of developing methods as described above include a step in which a developing liquid is discharged from a development nozzle of a development apparatus toward a resist film, the discharge pressure of the developing liquid discharged (a flow rate per unit area of the developing liquid discharged) is preferably 2 mL/sec/mm² or less, more preferably 1.5 mL/sec/mm² or less, and still more preferably 1 mL/sec/mm² or less. The lower limit of the flow rate is not particularly limited, but is preferably 0.2 mL/sec/mm² or more, taking consideration of throughput. The details of this are particularly described in paragraphs 0022 to 0029 of JP2010-232550A, and the like.

In addition, after the step of carrying out development using a developing liquid containing an organic solvent, a step of stopping the development while replacing the solvent with another solvent may be carried out.

(Rinsing Treatment)

It is preferable to carry out washing using a rinsing liquid after the organic solvent development.

The rinsing liquid is not particularly limited as long as it does not dissolve the resist film, and a solution containing common organic solvents can be used.

As the rinsing liquid, a rinsing liquid containing at least one organic solvent selected from the group consisting of a hydrocarbon-based solvent, a ketone-based solvent, an ester-based solvent, an alcohol-based solvent, an amide-based solvent, and an ether-based solvent is preferred; a rinsing liquid containing at least one organic solvent selected from the group consisting of a ketone-based solvent, an ester-based solvent, an alcohol-based solvent, and an amide-based solvent is more preferred; a rinsing liquid containing an alcohol-based solvent or an ester-based solvent is still more preferred; a rinsing liquid containing a monohydric alcohol is particularly preferred; and a rinsing liquid containing a monohydric alcohol having 5 or more carbon atoms is most preferred.

Specific examples of the hydrocarbon-based solvent, the ketone-based solvent, the ester-based solvent, the alcohol-based solvent, the amide-based solvent, and the ether-based solvent are the same as those for the organic developing liquid as described above.

Examples of the monohydric alcohol include a linear, branched, or cyclic monohydric alcohol, and more specifically, 1-hexanol, 2-hexanol, 4-methyl-2-pentanol, 1-pentanol, and 3-methyl-1-butanol.

The rinsing liquid may contain a plurality of solvents. Further, the rinsing liquid may contain an organic solvent other than those as mentioned above.

The moisture content in the rinsing liquid is preferably 10% by mass or less, more preferably 5% by mass or less, and particularly preferably 3% by mass or less. By setting the moisture content to 10% by mass or less, superior development characteristics can be obtained.

The vapor pressure of the rinsing liquid is preferably from 0.05 kPa to 5 kPa, more preferably from 0.1 kPa to 5 kPa, and most preferably from 0.12 kPa to 3 kPa at 20° C. By setting the vapor pressure of the rinsing liquid to from 0.05 kPa to 5 kPa, the temperature uniformity within a wafer plane is improved, and further, the dimensional uniformity within a wafer plane is enhanced by inhibition of swelling due to the penetration of the rinsing liquid.

An appropriate amount of a surfactant can be added to the rinsing liquid, and used. Specific examples and amounts used of the surfactant are the same as the organic developing liquid as described above.

In the rinsing treatment, the wafer which has been subjected to organic solvent development is subjected to a washing treatment using the rinsing liquid. A method for the washing treatment is not particularly limited, but for example, a method in which a rinsing liquid is continuously discharged on a substrate rotated at a constant rate (a spin rotation method), a method in which a substrate is immersed in a tank filled with a rinsing liquid for a certain period of time (a dip method), a method in which a rinsing liquid is sprayed on a substrate surface (a spray method), or the like, may be applied. Among these, a method in which a washing treatment is carried out using the rotation application method, a substrate is rotated at a rotational speed of 2000 rpm to 4000 rpm after washing, thereby removing the rinsing liquid from the substrate, is preferred. Further, it is preferable that a heating treatment (Post Bake) is carried out after the rinsing treatment. The residual developing liquid and the rinsing liquid between and inside the patterns are removed by the heating treatment. The heating treatment after the rinsing treatment is usually carried out at 40° C. to 160° C., and preferably at 70° C. to 95° C., and typically for 10 seconds to 3 minutes, and preferably for 30 seconds to 90 seconds.

<Alkali Development>

As described above, the alkali development is development using an alkali developing liquid.

The alkali developing liquid is not particularly limited, and examples thereof include aqueous alkali solutions of quaternary ammonium salts represented by tetramethylammonium hydroxide, inorganic alkalis, primary amines, secondary amines, tertiary amines, alcohol amines, cyclic amines, and the like, among which aqueous alkali solutions of quaternary ammonium salts represented by tetramethylammonium hydroxide are preferred.

The alkali developing liquid may also be used after an appropriate amount of alcohols and a surfactant are added thereto. Specific examples and the amount used of the surfactant are the same as the organic developing liquid as described above.

The alkali concentration of the alkali developing liquid is usually from 0.1% by mass to 20% by mass.

The pH of the alkali developing liquid is usually 10.0 to 15.0.

The developing method is the same as the organic solvent development as described above.

As the rinsing liquid after the alkali development, it is preferable to carry out washing using pure water (rinsing treatment). An appropriate amount of a surfactant may be added to the rinsing liquid, and used. Specific examples and the amount used of the surfactant are the same as the organic developing liquid as described above.

It is preferable that the organic developing liquid, the alkali developing liquid, and the rinsing liquid used in the present invention has a small content of various fine particles or impurities such as metal elements. In order to obtain such a chemical solution with small amounts of impurities, it is preferable to reduce the impurities, for example, by producing the chemical solution in a clean room or performing filtration through various filters such as a Teflon (registered mark) filter, a polyolefin-based filter, and an ion exchange filter. With regard to the metal element, any of metal element concentrations of Na, K, Ca, Fe, Cu, Mg, Mn, Li, Al, Cr, Ni, and Zn is preferably 10 ppm or less, and more preferably 5 ppm or less.

In addition, the container for storing the developing liquid or the rinsing liquid is not particularly limited, and a container made of a polyethylene resin, a polypropylene resin, a polyethylene-polypropylene resin, or the like, which is used in the application of electronic materials, may be used appropriately, but in order to reduce the impurities eluted from the container, it is also preferable to select a container which is less likely to cause elution of a component from the inner wall of the container to the chemical solution. Examples of such a container include a container where the inner wall of the container is formed of a perfluororesin (for example, a FluoroPure PFA composite drum (inner surface coming into contact with a liquid; a PFA resin lining) manufactured by Entegris, and a steel-made drum (inner surface coming into contact with a liquid; and a zinc phosphate coat) manufactured by JFE).

### Second Embodiment

The second embodiment of the pattern forming method of the present invention includes the following five steps:
(5) an antireflection film forming step of forming an antireflection film on the substrate;
(1) an adhesion aiding layer forming step of applying the composition for forming an adhesion aiding layer onto the antireflection film to form an adhesion aiding layer containing a polymerizable group and having a light transmittance of 80% or more at a wavelength of 193 nm;
(2) a resist film forming step of applying a radiation-sensitive resin composition onto the adhesion aiding layer to form a resist film;
(3) an exposing step of exposing the resist film; and
(4) a developing step of developing the exposed resist film to form a pattern.

The second embodiment as described above has the same configuration as the first embodiment except for further including the step (5). Accordingly, the step (5) will be mainly described below in detail.

[Step (5): Antireflection Film Forming Step]

The step (5) is a step of forming an antireflection film on a substrate.

As the antireflection film, either an inorganic film type one such as titanium, titanium dioxide, titanium nitride, chromium oxide, carbon, and amorphous silicon, or an organic film type one including a light absorber and a polymer material can be used. The former requires equipment for film formation, such as a vacuum deposition apparatus, a CVD apparatus, and a sputtering apparatus. Examples of the organic antireflection film include a film including a condensate of a diphenylamine derivative and a formaldehyde-modified melamine resin, an alkali-soluble resin, and a light absorber described in JP1995-69611B (JP-H07-69611B), a reaction product of a maleic anhydride copolymer and a diamine-type light absorber described in U.S. Pat. No. 5,294,680A, a film containing a resin binder and a methylolmelamine-based heat crosslinking agent described in JP1994-118631A (JP-H06-118631A), an acrylic resin-type antireflection film containing a carboxylic acid group, an epoxy group, and a light absorbing group within the same molecule described in JP1994-118656A (JP-H06-118656A), a film including a methylolmelamine and a benzophenone-based light absorber described in JP1996-87115A (JP-H08-87115A), and a film obtained by adding a low molecular light absorber to a polyvinyl alcohol resin described in JP1996-179509A (JP-H08-179509A).

Furthermore, as the organic antireflection film, a commercially available organic antireflection film such as DUV-30 Series and DUV-40 Series, manufactured by Brewer Science, Inc.; and AR-2, AR-3, and AR-5, manufactured by Shipley Co., Ltd. can also be used.

Other examples of the antireflection film include AQUATAR-II, AQUATAR-III, AQUATAR-VII, and AQUATAR-VIII, manufactured by AZ Electronic Materials Co., Ltd.

The thickness of the antireflection film is not particularly limited, but from the viewpoint of anti-reflection properties, the thickness is preferably from 1 μm to 500 μm, and more preferably from 1 μm to 200 μm.

In the step (1) of the second embodiment, the composition for forming an adhesion aiding layer is applied onto the antireflection film as described above to form an adhesion aiding layer containing a polymerizable group and having a light transmittance of 80% or more at a wavelength of 193 nm. A method for forming the adhesion aiding layer is the same as the first embodiment as described above.

In addition, the steps (2) to (4) in the second embodiment are the same as the steps (2) to (4) in the first embodiment as described above.

The present invention also relates to a method for manufacturing an electronic device, including the pattern forming method of the present invention, and an electronic device manufactured by the manufacturing method.

The electronic device of the present invention is suitably mounted on electric electronic equipment (home electronics, OA/media-related equipment, optical equipment, telecommunication equipment, and the like).

Generally, the pattern obtained by the pattern forming method of the present invention is suitably used as, for example, an etching mask in a semiconductor device, but may also be used in other applications. Examples of such the other applications include applications for guide pattern formation in Directed Self-Assembly (DSA) (see, for example, ACS Nano, Vol. 4, No. 8, pp. 4815-4823), that is, a so-called core material (core) in a spacer process (see, for example, JP1991-270227A (JP-H03-270227A) and JP2013-164509A).

### EXAMPLES

Examples are shown below, but the present invention is not limited thereto.

<Material for Forming Adhesion Aiding Layer>

(Materials A1 to A6 for Forming Adhesion Aiding Layers)

The compounds A (A1 to A6) shown in Table 1 below are used as materials A1 to A6 for forming adhesion aiding layers, respectively.

TABLE 1

| | | Molecular | |
|---|---|---|---|
| | Compound A | weight | Availability |
| A1 | 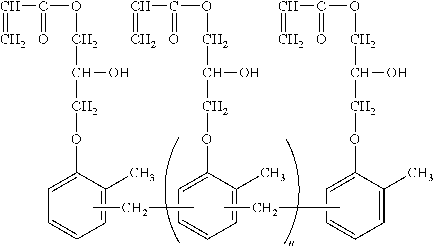 n ≈ 4 | ca. 1,500 | NK Oligo EA- 7120/PGMAc (cresol novolac-type epoxy acrylate), manufactured by Shin-Nakamura Chemical Co., Ltd. |
| A2 | 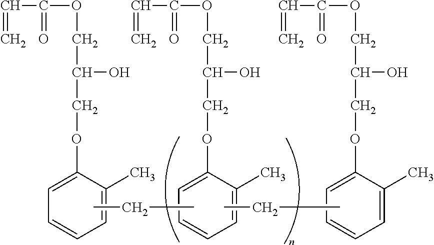 n ≈ 11 | ca. 3,500 | NK Oligo EA- 7420/PGMAc (cresol novolac-type epoxy acrylate), manufactured by Shin-Nakamura Chemical Co., Ltd. |
| A3 | 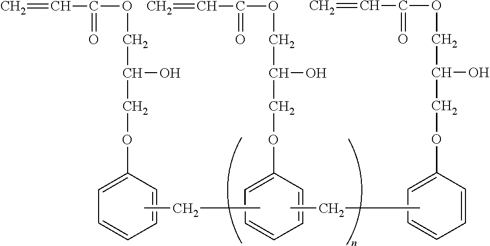 n ≈ 2 n ≈ 2 | ca. 1,000 | NK Oligo EA- 6320/PGMAc (phenol novolac-type epoxy acrylate), manufactured by Shin-Nakamura Chemical Co., Ltd. |
| A4 | 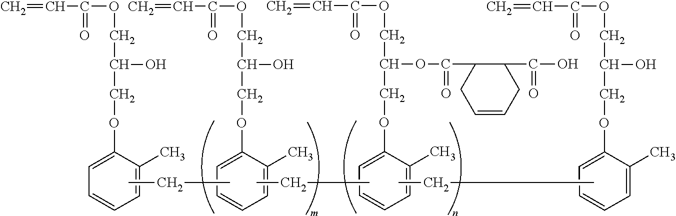 Average m + n ≈ 4 Average n/(m + n) ≈ 0.5 | ca. 2,000 | NK Oligo EA- 7140/PGMAc (carboxylic anhydride-modified epoxy acrylate), manufactured by Shin-Nakamura Chemical Co., Ltd. |
| A5 | 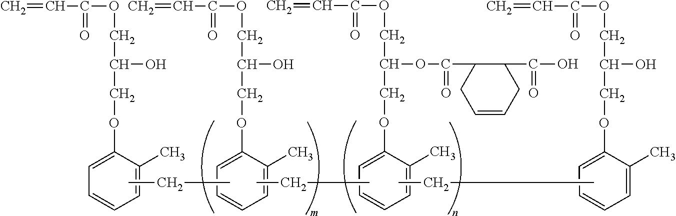 Average m + n ≈ 11 Average n/(m + n) ≈ 0.5 | ca. 4,500 | NK Oligo EA- 7440/PGMAc (carboxylic anhydride-modified epoxy acrylate), manufactured by Shin-Nakamura Chemical Co., Ltd. |
| A6 | 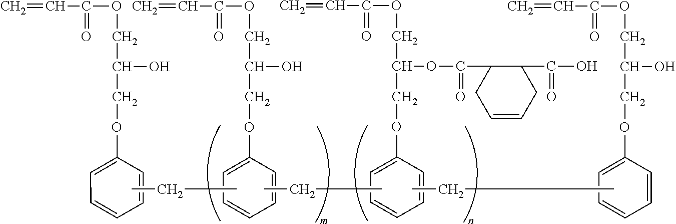 Average m + n ≈ 2 Average n/(m + n) ≈ 0.5 | ca. 1,400 | NK Oligo EA- 6340/PGMAc (carboxylic anhydride-modified epoxy acrylate), manufactured by Shin-Nakamura Chemical Co., Ltd. |

(Material A7 for Forming Adhesion Aiding Layer)

Dipentaerythritol hexaacrylate (KAYARAD DPHA, molecular weight: 579, manufactured by Nippon Kayaku Co., Ltd.) is used as a material A7 for forming an adhesion aiding layer.

(Material A8 for Forming Adhesion Aiding Layer)

Styrene and methacrylic acid were polymerized using a polymerization initiator V601 (Wako Pure Chemical Industries, Ltd.) to obtain a styrene/methacrylic acid copolymer (repeating unit molar ratio: 40/60, repeating unit mass ratio: 31/69). By allowing the obtained styrene/methacrylic acid copolymer to undergo a reaction with glycidyl methacrylate, a compound (Mw: 13100, dispersity: 2.1) having the following repeating units was obtained. Here, a/b/c is 40/30/30 in terms of a molar ratio, or 31/19/50 in terms of a mass ratio. The obtained compound is used as a material A8 for forming an adhesion aiding layer.

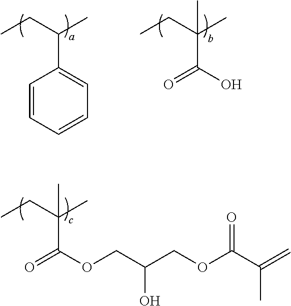

(Material A9 for Forming Adhesion Aiding Layer)

Methacrylic acid and methyl methacrylate were polymerized using a polymerization initiator V601 (manufactured by Wako Pure Chemical Industries, Ltd.) to obtain a methacrylic acid/methyl methacrylate copolymer (repeating unit molar ratio: 70/30, repeating unit mass ratio: 67/33, Mw: 12300, dispersity: 2.1).

By allowing the methacrylic acid/methyl methacrylate copolymer to undergo a reaction with glycidyl methacrylate, the following compound (Mw: 13400, dispersity: 2.1) was obtained. Here, a/b/c is 40/30/30 in terms of a molar ratio, or 23/26/51 in terms of a mass ratio. The obtained compound is defined as a material A9 for forming an adhesion aiding layer.

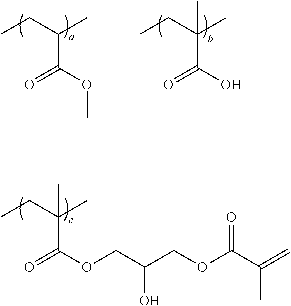

(Material A10 for Forming Adhesion Aiding Layer)

NK ester A-DPH-12E (molecular weight: 1107, manufactured by Shin-Nakamura Chemical Co., Ltd.) (the following structure) is defined as a material A10 for forming an adhesion aiding layer.

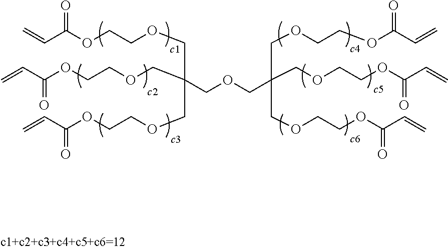

(Material A11 for Forming Adhesion Aiding Layer)

PVEEA (Mw: 21300, dispersity: 2.2, manufactured by Nippon Shokubai Co., Ltd.) (the following structure) is defined as a material A11 for forming an adhesion aiding layer.

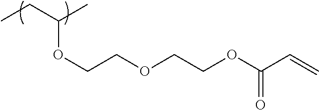

(Material A12 for Forming Adhesion Aiding Layer)

NK ester 600 (molecular weight: 708, manufactured by Shin-Nakamura Chemical Co., Ltd.) (the following structure) is defined as a material A12 for forming an adhesion aiding layer. In the following structural formula, c8 is about 14.

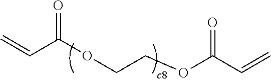

(Material A13 for Forming Adhesion Aiding Layer)

U-4HA (molecular weight: 596, manufactured by Shin-Nakamura Chemical Co., Ltd.) (the following structure) is defined as a material A13 for forming an adhesion aiding layer.

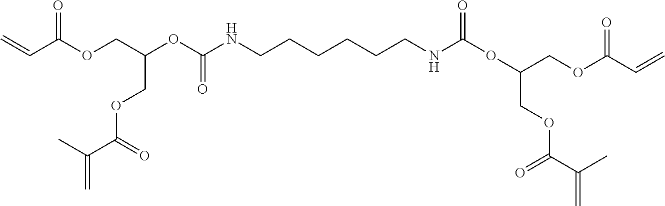 [SMILES: C=CC(=O)OCC(COC(=O)C(=C)C)OC(=O)NCCCCCCNC(=O)OC(COC(=O)C=C)COC(=O)C(=C)C]

(Transmittance of Adhesion Aiding Layer)

Each of the materials for forming an adhesion aiding layer was dissolved in propylene glycol monomethyl ether acetate to prepare a 0.1%-by-mass solution, and the solution was filtered through a 0.1-μm tetrafluoroethylene filter to obtain a composition for forming an adhesion aiding layer.

The obtained composition for forming an adhesion aiding layer was spin-coated onto a transparent substrate, and heated and cured on a hot plate to manufacture a model film (film thickness: 3 nm) of the adhesion aiding layer.

For the obtained model film, the light transmittance at a wavelength of 193 nm was measured by means of a spectrophotometer, and the value was 80% or more in any case.

### Synthesis Example of Resin (A)

### Resin A-1

Under a nitrogen air flow, 40 g of cyclohexanone was put into a three-neck flask, and heated at 80° C. (Solvent 1). The monomers corresponding to each of the following repeating units, LM-1, IM-1, and PM-1, were dissolved in cyclohexanone at a molar ratio of 40/10/50 to prepare a solution of 22% by mass of the monomers (400 g).

Further, 7.2% by mole of a polymerization initiator V-601 (manufactured by Wako Pure Chemical Industries, Ltd.) with respect to the monomers was added thereto and dissolved. The obtained solution was added dropwise to the Solvent 1 for 6 hours. After addition dropwise, the solution was further subjected to a reaction at 80° C. for 2 hours. The reaction liquid was left to be cooled, and then poured into 3600 ml of heptane/400 ml of ethyl acetate. The precipitated solid (powder) was collected by filtration, and dried to obtain 74 g of a resin. The obtained resin was defined as a resin A-1. The compositional ratio of the resin A-1, as determined by NMR, was 40/10/50 (molar ratio). Further, the weight-average molecular weight and the dispersity (Mw/Mn) of the obtained resin (A-1) were 10200 and 1.5, respectively.

(Resins A-2 to A-28)

Resins A-2 to A-28 having the repeating units (LM, IM, and PM) shown in Table 2 below were synthesized by the same procedure as the synthesis of the resin A-1. Here, the specific structures of the repeating units (LM, IM, and PM) are as follows. Further, all are the repeating units derived from the (meth)acrylate.

The compositional ratio, the weight-average molecular weight, and the dispersity of the respective resins are as shown in Table 2 below. Here, with regard to the compositional ratios, the compositional ratios (molar ratios) of the repeating units contained in each resin are shown in order starting from the left side.

TABLE 2

| | | | | | Compositional | Molecular | |
|---|---|---|---|---|---|---|---|
| Resin (A) | LM | IM | PM | | ratio | weight | Dispersity |
| A-1 | LM-1 | IM-1 | PM-1 | — | 40/10/50 | 10200 | 1.5 |
| A-2 | LM-7 | IM-1 | PM-1 | PM-3 | 40/10/35/15 | 9500 | 1.8 |
| A-3 | LM-1 | IM-1 | PM-2 | PM-6 | 45/10/20/25 | 8400 | 1.5 |
| A-4 | LM-7 | IM-1 | PM-3 | PM-9 | 45/10/25/20 | 10000 | 2.0 |
| A-5 | LM-1 | IM-1 | PM-4 | — | 40/10/50 | 9200 | 1.6 |
| A-6 | LM-1 | IM-1 | PM-5 | PM-3 | 40/10/25/25 | 10500 | 1.5 |
| A-7 | LM-6 | IM-1 | PM-1 | — | 50/10/40 | 9300 | 1.5 |
| A-8 | LM-5 | IM-1 | PM-1 | — | 30/10/60 | 8700 | 1.6 |
| A-9 | LM-1 | IM-1 | PM-11 | — | 55/5/40 | 10300 | 1.5 |
| A-10 | LM-1 | IM-1 | PM-5 | — | 50/10/40 | 9200 | 1.6 |
| A-11 | LM-2 | IM-1 | PM-1 | PM-3 | 40/10/25/25 | 9000 | 1.5 |
| A-12 | LM-10 | — | PM-7 | — | 40/60 | 9700 | 1.8 |
| A-13 | LM-9 | — | PM-10 | — | 40/60 | 10100 | 1.6 |
| A-14 | LM-5 | — | PM-1 | PM-3 | 50/25/25 | 9400 | 1.5 |
| A-15 | LM-8 | — | PM-1 | PM-5 | 40/40/20 | 9600 | 1.7 |
| A-16 | LM-3 | — | PM-3 | PM-8 | 40/45/15 | 11400 | 1.5 |
| A-17 | LM-4 | IM-2 | PM-10 | — | 40/10/50 | 9900 | 1.5 |
| A-18 | LM-1 | — | PM-1 | — | 30/70 | 8000 | 1.6 |
| A-19 | LM-1 | — | PM-3 | PM-9 | 40/40/20 | 10000 | 1.5 |
| A-20 | LM-5 | — | PM-12 | — | 50/50 | 12000 | 2.0 |
| A-21 | LM-2 | IM-1 | PM-13 | PM-14 | 45/5/40/10 | 12000 | 2.1 |
| A-22 | LM-4 | IM-1 | PM-10 | — | 35/10/55 | 8000 | 1.9 |
| A-23 | LM-1 | — | PM-10 | — | 50/50 | 20000 | 1.6 |
| A-24 | LM-1 | IM-1 | PM-12 | — | 45/10/45 | 11000 | 1.6 |
| A-25 | LM-5 | IM-1 | PM-4 | PM-9 | 35/15/40/10 | 12000 | 1.7 |
| A-26 | LM-2 | — | PM-8 | PM-14 | 40/50/10 | 10000 | 1.7 |
| A-27 | LM-7 | — | PM-1 | — | 45/55 | 8000 | 1.8 |
| A-28 | LM-7 | IM-1 | PM-4 | — | 30/10/60 | 10000 | 2.0 |

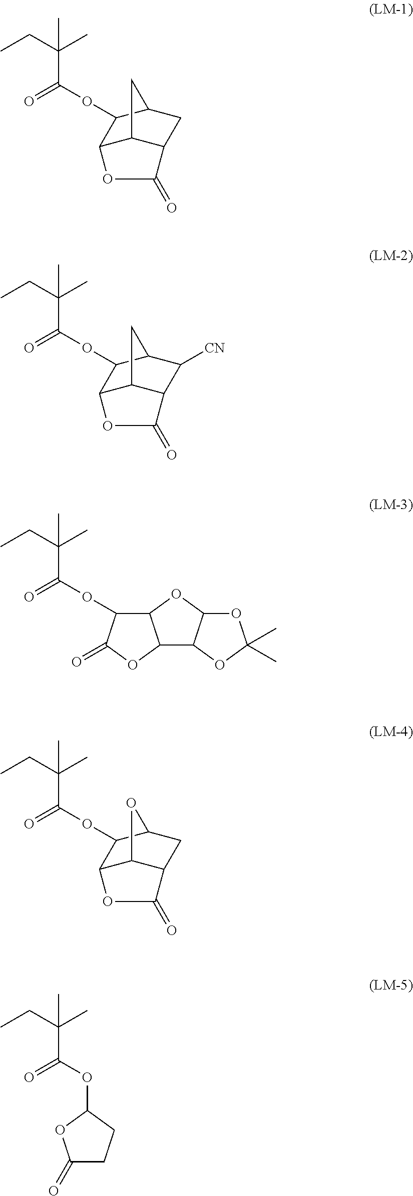

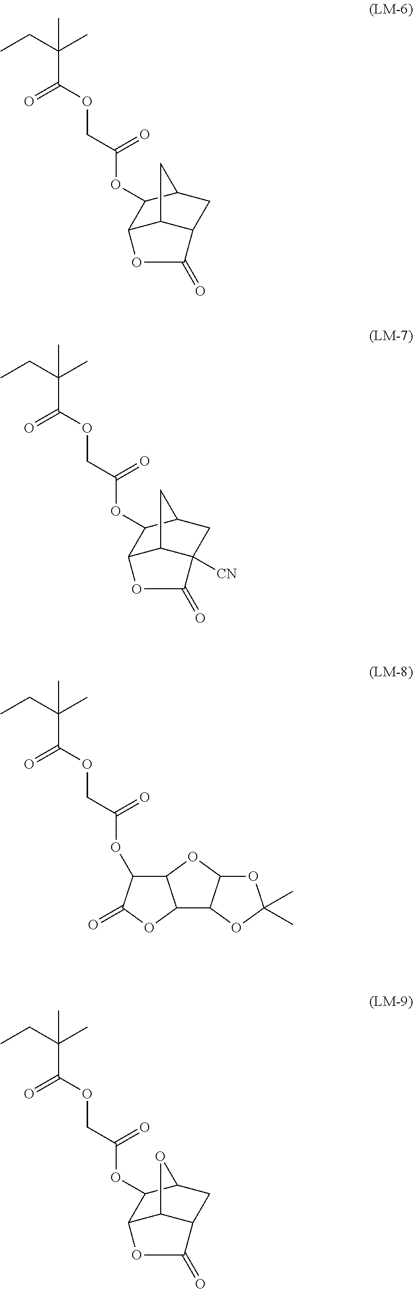

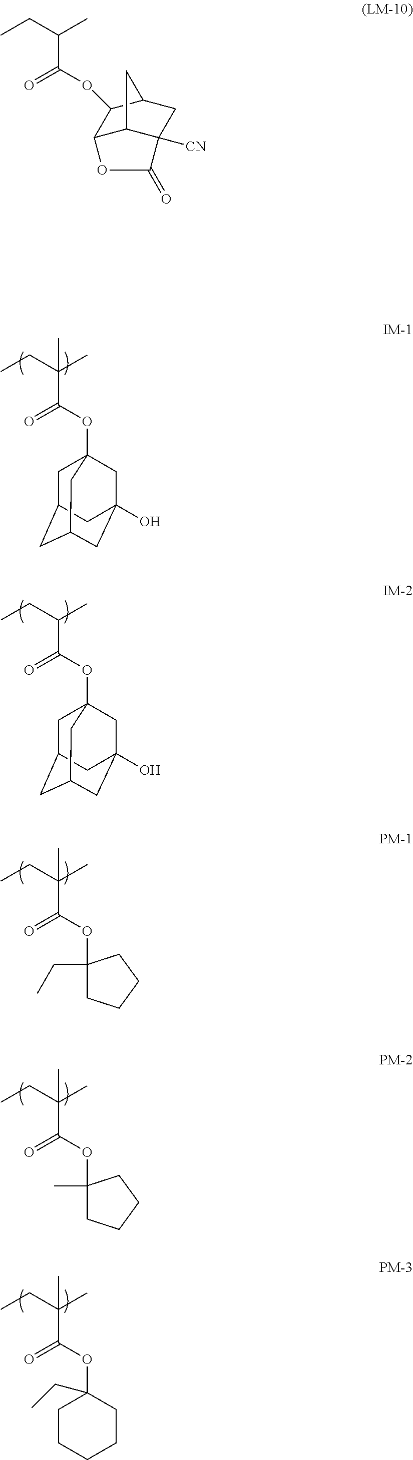

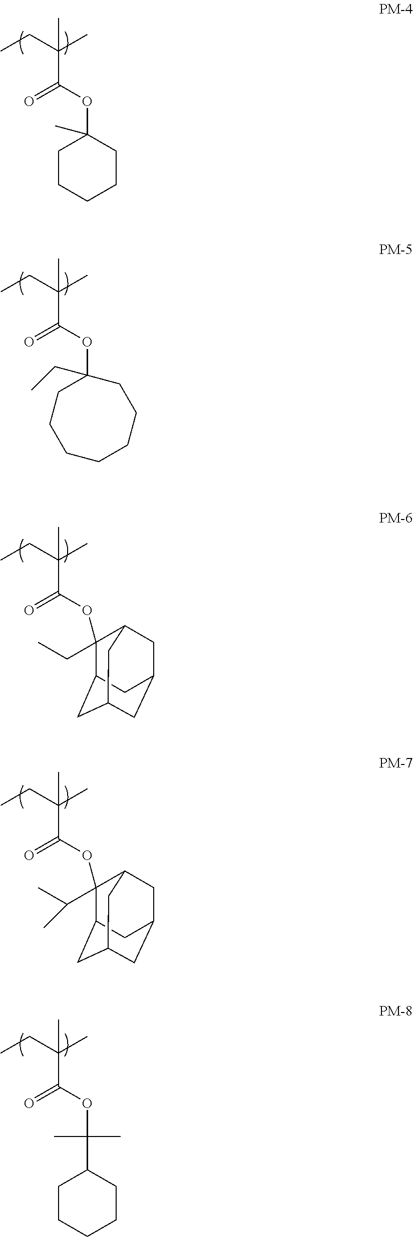

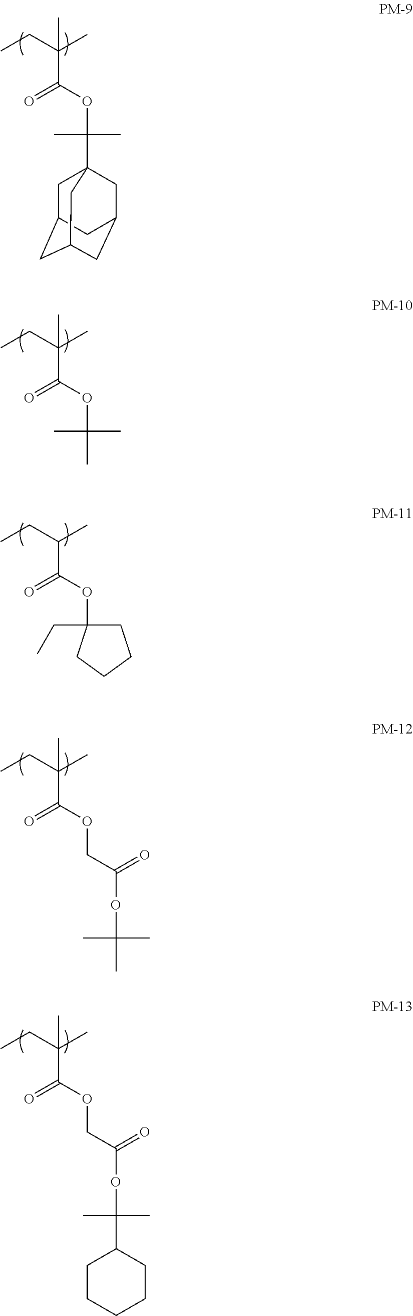

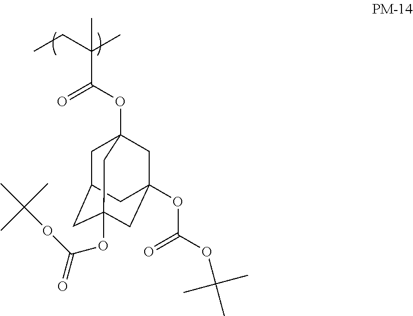

### Preparation Example of Composition for Forming Resist Film

The components shown in Table 3 below were dissolved in the solvents shown in Table 3 below, and each of the obtained solutions (with a solid content concentration of 3.5% by mass for AR-1 to AR-13, a solid content concentration of 4.0% by mass for AR-14 to AR-23, or a solid content concentration of 2.5% by mass for AR-24 to AR-33) was filtered through a polyethylene filter having a pore size of 0.03 μm to obtain compositions AR-1 to AR-33 for forming a resist film. Here, in Table 3, the numerical values in the parenthesis represent parts by mass of the respective components.

TABLE 3

| | Composition | | | | | | | |
|---|---|---|---|---|---|---|---|---|
| Composition | Resin(A) | | Basic | Surfactant | Hydrophobic | | | |
| for forming | (parts by | Acid generator | compound | (parts by | resin (parts by | Addition mode | | Solvent (parts by |
| resist film | mass) | (parts by mass) | (parts by mass) | mass) | mass) | (added/TC) | Solvent (TC) | mass) |
| AR-1 | A-4 | PAG-3/PAG-5 | N-11 | | B-4 | Added | | SL-1/SL-2 |
| | (77.900) | (8.0/12.0) | (1.0) | | (0.5) | | | (1140/760) |
| AR-2 | A-2 | PAG-3 | N-2 | | B-6 | TC | SL-6 | SL-1/SL-3 |
| | (80.100) | (13.5) | (3.0) | | (2.5) | | | (1140/760) |
| AR-3 | A-3 | PAG-1/PAG-5 | N-5 | W-2 | B-4 | Added | | SL-1 |
| | (80.200) | (6.5/11.0) | (0.7) | (0.50) | (0.6) | | | (1900) |
| AR-4 | A-11 | PAG-5 | N-7 | | B-1 | Added | | SL-1/SL-2/SL-3 |
| | (73.700) | (24.0) | (1.2) | | (0.7) | | | (1641/244/15) |
| AR-5 | A-15 | PAG-8/PAG-10 | N-9 | W-1 | B-6 | Added | | SL-1/SL-3/SL-4 |
| | (74.600) | (8.0/11.0) | (0.7) | (0.50) | (4.0) | | | (1438/442/20) |
| AR-6 | A-16 | PAG-2/PAG-3 | N-4 | W-3 | B-8 | Added | | SL-1 |
| | (85.400) | (4.0/6.0) | (1.5) | (0.50) | (2.0) | | | (1900) |
| AR-7 | A-7 | PAG-2 | N-12 | | B-7 | Added | | SL-1/SL-2/SL-5 |
| | (86.200) | (9.0) | (0.8) | | (3.0) | | | (1354/531/15) |
| AR-8 | A-6 | PAG-9/PAG-10 | N-9 | W-1 | B-5 | Added | | SL-1/SL-2 |
| | (77.400) | (10.0/10.0) | (0.8) | (0.50) | (0.7) | | | (1140/760) |
| AR-9 | A-10 | PAG-3/PAG-4 | N-6/N-8 | W-2 | B-6 | TC | SL-7 | SL-1/SL-3 |
| | (73.700) | (1.0/19.0) | (2.0/0.2) | (0.50) | (3.0) | | | (1140/760) |
| AR-10 | A-8 | PAG-7 | N-2 | | B-7 | Added | | SL-1/SL-3 |
| | (68.700) | (23.5) | (4.0) | | (3.0) | | | (1140/760) |
| AR-11 | A-14 | PAG-3 | N-10 | | B-6 | Added | | SL-1/SL-3 |
| | (84.600) | (10.0) | (1.0) | | (4.0) | | | (1140/760) |
| AR-12 | A-2/A-17 | PAG-7 | N-2 | | B-4 | Added | | SL-1/SL-3 |
| | (40.900/30.000) | (24.0) | (4.0) | | (0.8) | | | (1140/760) |
| AR-13 | A-9 | PAG-10 | N-3 | | B-4/B-6 | Added | | SL-1/SL-3 |
| | (70.5) | (22.5) | (2.6) | | (0.5/3.5) | | | (1140/760) |
| AR-14 | A-18 | PAG-3/PAG-5 | N-11 | | B-4 | Added | | SL-1/SL-2 |
| | (78.500) | (8.0/12.0) | (1.0) | | (0.5) | | | (1140/760) |
| AR-15 | A-19 | PAG-3 | N-1 | W-1 | B-9 | Added | | SL-1/SL-3 |
| | (83.500) | (10.5) | (2.5) | (0.50) | (3.0) | | | (1140/760) |
| AR-16 | A-16 | PAG-9 | N-9 | | B-4 | Added | | SL-1/SL-2 |
| | (87.800) | (10.5) | (0.6) | | (0.5) | | | (1140/760) |
| AR-17 | A-15 | PAG-9/PAG-8 | N-2 | | B-4 | Added | | SL-1/SL-2/SL-3 |
| | (76.850) | (10.0/10.0) | (2.0) | | (0.55) | | | (1641/244/15) |
| AR-18 | A-12 | PAG-3 | N-11 | W-2 | B-4 | Added | | SL-1 |
| | (87.950) | (9.5) | (0.9) | (0.50) | (0.45) | | | (1900) |
| AR-19 | A-5 | PAG-2/PAG-6 | N-11 | | B-9 | Added | | SL-1/SL-2/SL-3 |
| | (75.400) | (3.0/17.0) | (1.1) | | (3.5) | | | (1641/244/15) |
| AR-20 | A-1 | PAG-10 | N-9 | W-1 | B-4 | Added | | SL-1 |
| | (80.650) | (16.5) | (1.0) | (0.50) | (0.55) | | | (1900) |
| AR-21 | A-13/A-14 | PAG-7 | N-9 | | B-9 | Added | | SL-1/SL-2 |
| | (37.450/37.450) | (22.0) | (1.9) | | (0.9) | | | (1140/760) |
| AR-22 | A-12 | PAG-1 | N-6 | | B-3 | Added | | SL-1/SL-2 |
| | (82.600) | (11.0) | (5.0) | | (0.8) | | | (1140/760) |
| AR-23 | A-16 | PAG-9 | N-9 | | B-4 | Added | | SL-1/SL-2 |
| | (88.400) | (10.5) | (0.6) | | (0.5) | | | (1140/760) |
| AR-24 | A-18 | PAG-2 | N-1 | | B-9 | Added | | SL-1 |
| | (85.500) | (8.5) | (2.0) | | (4.0) | | | (1900) |
| AR-25 | A-19 | PAG-3/PAG-4 | N-2 | W-1 | B-9 | Added | | SL-1/SL-2/SL-3 |
| | (75.400) | (5.5/11.5) | (3.5) | (0.50) | (3.6) | | | (1641/244/15) |
| AR-26 | A-20 | PAG-8/PAG-9 | N-7 | | B-4 | Added | | SL-1/SL-3/SL-4 |
| | (78.800) | (15.0/5.0) | (0.6) | | (0.6) | | | (1438/442/20) |
| AR-27 | A-21 | PAG-6 | N-8 | | B-9 | Added | | SL-1/SL-2 |
| | (83.700) | (12.0) | (1.2) | | (3.1) | | | (1140/760) |
| AR-28 | A-22 | PAG-3 | N-9 | | B-9 | Added | | SL-1/SL-2 |
| | (83.100) | (11.0) | (1.4) | | (4.5) | | | (1140/760) |
| AR-29 | A-23 | PAG-1/PAG-10 | N-10 | W-2 | B-4 | Added | | SL-1 |
| | (70.800) | (8.0/18.0) | (2.0) | (0.50) | (0.7) | | | (1900) |
| AR-30 | A-24 | PAG-8 | N-11 | | B-9 | Added | | SL-1/SL-2 |
| | (65.600) | (26.0) | (5.0) | | (3.4) | | | (1140/760) |
| AR-31 | A-25 | PAG-5 | N-9 | | B-9 | Added | | SL-1/SL-3 |
| | (69.800) | (24.0) | (2.5) | | (3.7) | | | (1140/760) |
| AR-32 | A-26 | PAG-9 | N-2 | | B-4 | Added | | SL-1/SL-2 |
| | (75.700) | (19.0) | (4.5) | | (0.8) | | | (1140/760) |
| AR-33 | A-27 | PAG-2 | N-11 | | B-4 | Added | | SL-1/SL-2 |
| | (83.900) | (14.0) | (1.6) | | (0.5) | | | (1140/760) |

In Table 3, the resin (A) represents one corresponding to each of the resins A-1 to A-28 as described above.

In Table 3, the specific structures of the acid generator, the basic compound, and the hydrophobic resin are as follows. The compositional ratio, the weight-average molecular weight, and the dispersity of the hydrophobic resin are as shown in Table A below. Here, with regard to the compositional ratios, the compositional ratios (molar ratios) of the repeating units contained in each resin are shown in order from the left side.

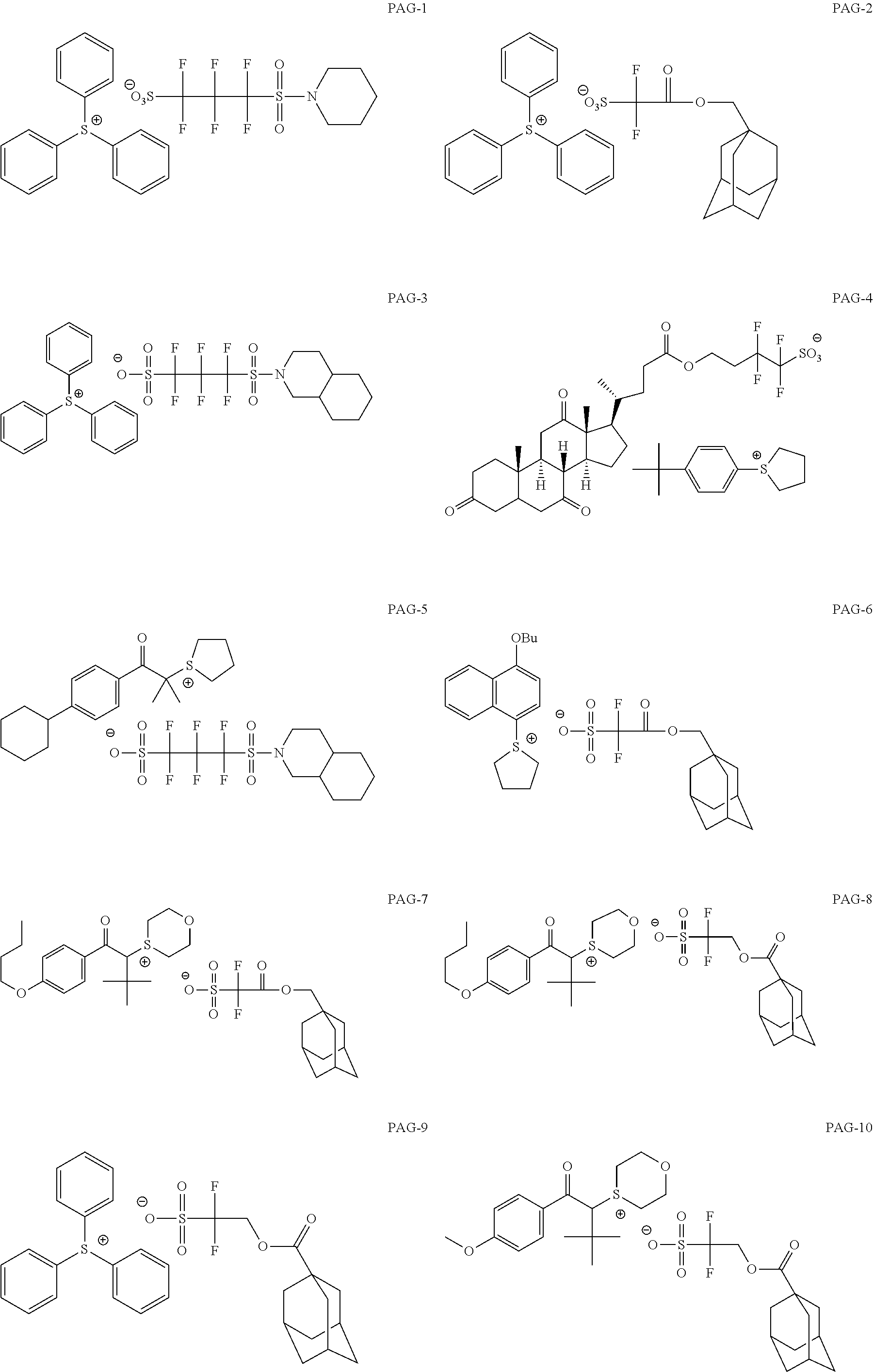

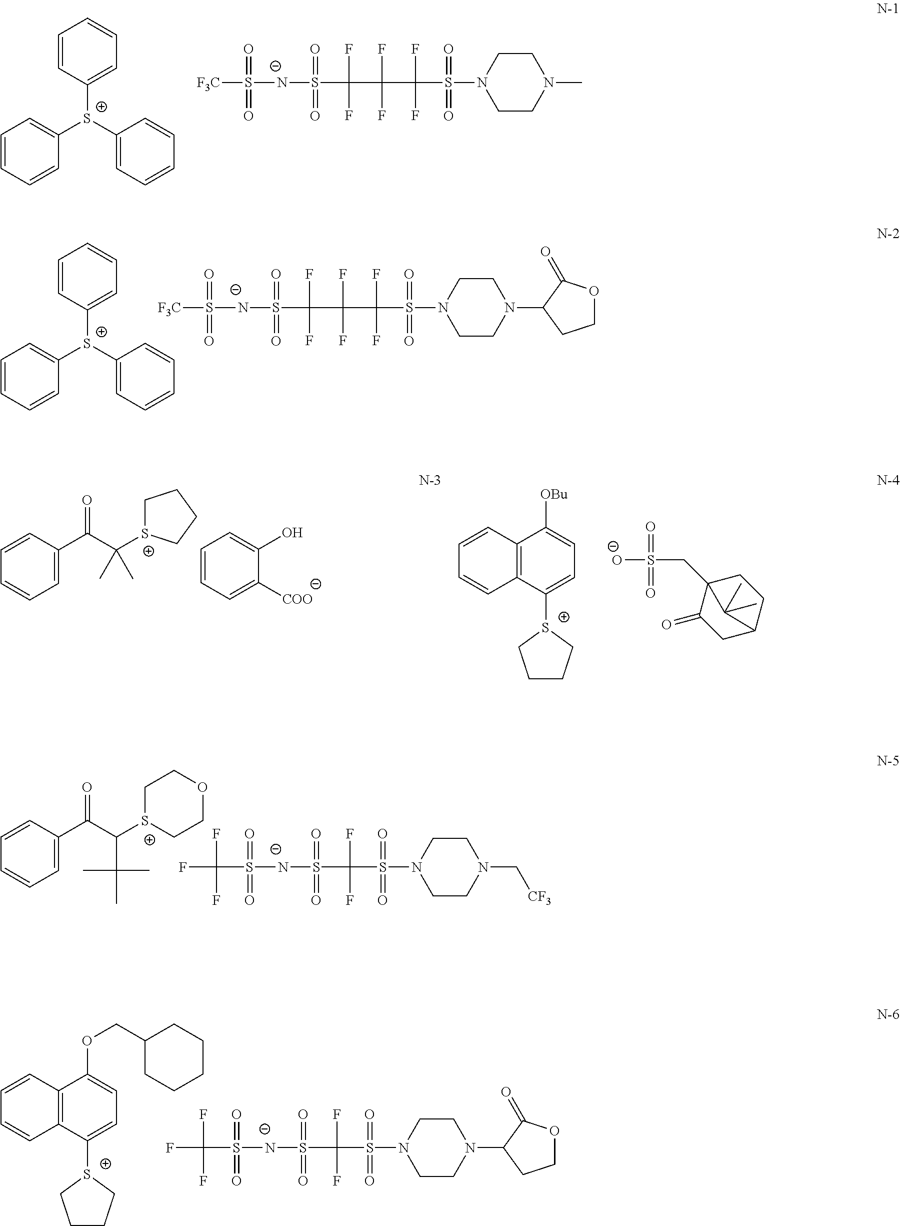

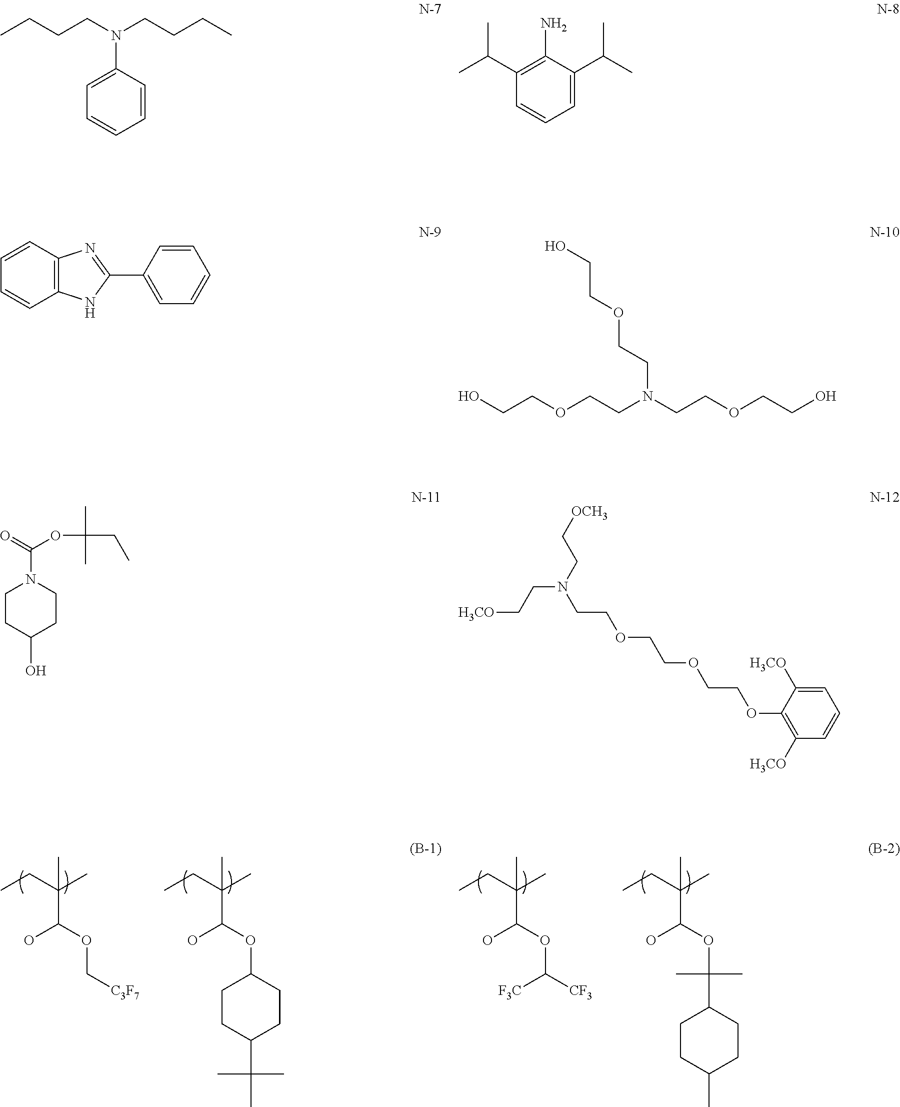

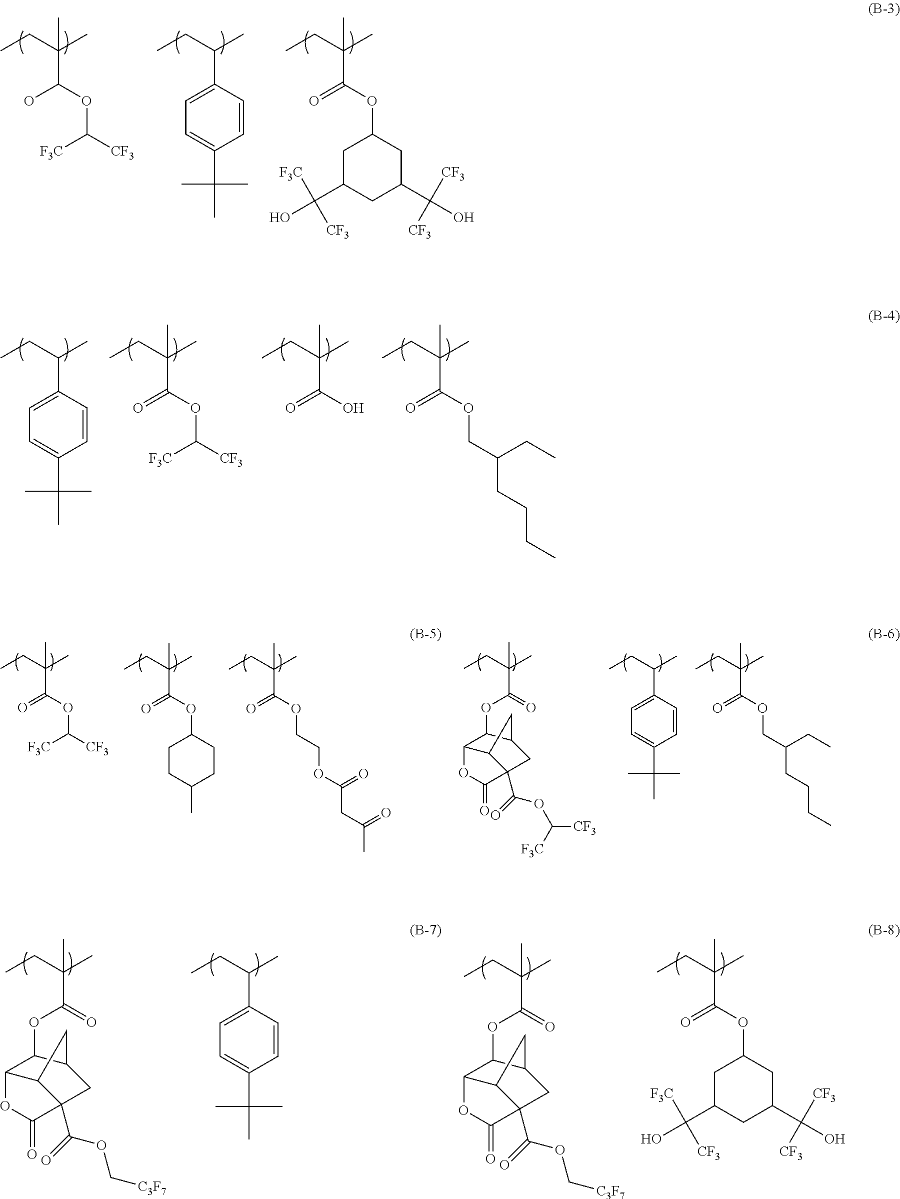

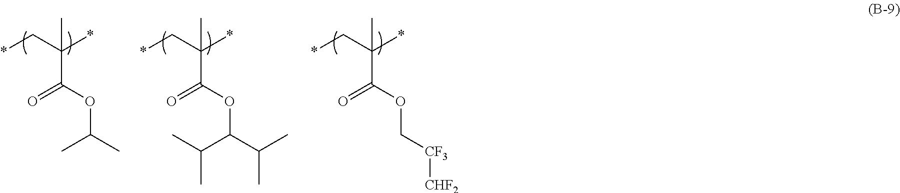

TABLE A

| Resin | Compositional ratio | Molecular weight | Dispersity |
|---|---|---|---|
| B-1 | 50/50 | 4800 | 1.4 |
| B-2 | 50/50 | 5100 | 2.1 |
| B-3 | 40/15/45 | 6100 | 1.8 |
| B-4 | 57/39/2/2 | 6000 | 1.6 |
| B-5 | 45/20/35 | 6600 | 1.6 |
| B-6 | 90/8/2 | 6500 | 1.5 |
| B-7 | 95/5 | 4900 | 1.8 |
| B-8 | 80/20 | 5200 | 1.9 |
| B-9 | 30/65/5 | 28000 | 1.6 |

In Table 3, the surfactants are each as follows.
W-1: PF6320 (fluorine-based, manufactured by OMNOVA)
W-2: Troysol S-366 (manufactured by Troy Chemical Corp.)
W-3: Polysiloxane polymer KP-341 (silicon-based, manufactured by Shin-Etsu Chemical Co., Ltd.)

In Table 3, the solvents are each as follows.
SL-1: Propylene glycol monomethyl ether acetate (PGMEA)
SL-2: Cyclohexanone
SL-3: Propylene glycol monomethyl ether (PGME)
SL-4: γ-Butyrolactone
SL-5: Propylene carbonate

Here, in the case where the examples denoted as “TC” in the column of “Addition mode” in Table 3 were used as the liquid immersion exposure, a resist film was formed using a composition for forming a resist film, containing no hydrophobic resin, and then a top coat (TC) containing a hydrophobic resin was formed thereon. A method for forming the top coat is as follows.

In Table 3, the solvents are each as follows.
SL-6: 2-Ethylbutanol
SL-7: Perfluorobutyl tetrahydrofuran

### Example 1

### Alkali Development, Immersion Exposure

A composition ARC29SR (manufactured by Nissan Chemical Industries, Ltd.) for forming an antireflection film was applied onto a silicon wafer (12-inch aperture), and baked at 205° C. for 60 seconds to form an antireflection film having a film thickness of 86 nm.

The material A7 for forming an adhesion aiding layer was dissolved in propylene glycol monomethyl ether acetate to prepare a 0.1%-by-mass solution, and the solution was filtered through a 0.1-μm tetrafluoroethylene filter to obtain a composition for forming an adhesion aiding layer.

The obtained composition for forming an adhesion aiding layer was spin-coated on the antireflection film as formed above, and the solvent was dried (at 100° C. for 1 minute) on a hot plate to form an adhesion aiding layer (layer thickness: 3 nm).

Furthermore, the composition AR-1 for forming a resist film was applied onto the formed adhesion aiding layer, and baked at 100° C. for 60 seconds to form a photosensitive film (resist film) having a film thickness of 75 nm. The obtained wafer was exposed using an ArF excimer laser liquid immersion scanner (manufactured by ASML, XT1700i, NA1.20, C-Quad, outer sigma 0.750, inner sigma 0.650, XY deflection) through a 6% half-tone mask having a 1:1 line-and-space pattern with a line width of 50 nm. Ultrapure water was used as the immersion liquid. Thereinafter, the film was heated at 120° C. for 60 seconds, then developed with an aqueous tetramethylammonium hydroxide (TMAH) solution (2.38% by mass) for 30 seconds, rinsed with pure water, and then spin-dried to obtain a pattern with 1:1 line-and-space having a line width of 50 nm.

### Examples 2 to 7 and Comparative Examples 1 and 2

### Alkali Development, Liquid Immersion Exposure

Patterns were obtained by the same procedure as in Example 1 except that the materials for forming an adhesion aiding layer and the compositions for forming a resist film, each shown in Table 4 below, were used instead of the material A7 for forming an adhesion aiding layer and the composition AR-1 for forming a resist film.

Incidentally, in the case where the antireflection film is described to be “Absent” in Table 4, an adhesion aiding layer was directly formed on a silicon wafer, while not forming an antireflection film.

Furthermore, in the case where a material for forming an adhesion aiding layer is described to be “Absent” in Table 4, a resist film was directly formed on a silicon wafer or an antireflection film, while not forming an adhesion aiding layer.

In addition, in the case of using the composition for forming a resist film with the addition mode being “TC” in Table 3, a resist film was formed using a composition for forming a resist film, containing no hydrophobic resin, and then a top coat (TC) containing a hydrophobic resin was formed thereon by the following procedure.

(Method for Forming Top Coat)

The hydrophobic resin shown in Table 3 was dissolved in a solvent (SL-6 or SL-7 as described above), and the obtained solution was applied onto the resist film using a spin coater. Thereinafter, the film was heated and dried at 115° C. for 60 seconds to form a top coat having a film thickness of 0.05 μm. After the formation, the top coat was observed for the application unevenness, and it was found that the top coat was uniformly applied.

<Collapse Performance>

For Examples 1 to 7 and Comparative Examples 1 and 2, when the exposure amount for resolving a line-and-space pattern having a line width of 50 nm was defined as an optimal exposure amount, the exposure amount was further increased from the optimal exposure amount, and the line width of the formed line pattern was made fine, the line width (nm) for resolution while not deteriorating the pattern was evaluated as “collapse performance”. The results are shown in Table 4 below. A smaller value indicates that a resolution is provided without deterioration of fine patterns, and that a fine pattern can be stably formed.

TABLE 4

| | | Material for | | | | | | |
|---|---|---|---|---|---|---|---|---|
| | | forming | | | | | | Test results |
| | Antireflection | adhesion | Composition for | | | | | Collapse |
| | film | aiding layer | forming resist film | Exposure | Development | | Rinsing | performance (nm) |
| Example 1 | Present | A7 | AR-1 | Liquid | Positive | 2.38% Aqueous | Pure water | 30.2 |
| | | | | immersion | | TMAH solution | | |
| Example 2 | Present | A7 | AR-2 | Liquid | Positive | 2.38% Aqueous | Pure water | 29.1 |
| | | | | immersion | | TMAH solution | | |
| Example 3 | Absent | A8 | AR-3 | Liquid | Positive | 2.38% Aqueous | Pure water | 31.9 |
| | | | | immersion | | TMAH solution | | |
| Example 4 | Present | A9 | AR-4 | Liquid | Positive | 2.38% Aqueous | Pure water | 33.3 |
| | | | | immersion | | TMAH solution | | |
| Example 5 | Present | A10 | AR-5 | Liquid | Positive | 2.38% Aqueous | Pure water | 30.5 |
| | | | | immersion | | TMAH solution | | |
| Example 6 | Present | A11 | AR-6 | Liquid | Positive | 2.38% Aqueous | Pure water | 32.4 |
| | | | | immersion | | TMAH solution | | |
| Example 7 | Present | A1 | AR-7 | Liquid | Positive | 2.38% Aqueous | Pure water | 28.9 |
| | | | | immersion | | TMAH solution | | |
| Comparative | Absent | Absent | AR-3 | Liquid | Positive | 2.38% Aqueous | Pure water | 39.5 |
| Example 1 | | | | immersion | | TMAH solution | | |
| Comparative | Present | Absent | AR-4 | Liquid | Positive | 2.38% Aqueous | Pure water | 37.9 |
| Example 2 | | | | immersion | | TMAH solution | | |

### Example 8

### Alkali Development, Dry Exposure

A composition ARC29A (manufactured by Nissan Chemical Industries, Ltd.) for forming an antireflection film was applied onto a silicon wafer (8-inch aperture), and baked at 205° C. for 60 seconds to form an antireflection film having a film thickness of 86 nm.

The material A8 for forming an adhesion aiding layer was dissolved in propylene glycol monomethyl ether acetate to prepare a 0.1%-by-mass solution, and the solution was filtered through a 0.1-μm tetrafluoroethylene filter to obtain a composition for forming an adhesion aiding layer.

The obtained composition for forming an adhesion aiding layer was spin-coated on the antireflection film as formed above, and the solvent was dried (at 100° C. for 1 minute) on a hot plate to form an adhesion aiding layer (layer thickness: 3 nm).

Furthermore, the composition AR-8 for forming a resist film was applied onto the formed adhesion aiding layer, and baked at 100° C. for 60 seconds to form a photosensitive film (resist film) having a film thickness of 75 nm.

The obtained wafer was exposed using an ArF excimer laser scanner (manufactured by ASML, PAS5500, NA0.75, Dipole, outer sigma 0.89, inner sigma 0.65) through a 6% half-tone mask having a 1:1 line-and-space pattern with a line width of 75 nm. Thereinafter, the film was heated at 100° C. for 60 seconds, then developed with an aqueous tetramethylammonium hydroxide solution (2.38% by mass) for 30 seconds, rinsed with pure water, and then spin-dried to obtain a pattern with 1:1 line-and-space having a line width of 75 nm.

### Examples 9 to 13 and Comparative Example 3

### Alkali Development, Dry Exposure

Patterns were obtained by the same procedure as in Example 8 except that the materials for forming an adhesion aiding layer and the compositions for forming a resist film, each shown in Table 5 below, were used instead of the material A8 for forming an adhesion aiding layer and the composition AR-8 for forming a resist film.

Incidentally, in the case where a material for forming an adhesion aiding layer is described to be “Absent” in Table 5, a resist film was directly formed on an antireflection film, while not forming an adhesion aiding layer.

<Collapse Performance>

For Examples 8 to 13 and Comparative Example 3, when the exposure amount for resolving a line-and-space pattern having a line width of 75 nm was defined as an optimal exposure amount, the exposure amount was further increased from the optimal exposure amount, and the line width of the formed line pattern was made fine, the line width (nm) for resolution while not deteriorating the pattern was evaluated as “collapse performance”. The results are shown in Table 5 below. A smaller value indicates that a resolution is provided without deterioration of fine patterns, and fine patterns can be stably formed.

TABLE 5

| | | Material for | | | | | | |
|---|---|---|---|---|---|---|---|---|
| | | Forming | Composition for | | | | | Test results |
| | Antireflection | Adhesion | Forming Resist | | | | | Collapse |
| | film | Aiding Layer | Film | Exposure | Development | | Rinsing | performance (nm) |
| Example 8 | Present | A8 | AR-8 | Dry | Positive | 2.38% Aqueous | Pure water | 35.4 |
| | | | | | | TMAH solution | | |
| Example 9 | Present | A12 | AR-9 | Dry | Positive | 2.38% Aqueous | Pure water | 36.5 |
| | | | | | | TMAH solution | | |
| Example 10 | Present | A13 | AR-10 | Dry | Positive | 2.38% Aqueous | Pure water | 38.1 |
| | | | | | | TMAH solution | | |
| Example 11 | Present | A2 | AR-11 | Dry | Positive | 2.38% Aqueous | Pure water | 37.4 |
| | | | | | | TMAH solution | | |
| Example 12 | Present | A3 | AR-12 | Dry | Positive | 2.38% Aqueous | Pure water | 37.0 |
| | | | | | | TMAH solution | | |
| Example 13 | Present | A4 | AR-13 | Dry | Positive | 2.38% Aqueous | Pure water | 35.9 |
| | | | | | | TMAH solution | | |
| Comparative | Present | Absent | AR-8 | Dry | Positive | 2.38% Aqueous | Pure water | 43.4 |
| Example 3 | | | | | | TMAH solution | | |

### Example 14

### Organic Solvent Development, Liquid Immersion Exposure

A composition ARC29SR (manufactured by Nissan Chemical Industries, Ltd.) for forming an antireflection film was applied onto a silicon wafer (12-inch aperture), and baked at 205° C. for 60 seconds to form an antireflection film having a film thickness of 86 nm.

The material A9 for forming an adhesion aiding layer was dissolved in propylene glycol monomethyl ether acetate to prepare a 0.1%-by-mass solution, and the solution was filtered through a 0.1-μm tetrafluoroethylene filter to obtain a composition for forming an adhesion aiding layer.

The obtained composition for forming an adhesion aiding layer was spin-coated on the antireflection film as formed above, and the solvent was dried (at 100° C. for 1 minute) on a hot plate to form an adhesion aiding layer (layer thickness: 3 nm).

Furthermore, the composition AR-14 for forming a resist film was applied onto the formed adhesion aiding layer, and baked at 100° C. for 60 seconds to form a resist film having a film thickness of 85 nm.

The obtained wafer was exposed using an ArF excimer laser liquid immersion scanner (manufactured by ASML, XT1700i, NA1.20, C-Quad, outer sigma 0.750, inner sigma 0.650, XY deflection) through a 6% half-tone mask having a 1:1 line-and-space pattern with a line width of 50 nm. Ultrapure water was used as the immersion liquid. Thereinafter, the film was heated at 120° C. for 60 seconds and then developed by paddling with butyl acetate for 30 seconds, and spin-dried by rotating the wafer at a rotational speed of 4000 rpm for 30 seconds to obtain a pattern with 1:1 line-and-space having a line width of 50 nm.

### Examples 15 to 18 and Comparative Example 4

### Organic Solvent Development, Liquid Immersion Exposure

Patterns were obtained by the same procedure as in Example 14 except that the materials for forming an adhesion aiding layer and the compositions for forming a resist film, each shown in Table 6 below, were used instead of the material A9 for forming an adhesion aiding layer and the composition AR-14 for forming a resist film.

Incidentally, in the case where a material for forming an adhesion aiding layer is described to be “Absent” in Table 6, a resist film was directly formed on an antireflection film, while not forming an adhesion aiding layer.

In addition, for Examples 16 and 18, the film was rinsed with MIBC (4-methyl-2-pentanol) after the development, and then spin-dried.

<Collapse Performance>

For Examples 14 to 18 and Comparative Example 4, when the exposure amount for resolving a line-and-space pattern having a line width of 50 nm was defined as an optimal exposure amount, the exposure amount was further increased from the optimal exposure amount, and the line width of the formed line pattern was made fine, the line width (nm) for resolution while not deteriorating the pattern was evaluated as “collapse performance”. The results are shown in Table 6 below. A smaller value indicates that a resolution is provided without deterioration of fine patterns, and fine patterns can be stably formed.

TABLE 6

| | | Material for | | | | | | |
|---|---|---|---|---|---|---|---|---|
| | | forming | | | | | | Test results |
| | Antireflection | adhesion | Composition for | | | | | Collapse |
| | film | aiding layer | forming resist film | Exposure | Development | | Rinsing | performance (nm) |
| Example 14 | Present | A9 | AR-14 | Liquid | Negative | Butyl | | 34.8 |
| | | | | immersion | | acetate | | |
| Example 15 | Present | A10 | AR-15 | Liquid | Negative | Butyl | | 36.8 |
| | | | | immersion | | acetate | | |
| Example 16 | Present | A11 | AR-16 | Liquid | Negative | Butyl | MIBC | 35.9 |
| | | | | immersion | | acetate | | |
| Example 17 | Present | A12 | AR-17 | Liquid | Negative | Butyl | | 37.0 |
| | | | | immersion | | acetate | | |
| Example 18 | Present | A5 | AR-18 | Liquid | Negative | Butyl | MIBC | 35.5 |
| | | | | immersion | | acetate | | |
| Comparative | Present | Absent | AR-14 | Liquid | Negative | Butyl | | 43.2 |
| Example 4 | | | | immersion | | acetate | | |

In Examples 14 to 18, the same evaluation was carried out except that 2% by mass of tri-n-octylamine was added to butyl acetate as the developing liquid, and good performance was also exhibited in this case.

### Example 19

### Organic Solvent Development, Dry Exposure

A composition ARC29A (manufactured by Nissan Chemical Industries, Ltd.) for forming an antireflection film was applied onto a silicon wafer (8-inch aperture), and baked at 205° C. for 60 seconds to form an antireflection film having a film thickness of 86 nm.

The material A7 for forming an adhesion aiding layer was dissolved in propylene glycol monomethyl ether acetate to prepare a 0.1%-by-mass solution, and the solution was filtered through a 0.1-μm tetrafluoroethylene filter to obtain a composition for forming an adhesion aiding layer.

The obtained composition for forming an adhesion aiding layer was spin-coated on the antireflection film as formed above, and the solvent was dried (at 100° C. for 1 minute) on a hot plate to form an adhesion aiding layer (layer thickness: 3 nm).

Furthermore, the composition AR-19 for forming a resist film was applied onto the formed adhesion aiding layer, and baked at 100° C. for 60 seconds to form a resist film having a film thickness of 75 nm.

The obtained wafer was exposed using an ArF excimer laser scanner (manufactured by ASML, PAS5500, NA0.75, Dipole, outer sigma 0.89, inner sigma 0.65) through a 6% half-tone mask having a 1:1 line-and-space pattern with a line width of 75 nm. Thereinafter, the film was heated at 100° C. for 60 seconds, then developed by paddling with butyl acetate for 30 seconds, rinsed with MIBC, and then spin-dried by rotating the wafer at a rotational speed of 4000 rpm for 30 seconds to obtain a pattern with 1:1 line-and-space having a line width of 75 nm.

### Examples 20 to 23 and Comparative Example 5

### Organic Solvent Development, Dry Exposure

Patterns were obtained by the same procedure as in Example 19 except that the materials for forming an adhesion aiding layer and the compositions for forming a resist film, each shown in Table 7 below, were used instead of the material A7 for forming an adhesion aiding layer and the composition AR-19 for forming a resist film.

Incidentally, in the case where a material for forming an adhesion aiding layer is described to be “Absent” in Table 7, a resist film was directly formed on an antireflection film, while not forming an adhesion aiding layer.

Further, in Examples 20, 21, and 23, rinsing was not carried out after the development.

<Collapse Performance>

For Examples 19 to 23 and Comparative Example 5, when the exposure amount for resolving a line-and-space pattern having a line width of 75 nm was defined as an optimal exposure amount, the exposure amount was further increased from the optimal exposure amount, and the line width of the formed line pattern was made fine, the line width (nm) for resolution while not deteriorating the pattern was evaluated as “collapse performance”. The results are shown in Table 7 below. A smaller value indicates that a resolution is provided without deterioration of fine patterns, and fine patterns can be stably formed.

TABLE 7

| | | Material for | | | | | | |
|---|---|---|---|---|---|---|---|---|
| | | forming | | | | | | Test results |
| | | adhesion | Composition for | | | | | Collapse |
| | Antireflection film | aiding layer | forming resist film | Exposure | Development | | Rinsing | performance (nm) |
| Example 19 | Present | A7 | AR-19 | Dry | Negative | Butyl | MIBC | 40.0 |
| | | | | | | acetate | | |
| Example 20 | Present | A8 | AR-20 | Dry | Negative | Butyl | | 39.9 |
| | | | | | | acetate | | |
| Example 21 | Present | A10 | AR-21 | Dry | Negative | Butyl | | 40.5 |
| | | | | | | acetate | | |
| Example 22 | Present | A12 | AR-22 | Dry | Negative | Butyl | MIBC | 41.0 |
| | | | | | | acetate | | |
| Example 23 | Present | A6 | AR-23 | Dry | Negative | Butyl | | 39.2 |
| | | | | | | acetate | | |
| Comparative | Present | Absent | AR-19 | Dry | Negative | Butyl | MIBC | 48.8 |
| Example 5 | | | | | | acetate | | |

### Example 24

### Double Development (Positive→Negative), Liquid Immersion Exposure

A composition ARC29SR (manufactured by Nissan Chemical Industries, Ltd.) for forming an antireflection film was applied onto a silicon wafer (12-inch aperture), and baked at 205° C. for 60 seconds to form an antireflection film having a film thickness of 98 nm on the silicon wafer.

The material A7 for forming an adhesion aiding layer was dissolved in propylene glycol monomethyl ether acetate to prepare a 0.1%-by-mass solution, and the solution was filtered through a 0.1-μm tetrafluoroethylene filter to obtain a composition for forming an adhesion aiding layer.

The obtained composition for forming an adhesion aiding layer was spin-coated on the antireflection film as formed above, and the solvent was dried (at 100° C. for 1 minute) on a hot plate to form an adhesion aiding layer (layer thickness: 3 nm).

Furthermore, the composition AR-24 for forming a resist film was applied onto the formed adhesion aiding layer, and baked at 90° C. for 60 seconds to form a resist film having a film thickness of 50 nm.

Thereinafter, the formed resist film was subjected to pattern exposure by an ArF excimer laser liquid immersion scanner (manufactured by ASML, XT1700i, NA1.20, C-Quad, outer sigma 0.960, inner sigma 0.709, XY deflection). Incidentally, a 6% half-tone mask of a line size of 60 nm and a line:space of 1:1 was used as a reticle. Further, ultrapure water was used as the immersion liquid.

Then, the film was baked (1^{st} PEB) (PEB: Post Exposure Bake) under the conditions of 90° C. and 60 seconds, and then cooled to room temperature. Thereinafter, the film was developed using an aqueous tetramethylammonium hydroxide solution (2.38% by mass) for 10 seconds, and rinsed with pure water for 30 seconds.

Then, the film was baked (2^{nd} PEB) under the conditions of 130° C. and 60 seconds, and then cooled to room temperature. Thereinafter, the film was developed using butyl acetate for 20 seconds and the wafer was rotated at a rotational speed of 4000 rpm for 30 seconds to obtain a pattern with a 30 nm line-and-space (1:1).

### Examples 25, 27, and 28, and Comparative Example 6

### Double Development (Positive→Negative), Liquid Immersion Exposure

Patterns were obtained by the same procedure as in Example 24 except that the materials for forming an adhesion aiding layer and the compositions for forming a resist film, each shown in Table 8 below, were used instead of the material A7 for forming an adhesion aiding layer and the composition AR-24 for forming a resist film, and the conditions for the 1^{st} PEB and the 2^{nd} PEB were changed to those shown in Table 8 below.

Incidentally, in the case where a material for forming an adhesion aiding layer is described to be “Absent” in Table 8, a resist film was directly formed on an antireflection film, while not forming an adhesion aiding layer.

In addition, in Examples 25 and 27, the film was rinsed with MIBC after the development using butyl acetate, and the wafer was rotated.

### Example 26

### Double Development (Negative→Positive), Liquid Immersion Exposure

By the same procedure as in Example 24 except that the material A10 for forming an adhesion aiding layer and the composition A-26 for forming a resist film were used, respectively, instead of the material A7 for forming an adhesion aiding layer and the composition AR-24 for forming a resist film, an antireflection film was formed on a silicon wafer, an adhesion aiding layer was formed on the formed antireflection film, a resist film was formed on the formed adhesion aiding layer, and the formed resist film was subjected to pattern exposure.

Then, the film was baked (1^{st} PEB) under the conditions of 100° C. and 60 seconds, and then cooled to room temperature. Thereinafter, the film was developed using butyl acetate for 20 seconds, and the wafer was rotated at a rotational speed of 4000 rpm for 30 seconds.

Then, the film was baked (2^{nd} PEB) under the conditions of 130° C. and 60 seconds, and then cooled to room temperature. Thereinafter, the film was developed using an aqueous tetramethylammonium hydroxide solution (2.38% by mass) for 10 seconds, and rinsed with pure water for 30 seconds to obtain a pattern with a 40 nm line-and-space (1:1).

<Pattern Observation>

For Examples 24 to 28 and Comparative Example 6, the patterns were observed by a length-measuring scanning electron microscope (SEM S-9380II manufactured by Hitachi, Ltd.), and subjected to 2-stage evaluation as follows (A and B). The results are shown in Table 8 below. For a practical use, A is preferred.

A: A case where a pattern with a line-and-space is formed without disconnection or collapse.

B: A case where a pattern with a line-and-space is formed but disconnection or collapse is observed. Alternatively, a case where the resist film is totally dissolved or falling, and thus, a pattern is not formed.

The “C” in the columns of “1^{st} PEB” and “2^{nd} PEB” in Table 8 below denotes “° C. (degrees)”.

The column of Rinsing in Table 8 below denotes the rinsing after the organic solvent development. Specifically, the “MIBC” shown in the column of Rinsing denotes rinsing with “4-methyl-2-pentanol (MIBC)” after the organic solvent development.

TABLE 8

| | | Adhesion | Composition | | | | |
|---|---|---|---|---|---|---|---|
| | Antireflection | aiding | for forming | | | | |
| | film | layer | resist film | Exposure | 1^{st} PEB | 1^{st} Development | |
| Example 24 | Present | A7 | AR-24 | Liquid | 90 C./60 s | Positive | 2.38% Aqueous |
| | | | | immersion | | | TMAH solution |
| Example 25 | Present | A9 | AR-25 | Liquid | 90 C./60 s | Positive | 2.38% Aqueous |
| | | | | immersion | | | TMAH solution |
| Example 26 | Present | A10 | AR-26 | Liquid | 100 C./60 s | Negative | Butyl acetate |
| | | | | immersion | | | |
| Example 27 | Present | A2 | AR-27 | Liquid | 95 C./60 s | Positive | 2.38% Aqueous |
| | | | | immersion | | | TMAH solution |
| Example 28 | Present | A3 | AR-28 | Liquid | 95 C./60 s | Positive | 2.38% Aqueous |
| | | | | immersion | | | TMAH solution |
| Comparative | Present | Absent | AR-24 | Liquid | 90 C./60 s | Positive | 2.38% Aqueous |
| Example 6 | | | | immersion | | | TMAH solution |

| | | | | | Test results |
|---|---|---|---|---|---|
| | | | | | Pattern |
| | 2^{nd} PEB | 2^{nd} Development | | Rinsing | observation |
| Example 24 | 130 C./60 s | Negative | Butyl | | A |
| | | | acetate | | |
| Example 25 | 140 C./60 s | Negative | Butyl | MIBC | A |
| | | | acetate | | |
| Example 26 | 130 C./60 s | Positive | 2.38% | | A |
| | | | aqueous | | |
| | | | TMAH | | |
| | | | solution | | |
| Example 27 | 150 C./60 s | Negative | Butyl | MIBC | A |
| | | | acetate | | |
| Example 28 | 140 C./60 s | Negative | Butyl | | A |
| | | | acetate | | |
| Comparative | 130 C./60 s | Negative | Butyl | | B |
| Example 6 | | | acetate | | |

### Example 29

### Double Development (Positive→Negative), Dry Exposure

A composition ARC29A (manufactured by Nissan Chemical Industries, Ltd.) for forming an antireflection film was applied onto a silicon wafer (8-inch aperture), and baked at 205° C. for 60 seconds to form an antireflection film having a film thickness of 86 nm.

The material A8 for forming an adhesion aiding layer was dissolved in propylene glycol monomethyl ether acetate to prepare a 0.1%-by-mass solution, and the solution was filtered through a 0.1-μm tetrafluoroethylene filter to obtain a composition for forming an adhesion aiding layer.

The obtained composition for forming an adhesion aiding layer was spin-coated on the antireflection film as formed above, and the solvent was dried (at 100° C. for 1 minute) on a hot plate to form an adhesion aiding layer (layer thickness: 3 nm).

Furthermore, the composition AR-29 for forming a resist film was applied onto the formed adhesion aiding layer, and baked at 100° C. for 60 seconds to form a resist film having a film thickness of 50 nm.

Thereinafter, the formed resist film was subjected to exposure by an ArF excimer laser scanner (manufactured by ASML, PAS5500, NA0.75, Annular, outer sigma 0.89, inner sigma 0.65) through a mask having a 1:1 line-and-space pattern with a line width of 80 nm.

Then, the film was baked (1^{st} PEB) under the conditions of 95° C. and 60 seconds, and then cooled to room temperature. Thereinafter, the film was developed using an aqueous tetramethylammonium hydroxide solution (2.38% by mass) for 10 seconds, and rinsed with pure water for 30 seconds.

Then, the film was baked (2^{nd} PEB) under the conditions of 150° C. and 60 seconds, and then cooled to room temperature. Thereinafter, the film was developed using butyl acetate for 20 seconds and rinsed with MIBC, and then the wafer was rotated at a rotational speed of 4000 rpm for 30 seconds to obtain a pattern with a 40 nm line-and-space (1:1).

### Examples 30, 32, and 33, and Comparative Example 7

### Double Development (Positive→Negative), Dry Exposure

Patterns were obtained by the same procedure as in Example 29 except that the materials for forming an adhesion aiding layer and the compositions for forming a resist film, each shown in Table 9 below, were used instead of the material A8 for forming an adhesion aiding layer and the composition AR-29 for forming a resist film, and the conditions for the 1^{st} PEB and the 2^{nd} PEB were changed to those shown in Table 9 below.

Incidentally, in the case where a material for forming an adhesion aiding layer is described to be “Absent” in Table 9, a resist film was directly formed on an antireflection film, while not forming an adhesion aiding layer.

In addition, in Examples 30 and 33, rinsing was not carried out after the development.

### Example 31

### Double Development (Negative Positive), Dry Exposure

By the same procedure as in Example 29 except that the material A11 for forming an adhesion aiding layer and the composition A-31 for forming a resist film were used, respectively, instead of the material A8 for forming an adhesion aiding layer and the composition AR-29 for forming a resist film, an antireflection film was formed on a silicon wafer, an adhesion aiding layer was formed on the formed antireflection film, a resist film was formed on the formed adhesion aiding layer, and the formed resist film was subjected to pattern exposure.

Then, the film was baked (1^{st} PEB) under the conditions of 100° C. and 60 seconds, and then cooled to room temperature. Thereinafter, the film was developed using butyl acetate for 20 seconds, and the wafer was rotated at a rotational speed of 4000 rpm for 30 seconds.

Then, the film was baked (2^{nd} PEB) under the conditions of 130° C. and 60 seconds, and then cooled to room temperature. Thereinafter, the film was developed using an aqueous tetramethylammonium hydroxide solution (2.38% by mass) for 10 seconds, and rinsed with pure water for 30 seconds to obtain a pattern with a 40 nm line-and-space (1:1).

<Pattern Observation>

For Examples 29 to 33 and Comparative Example 7, the patterns were observed by the same procedure as the pattern observation as described above, and subjected to 2-stage evaluation as follows (A and B). The results are shown in Table 9 below. For a practical use, A is preferred.

The “C” in the columns of “1^{st} PEB” and “2^{nd} PEB” in Table 9 below denotes “° C. (degrees)”.

Further, the column of Rinsing in Table 9 below denotes the rinsing after the organic solvent development. Specifically, the “MIBC” shown in the column of Rinsing denotes rinsing with “4-methyl-2-pentanol (MIBC)” after the organic solvent development.

TABLE 9

| | | Adhesion | Composition | | | | |
|---|---|---|---|---|---|---|---|
| | Antireflection | aiding | for Forming | | | | |
| | film | layer | Resist Film | Exposure | 1^{st} PEB | 1^{st} Development | |
| Example 29 | Present | A8 | AR-29 | Dry | 95 C./60 s | Positive | 2.38% Aqueous |
| | | | | | | | TMAH solution |
| Example 30 | Present | A9 | AR-30 | Dry | 105 C./60 s | Positive | 2.38% Aqueous |
| | | | | | | | TMAH solution |
| Example 31 | Present | A11 | AR-31 | Dry | 100 C./60 s | Negative | Butyl acetate |
| Example 32 | Present | A12 | AR-32 | Dry | 90 C./60 s | Positive | 2.38% Aqueous |
| | | | | | | | TMAH solution |
| Example 33 | Present | A13 | AR-33 | Dry | 90 C./60 s | Positive | 2.38% Aqueous |
| | | | | | | | TMAH solution |
| Comparative | Present | Absent | AR-29 | Dry | 95 C./60 s | Positive | 2.38% Aqueous |
| Example 7 | | | | | | | TMAH solution |

| | | | | | Test results |
|---|---|---|---|---|---|
| | | | | | Pattern |
| | 2^{nd} PEB | 2^{nd} Development | | Rinsing | observation |
| Example 29 | 150 C./60 s | Negative | Butyl | MIBC | A |
| | | | acetate | | |
| Example 30 | 140 C./60 s | Negative | Butyl | | A |
| | | | acetate | | |
| Example 31 | 130 C./60 s | Positive | 2.38% | | A |
| | | | aqueous | | |
| | | | TMAH | | |
| | | | solution | | |
| Example 32 | 130 C./60 s | Negative | Butyl | MIBC | A |
| | | | acetate | | |
| Example 33 | 130 C./60 s | Negative | Butyl | | A |
| | | | acetate | | |
| Comparative | 150 C./60 s | Negative | Butyl | MIBC | B |
| Example 7 | | | acetate | | |

As seen from Tables 4 to 9, the patterns formed by the methods of Comparative Examples 1 to 7 in which the adhesion aiding layers were not formed had occurrence of the collapse or peeling of pattern when the patterns which were fine and have high aspect ratios were formed.

On the other hand, the patterns formed by the methods of Examples of the present application in which the adhesion aiding layers were formed had inhibited the collapse or peeling of pattern when the patterns which were fine and have high aspect ratios were formed.

In particular, in the double development, the chemical states and properties of the patterns differ on the left and right sides of the line patterns due to combination of the alkali development and the organic solvent development, resulting in potential distortion of the patterns, and thus, there is a concern about the collapse of the patterns. However, it was found that the pattern forming method of the present invention inhibited such collapse.

### Example 34

Patterns were formed and evaluated by the same procedure as in Example 19 except that the composition 1-8 for forming a resist film shown in Table 10 below was used instead of the composition AR-19 for forming a resist film, and exposure by EUV light (wavelength: 13.5 nm) was carried out instead of exposure by an ArF excimer laser. As a result, the effectiveness of the present approach could also be confirmed in EUV lithography exhibiting good performance as in Example 19 and targeting a resolution of a line-and-space pattern with a line width in the order of 20 nm or less.

### Example 35

Patterns were formed and evaluated by the same procedure as in Example 19 except that the composition 1-9 for forming a resist film shown in Table 10 below was used instead of the composition AR-19 for forming a resist film, and exposure by EUV light (wavelength: 13.5 nm) was carried out instead of exposure by an ArF excimer laser. As a result, the effectiveness of the present approach could also be confirmed in EUV lithography which is good as in Example 19 and targets a resolution of a line-and-space pattern with a line width in the order of 20 nm or less.

TABLE 10

| Composition | Composition | | | | |
|---|---|---|---|---|---|
| for | | Acid | Basic | | |
| forming | Resin (A) | generator | compound | Surfactant | |
| resist | (blending | (blending | (blending | (blending | |
| film | amount) | amount) | amount) | amount) | Solvent |
| I-8 | R-1 | z2-1 | N-6 | W-1 | SL-1/SL-3 |
| | (10 g) | (3 g) | (0.90 g) | (0.003 g) | |
| I-9 | R-2 | z2-2 | N-10 | W-1 | SL-1/SL-3 |
| | (10 g) | (3 g) | (0.90 g) | (0.003 g) | |

The compositions 1-8 and 1-9 for forming a resist film shown in Table 10 were each obtained by dissolving the components shown in Table 10 in a solvent (SL-1/SL3=60/40 (mass ratio)), and the obtained solutions were filtered through a polyethylene filter having a pore size of 0.03 μm.

In Table 10, the specific structures of the resin (A) and the acid generator are as follows.

In Table 10, the basic compounds (N-6, N-10), the surfactant (W-1), and the solvents (SL-1, SL-3) are the same as described above.

In Table 10, the values in the parenthesis represent the blending amounts (g) of the respective components.

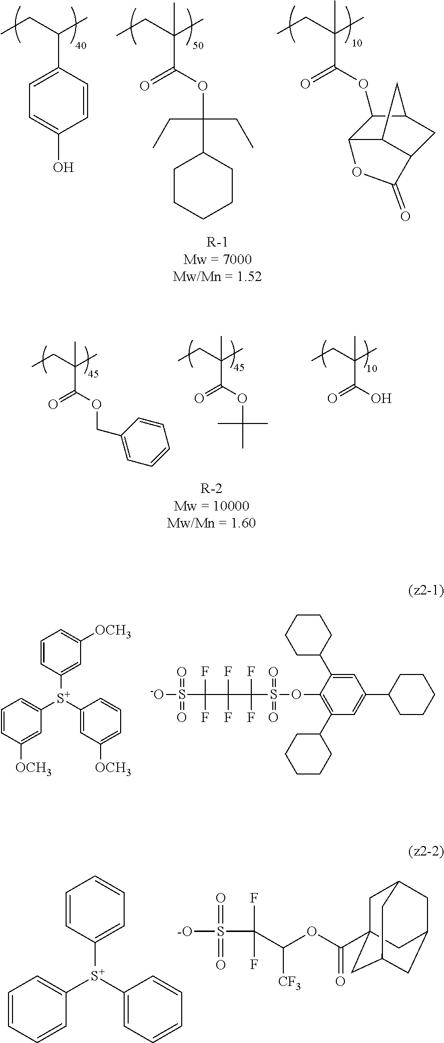

What is claimed is:

1. A pattern forming method comprising:
an adhesion aiding layer forming step of forming an adhesion aiding layer containing a polymerizable group and having a light transmittance of 80% or more at a wavelength of 193 nm on a substrate;
a resist film forming step of applying a radiation-sensitive resin composition onto the adhesion aiding layer to form a resist film;
an exposing step of exposing the resist film; and
a developing step of developing the exposed resist film to form a pattern.

2. The pattern forming method according to claim 1, further comprising an antireflection film forming step of forming an antireflection film on the substrate before the adhesion aiding layer forming step, wherein
the adhesion aiding layer forming step is a step of forming the adhesion aiding layer on the antireflection film.

3. The pattern forming method according to claim 1, wherein the developing step comprises a step of carrying out development using a developing liquid containing an organic solvent.

4. The pattern forming method according to claim 3, wherein the developing step further comprises a step of carrying out development using an aqueous alkali solution.

5. The pattern forming method according to claim 1, wherein the thickness of the adhesion aiding layer is from 1 nm to 10 nm.

6. The pattern forming method according to claim 1, wherein the exposing step is a step of exposing the resist film through an immersion liquid.

7. A method for manufacturing an electronic device, comprising the pattern forming method according to claim 1.

8. The pattern forming method according to claim 2, wherein the developing step comprises a step of carrying out development using a developing liquid containing an organic solvent.

9. The pattern forming method according to claim 2, wherein the thickness of the adhesion aiding layer is from 1 nm to 10 nm.

10. The pattern forming method according to claim 2, wherein the exposing step is a step of exposing the resist film through an immersion liquid.

11. A method for manufacturing an electronic device, comprising the pattern forming method according to claim 2.

12. The pattern forming method according to claim 3, wherein the thickness of the adhesion aiding layer is from 1 nm to 10 nm.

13. The pattern forming method according to claim 3, wherein the exposing step is a step of exposing the resist film through an immersion liquid.

14. A method for manufacturing an electronic device, comprising the pattern forming method according to claim 3.

15. The pattern forming method according to claim 4, wherein the thickness of the adhesion aiding layer is from 1 nm to 10 nm.

16. The pattern forming method according to claim 4, wherein the exposing step is a step of exposing the resist film through an immersion liquid.

17. A method for manufacturing an electronic device, comprising the pattern forming method according to claim 4.

18. The pattern forming method according to claim 5, wherein the exposing step is a step of exposing the resist film through an immersion liquid.

19. A method for manufacturing an electronic device, comprising the pattern forming method according to claim 5.

20. A method for manufacturing an electronic device, comprising the pattern forming method according to claim 6.
